(19) United States
(12) Patent Application Publication
(10) Pub. No.: US 2017/0121437 A1
(43) Pub. Date: May 4, 2017

(54) PATTERN FORMING METHOD, METHOD FOR MANUFACTURING ELECTRONIC DEVICE, ELECTRONIC DEVICE, ACTIVE-LIGHT-SENSITIVE OR RADIATION-SENSITIVE RESIN COMPOSITION, RESIST FILM AND MASK BLANK

(71) Applicant: FUJIFILM Corporation, Tokyo (JP)

(72) Inventor: Tomotaka TSUCHIMURA, Haibara-gun (JP)

(73) Assignee: FUJIFILM Corporation, Tokyo (JP)

(21) Appl. No.: 15/405,527

(22) Filed: Jan. 13, 2017

Related U.S. Application Data
(63) Continuation of application No. PCT/JP2015/064462, filed on May 20, 2015.

(30) Foreign Application Priority Data
Aug. 1, 2014 (JP) 2014-157599

(51) Int. Cl. C08F 212/14; C08F 220/68; C08F 220/18; G03F 7/004; G03F 7/038; G03F 7/38; G03F 7/32; G03F 7/40; G03F 7/039; G03F 7/20; G03F 7/16

(52) U.S. Cl. CPC C08F 212/14; G03F 7/2004; G03F 7/2037; C08F 220/68; C08F 220/18; G03F 7/0045; G03F 7/162; G03F 7/168; G03F 7/38; G03F 7/32; G03F 7/40; G03F 7/039; G03F 7/038

(57) ABSTRACT

A pattern forming method includes forming a film using an actinic ray-sensitive or radiation-sensitive resin composition, exposing the film with active light or radiation, and developing the exposed film using a developer including an organic solvent, in which the actinic ray-sensitive or radiation-sensitive resin composition contains a compound having a partial structure represented by General Formula (I).

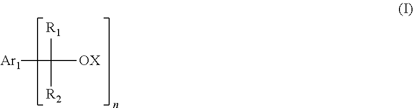

### CROSS-REFERENCE TO RELATED APPLICATIONS

This application is a Continuation of PCT International Application No. PCT/JP2015/64462, filed on May 20, 2015, which claims priority under 35 U.S.C. §119(a) to Japanese Patent Application No. 2014-157599, filed on Aug. 1, 2014. Each of the above application(s) is hereby expressly incorporated by reference, in its entirety, into the present application.

### BACKGROUND OF THE INVENTION

1. Field of the Invention

The present invention relates to a pattern forming method using a developer including an organic solvent, which is appropriately used in an ultramicrolithography process for the manufacture of a super-LSI or a high-capacity microchip, or the like, or other photofabrication processes; a method for manufacturing an electronic device; and an electronic device. More specifically, the present invention relates to a pattern forming method using a developer including an organic solvent, which can be appropriately used in fine processing of semiconductor elements using electron beams or EUV light (a wavelength: around 13 nm); a method for manufacturing an electronic device; and an electronic device. In addition, the present invention also relates to an actinic ray-sensitive or radiation-sensitive resin composition with which a pattern with high accuracy can be formed using electron beams or extreme ultraviolet rays; and a resist film and a mask blank, each using the composition.

2. Description of the Related Art

In the related art, fine processing by lithography using a photoresist composition has been performed in processes for manufacturing semiconductor devices such as an IC and an LSI.

For example, JP2013-164588A discloses a chemical amplification negative type resist composition which includes a polymer including a repeating unit represented by the following General Formula (1), and the like, and can realize high resolution. More specifically, JP2013-164588A discloses an aspect in which a resist film is formed using this chemical amplification negative type resist composition, subjected to pattern irradiation, and then developed using an alkaline developer to obtain a resist pattern.

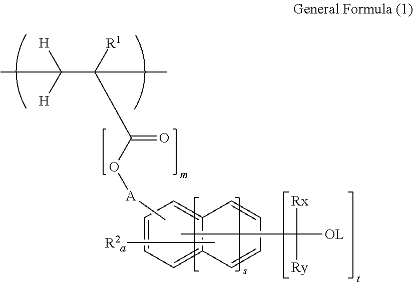

### SUMMARY OF THE INVENTION

On the other hand, there has recently been a demand for forming a fine pattern with higher accuracy (high resolution) as high integration of an integrated circuit is further enhanced.

The present inventors had conducted formation of a resist pattern by means of a developing treatment by an alkaline developer, using the chemical amplification negative type resist composition which is specifically described in JP2013-164588A, and thus, have found that the resolution of the obtained pattern does not necessarily reach a level that is currently required, and an additional improvement thereof is required.

In consideration of these situations, the present invention has an object to provide a pattern forming method by which a pattern satisfying high resolution can be formed.

Furthermore, the present invention has other objects to provide a method for manufacturing an electronic device, an electronic device, an actinic ray-sensitive or radiation-sensitive resin composition, a resist film, and a mask blank.

The present inventors have conducted extensive studies on the problems in the related art, and as a result, they have found that the objects can be accomplished by the following configurations.

(1) A pattern forming method comprising:

forming a film using an actinic ray-sensitive or radiation-sensitive resin composition,

exposing the film with active light or radiation, and

developing the exposed film using a developer including an organic solvent,

in which the actinic ray-sensitive or radiation-sensitive resin composition contains a compound having a partial structure represented by General Formula (I) which will be described later.

(2) The pattern forming method as described in (1), in which the compound is a resin having a partial structure represented by General Formula (I) which will be described later and a repeating unit represented by General Formula (II) which will be described later.

(3) The pattern forming method as described in (2), in which the compound is a resin containing a repeating unit represented by General Formula (II) which will be described later and a repeating unit represented by General Formula (III) which will be described later.

(4) The pattern forming method as described in (3), in which the compound is a resin having a repeating unit represented by any one of General Formulae (IVa) to (IVc) which will be described later, a repeating unit represented by General Formula (II) which will be described later, and a repeating unit represented by General Formula (III) which will be described later.

(5) The pattern forming method as described in any one of (1) to (4), in which the actinic ray-sensitive or radiation-sensitive resin composition further comprises a compound that generates an acid by active light or radiation.

(6) The pattern forming method as described in (5), in which the compound that generates an acid by active light or radiation is a compound that generates an acid in a size for a volume of 240 Angstrom³ or more.

(7) The pattern forming method as described in any one of (1) to (6), which uses electron beams or extreme ultraviolet rays as the active light or radiation.

(8) A method for manufacturing an electronic device, comprising the pattern forming method as described in any one of (1) to (7).

(9) An electronic device manufactured by the method for manufacturing an electronic device as described in (8).

(10) An actinic ray-sensitive or radiation-sensitive resin composition comprising a resin that contains a repeating unit represented by General Formula (II) which will be described later, a repeating unit represented by General Formula (III) which will be described later, and a repeating unit having a group that decomposes by the action of an acid to generate a polar group.

(11) The actinic ray-sensitive or radiation-sensitive resin composition as described in (10), in which the repeating unit having a group that decomposes by the action of an acid to generate a polar group includes a repeating unit represented by any one of General Formulae (IVa) to (IVc) which will be described later.

(12) A resist film formed by using the actinic ray-sensitive or radiation-sensitive resin composition as described in (10) or (11).

(13) A mask blank comprising the resist film as described in (12).

According to the present invention, it is possible to provide a pattern forming method by which a pattern satisfying high resolution can be formed.

Furthermore, according to the present invention, it is also possible to provide a method for manufacturing an electronic device, an electronic device, an actinic ray-sensitive or radiation-sensitive resin composition, a resist film, and a mask blank.

### DESCRIPTION OF THE PREFERRED EMBODIMENTS

Hereinafter, embodiments of the present invention will be described in detail.

In citations for group (atomic groups) in the present specification, in a case where a group is denoted without specifying whether it is substituted or unsubstituted, the group includes both a group not having a substituent and a group having a substituent. For example, an “alkyl group” includes not only an alkyl group not having a substituent (unsubstituted alkyl group), but also an alkyl group having a substituent (substituted alkyl group).

“Active light” or “radiation” in the present specification means, for example, a bright line spectrum of a mercury lamp, far ultraviolet rays represented by an excimer laser, extreme ultraviolet rays (EUV light), X-rays, electron beams (EB), or the like. In addition, in the present specification, light means active light or radiation.

In addition, unless otherwise specified, “exposure” in the present specification includes not only exposure by a mercury lamp, far ultraviolet rays represented by an excimer laser, extreme ultraviolet rays (EUV light), X-rays, or the like, but also writing by particle rays such as electron beams and ion beams.

As one of the characteristics of one embodiment of the present invention, it could be mentioned that an actinic ray-sensitive or radiation-sensitive resin composition including a predetermined compound is employed, and also, a developer including an organic solvent is used.

The present inventors have investigated the problems in the related art, and have found that in a case of using an alkaline developer, a resist pattern formed during a developing treatment is swollen, and as a result, the resolution of the formed resist pattern is reduced. The present inventors have conducted investigations based on the findings, and have found that by using a developer including an organic solvent, the swelling of the resist pattern is suppressed, and as a result, desired effects are obtained.

In addition, it was found that in a case of using an actinic ray-sensitive or radiation-sensitive resin composition containing a resin including a repeating unit having a group that decomposes by the action of an acid to generate a polar group, as described later, the resolution of the formed pattern becomes more excellent. The reason therefor is considered to be that an exposed area becomes more hydrophilic by a polar group that is generated in the exposed area, and thus, it is difficult for the exposed area (insoluble area) to be swollen by a developer including an organic solvent.

The pattern forming method of the present invention has at least a step of forming a film using an actinic ray-sensitive or radiation-sensitive resin composition including a predetermined compound (film forming step), a step of exposing the film with active light or radiation (exposing step), and a step of developing the exposed film using a developer including an organic solvent (hereinafter also referred to as an “organic developer,” if necessary) (developing step).

Hereinafter, the materials and the procedures used in the respective steps will be described in detail.

<Film Forming Step>

The film forming step is a step of forming a film (hereinafter also referred to as a resist film), using an actinic ray-sensitive or radiation-sensitive resin composition (hereinafter also simply referred to as a “composition”) including a predetermined compound.

First, the procedure in the present step will be described in detail, and with respect to the compositions used in the present step, the procedures of the respective steps are described and then the details thereof will described in the following section.

A method for forming the film using the composition is not particularly limited, but an aspect in which the composition is coated on a substrate to form a film is preferable, in view that it is easy to adjust the thickness of the film.

The coating method is not particularly limited, but a known method can be adopted and used. Examples of the method include spin coating, roll coating, flow coating, dip coating, spray coating, and doctor coating, and among these, spin coating is preferably used in a semiconductor manufacturing field. In a case of the spin coating, the rotation speed is preferably 1,000 to 3,000 rpm.

Furthermore, after coating the composition, a drying treatment for removing the solvent may also be carried out, if necessary. The method for the drying treatment is not particularly limited, and examples thereof include a heating treatment and an air-drying treatment. The conditions for the heating treatment include drying at 60° C. to 150° C. for 1 to 20 minutes, and preferably drying at 80° C. to 120° C. for 1 to 10 minutes.

The thickness of the film is not particularly limited, but for a reason that a fine pattern with higher accuracy can be formed, the thickness is preferably 1 to 500 nm, and more preferably 10 to 100 nm.

The substrate that is used for forming the film in the present step is not particularly limited. As the substrate, a substrate which is generally used for a process for manufacturing a semiconductor such as an IC, a process for manufacturing a circuit board for a liquid crystal, a thermal head, or the like, and other lithographic processes for photofabrication can be used. Examples of such a substrate include inorganic substrates such as silicon, SiO₂, and SiN, and coated inorganic substrates such as Silicon On Glass (SOG). Further, an organic antireflection film may be formed between the film and the substrate, if necessary.

After film formation and before an exposing step which will be described later, a prebake (PB) step is also preferably included. In addition, after the exposing step and before a developing step, a post exposure bake (PEB) step is also preferably included.

Both the PB step and the PEB step are preferably carried out at a heating temperature of 40° C. to 130° C., more preferably 50° C. to 120° C., and still more preferably 60° C. to 110° C. In particular, in a case where the PEB step is carried out at a low temperature of 60° C. to 90° C., exposure latitude (EL) and resolving power can be significantly improved.

Furthermore, the heating time is preferably 30 to 300 seconds, more preferably 30 to 180 seconds, and still more preferably 30 to 90 seconds.

<Exposing Step>

The exposing step is a step of exposing the film obtained in the film forming step with active light or radiation. More specifically, the step is a step of selectively exposing the film so as to form a desired pattern. Thus, the film is patternwise exposed, and the film undergoes a change in solubility only in the exposed area, and thus, becomes insoluble in an organic developer which will be described later.

The definitions of active light and radiation are as described above, and among these, as the light used for exposure, extreme ultraviolet rays (EUV light) or electron beams (EB) are preferable.

The method for selectively exposing the film is not particularly limited, and a known method can be used. For example, a binary mask having a transmittance of a light-shielding portion is 0% or a halftone-type phase shift mask (HT-mask) having a transmittance of a light-shielding portion is 6% can be used.

As the binary mask, ones having a chromium film, a chromium oxide film, or the like as a light-shielding portion formed on a quartz glass substrate are generally used.

As the halftone-type phase shift mask, ones having a silicide molybdenum (MoSi) film, a chromium film, a chromium oxide film, a silicon oxynitride film, or the like as a light-shielding portion formed on a quartz glass substrate are generally used.

In addition, in the present invention, the exposure is not limited to exposure which is carried out through a photo mask, and selective exposure (pattern exposure) may also be carried out by, for example, writing using electron beams or the like.

The present step may include exposure in plural times.

(Suitable Aspects: Liquid Immersion Exposure)

Suitable aspects of exposure include liquid immersion exposure. By using the liquid immersion exposure, a finer pattern can be formed. Furthermore, the liquid immersion exposure is an exposure that is carried out by filling a liquid (immersion liquid) having a higher refractive index than that of air between the film and a lens, and can be combined with, for example, super-resolution technology such as a phase shift method and a modified illumination method.

As the immersion liquid used, any liquid having a higher refractive index than that of air can be used, and is preferably pure water. Further, regarding the immersion liquid used during the liquid immersion exposure, reference can be made to the description in paragraphs 0059 and 0060 of JP2013-76991A, the contents which are incorporated in the present specification.

In order not to make the film in direct contact with the immersion liquid, a film (hereinafter also referred to as an “overcoat”) having poor solubility in an immersion liquid may be provide between the film and the immersion liquid. The function required for the overcoat may be coating suitability and poor solubility in an immersion liquid. The overcoat is preferably one that is not mixed with a film and can be uniformly coated on the upper layer of the film.

The overcoat is not particularly limited, and an overcoat known in the related art can be formed according to a method known in the related art, and for example, an overcoat can be formed, based on the description in paragraphs <0072> to <0082> of JP2014-059543A.

Furthermore, for example, an overcoat containing a basic compound as described in JP2013-61648A is preferably formed on a resist film.

<Developing Step>

The developing step is a step of forming the film exposed in the exposing step, using an organic developer. In the present step, a region having a small exposure dose (preferably an unexposed region) is dissolved by a developer, and a so-called negative type pattern is formed.

Hereinafter, the developer used in the present step will be described in detail, and then the procedure of the present step will be described in detail.

Examples of the organic developer include developers including polar solvents such as a ketone-based solvent, an ester-based solvent, an alcohol-based solvent, an amide-based solvent, and an ether-based solvent, and a hydrocarbon-based solvent. Further, a mixed solvent thereof may also be used.

Examples of the ketone-based solvent include 1-octanone, 2-octanone, 1-nonanone, 2-nonanone, acetone, 4-heptanone, 1-hexanone, 2-hexanone, diisobutyl ketone, cyclohexanone, methylcyclohexanone, phenylacetone, methyl ethyl ketone, methyl isobutyl ketone, methyl amyl ketone, acetylacetone, acetonylacetone, ionone, diacetonyl alcohol, acetylcarbinol, acetophenone, methyl naphthyl ketone, isophorone, and propylene carbonate.

Examples of the ester-based solvent include methyl acetate, butyl acetate, ethyl acetate, isopropyl acetate, amyl acetate, methyl 2-hydroxyisobutyrate, isoamyl acetate, n-pentyl acetate, propylene glycol monomethyl ether acetate, propylene glycol monoethyl ether acetate, ethylene glycol monoethyl ether acetate, diethylene glycol monobutyl ether acetate, diethylene glycol monoethyl ether acetate, ethyl-3-ethoxypropionate, 3-methoxybutylacetate, 3-methyl-3-methoxybutylacetate, methyl formate, ethyl formate, butyl formate, propyl formate, ethyl lactate, butyl lactate, propyl lactate, methyl propionate, methyl 3-methoxypropionate (MMP), ethyl propionate, ethyl 3-ethoxypropionate (EEP), and propyl propionate. Particularly, alkyl acetate esters such as methyl acetate, butyl acetate, ethyl acetate, isopropyl acetate, and amyl acetate, or alkyl propionate esters such as methyl propionate, ethyl propionate, and propyl propionate are preferable.

Examples of the alcohol-based solvent include alcohols such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, 4-methyl-2-pentanol, n-heptyl alcohol, n-octyl alcohol and n-decanol; glycols such as ethylene glycol, diethylene glycol, and triethylene glycol; and glycol ethers such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethyl butanol.

Examples of the ether-based solvent includes dioxane and tetrahydrofuran in addition to the glycols.

Examples of the amide-based solvent include N-methyl-2-pirroridone, N,N-dimethylacetamide, N,N-dimethylformamide, hexamethylphosphoric triamide, and 1,3-dimethyl-2-imidazolidinone.

Examples of the hydrocarbon-based solvent include aromatic hydrocarbon-based solvents such as toluene, xylene, and anisole, and aliphatic hydrocarbon-based solvents such as pentane, hexane, octane, and decane.

The above solvent is used by mixing two or more thereof or used by mixing the solvent with other solvent(s) and/or water in a range in which sufficient performance can be exhibited. Here, the moisture content in the whole volume of the developer is preferably less than 10% by mass, but a developer having substantially no moisture is more preferable. That is, this developer is preferably a developer that is composed substantially only of organic solvents. Incidentally, in this case, the developer can also include a surfactant which will be described later. Further, in this case, the developer may include inevitable impurities derived from atmosphere.

The amount of the organic solvent to be used with respect to the developer is preferably from 80% by mass to 100% by mass, more preferably from 90% by mass to 100% by mass, and still more preferably from 95% by mass to 100% by mass, with respect to the total amount of the developer.

In particular, the organic solvent included in the developer is preferably at least one selected from a ketone-based solvent, an ester-based solvent, an alcohol-based solvent, an amide-based solvent, or an ether-based solvent.

The vapor pressure of the organic developer is preferably 5 kPa or less, more preferably 3 kPa or less, and particularly preferably 2 kPa or less at 20° C. By setting the vapor pressure of the developer to 5 kPa or less, evaporation of the developer on the substrate or in a development cup is suppressed, the temperature evenness in the wafer surface is improved, and as a result, the dimensional evenness in the wafer surface is improved.

Specific examples of the developer having a vapor pressure of 5 kPa or less include ketone-based solvents such as 1-octanone, 2-octanone, 1-nonanone, 2-nonanone, 4-heptanone, 2-hexanone, diisobutyl ketone, cyclohexanone, methyl cyclohexanone, phenyl acetone, and methyl isobutyl ketone; ester-based solvents such as butyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, butyl formate, propyl formate, ethyl lactate, butyl lactate, methyl 2-hydroxyisobutyrate, and propyl lactate; alcohol-based solvents such as n-propyl alcohol, isopropyl alcohol, n-butyl alcohol, sec-butyl alcohol, tert-butyl alcohol, isobutyl alcohol, n-hexyl alcohol, 4-methyl-2-pentanol, n-heptyl alcohol, n-octyl alcohol, and n-decanol; glycol-based solvents such as ethylene glycol, diethylene glycol, and triethylene glycol; glycol ether-based solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethyl butanol; ether-based solvents such as tetrahydrofuran; amide-based solvents such as N-methyl-2-pyrrolidone, N,N-dimethyl acetamide, and N,N-dimethyl formamide; aromatic hydrocarbon-based solvents such as toluene and xylene; and aliphatic hydrocarbon-based solvents such as octane and decane.

Specific examples of the developer having a vapor pressure of 2 kPa or less include ketone-based solvents such as 1-octanone, 2-octanone, 1-nonanone, 2-nonanone, 4-heptanone, 2-hexanone, diisobutyl ketone, cyclohexanone, methyl cyclohexanone, and phenyl acetone; ester-based solvents such as butyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, ethyl lactate, butyl lactate, methyl 2-hydroxyisobutyrate, and propyl lactate; alcohol-based solvents such as n-butyl alcohol, sec-butyl alcohol, tert-butyl alcohol, isobutyl alcohol, n-hexyl alcohol, 4-methyl-2-pentanol, n-heptyl alcohol, n-octyl alcohol, and n-decanol; glycol-based solvents such as ethylene glycol, diethylene glycol, and triethylene glycol; glycol ether-based solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxy methyl butanol; amide-based solvents such as N-methyl-2-pyrrolidone, N,N-dimethyl acetamide, and N,N-dimethyl formamide; aromatic hydrocarbon-based solvents such as xylene; and aliphatic hydrocarbon-based solvents such as octane and decane.

An appropriate amount of a surfactant can be added to the developer, if necessary.

The surfactant is not particularly limited, and for example, ionic or non-ionic fluorine-based and/or silicon-based surfactants, or the like can be used. Examples of the fluorine- and/or the silicon-based surfactant include the surfactants described in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540A), JP1995-230165A (JP-H07-230165A), JP1996-62834A (JP-H08-62834A), JP1997-54432A (JP-H09-54432A), JP1997-5988A (JP-H09-5988A), U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A. The surfactant is preferably a non-ionic surfactant. The non-ionic surfactant is not particularly limited, but a fluorine-based surfactant or a silicon-based surfactant is more preferably used.

Furthermore, the amount of the surfactant to be used is usually 0.001% to 5% by mass, preferably 0.005% to 2% by mass, and more preferably 0.01% to 0.5% by mass, with respect to the total amount of the developer.

In addition, the basic compound can also be included in the organic developer, as described in JP2013-11833A, in particular, paragraphs 0032 to 0063. Further, examples of the basic compound include the basic compounds which may be contained in the actinic ray-sensitive or radiation-sensitive resin composition.

(Procedure of Steps)

Examples of the developing method include a method in which a substrate is immersed in a tank filled with a developer for a certain period of time (a dip method), a method in which a developer is heaped up to the surface of a substrate by surface tension and developed by stopping for a certain period of time (a paddle method), a method in which a developer is sprayed on the surface of a substrate (a spray method), and a method in which a developer is continuously discharged on a substrate spun at a constant rate while scanning a developer discharging nozzle at a constant rate (a dynamic dispense method).

In a case where the various developing methods include a step of discharging a developer toward a resist film from a development nozzle of a developing device, the discharge pressure of the developer discharged (the flow velocity per unit area of the developer discharged) is preferably 2 mL/sec/mm² or less, more preferably 1.5 mL/sec/mm² or less, and still more preferably 1 mL/sec/mm² or less. The flow velocity has no particular lower limit, but is preferably 0.2 mL/sec/mm² or more in consideration of a throughput.

By setting the discharge pressure of a developer to be discharged to be within the above range, the defects of the pattern resulting from a resist residue after development can be significantly reduced.

Details of the mechanism are not clear, but it is considered that this is probably because, when the discharge pressure is within the above range, the pressure applied to the resist film by the developer decreases, or unexpected scraping or collapsing of the composition film and/or the pattern is suppressed.

Moreover, the discharge pressure (mL/sec/mm²) of a developer is a value at the developing nozzle exit in the developing device.

Examples of the method of adjusting the discharge pressure of a developer include a method of adjusting the discharge pressure using a pump and a method of adjusting the pressure by supply from a pressure tank.

In addition, after a step of carrying out development, a step of stopping the development while replacing with another solvent may also be carried out.

<Rinsing Step>

The pattern forming method preferably further includes a rinsing step (a step of washing a film using a rinsing liquid including an organic solvent) after the developing step.

The rinsing liquid used in the rinsing step is not particularly limited as long as it does not dissolve the pattern after development, and a solution including a general organic solvent can be used.

Examples of the rinsing liquid include a rinsing liquid including at least one kind of organic solvent selected from a hydrocarbon-based solvent, a ketone-based solvent, an ester-based solvent, an alcohol-based solvent, an amide-based solvent, or an ether-based solvent. The rinsing liquid more preferably includes at least one kind of organic solvent selected from a ketone-based solvent, an ester-based solvent, an alcohol-based solvent, or an amide-based solvent, and still more preferably includes an alcohol-based solvent or an ester-based solvent.

The rinsing liquid preferably includes a monohydric alcohol, and more preferably includes a monohydric alcohol having 5 or more carbon atoms.

These monohydric alcohols may be linear, branched, or cyclic. Examples of these monohydric alcohols include 1-butanol, 2-butanol, 3-methyl-1-butanol, tert-butyl alcohol, 1-pentanol, 2-pentanol, 1-hexanol, 4-methyl-2-pentanol(methyl isobutyl carbinol), 1-heptanol, 1-octanol, 2-hexanol, cyclopentanol, 2-heptanol, 2-octanol, 3-hexanol, 3-heptanol, 3-octanol, and 4-octanol. Examples of the monohydric alcohol having 5 or more carbon atoms include 1-hexanol, 2-hexanol, 4-methyl-2-pentanol, 1-pentanol, and 3-methyl-1-butanol.

The respective components as described above may be used in mixture with two or more kinds thereof, and may be used in mixture with an organic solvent other than the components as described above.

The moisture content of the rinsing liquid is preferably less than 10% by mass, more preferably less than 5% by mass, and still more preferably less than 3% by mass. That is, the amount of an organic solvent to be used with respect to the rinsing liquid is preferably from 90% by mass to 100% by mass, more preferably from 95% by mass to 100% by mass, and still more preferably from 97% by mass to 100%, with respect to the total amount of the rinsing liquid. When the moisture content of the rinsing liquid is less than 10% by mass, more favorable development characteristics can be accomplished.

The vapor pressure of the rinsing liquid is preferably from 0.05 kPa to 5 kPa, more preferably from 0.1 kPa to 5 kPa, and still more preferably from 0.12 kPa to 3 kPa, at 20° C. By setting the vapor pressure of the rinsing liquid to a range from 0.05 kPa to 5 kPa, the temperature evenness in the wafer surface is improved, swelling due to permeation of the rinsing liquid is suppressed, and the dimensional evenness in the wafer surface is improved.

Moreover, a suitable amount of a surfactant may be added to the rinsing liquid.

In the rinsing step, the developed substrate is rinsed with the above-described rinsing liquid. The method for the rinsing treatment is not particularly limited, and examples thereof include a method in which a rinsing liquid is discharged continuously onto a substrate while the substrate is spun at a constant rate (a spin coating method), a method in which a substrate is dipped in a bath filled with a rinsing liquid for a predetermined period of time (a dipping method), and a method in which a rinsing liquid is sprayed onto a substrate surface (a spray method). Among these, it is preferable that after carrying out a washing treatment by the spin coating method, a rinsing liquid is removed from the substrate by rotating the substrate at a rotation speed of 2,000 rpm to 4,000 rpm.

In addition, the present invention also relates to a method for manufacturing an electronic device including the pattern forming method of the present invention as described above, and an electronic device manufactured by the manufacturing method.

The electronic device is suitably mounted on electric or electronic equipment (home electronics, OA/media-related equipment, optical equipment, telecommunication equipment, and the like).

<Actinic Ray-Sensitive or Radiation-Sensitive Resin Composition>

Hereinafter, the actinic ray-sensitive or radiation-sensitive resin composition which can be used in the present invention will be described.

The actinic ray-sensitive or radiation-sensitive resin composition is used for negative type development (development in which when the composition is exposed, its solubility in a developer is reduced, and thus, an exposed area remains as a pattern and an unexposed area is removed). That is, the actinic ray-sensitive or radiation-sensitive resin composition can be suitably used as an actinic ray-sensitive or radiation-sensitive resin composition for organic solvent development, which is used for development using a developer including an organic solvent. Here, being used for an organic solvent development means a use of the composition to be supplied to a step of carrying out development using a developer including an organic solvent.

The actinic ray-sensitive or radiation-sensitive resin composition is typically a resist composition, and is preferably a negative type resist composition (that is, a resist composition for organic solvent development), particularly in view that good effects can be obtained. Further, the composition is a typically a chemical amplification type resist composition.

The composition contains at least a compound having a partial structure represented by General Formula (I) which will be described later.

Furthermore, the composition preferably includes a compound that generates an acid by active light or radiation, a basic compound, and a solvent, and may further include at least one of a hydrophobic resin, a surfactant, or other additives.

Hereinafter, these respective components will be described in order.

<Compound Having Partial Structure Represented by General Formula (I)>

The composition includes a compound having a partial structure represented by General Formula (I) (hereinafter also simply referred to as a “compound X”).

The compound X is not limited as long as it includes at least the partial structure represented by General Formula (I), and the compound X may be a low molecular compound or a high molecular compound. The high molecular compound (hereinafter also appropriately referred to as a “resin (A)”) corresponds to a resin having a predetermined repeating unit.

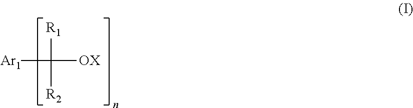

In General Formula (I), Ar₁ represents an aromatic ring group or an alicyclic group.

In a case where Ar₁ represents an aromatic ring group, the aromatic ring group is preferably a group formed by removing n+1 hydrogen atoms from a monocyclic or polycyclic aromatic ring (n represents an integer of 1 or more).

As the aromatic ring, an aromatic hydrocarbon ring (preferably having 6 to 18 carbon atoms), such as a benzene ring, a naphthalene ring, an anthracene ring, a fluorene ring, and a phenanthrene ring, or an aromatic heterocycle including a heterocycle, such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a triazole ring. Among these, a benzene ring and a naphthalene ring are preferable from the viewpoint of resolution, and a benzene ring is most preferable.

In a case where Ar₁ represents an alicyclic group, the alicyclic group may be monocyclic or polycyclic, and specifically, a group formed by removing n+1 hydrogen atom (n represents an integer of 1 or more) from a monocyclic or polycyclic alicycle (preferably an alicycle having 3 to 18 carbon atoms) is preferable, and a group corresponding to a monocyclic or polycyclic monovalent alicyclic group (a group formed by removing n hydrogen atoms from a monovalent alicyclic group) is more preferable.

Examples of the monocyclic alicyclic group include groups corresponding to cycloalkyl groups such as a cyclopropyl group, a cyclobutyl group, a cycloheptyl group, a cyclohexyl group, a cyclopentyl group, a cyclooctyl group, a cyclononyl group, a cyclodecyl group, a cycloundecyl group, a cyclododecanyl group, a cyclohexenyl group, a cyclohexadienyl group, a cyclopentenyl group, and a cyclopentadienyl group, with a group corresponding to a cyclohexyl group or a cyclopentyl group being preferable.

Examples of the polycyclic alicyclic group include groups having a bicyclic, tricyclic, or tetracyclic structure, or the like, for example, a group corresponding to a bicyclobutyl group, a bicyclooctyl group, a bicyclononyl group, a bicyclooctyl group, a bicycloundecyl group, a bicyclooctenyl group, a bicyclotridecenyl group, an adamantyl group, an isobornyl group, a norbornyl group, a camphanyl group, an α-pinel group, a tricyclodecanyl group, a tetracyclododecyl group, or an androstanyl group. More preferred examples thereof include groups corresponding to an adamantyl group, a decalin group, a norbornyl group, a cedrol group, a cyclohexyl group, a cycloheptyl group, a cyclooctyl group, a cyclodecanyl group, a cyclododecanyl group, and a tricyclodecanyl group, with a group corresponding to an adamantyl group being most preferable, from the viewpoint of dry etching resistance.

In addition, some of carbon atoms in the monocyclic or polycyclic alicyclic group may be substituted with heteroatoms such as an oxygen atom.

At least one of R₁ or R₂ may be bonded to Ar₁ to form a ring, and R₁ and R₂ are preferably bonded to Ar₁ to form a polycyclic alicycle having 5 to 12 carbon atoms, and particularly preferably to form an adamantane ring.

The aromatic ring group or the alicyclic group of Ar₁ may have a substituent, examples of the substituent include an alkyl group, a halogen atom, a hydroxyl group, an alkoxy group, a carboxyl group, an alkoxycarbonyl group, an alkylcarbonyl group, an alkylcarbonyloxy group, an alkylsulfonyloxy group, and an arylcarbonyl group.

R₁ and R₂ each independently represent an alkyl group, a cycloalkyl group, or an aryl group. R₁ and R₂ may be bonded to each other to form a ring, together with a carbon atom to which they are bonded.

R₁ and R₂ each independently preferably represent an alkyl group having 1 to 10 carbon atoms, or a cycloalkyl group having 3 to 10 carbon atoms, and more preferably represent an alkyl group having 1 to 5 carbon atoms.

R₁ and R₂ each may have a substituent, and examples of the substituent include an alkyl group, a halogen atom, a hydroxyl group, an alkoxy group, a carboxyl group, an alkoxycarbonyl group, an alkylcarbonyl group, an alkylcarbonyloxy group, an alkylsulfonyloxy group, and an arylcarbonyl group.

Examples of R₁ and R₂ in a case where they each have a substituent include a benzyl group and a cyclohexylmethyl group.

X represents a hydrogen atom, an alkyl group, a cycloalkyl group, an aryl group, or an acyl group. X is preferably a hydrogen atom, an alkyl group, or an acyl group and more preferably a hydrogen atom, an alkyl group having 1 to 5 carbon atoms, or an acyl group having 2 to 5 carbon atoms.

In General Formula (I), n represents an integer of 1 or more, preferably represents an integer of 1 to 5, and more preferably represents an integer of 1 to 3.

Specific examples of a case where the compound X is a low molecular compound are shown below.

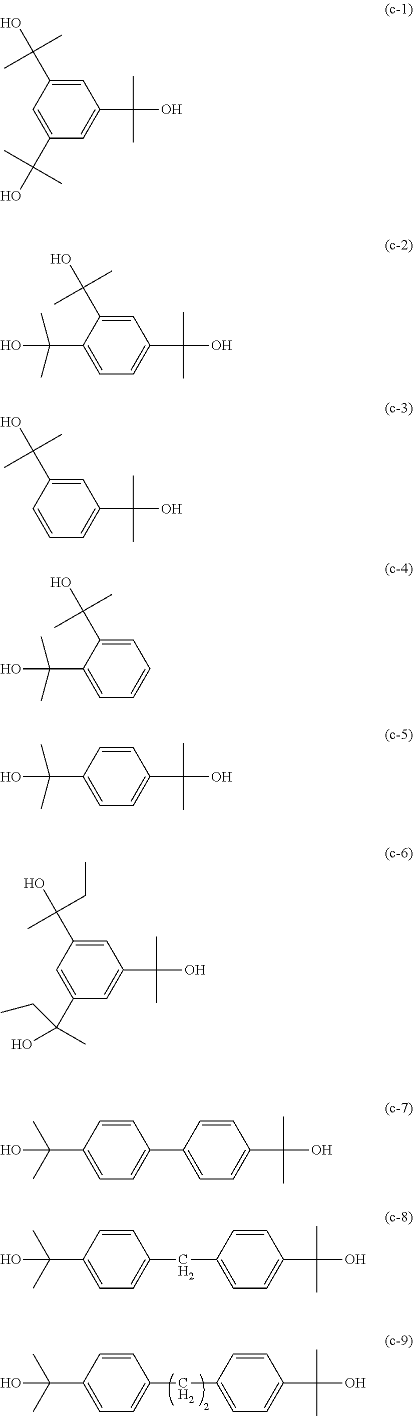

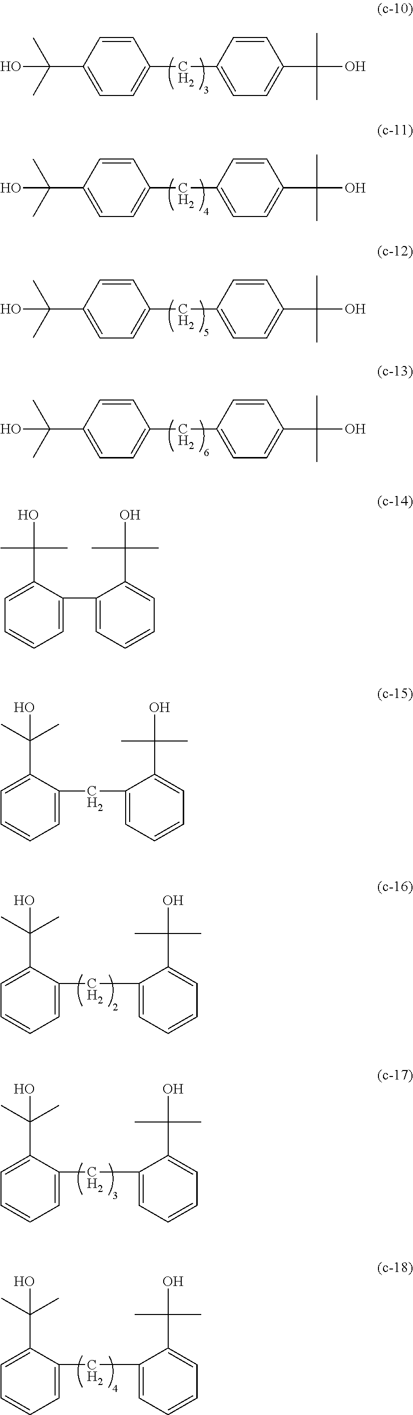

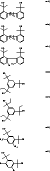

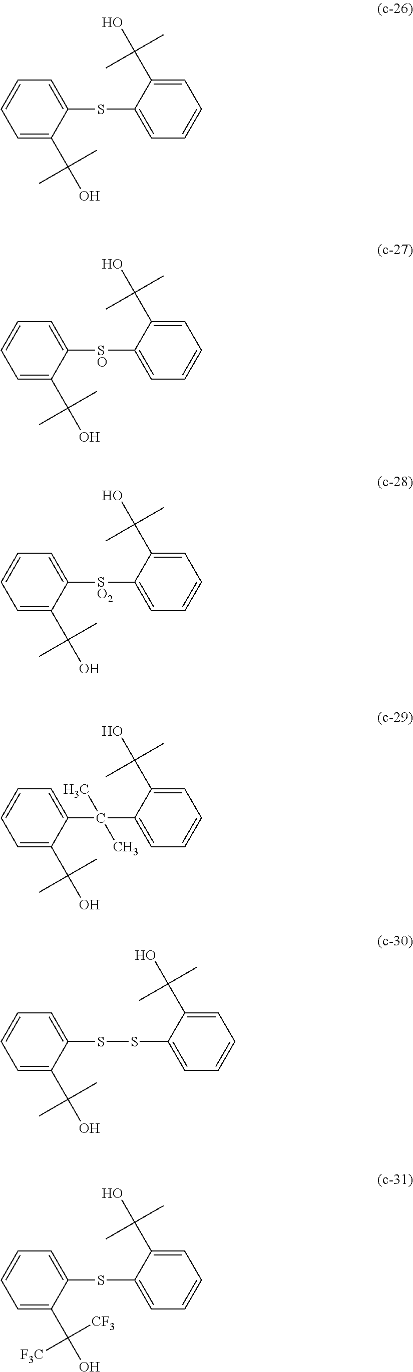

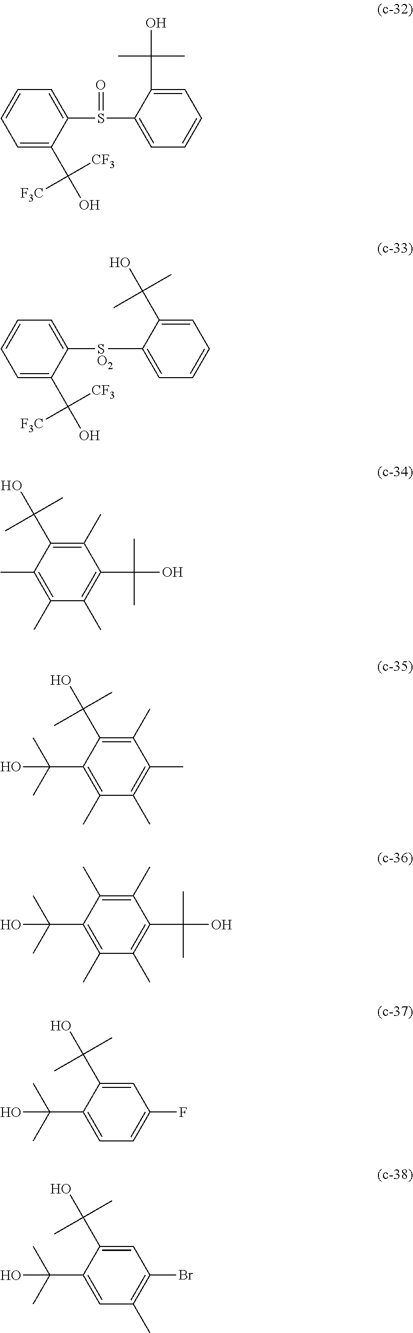

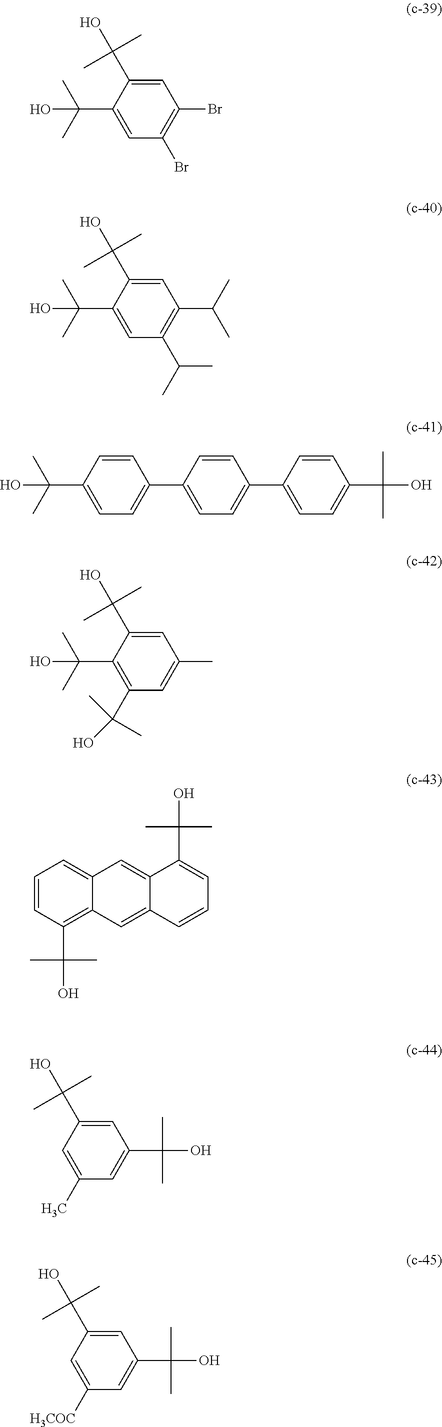

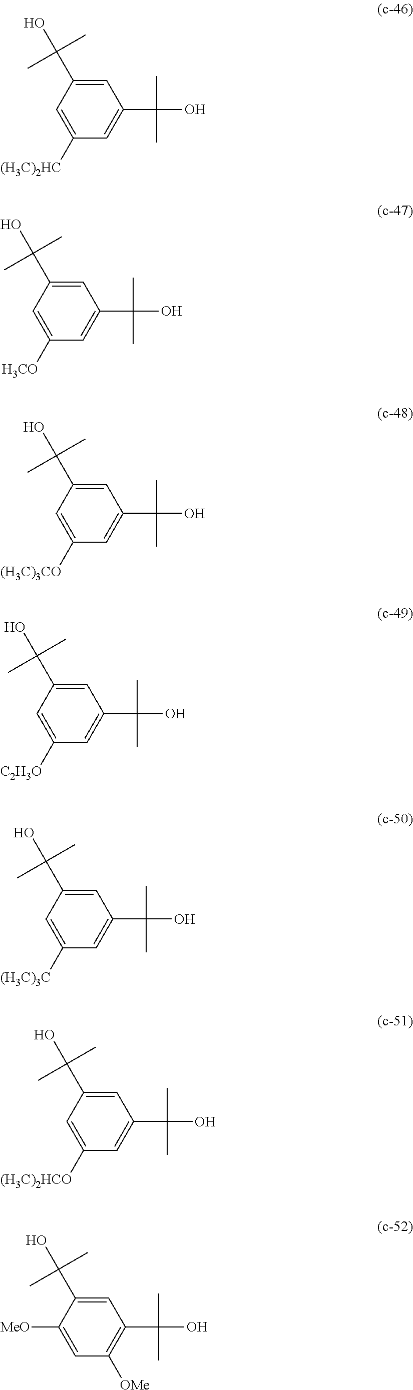

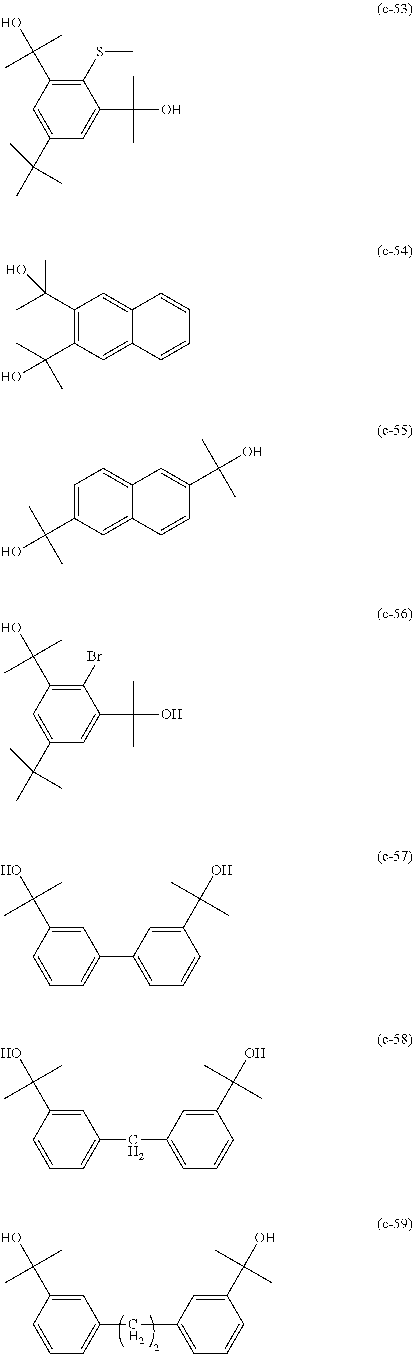

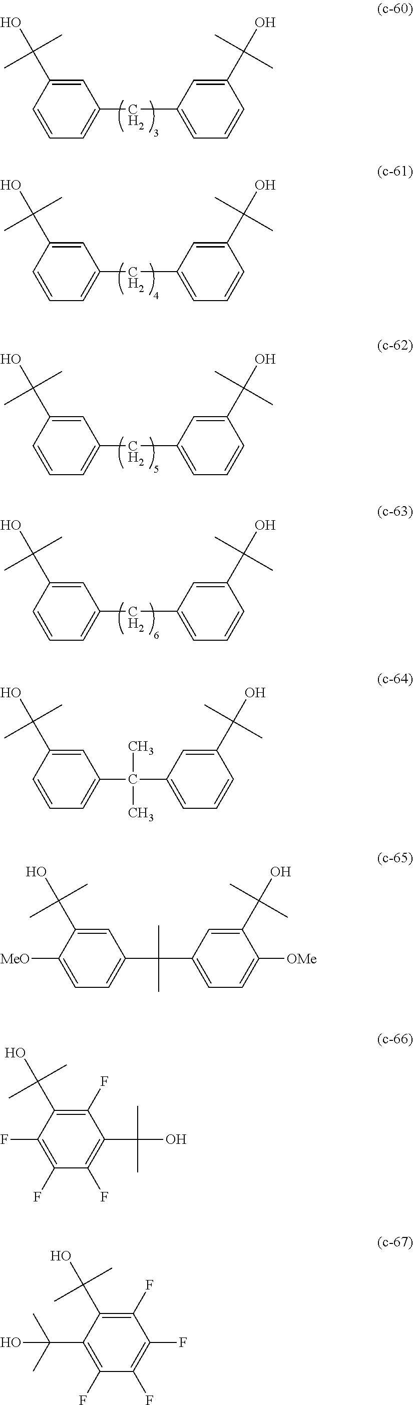

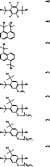

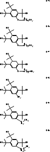

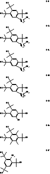

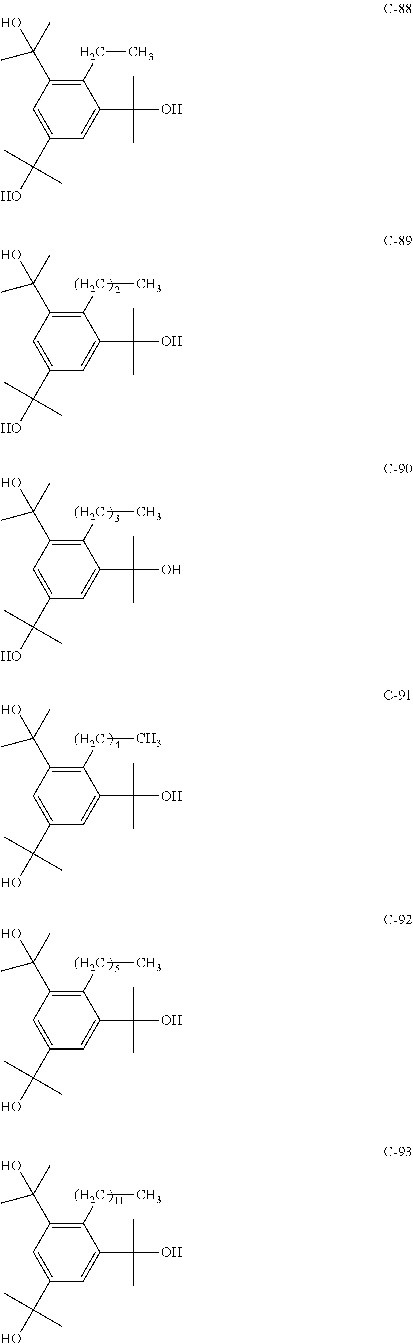

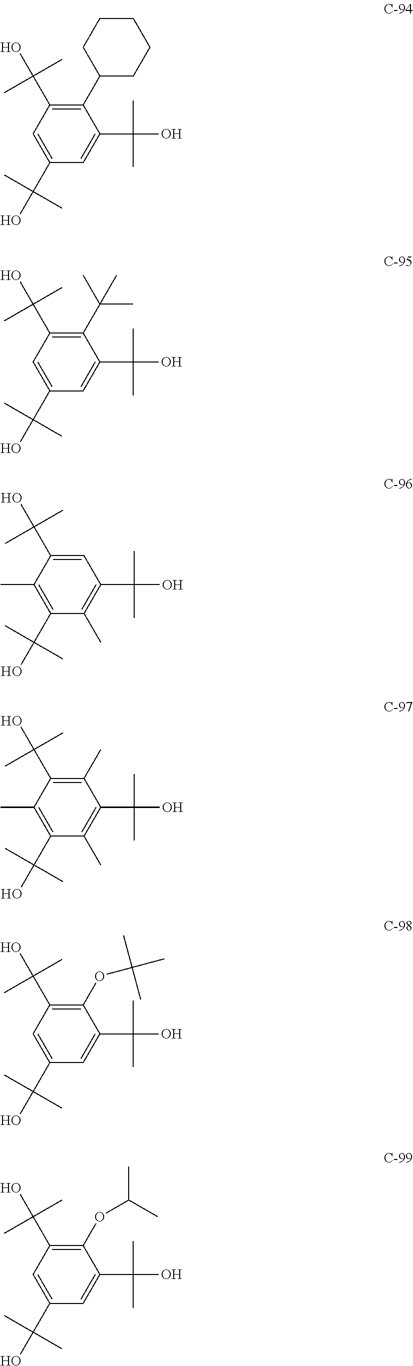 [SMILES: CC(C)(O)c1cc(C(C)(C)O)c(C2CCCCC2)c(C(C)(C)O)c1 ; CC(C)(C)c1c(C(C)(C)O)cc(C(C)(C)O)cc1C(C)(C)O ; Cc1c(C(C)(C)O)cc(C(C)(C)O)c(C)c1C(C)(C)O ; Cc1c(C(C)(C)O)c(C)c(C(C)(C)O)c(C)c1C(C)(C)O ; CC(C)(C)Oc1c(C(C)(C)O)cc(C(C)(C)O)cc1C(C)(C)O ; CC(C)Oc1c(C(C)(C)O)cc(C(C)(C)O)cc1C(C)(C)O]

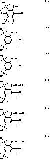

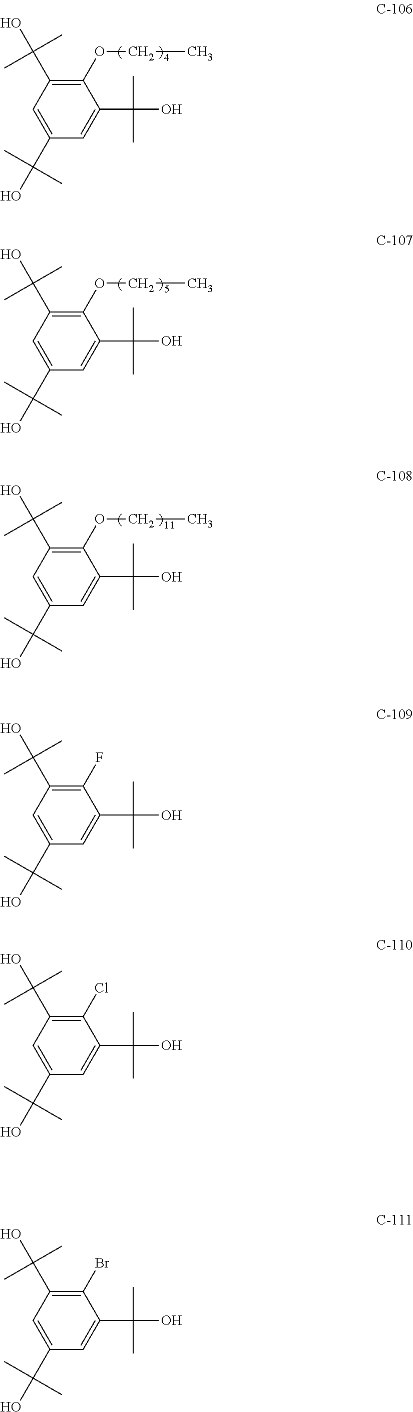

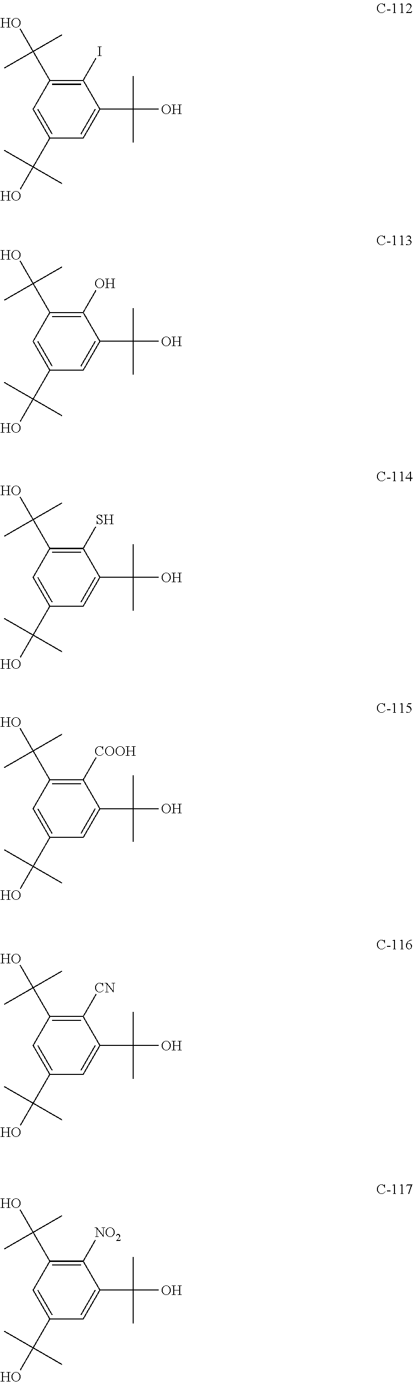 [SMILES: CC(C)(O)c1cc(C(C)(C)O)c(I)c(C(C)(C)O)c1 ; CC(C)(O)c1cc(C(C)(C)O)c(O)c(C(C)(C)O)c1 ; CC(C)(O)c1cc(C(C)(C)O)c(S)c(C(C)(C)O)c1 ; CC(C)(O)c1cc(C(C)(C)O)c(C(=O)O)c(C(C)(C)O)c1 ; CC(C)(O)c1cc(C(C)(C)O)c(C#N)c(C(C)(C)O)c1 ; CC(C)(O)c1cc(C(C)(C)O)c([N+](=O)[O-])c(C(C)(C)O)c1]

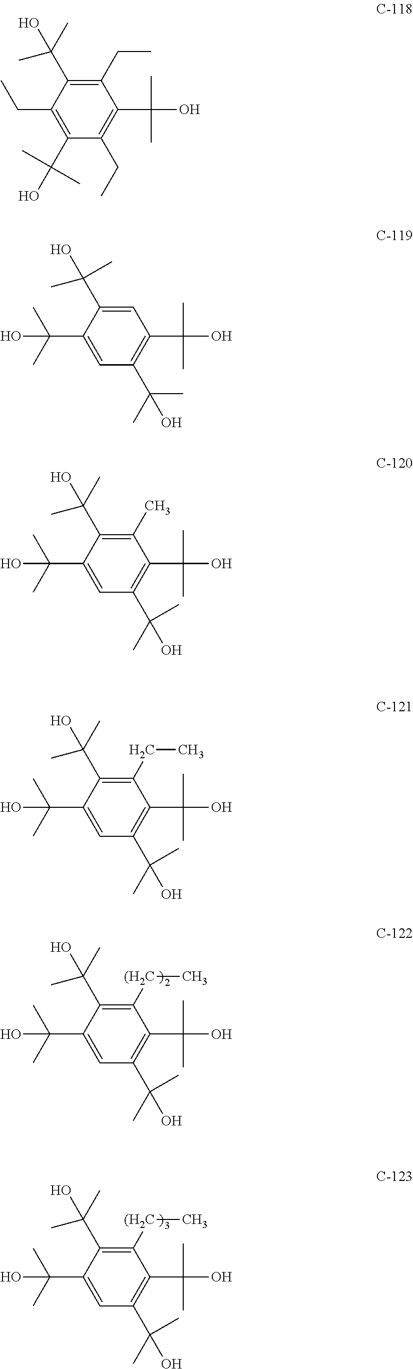

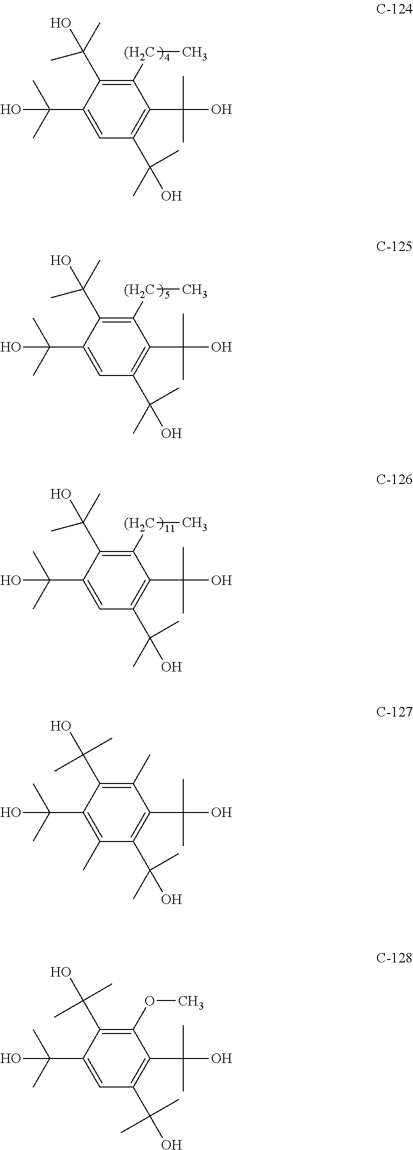

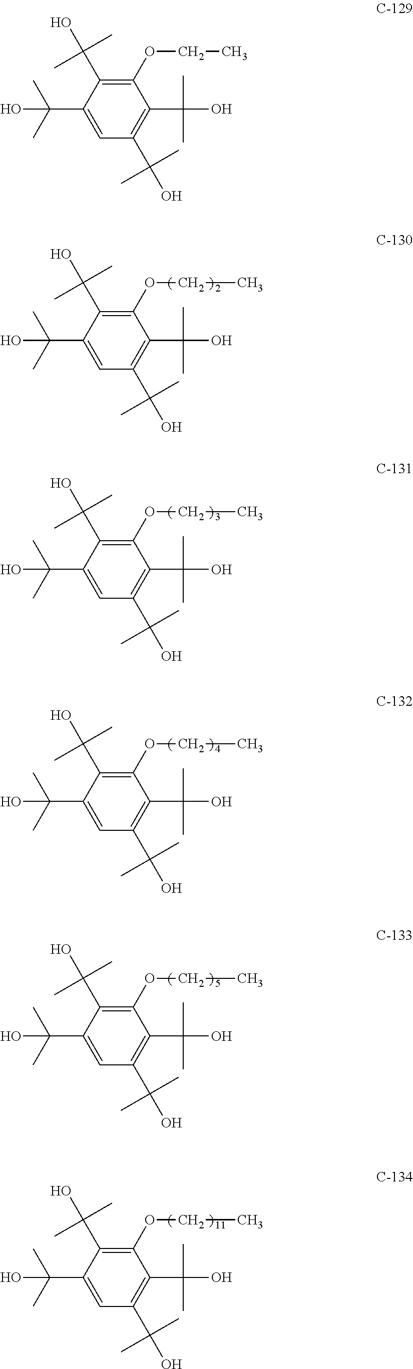 [SMILES: CCOc1c(C(C)(C)O)c(C(C)(C)O)cc(C(C)(C)O)c1C(C)(C)O ; CCOc1c(C(C)(C)O)c(C(C)(C)O)cc(C(C)(C)O)c1C(C)(C)O ; CCOc1c(C(C)(C)O)c(C(C)(C)O)cc(C(C)(C)O)c1C(C)(C)O ; CCOc1c(C(C)(C)O)c(C(C)(C)O)cc(C(C)(C)O)c1C(C)(C)O ; CCOc1c(C(C)(C)O)c(C(C)(C)O)cc(C(C)(C)O)c1C(C)(C)O ; CCOc1c(C(C)(C)O)c(C(C)(C)O)cc(C(C)(C)O)c1C(C)(C)O]

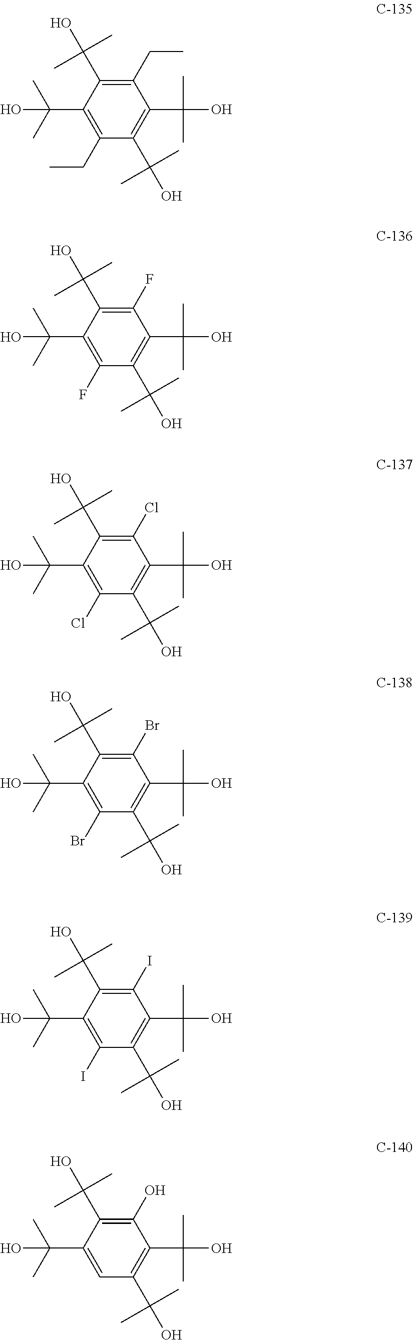 [SMILES: CCc1c(C(C)(C)O)c(C(C)(C)O)c(CC)c(C(C)(C)O)c1C(C)(C)O ; CC(C)(O)c1c(F)c(C(C)(C)O)c(C(C)(C)O)c(F)c1C(C)(C)O ; CC(C)(O)c1c(Cl)c(C(C)(C)O)c(C(C)(C)O)c(Cl)c1C(C)(C)O ; CC(C)(O)c1c(Br)c(C(C)(C)O)c(C(C)(C)O)c(Br)c1C(C)(C)O ; CC(C)(O)c1c(I)c(C(C)(C)O)c(C(C)(C)O)c(I)c1C(C)(C)O ; CC(C)(O)c1cc(C(C)(C)O)c(C(C)(C)O)c(O)c1C(C)(C)O]

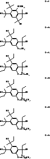

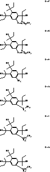

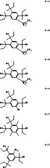

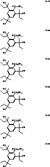

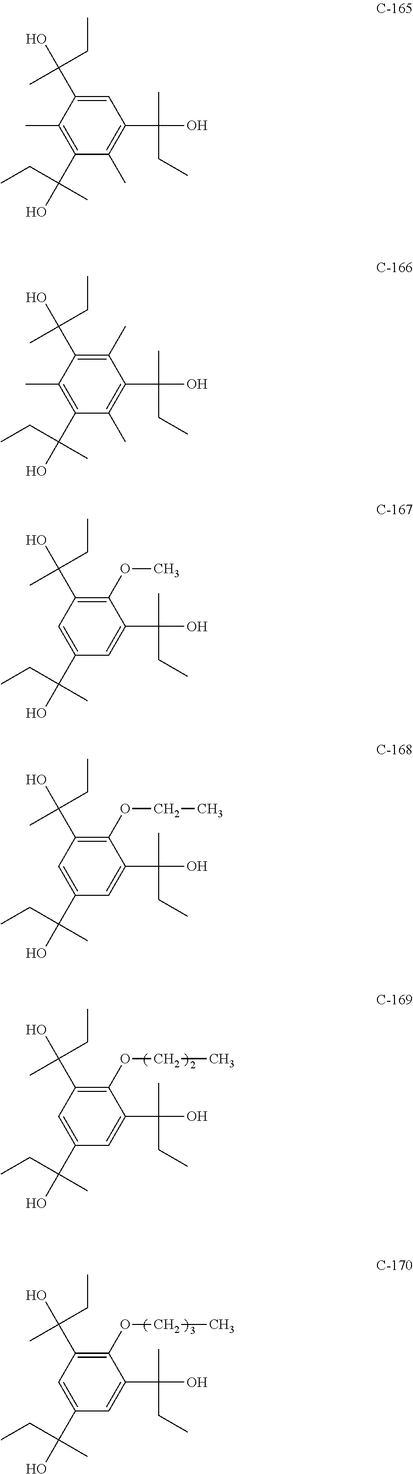

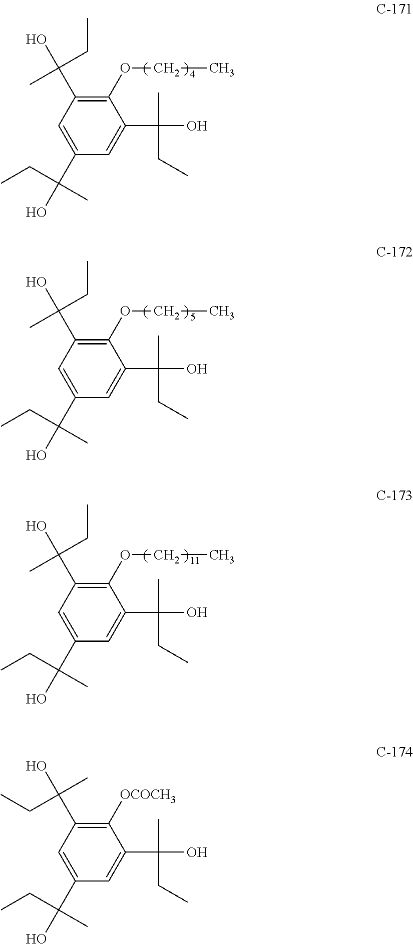

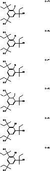 [SMILES: CCC(C)(O)c1cc(C(C)(O)CC)c(F)c(C(C)(O)CC)c1 ; CCC(C)(O)c1cc(C(C)(O)CC)c(Cl)c(C(C)(O)CC)c1 ; CCC(C)(O)c1cc(C(C)(O)CC)c(Br)c(C(C)(O)CC)c1 ; CCC(C)(O)c1cc(C(C)(O)CC)c(I)c(C(C)(O)CC)c1 ; CCC(C)(O)c1cc(C(C)(O)CC)c(O)c(C(C)(O)CC)c1 ; CCC(C)(O)c1cc(C(C)(O)CC)c(S)c(C(C)(O)CC)c1]

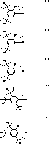 [SMILES: CCC(C)(O)c1cc(C(C)(O)CC)c(C(=O)O)c(C(C)(O)CC)c1 ; CCC(C)(O)c1cc(C(C)(O)CC)c(C#N)c(C(C)(O)CC)c1 ; CCC(C)(O)c1cc(C(C)(O)CC)c([N+](=O)[O-])c(C(C)(O)CC)c1 ; CCC(C)(O)c1cc(C(C)(O)CC)c(C(C)(O)CC)cc1C(C)(O)CC ; CCC(C)(O)c1cc(C(C)(O)CC)c(C(C)(O)CC)c(C)c1C(C)(O)CC]

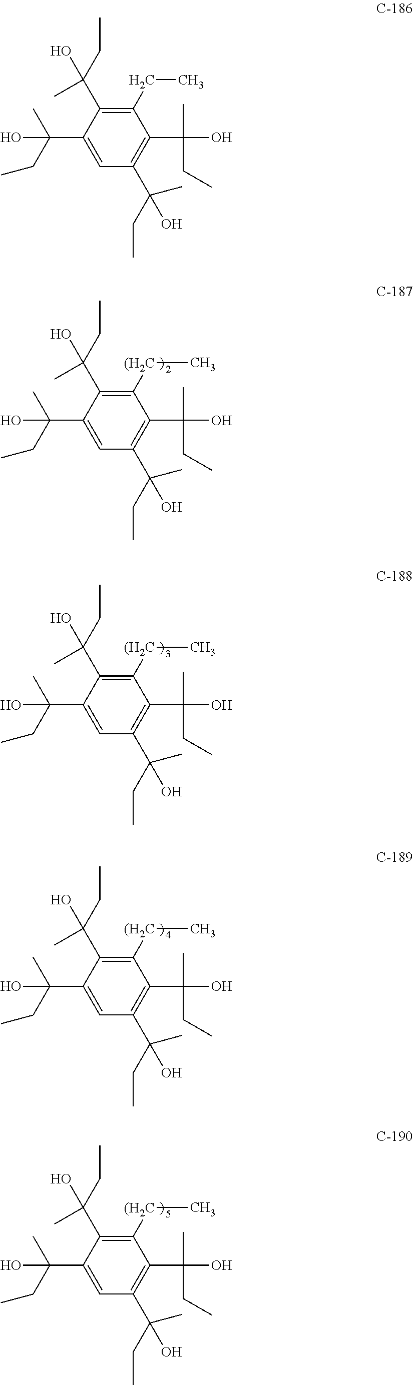

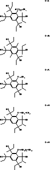

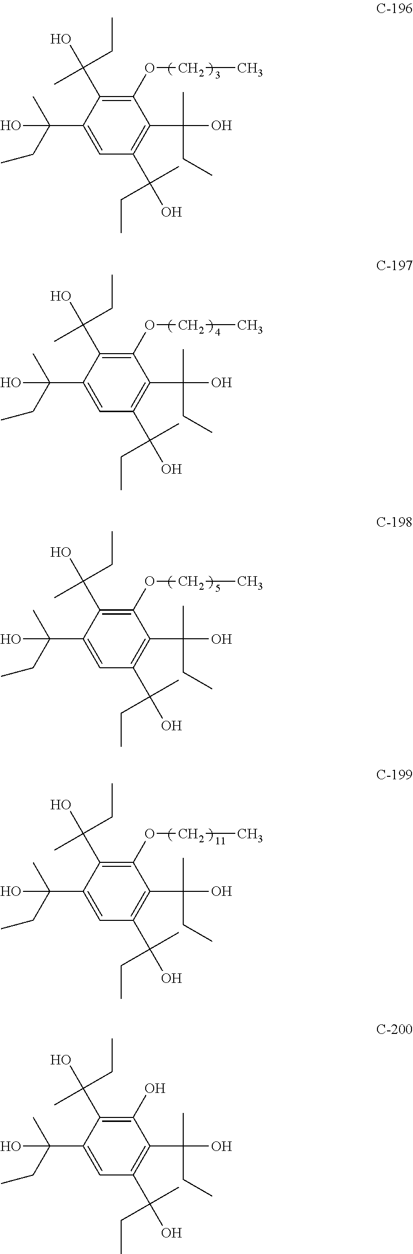

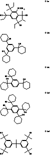

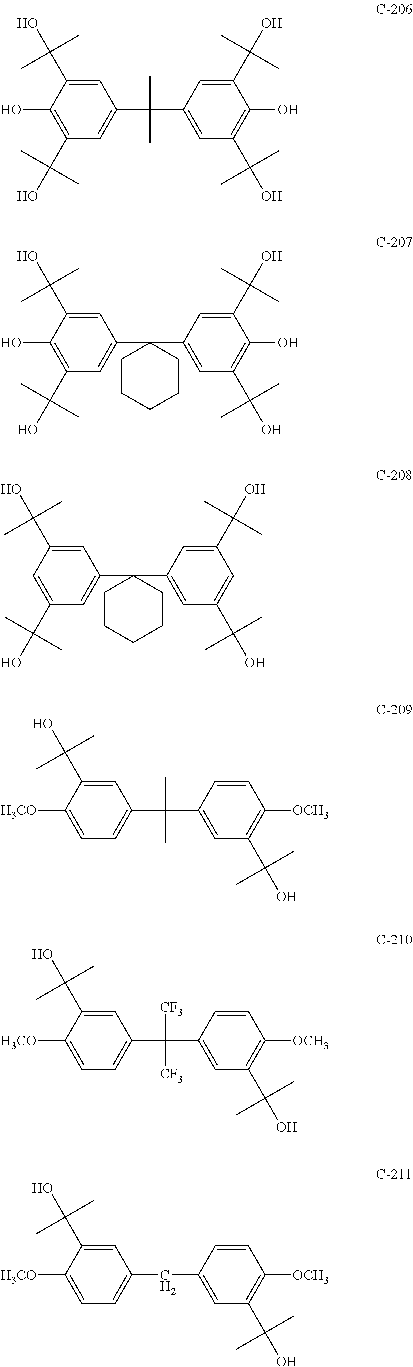 [SMILES: CC(C)(O)c1cc(C(C)(C)c2cc(C(C)(C)O)c(O)c(C(C)(C)O)c2)cc(C(C)(C)O)c1O ; CC(C)(O)c1cc(C2(c3cc(C(C)(C)O)c(O)c(C(C)(C)O)c3)CCCCC2)cc(C(C)(C)O)c1O ; CC(C)(O)c1cc(C(C)(C)O)cc(C2(c3cc(C(C)(C)O)cc(C(C)(C)O)c3)CCCCC2)c1 ; COc1ccc(C(C)(C)c2ccc(OC)c(C(C)(C)O)c2)cc1C(C)(C)O ; COc1ccc(C(c2ccc(OC)c(C(C)(C)O)c2)(C(F)(F)F)C(F)(F)F)cc1C(C)(C)O ; COc1ccc(Cc2ccc(OC)c(C(C)(C)O)c2)cc1C(C)(C)O]

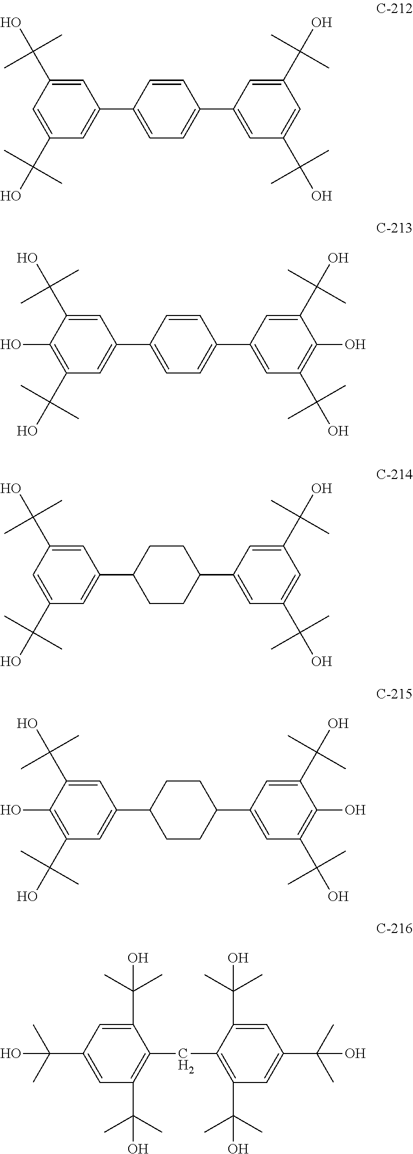

(Suitable Aspect (Aspect 1))

Suitable aspects of the compound X include a resin repeating unit represented by General Formula (III) in that the resolution of the pattern is more excellent. Further, the repeating unit represented by General Formula (III) has a partial structure represented by General Formula (I).

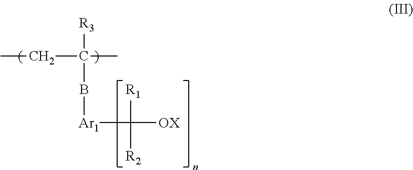

Ar₁ represents an aromatic ring group or an alicyclic group. R₁ and R₂ each independently represent an alkyl group, a cycloalkyl group, or an aryl group. X represents a hydrogen atom, an alkyl group, a cycloalkyl group, an aryl group, or an acyl group. n represents an integer of 1 or more.

The definitions of Ar₁, R₁, R₂, X, and n are as described above.

At least two members out of Ar₁, R₁, or R₂ may be bonded to each other to form a ring.

In a case where n represents an integer of 2 or more, a plurality of R₁'s, a plurality of R₂'s, and a plurality of X's may be the same or different from each other.

In the formula, R₃ represents a hydrogen atom, an organic group, or a halogen atom.

In a case where R₃ represents an organic group, the organic group is preferably an alkyl group, a cycloalkyl group, or an aryl group, and more preferably a linear or branched alkyl group having 1 to 10 carbon atoms (for example, a methyl group, an ethyl group, a propyl group, a butyl group, and a pentyl group), a cycloalkyl group having 3 to 10 carbon atoms (for example, a cyclopentyl group, a cyclohexyl group, and a norbornyl group), or an aryl group having 6 to 10 carbon atoms (for example, a phenyl group and a naphthyl group).

The organic group may further have a substituent. Examples of the substituent include a halogen atom (preferably a fluorine atom), a carboxyl group, a hydroxyl group, an amino group, and a cyano group, and are not limited thereto. As the substituent, a fluorine atom, or a hydroxyl group is particularly preferable.

Examples of the organic group in a case where it has a substituent include a trifluoromethyl group and a hydroxymethyl group.

R₃ is preferably a hydrogen atom or a methyl group, and more preferably a hydrogen atom.

B represents a single bond or a divalent linking group.

In a case where B represents a divalent linking group, the divalent linking group is preferably a carbonyl group, an alkylene group, an arylene group, a sulfonyl group, —O—, —NH—, or a group formed by combining these groups (for example, an ester bond).

B preferably represents a divalent linking group represented by the following General Formula (B).

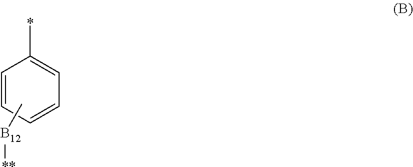

In General Formula (B), B₁₂ represents a single bond or a divalent linking group. * represents a binding arm bonded to the main chain. ** represents a binding arm bonded to Ar₁.

In a case where B₁₂ represents a divalent linking group, the divalent linking group is an alkylene group, —O—, or a group formed by combining these groups.

It is also preferable that B represents a divalent linking group represented by following General Formula (B-1).

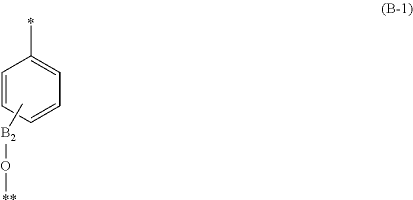

In General Formula (B-1), B₂ represents a single bond or a divalent linking group. * represents a binding arm bonded to the main chain. ** represents a binding arm bonded to Ar₁.

In a case where B₂ represents a divalent linking group, the divalent linking group is preferably an alkylene group or an alkylene oxy group, and more preferably an alkylene group having 1 to 5 carbon atoms, or an alkylene oxy group having 1 to 5 carbon atoms. Further, in a case where B₂ represents an alkylene oxy group, an oxy group of the alkylene oxy group is bonded to any one carbon atom constituting a benzene ring represented by General Formula (B-1).

B is particularly preferably a single bond, a carbonyloxy group, a divalent linking group represented by General Formula (B), or a divalent linking group represented by General Formula (B-1).

It is also preferable that General Formula (III) is the following General Formula (I-2).

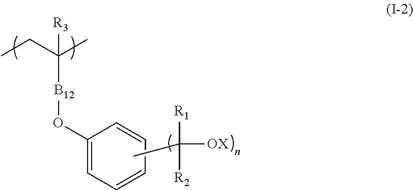

In the formula, the definitions of R₁ to R₃, X, B₁₂, and n are as described above.

R₁ and R₂ in General Formula (I-2) each independently preferably represent an alkyl group having 1 to 10 carbon atoms, or a cycloalkyl group having 3 to 10 carbon atoms, and more preferably represent an alkyl group having 1 to 5 carbon atoms.

n in General Formula (I-2) preferably represents an integer of 1 to 5, more preferably represents an integer of 1 to 3, and still more preferably represents 1 or 2.

It is also preferable that General Formula (III) is the following General Formula (I-3).

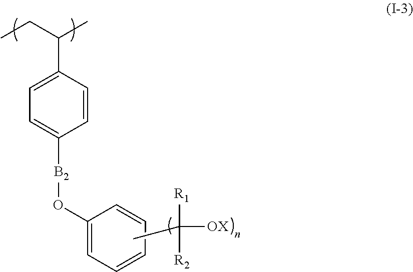

In the formula, the definitions of R₁ and R₂, X, B₂, and n are as described above.

R₁ and R₂ in General Formula (I-3) each independently preferably represent an alkyl group having 1 to 10 carbon atoms, or a cycloalkyl group having 3 to 10 carbon atoms, and more preferably represent an alkyl group having 1 to 5 carbon atoms.

n in General Formula (I-3) preferably represents an integer of 1 to 5, more preferably represents an integer of 1 to 3, and still more preferably represents 1 or 2.

Specific examples of the repeating unit represented by General Formula (III) are shown below, but are not limited thereto. Me represents a methyl group and Ac represents an acetyl group.

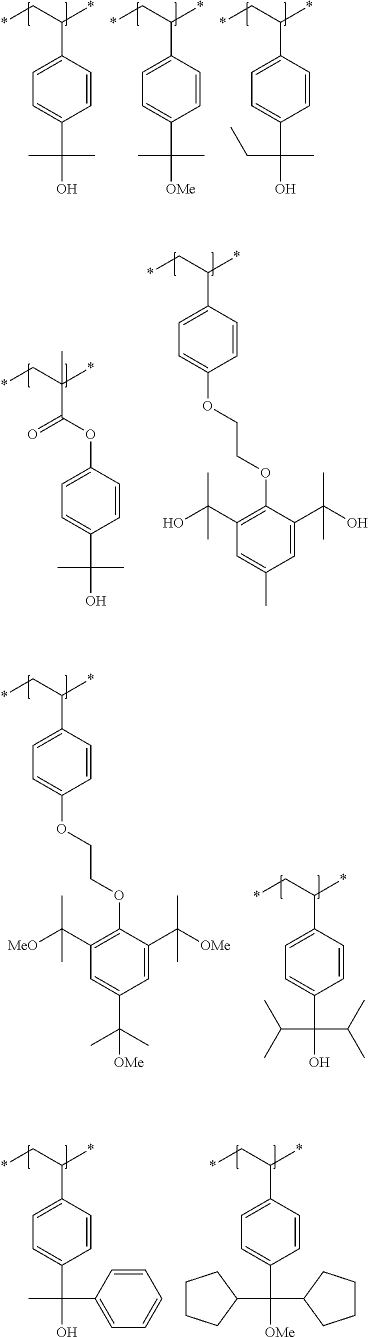

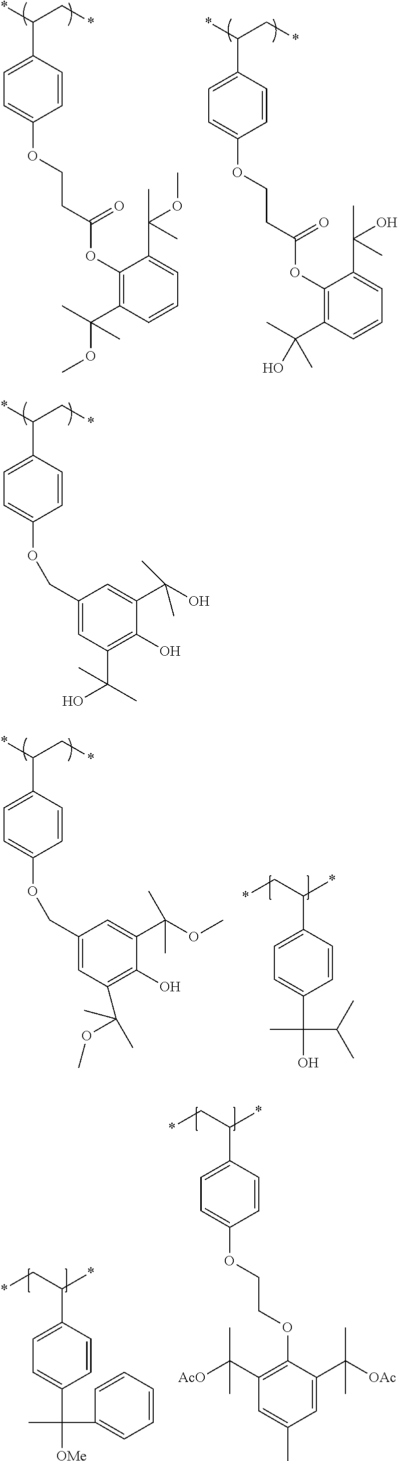

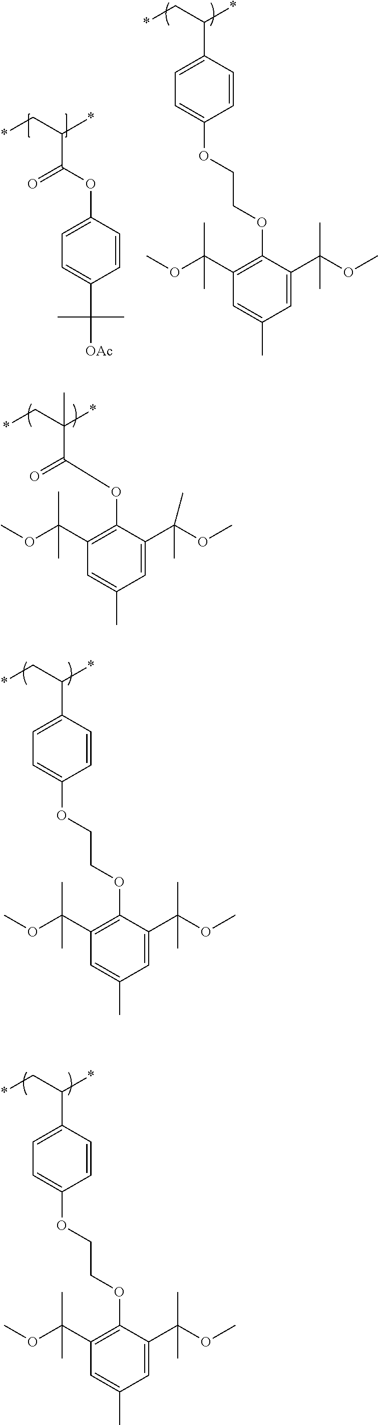

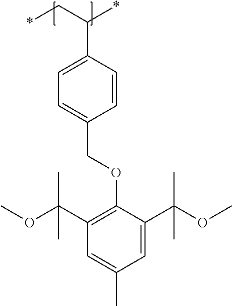

The content of the repeating unit represented by General Formula (III) in the resin is not particularly limited, but is preferably 1% to 60% by mole, more preferably 3% to 50% by mole, sill more preferably 5% to 40% by mole, and particularly preferably 10% to 30% by mole, with respect to all the repeating units in the resin, in view that the resolution of the pattern is more excellent.

(Suitable Aspect (Aspect 2))

Suitable aspects of the compound X include a resin having a repeating unit represented by General Formula (II), in addition to the partial structure represented by General Formula (I), in view that the resolution of the pattern is more excellent. Further, the compound X is more preferably a resin including the repeating unit represented by General Formula (III) as described above and the repeating unit represented by General Formula (II).

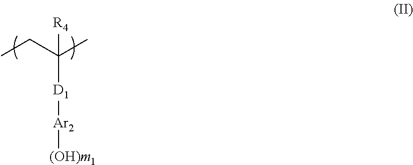

In General Formula (II), R₄ represents a hydrogen atom, an organic group, or a halogen atom.

In a case where R₄ represents an organic group, the organic group is preferably an alkyl group, a cycloalkyl group, or an aryl group, and more preferably a linear or branched alkyl group having 1 to 10 carbon atoms (for example, a methyl group, an ethyl group, a propyl group, a butyl group, and a pentyl group), a cycloalkyl group having 3 to 10 carbon atoms (for example, a cyclopentyl group, a cyclohexyl group, and a norbornyl group), or an aryl group having 6 to 10 carbon atoms (for example, a phenyl group and a naphthyl group).

The organic group may further have a substituent. Examples of the substituent include a halogen atom (preferably a fluorine atom), a carboxyl group, a hydroxyl group, an amino group, and a cyano group, but are not limited thereto. As the substituent, a fluorine atom, or a hydroxyl group is particularly preferable.

Examples of the organic group in a case where it has a substituent include a trifluoromethyl group and a hydroxymethyl group.

R₄ is preferably a hydrogen atom or a methyl group, and more preferably a hydrogen atom.

D₁ represents a single bond or a divalent linking group.

In a case where D₁ represents a divalent linking group, the divalent linking group is preferably a carbonyl group, an alkylene group, an arylene group, a sulfonyl group, —O—, —NH—, or a group formed by combining these groups (for example, an ester bond).

D₁ is preferably a single bond or a carbonyloxy group, and more preferably a single bond.

Ar₂ represents an aromatic ring group.

The aromatic ring group represented by Ar₂ is preferably a group formed by removing n+1 hydrogen atom from a monocyclic or polycyclic aromatic ring (n represents an integer of 1 or more).

Examples of the aromatic ring include aromatic hydrocarbon rings (preferably having 6 to 18 carbon atoms) which may have a substituent, such as a benzene ring, a naphthalene ring, an anthracene ring, a fluorene ring, and a phenanthrene ring; and aromatic heterocycles including a heterocycle, such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring. Among these, a benzene ring and a naphthalene ring are preferable from the viewpoint of resolution, and a benzene ring is most preferable.

m₁ represents an integer of 1 or more.

m₁ is preferably an integer of 1 to 5, more preferably represents an integer of 1 to 3, still more preferably represents 1 or 2, and most preferably represents 1.

In a case where m₁ represents 1 and Ar₂ represents a benzene ring, the position of —OH substitution may be any of the para-, meta-, and ortho-positions with respect to the site for binding to the main chain of the polymer in the benzene ring, but the para-position is preferable from the viewpoint of alkali developability.

The aromatic ring in the aromatic ring group of Ar₂ may have a substituent, in addition to a group represented by —OH, and examples of the substituent include alkyl group, a halogen atom, an alkoxy group, a carboxyl group, an alkoxycarbonyl group, an alkylcarbonyl group, an alkylcarbonyloxy group, an alkylsulfonyloxy group, and an arylcarbonyl group.

General Formula (II) is preferably the following General Formula (II-1).

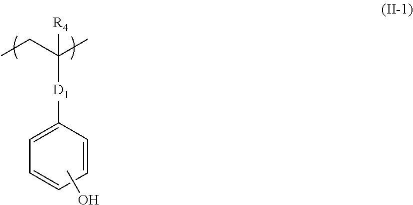

In the formula, R₄ represents a hydrogen atom, an organic group, or a halogen atom. D₁ represents a single bond or a divalent linking group. The definitions of R₄ and D₁ are as described above.

General Formula (II) is more preferably the following General Formula (II-2).

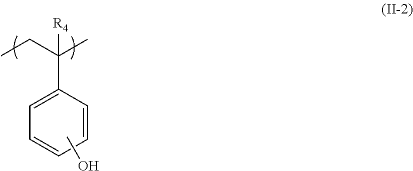

In the formula, R₄ represents a hydrogen atom, an organic group, or a halogen atom. The definition of R₄ is as described above.

Specific examples of the repeating unit represented by General Formula (II) are shown below, but are not limited thereto. Me represents a methyl group.

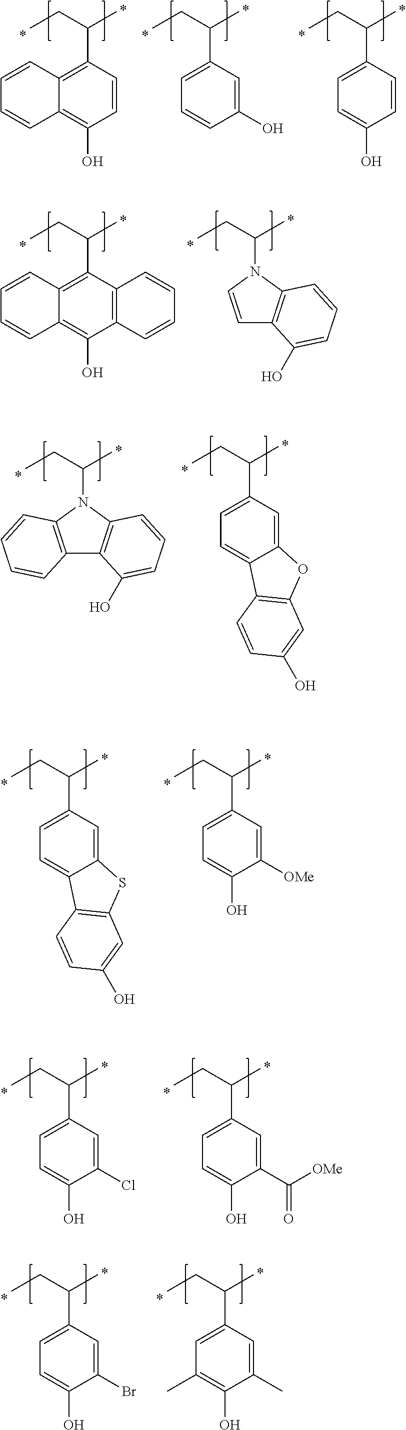

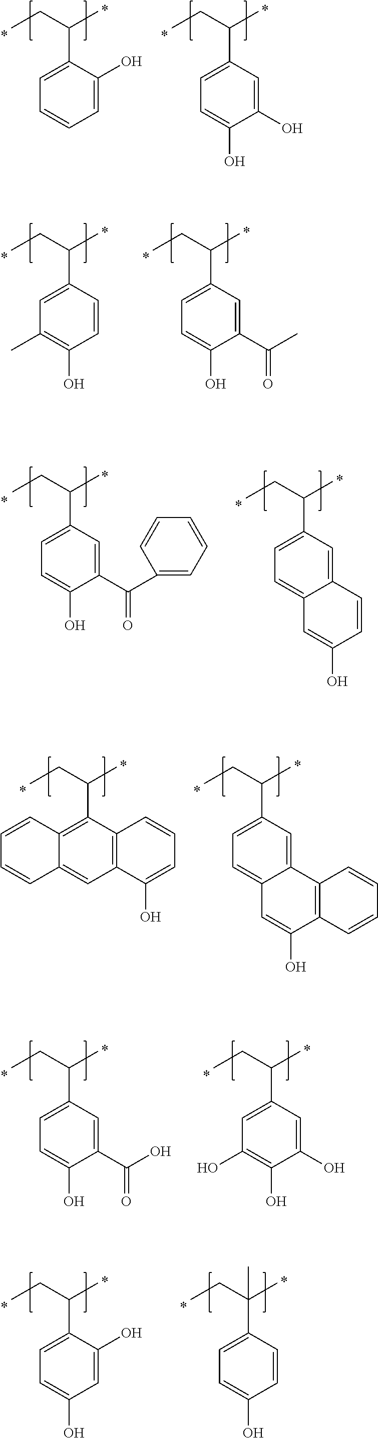

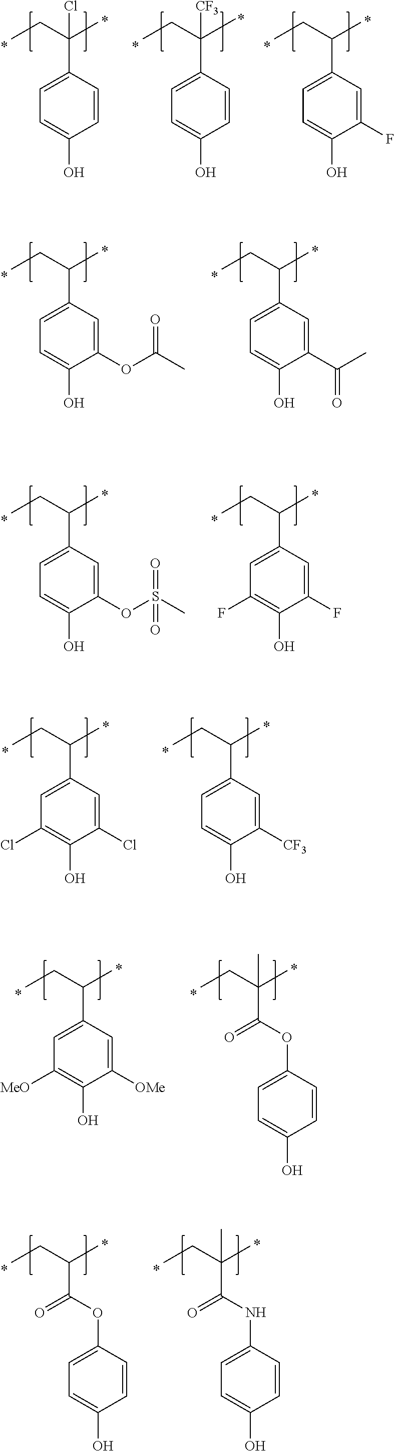

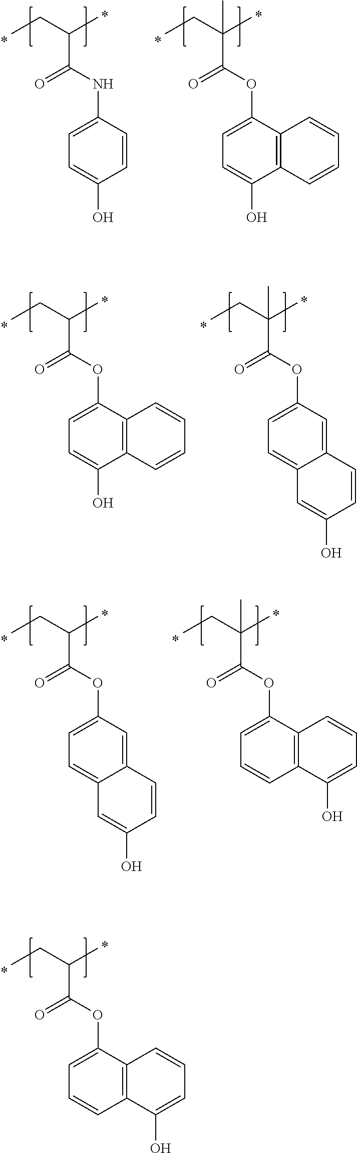

In a case where the resin includes the repeating unit represented by General Formula (II), the content of the repeating unit represented by General Formula (II) in the resin is not particularly limited, but is preferably 10% to 90% by mole, more preferably 30% to 90% by mole, still more preferably 40% to 90% by mole, and particularly preferably 40% to 60% by mole, with respect to all the repeating units of the resin, in view that the resolution of the pattern is more excellent.

(Suitable Aspect (Aspect 3))

Suitable aspects of the compound X include a resin having a repeating unit having a group that decomposes by the action of an acid to generate a polar group (hereinafter also simply referred to as an “acid-decomposable group”), in addition to the partial structure represented by General Formula (I), in view that the resolution of the pattern is more excellent. Further, the compound X is more preferably a resin including the repeating unit represented by General Formula (III) and the repeating unit represented by General Formula (II) as described above, and a repeating unit having a group that decomposes by the action of an acid.

The acid-decomposable group preferably has a structure in which a polar group is protected with a group that decomposes by the action of an acid to leave.

The polar group is not particularly limited as long as it is a group that is poorly soluble or insoluble in a developer including an organic solvent, and examples thereof include a carboxyl group, an acid group such as sulfonic acid (a group that is dissociated in a 2.38%-by-mass aqueous tetramethylammonium hydroxide solution used as a developer in a resist in the related art), or an alcoholic hydroxyl group.

Furthermore, the alcoholic hydroxyl group refers to a hydroxyl group bonded to a hydrocarbon group, which is a hydroxyl group other than a hydroxyl group (phenolic hydroxyl group) directly bonded to an aromatic ring, from which an aliphatic alcohol group (for example, a fluorinated alcohol group (a hexafluoroisopropanol group or the like)) having the α-position substituted with an electron withdrawing group such as a fluorine atom is excluded as an acid group. The alcoholic hydroxyl group is preferably a hydroxyl group having a pKa from 12 to 20.

The repeating unit having an acid-decomposable group is preferably a repeating unit having a group that generates a polar group other than a phenolic hydroxyl group.

Suitable aspects of the repeating unit having a group that decomposes by the action of an acid to generate a polar group include a repeating unit represented by any one of the following General Formulae (IVa) to (IVc), in view that the resolution of the pattern is more excellent. Here, the repeating unit represented by any one of General Formulae (IVa) to (IVc) corresponds to a repeating unit having a group (acid-decomposable group) that decomposes by the action of an acid to generate a polar group. That is, the repeating unit represented by General Formula (IVa) decomposes by the action of an acid to generate a group represented by —Ar₆OH as a polar group, and the repeating units represented by General Formulae (IVb) and (IVc) decompose by the action of an acid to generate a carboxylic acid group as a polar group.

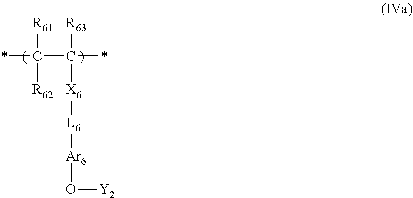

In General Formula (IVa),

R₆₁, R₆₂, and R₆₃ each independently represent a hydrogen atom, an alkyl group, a cycloalkyl group, a halogen atom, a cyano group, or an alkoxycarbonyl group. Here, R₆₂ may be bonded to Ar₆ to form a ring, and R₆₂ in this case represents a single bond or an alkylene group.

X₆ represents a single bond, —COO—, or —CONR₆₄—. R₆₄ represents a hydrogen atom or an alkyl group.

L₆ represents a single bond or an alkylene group.

Ar₆ represents a divalent aromatic ring group, and in the case of being bonded to R₆₂ to form a ring, represents a trivalent aromatic ring group.

Y₂ represents a group that leaves by the action of an acid.

General Formula (IVa) will be described in more detail.

R₆₁ to R₆₃ in General Formula (IVa) have the same definitions as R₅₁, R₅₂, and R₅₃ in General Formula (IVb) which will be described later, respectively, and the preferable ranges thereof are also the same.

In a case where R₆₂ represents an alkylene group, examples of the alkylene group include an alkylene group having 1 to 8 carbon atoms, such as a methylene group, an ethylene group, a propylene group, a butylene group, a hexylene group, and an octylene group, which may have a substituent.

Examples of the alkyl group of R₆₄ in —CONR₆₄— (R₆₄ represents a hydrogen atom or an alkyl group) represented by X₆ include the same ones as the alkyl groups represented by each of R₆₁ to R₆₃.

X₆ is preferably a single bond, —COO—, or —CONH—, and more preferably a single bond or —COO—.

Examples of the alkylene group in L₆ include an alkylene group having 1 to 8 carbon atoms, such as a methylene group, an ethylene group, a propylene group, a butylene group, a hexylene group, and an octylene group, which preferably may have a substituent. A ring formed by the bonding of R₆₂ and L₆ is particularly preferably a 5- or 6-membered ring.

Ar₆ represents a divalent aromatic ring group. The divalent aromatic ring group may have a substituent, and preferred examples thereof include an arylene group having 6 to 18 carbon atoms, such as a phenylene group, a tolylene group, and a naphthylene group, and divalent aromatic ring groups including a heterocycle, such as thiophene, furan, pyrrole, benzothiophene, benzofuran, benzopyrrole, triazine, imidazole, benzimidazole, triazole, thiadiazole, and thiazole.

Ar₆ may have a plurality of substituents, and in this case, the plurality of substituents may be bonded to each other to form a ring.

Examples of the substituent which the alkyl group, the cycloalkyl group, the alkoxycarbonyl group, the alkylene group, or the divalent aromatic ring group as described above can have include the same specific examples of the substituent which each of the groups represented by R₅₁ to R₅₃ in General Formula (IVb) which will be described later can have.

Y₂ represents a group that leaves by the action of an acid.

Examples of Y₂ which is a group that leaves by the action of an acid include —C(R₃₆)(R₃₇)(R₃₈), —C(═O)—O—C(R₃₆)(R₃₇)(R₃₈), —C(R₀₁)(R₀₂)(OR₃₉), —C(R₀₁)(R₀₂)—C(═O)—O—C(R₃₆)(R₃₇)(R₃₈), and —CH(R₃₆)(Ar).

In the formula, R₃₆ to R₃₉ each independently represent an alkyl group, a cycloalkyl group, an aryl group, a group formed by combining an alkylene group and an aryl group, or an alkenyl group. R₃₆ and R₃₇ may be bonded to each other to form a ring.

R₀₁ and R₀₂ each independently represent a hydrogen atom, an alkyl group, a cycloalkyl group, an aryl group, a group formed by combining an alkylene group and an aryl group, or an alkenyl group.

Ar represents an aryl group.

The alkyl group of each of R₃₆ to R₃₉, R₀₁, and R₀₂ may be linear or branched, and is preferably an alkyl group having 1 to 8 carbon atoms, and examples thereof include a methyl group, an ethyl group, a propyl group, an n-butyl group, a sec-butyl group, a hexyl group, and an octyl group.

The cycloalkyl group of each of R₃₆ to R₃₉, R₀₁, and R₀₂ may be monocyclic or polycyclic. The monocyclic cycloalkyl group is preferably a cycloalkyl group having 3 to 10 carbon atoms, and examples thereof include a cyclopropyl group, a cyclobutyl group, a cyclopentyl group, a cyclohexyl group, and a cyclooctyl group. The polycyclic cycloalkyl group is preferably a cycloalkyl group having 6 to 20 carbon atoms, and examples thereof include an adamantyl group, a norbornyl group, an isobornyl group, a camphanyl group, a dicyclopentyl group, an α-pinel group, a tricyclodecanyl group, a tetracyclododecyl group, and an androstanyl group. In addition, some of the carbon atoms in the cycloalkyl group may be substituted with heteroatoms such as an oxygen atom.

The aryl group of each of R₃₆ to R₃₉, R₀₁, R₀₂, and Ar is preferably an aryl group having 6 to 10 carbon atoms, and examples thereof include aryl groups such as a phenyl group, a naphthyl group, and an anthryl group, and divalent aromatic ring groups including a heterocycle, such as thiophene, furan, pyrrole, benzothiophene, benzofuran, benzopyrrole, triazine, imidazole, benzimidazole, triazole, thiadiazole, and thiazole.

A group formed by combining an alkylene group and an aryl group of each of R₃₆ to R₃₉, R₀₁, and R_{O2} is preferably an aralkyl group having 7 to 12 carbon atoms, and examples thereof include a benzyl group, a phenethyl group, and a naphthylmethyl group.

The alkenyl group of each of R₃₆ to R₃₉, R₀₁, and R₀₂ is preferably an alkenyl group having 2 to 8 carbon atoms, and examples thereof include a vinyl group, an allyl group, a butenyl group, and a cyclohexenyl group.

A ring formed by the mutual bonding of R₃₆ and R₃₇ may be monocyclic or polycyclic. The monocyclic ring preferably has a cycloalkyl structure having 3 to 10 carbon atoms, and examples thereof include a cyclopropane structure, a cyclobutane structure, a cyclopentane structure, a cyclohexane structure, a cycloheptane structure, and a cyclooctane structure. The polycyclic ring preferably has a cycloalkyl structure having 6 to 20 carbon atoms, and examples thereof include an adamantane structure, a norbornane structure, a dicyclopentane structure, a tricyclodecane structure, and a tetracyclododecane structure. In addition, some of the carbon atoms in the cycloalkyl structure may be substituted with heteroatoms such as an oxygen atom.

The respective groups as R₃₆ to R₃₉, R₀₁, R₀₂, and Ar may have a substituent, and examples of the substituent include an alkyl group, a cycloalkyl group, an aryl group, an amino group, an amide group, a ureido group, a urethane group, a hydroxyl group, a carboxyl group, a halogen atom, an alkoxy group, a thioether group, an acyl group, an acyloxy group, an alkoxycarbonyl group, a cyano group, and nitro group, and the substituent preferably has 8 or more carbon atoms.

Y₂ which is a group that leaves by the action of an acid more preferably has the structure represented by the following General Formula (VI-A).

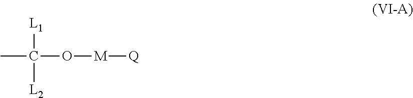

Here, L₁ and L₂ each independently represent a hydrogen atom, an alkyl group, a cycloalkyl group, an aryl group, or a group formed by combining an alkylene group and an aryl group.

M represents a single bond or a divalent linking group.

Q represents an alkyl group, a cycloalkyl group which may include a heteroatom, an aryl group which may include a heteroatom, an amino group, an ammonium group, a mercapto group, a cyano group, or an aldehyde group.

At least two members out of Q, M, or L₁ may be bonded to each other to form a ring (preferably a 5- or 6-membered ring).

The alkyl group as each of L₁ and L₂ is, for example, an alkyl group having 1 to 8 carbon atoms, and specifically, preferred examples thereof include a methyl group, an ethyl group, a propyl group, an n-butyl group, a sec-butyl group, a hexyl group, and an octyl group.

The cycloalkyl group represented by each of L₁ and L₂ is, for example, a cycloalkyl group having 3 to 15 carbon atoms, and specifically, preferred examples thereof include a cyclopentyl group, a cyclohexyl group, a norbornyl group, and an adamantyl group.

The aryl group represented by each of L₁ and L₂ is, for example, an aryl group having 6 to 15 carbon atoms, and specifically, preferred examples thereof include a phenyl group, a tolyl group, a naphthyl group, and anthryl group.

A group formed by combining an alkylene group and an aryl group represented by each of L₁ and L₂ has, for example, 6 to 20 carbon atoms, and examples thereof include aralkyl groups such as a benzyl group and a phenethyl group.

Examples of the divalent linking group represented by M include alkylene groups (for example, a methylene group, an ethylene group, a propylene group, a butylene group, a hexylene group, and an octylene group), cycloalkylene groups (for example, a cyclopentylene group, a cyclohexylene group, and adamantylene group), alkenylene groups (for example, an ethenylene group, a propenylene group, and a butenylene group), divalent aromatic ring groups (for example, a phenylene group, a tolylene group, and a naphthylene group), —S—, —O—, —CO—, —SO₂—, —N(R₀)—, and divalent linking groups formed by combining a plurality of these. R₀ is a hydrogen atom or an alkyl group (which is, for example, an alkyl group having 1 to 8 carbon atoms, and specifically, a methyl group, an ethyl group, a propyl group, an n-butyl group, a sec-butyl group, a hexyl group, an octyl group, or the like).

The alkyl group as Q is the same as each group represented by L₁ and L₂ as described above.

In the cycloalkyl group as Q, which may include a heteroatom and the aryl group which may include a heteroatom, examples of the aliphatic hydrocarbon ring group which does not include a heteroatom and the aryl group which does not include a heteroatom include the cycloalkyl group and the aryl group represented by each of L₁ and L₂ as described above, and each of the cycloalkyl group and the aryl group preferably has 3 to 15 carbon atoms.

Examples the cycloalkyl group including a heteroatom and the aryl group including a heteroatom include a group having a heterocyclic structure such as thiirane, cyclothiolane, thiophene, furan, pyrrole, benzothiophene, benzofuran, benzopyrrole, triazine, imidazole, benzimidazole, triazole, thiadiazole, thiazole, or pyrrolidone, and the cycloalkyl group and the aryl group are not limited thereto as long as, in general, the groups have a structure (a ring formed by carbon and a heteroatom or a ring formed by heteroatoms) called a heterocycle.

As a ring formed by the mutual bonding of at least two members out of Q, M, or L₁, a case where at least two members out of Q, M, or L₁ are bonded to each other to form, for example, a propylene group or a butylene group, and a 5- or 6-membered ring containing an oxygen atom is formed is exemplified.

The respective groups represented by L₁, L₂, M, and Q in General Formula (VI-A) may have a substituent, and examples thereof include a substituent described as a substituent which each of R₃₆ to R₃₉, R₀₁, R₀₂, and Ar as described above may have, and the substituent preferably has 8 or less carbon atoms.

The group represented by -M-Q is preferably a group composed of 1 to 30 carbon atoms.

The repeating unit represented by General Formula (IVa) is preferably the repeating unit represented by the following General Formula (Iva′).

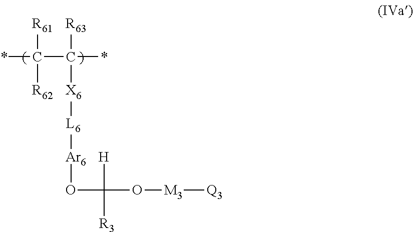

In General Formula (IVa′),

R₆₁, R₆₂, R₆₃, X₆, L₆, and Ar₆ have the same definitions as those in General Formula (IVa).

R₃ represents a hydrogen atom, an alkyl group, a cycloalkyl group, an aryl group, an aralkyl group, an alkoxy group, an acyl group, or a heterocyclic group.

M₃ represents a single bond or a divalent linking group.

Q₃ represents an alkyl group, a cycloalkyl group, an aryl group, or a heterocyclic group.

At least two members out of Q₃, M₃, or R₃ may be bonded to each other to form a ring.

Specific examples and preferred examples of R₆₁, R₆₂, R₆₃, X₆, and L₆ are the same as those of R₆₁, R₆₂, R₆₃, X₆, and L₆ in General Formula (IVa), respectively.

Specific examples of the divalent aromatic ring group represented by Ar₆ are the same as those of Ar₆ in General Formula (IVa), and the divalent aromatic ring group is more preferably a phenylene group or a naphthylene group, and still more preferably a phenylene group.

Ar₆ may have a substituent, and examples of the substituent which Ar₆ can have include the same ones as the substituent which Ar₆ in General Formula (IVa) as described above can have.

The alkyl group or the cycloalkyl group represented by R₃ has the same definition as the alkyl group or the cycloalkyl group represented by each of R₃₆ to R₃₉, R₀₁, and R₀₂ as described above.

The aryl group represented by R₃ described above has the same definition as the aryl group represented by each of R₃₆ to R₃₉, R₀₁, and R₀₂, and a preferred range thereof is also the same.

The aralkyl group represented by R₃ is preferably an aralkyl group having 7 to 12 carbon atoms, and examples thereof include a benzyl group, a penethyl group, and a naphthylmethyl group.

The alkyl group moiety of the alkoxy group represented by R₃ is the same as alkyl group represented by each of R₃₆ to R₃₉, R₀₁, and R₀₂ as described above, and a preferred range thereof is also the same.

Examples of the acyl group represented by R₃ include an aliphatic acyl group having 1 to 10 carbon atoms, such as a formyl group, an acetyl group, a propionyl group, a butyryl group, an isobutyryl group, a valeryl group, a pivaloyl group, a benzoyl group, and a naphthoyl group, and the acyl group is preferably an acetyl group or a benzoyl group.

Examples of the heterocyclic group represented by R₃ include the cycloalkyl group including a heteroatom and the aryl group including a heteroatom, as described above, and the heterocyclic group is preferably a pyridine ring group or a pyran ring group.

R₃ is preferably a linear or branched alkyl group having 1 to 8 carbon atoms (specifically, a methyl group, an ethyl group, a propyl group, an i-propyl group, an n-butyl group, a sec-butyl group, a tert-butyl group, a neopentyl group, a hexyl group, a 2-ethylhexyl group, or an octyl group), a cycloalkyl group having 3 to 15 carbon atoms (specifically, a cyclopentyl group, a cyclohexyl group, a norbornyl group, or an adamantyl group), or a group having 2 or more carbon atoms. R₃ is more preferably an ethyl group, an i-propyl group, a sec-butyl group, a tert-butyl group, a neopentyl group, a cyclohexyl group, an adamantyl group, a cyclohexyl methyl group, or an adamantane methyl group, and still more preferably a tert-butyl group, a sec-butyl group, a neopentyl group, a cyclohexyl methyl group, or an adamantane methyl group.

The alkyl group, the cycloalkyl group, the aryl group, the aralkyl group, the alkoxy group, the acyl group, or the heterocyclic group as described above may further have a substituent, and examples of the substituent that the groups may have include those described as a substituent that each of R₃₆ to R₃₉, R₀₁, R₀₂, and Ar as described above may have.

The divalent linking group represented by M₃ as described above has the same definition as M in the structure represented by General Formula (VI-A), and a preferred range thereof is also the same. M₃ may have a substituent, and examples of the substituent which M₃ may have include the same groups as those which M in the structure represented by General Formula (VI-A) as described above may have.

The alkyl group, the cycloalkyl group, and the aryl group represented by Q₃ has the same definitions as Q in the structure represented by General Formula (VI-A), and a preferred range thereof is also the same.

Examples of the heterocyclic group represented by Q₃ include a cycloalkyl group including a heteroatom and an aryl group including a heteroatom as Q in the structure represented by General Formula (VI-A).

Q₃ may have a substituent, and examples of the substituent which Q₃ may have include the same ones as the substituents which Q in the structure represented by General Formula (VI-A) as described above can have.

A ring which is formed by the bonding of at least two members out of Q₃, M₃, or R₃ has the same definition as the ring which is formed by the mutual bonding of at least two members out of Q, M, or L₁ in General Formula (VI-A) as described above, and a preferred range thereof is also the same.

R₃ in General Formula (IVa′) is preferably a group having 2 or more carbon atoms, and more preferably a group represented by the following General Formula (IV-2).

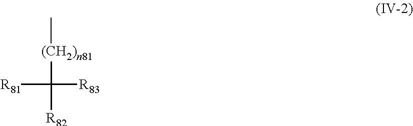

In General Formula (IV-2), R₈₁, R₈₂, and R₈₃ each independently represent an alkyl group, an alkenyl group, a cycloalkyl group or an aryl group. n81 represents 0 or 1.

At least two members out of R₈₁, . . . , or R₈₃ may be linked to each other to form a ring. The alkyl group represented by each of R₈₁ to R₈₃ may be linear or branched, and is preferably an alkyl group having 1 to 8 carbon atoms.

The alkenyl group represented by each of R₈₁ to R₈₃ may be linear or branched, and is preferably an alkenyl group having 1 to 8 carbon atoms.

Examples of the cycloalkyl groups represented by R₈₁ to R₈₃ include the same groups as those described as the cycloalkyl group of R₃₆ to R₃₉, R₀₁, and R_{oz} as described above.

Examples of the aryl groups represented by R₈₁ to R₈₃ include the same groups as those described as the aryl group of R₃₆ to R₃₉, R₀₁, and R₀₂ as described above.

R₈₁ to R₈₃ are each preferably an alkyl group, and more preferably a methyl group.

A ring which at least two members out of R₈₁, . . . , or R₈₃ can form is preferably a cyclopentyl group, a cyclohexyl group, a norbornyl group, or an adamantyl group.

Specific examples of the repeating unit represented by General Formula (IVa) are shown below, but the present invention is not limited thereto.

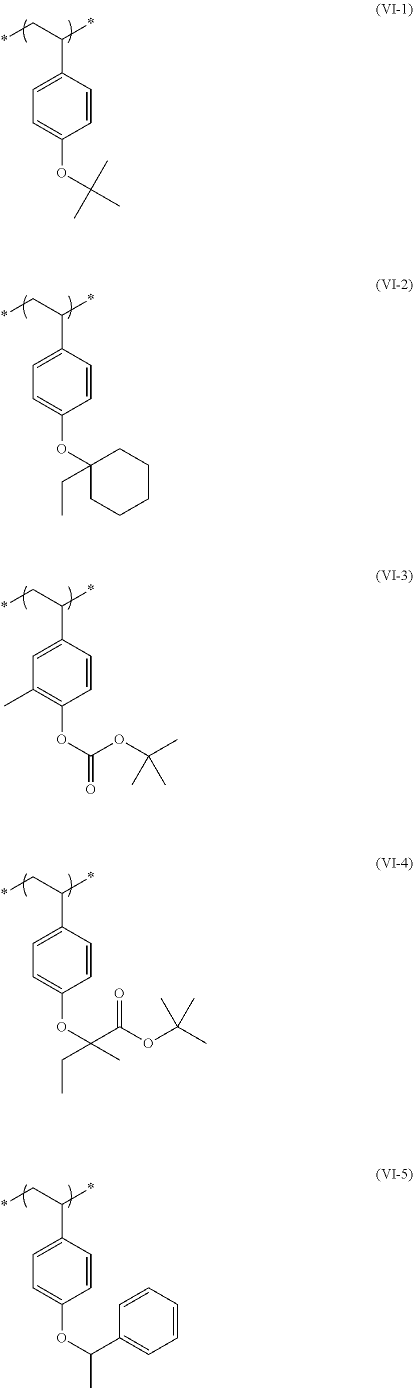

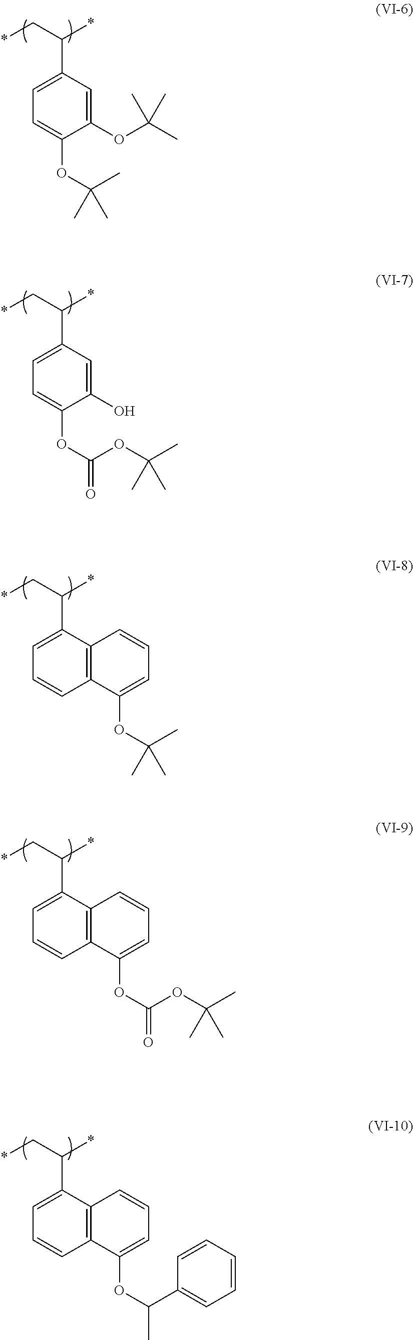

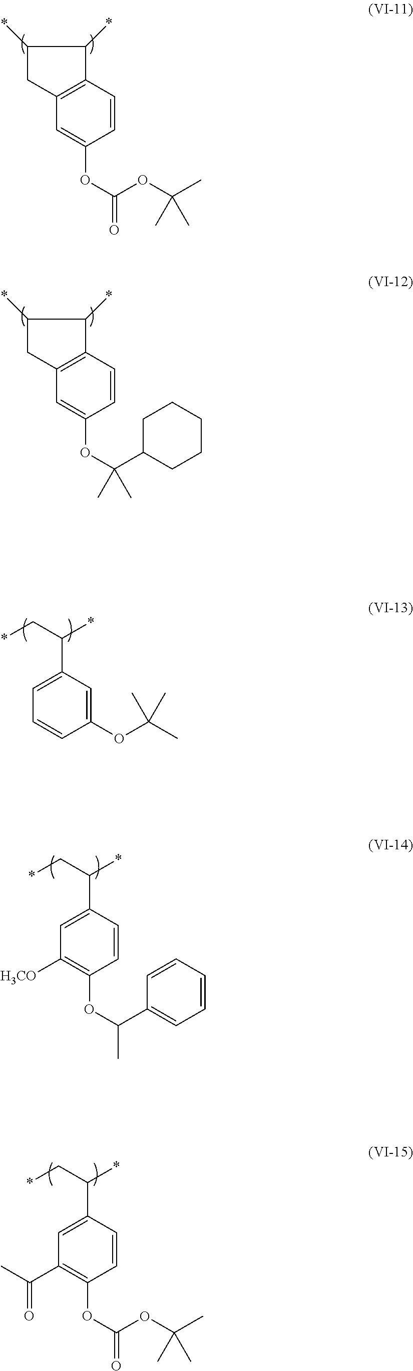

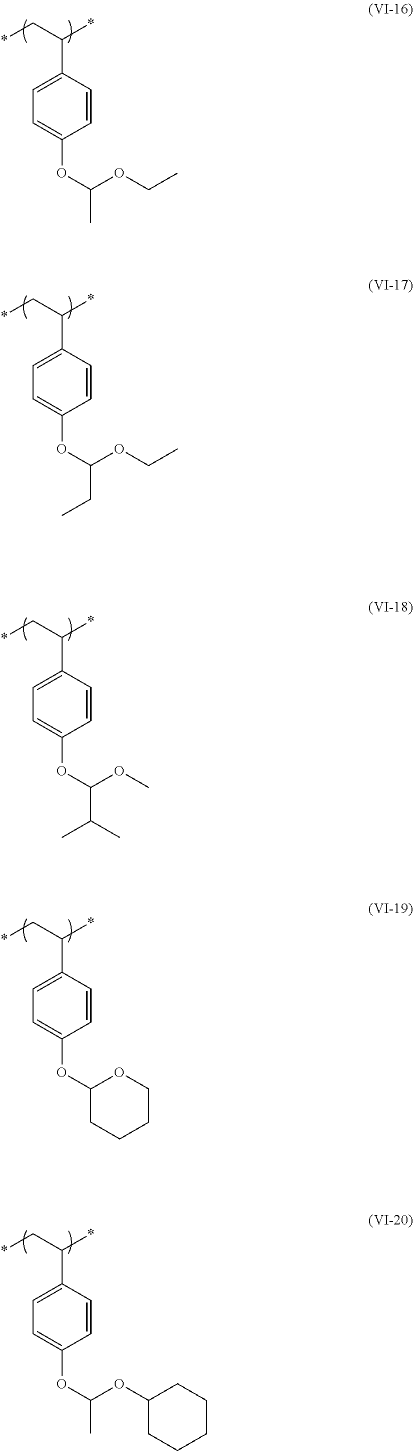

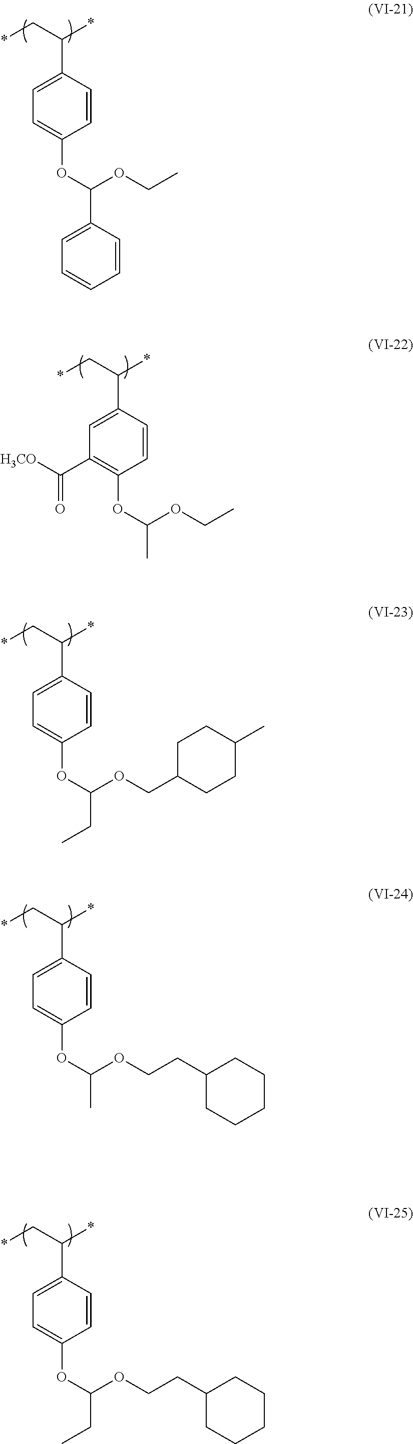

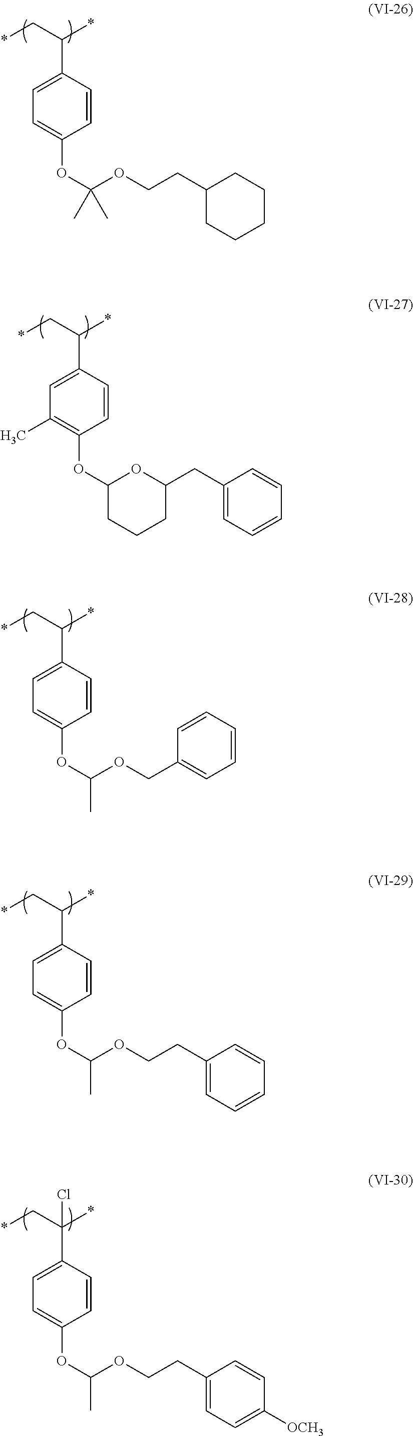

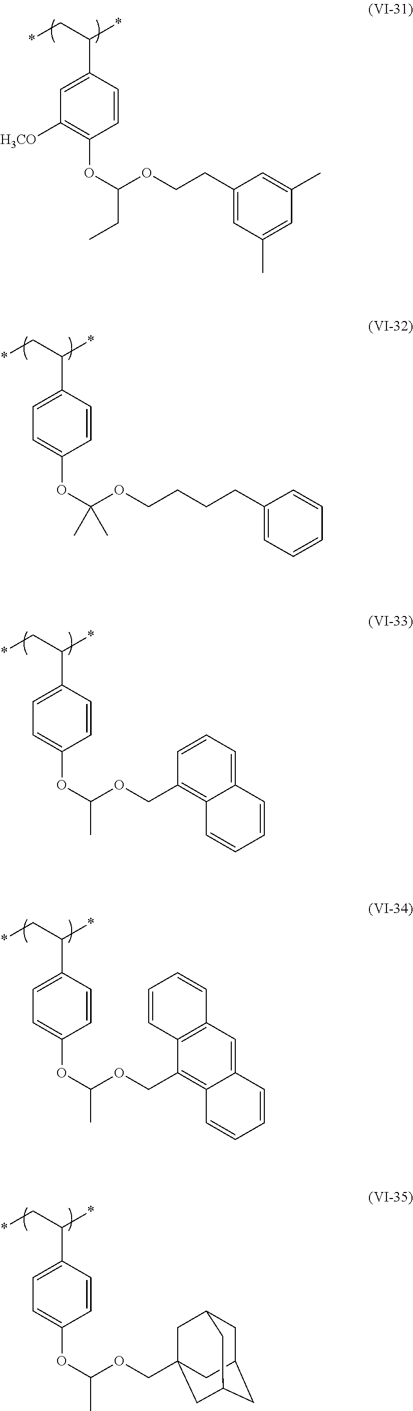

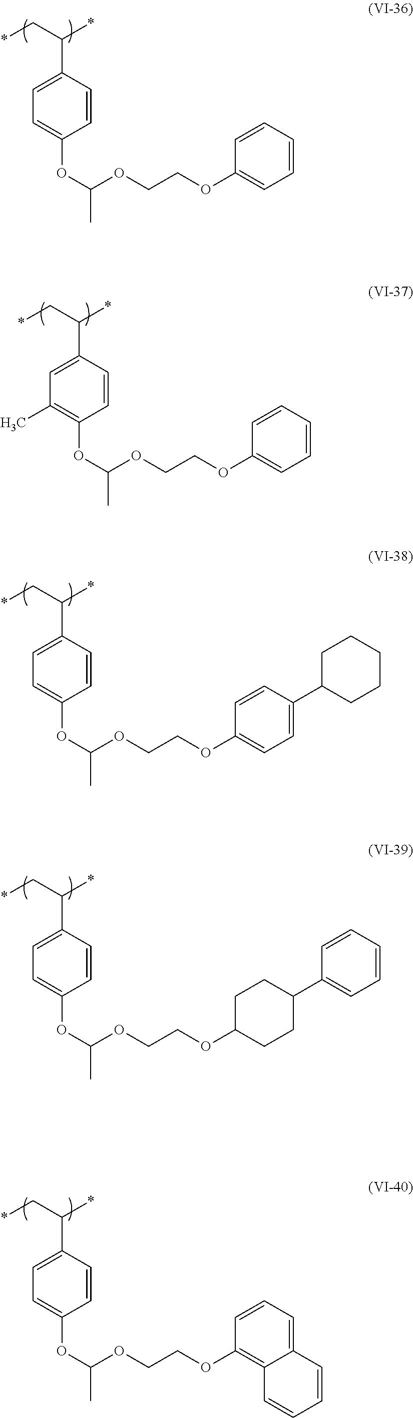

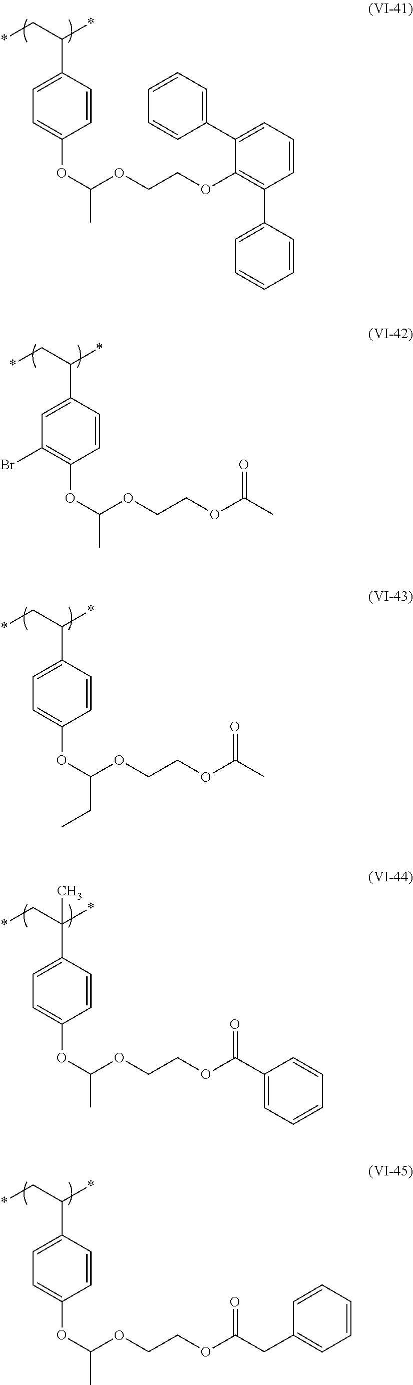

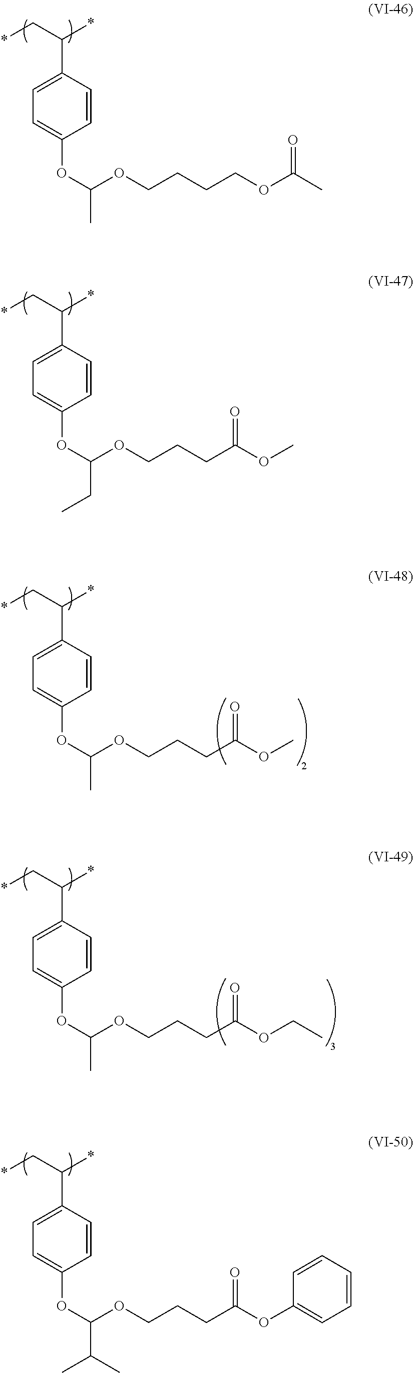

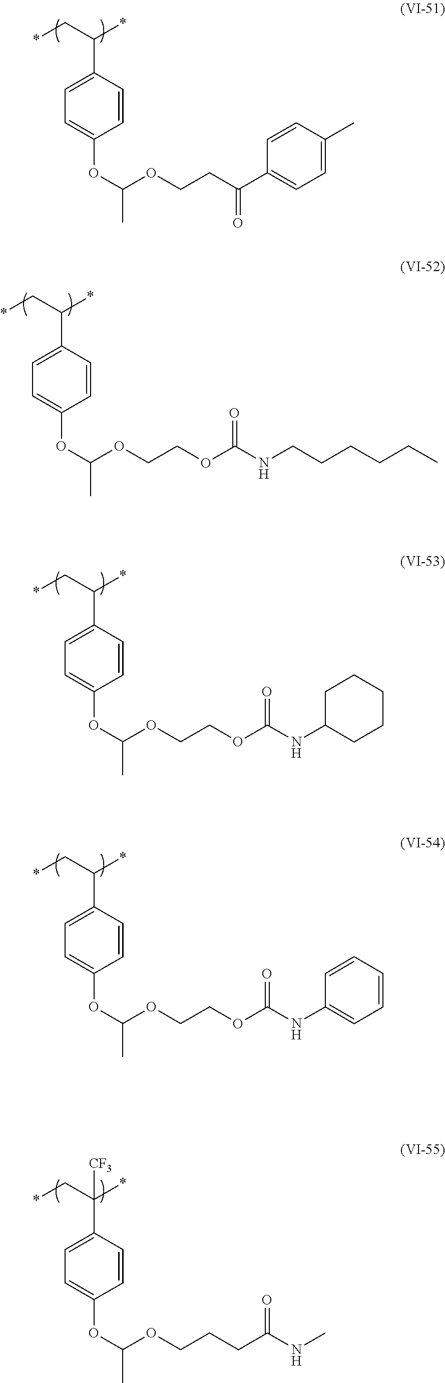

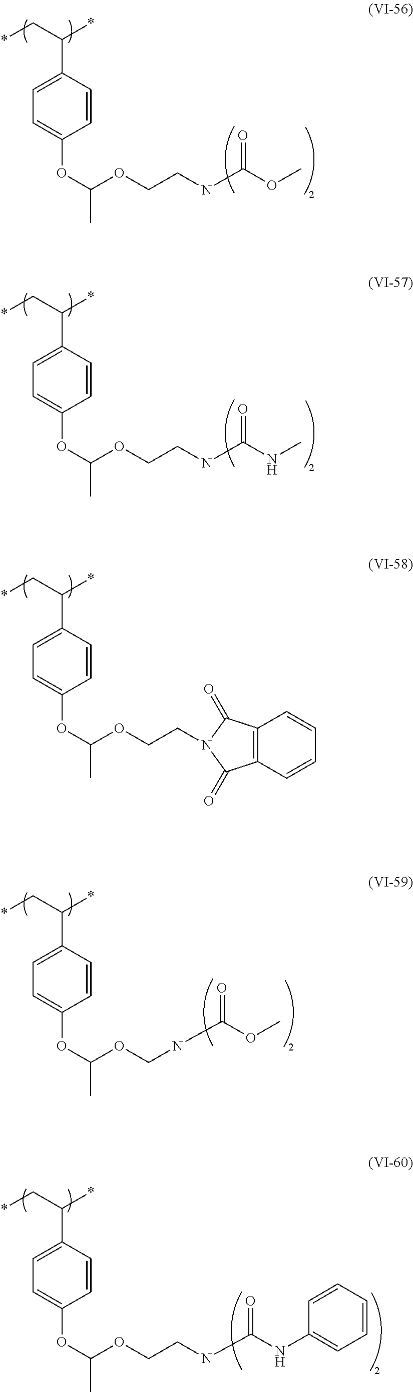

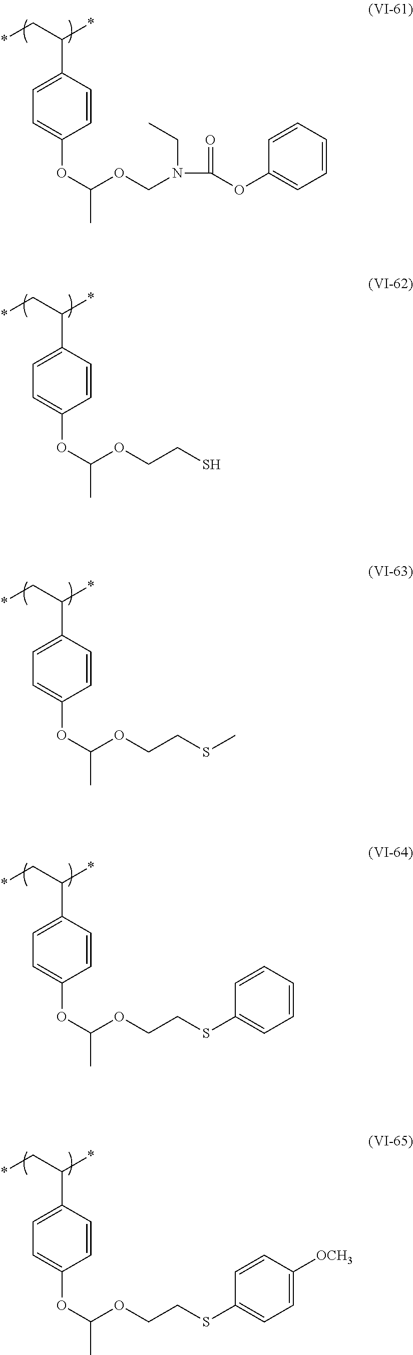

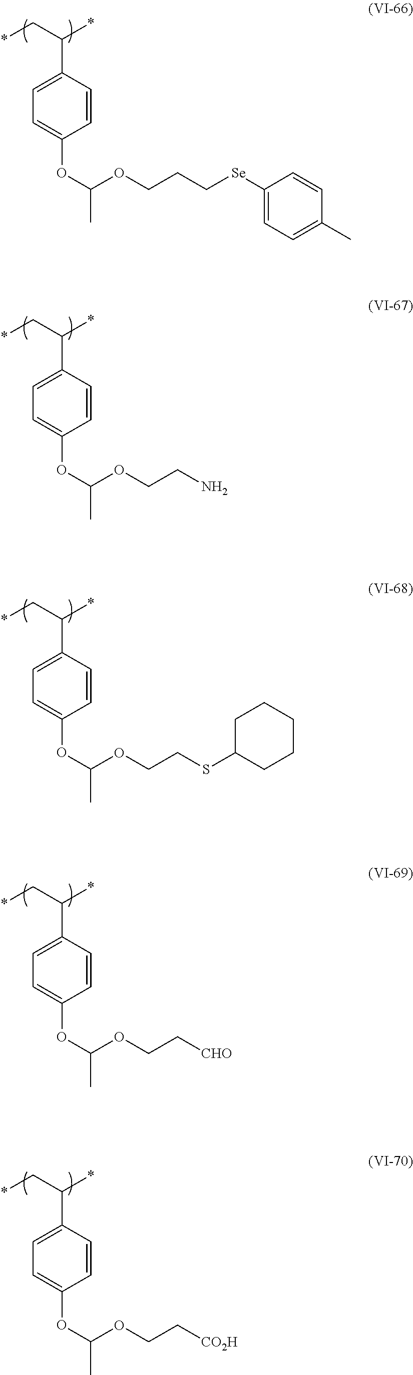

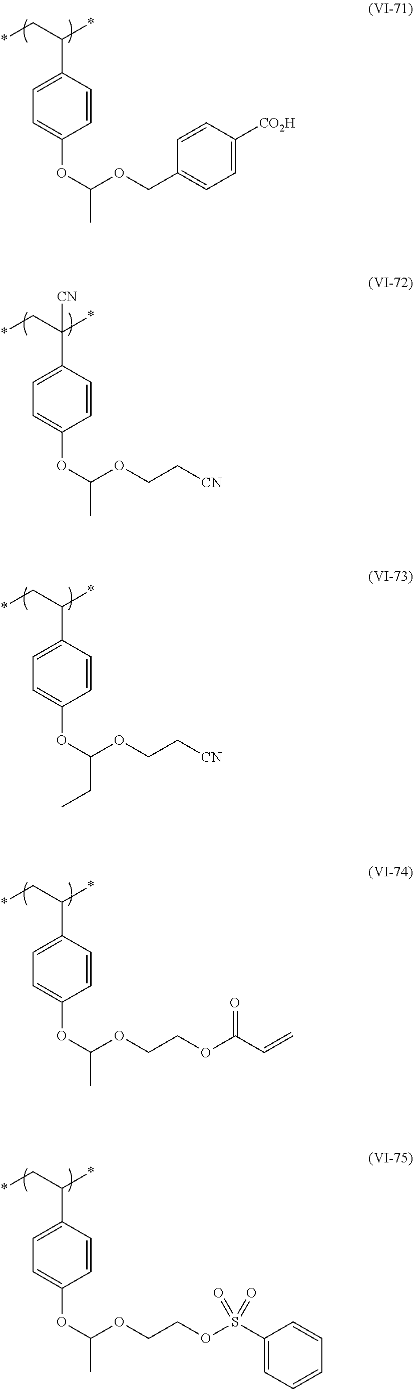

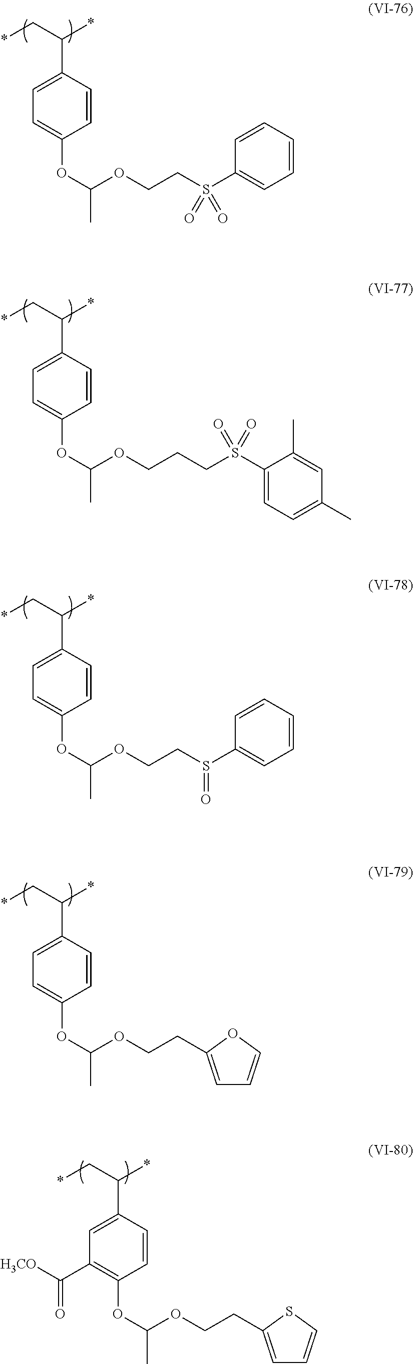

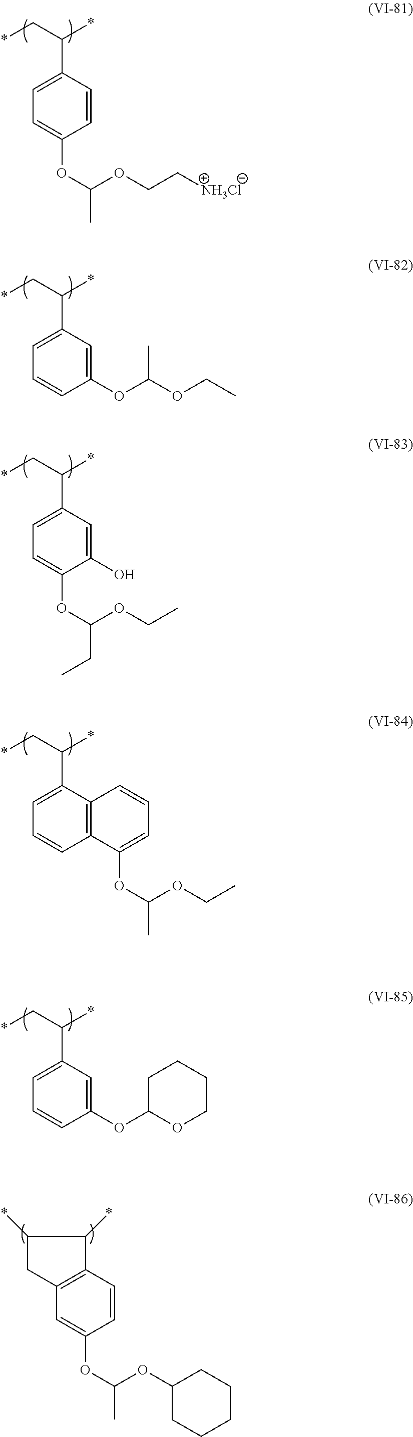

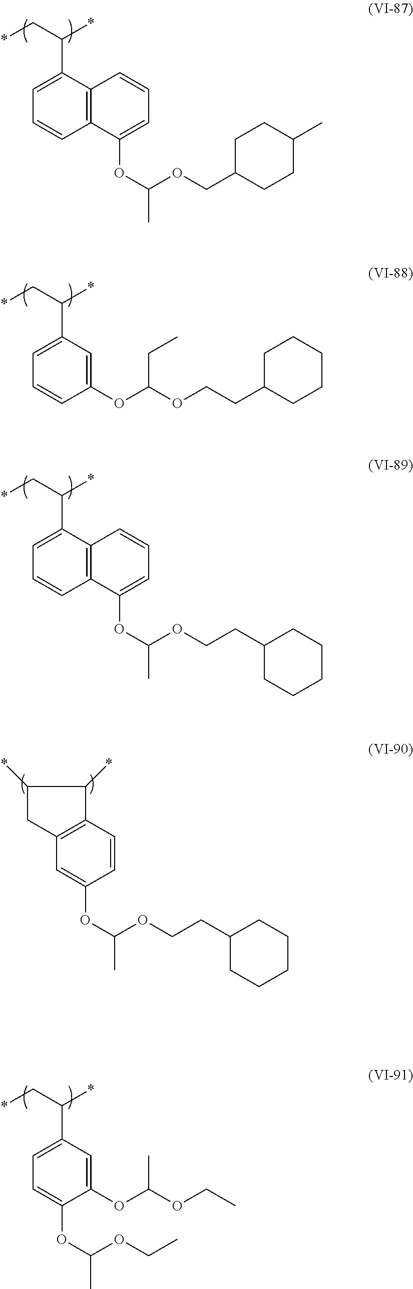

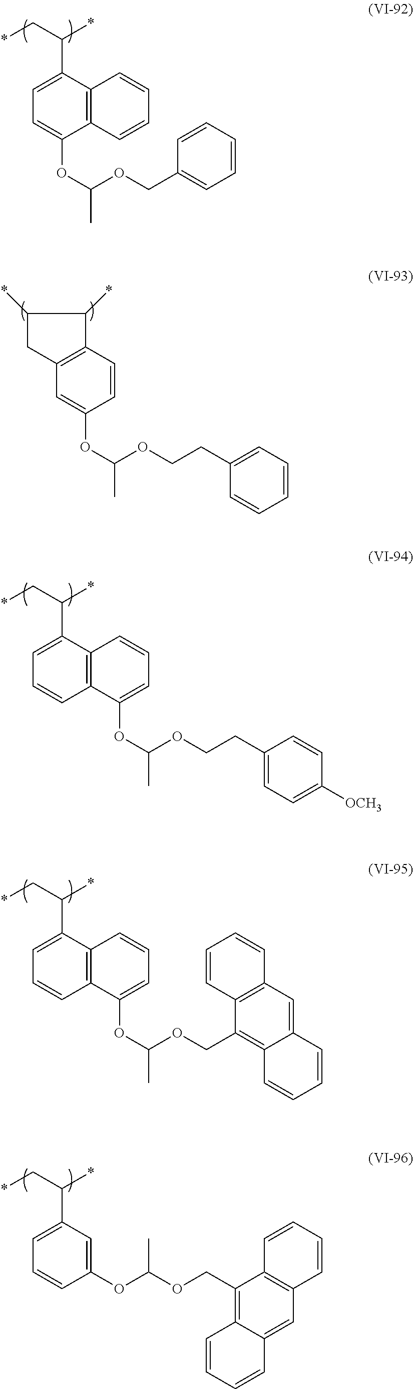

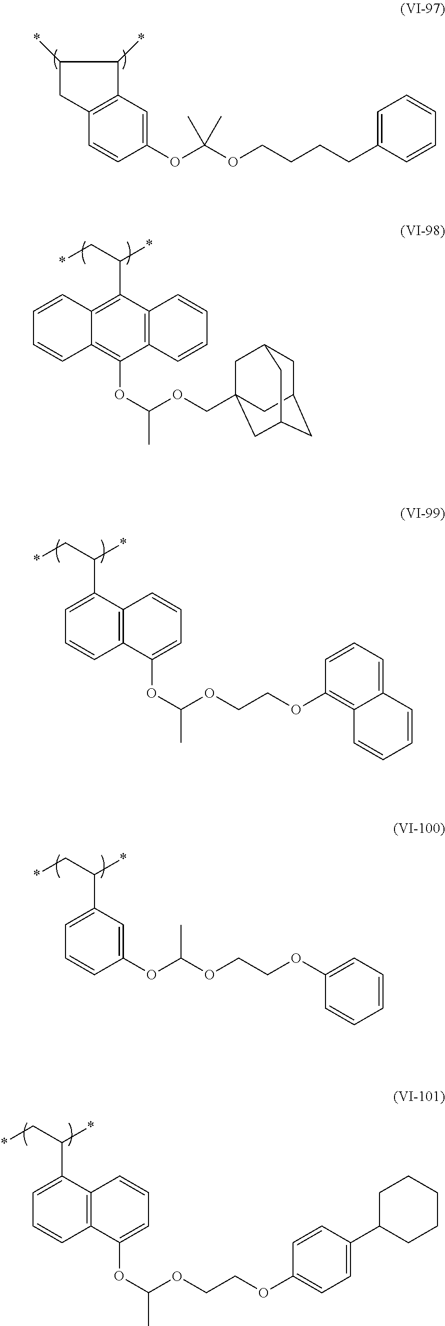

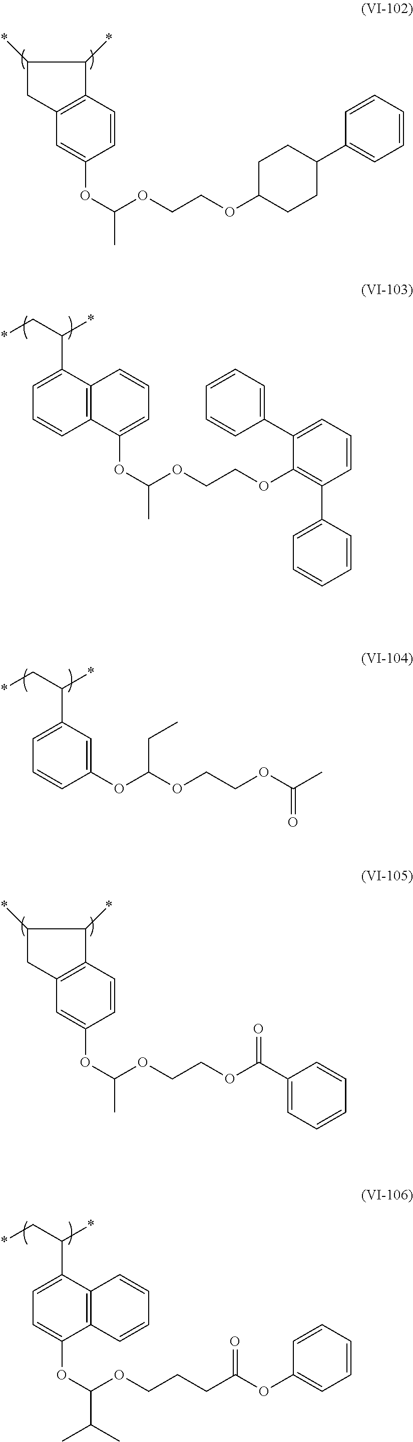

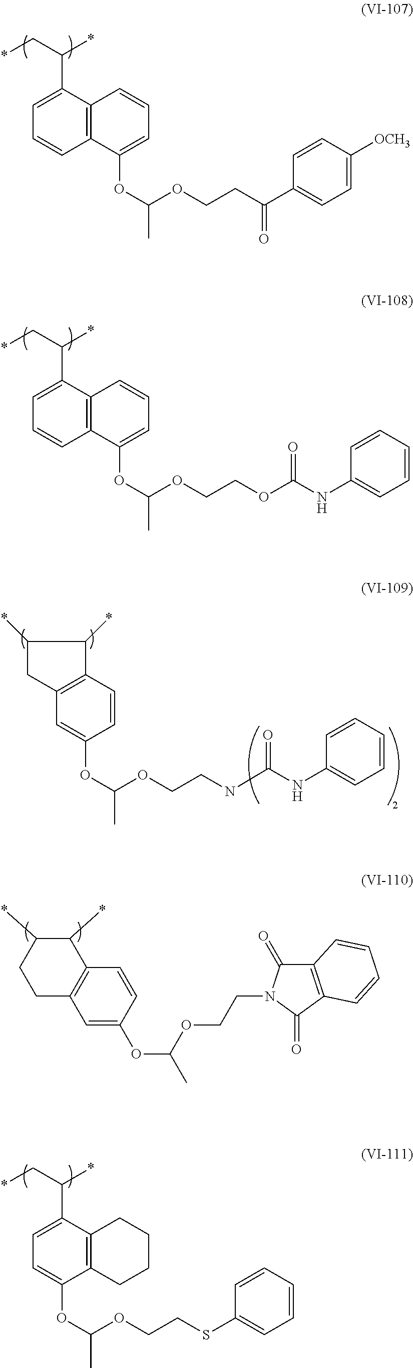

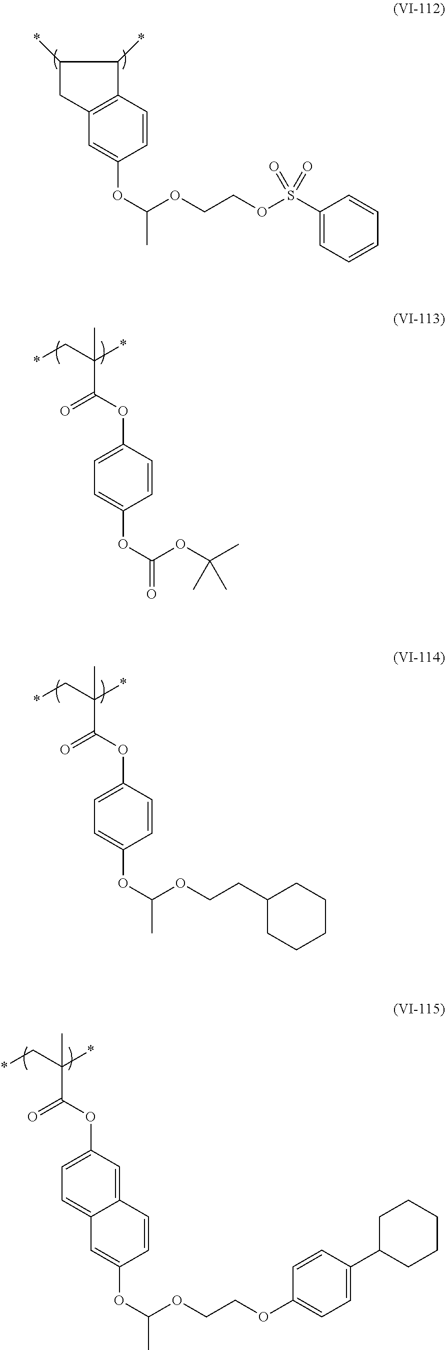

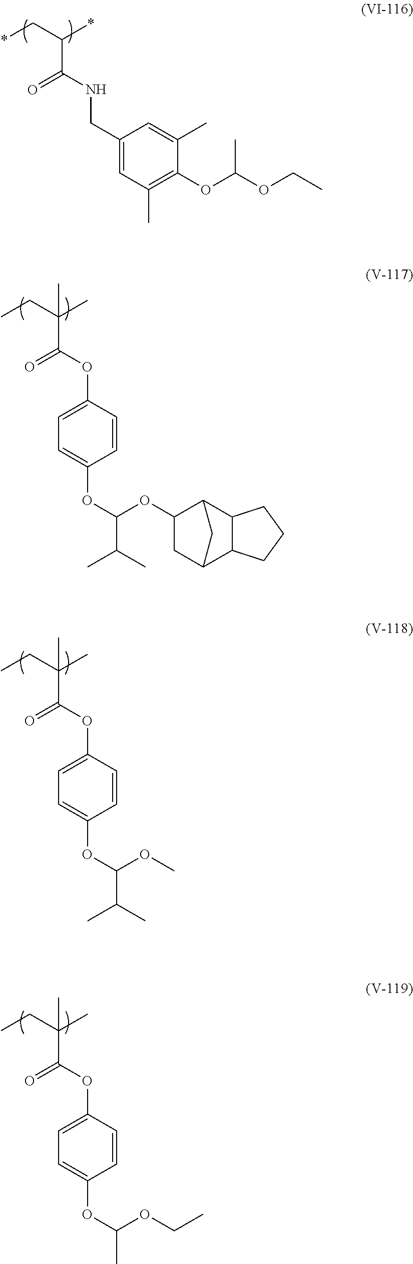

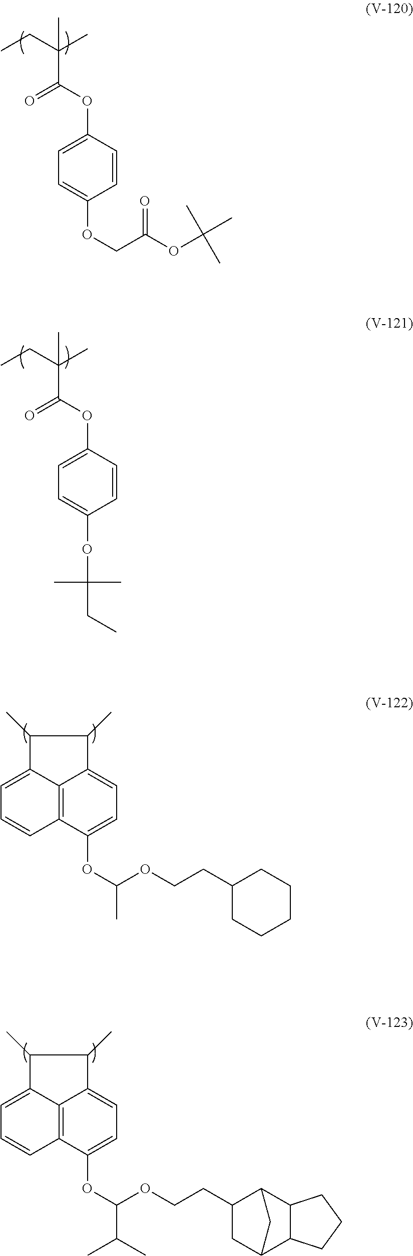

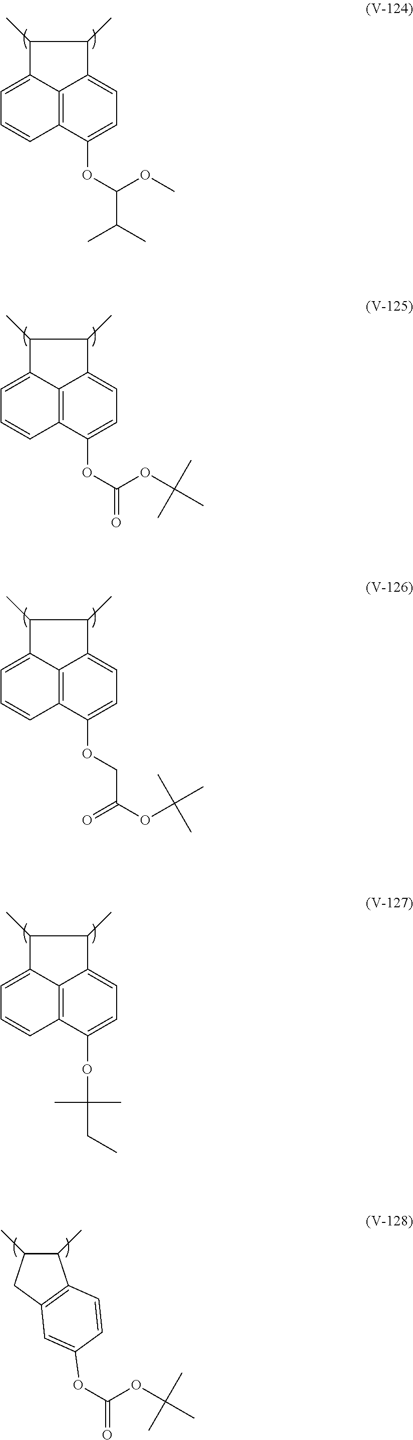

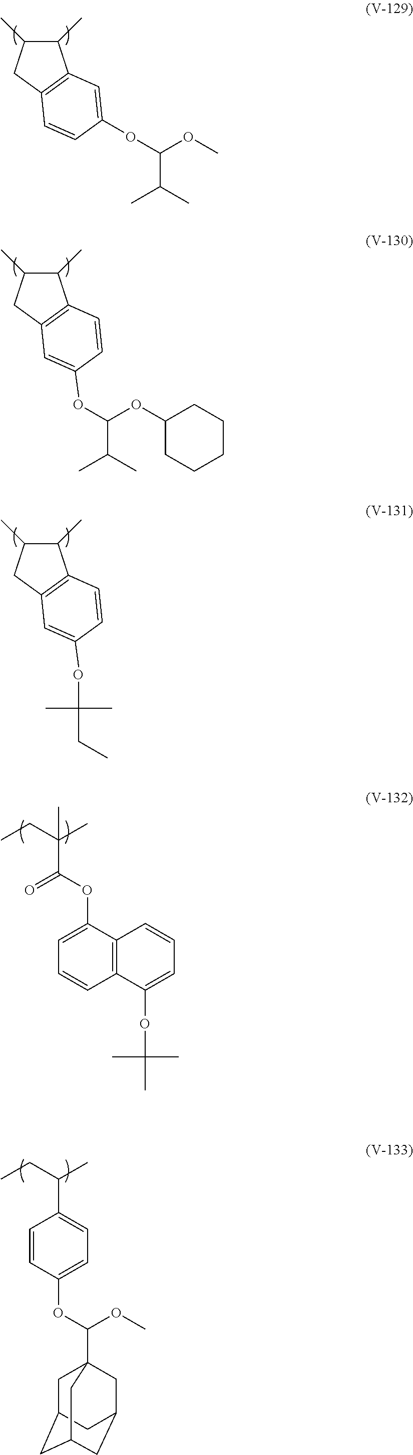

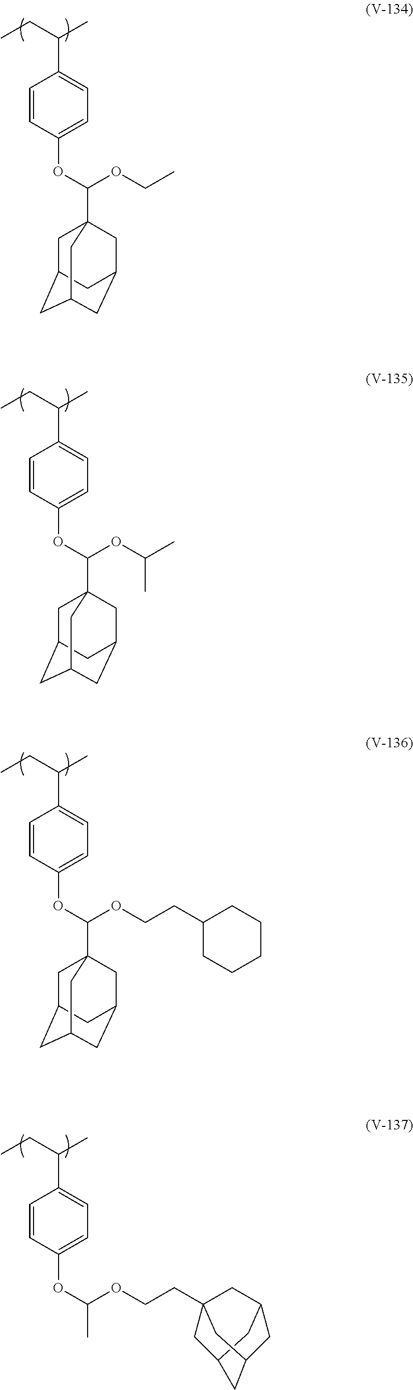

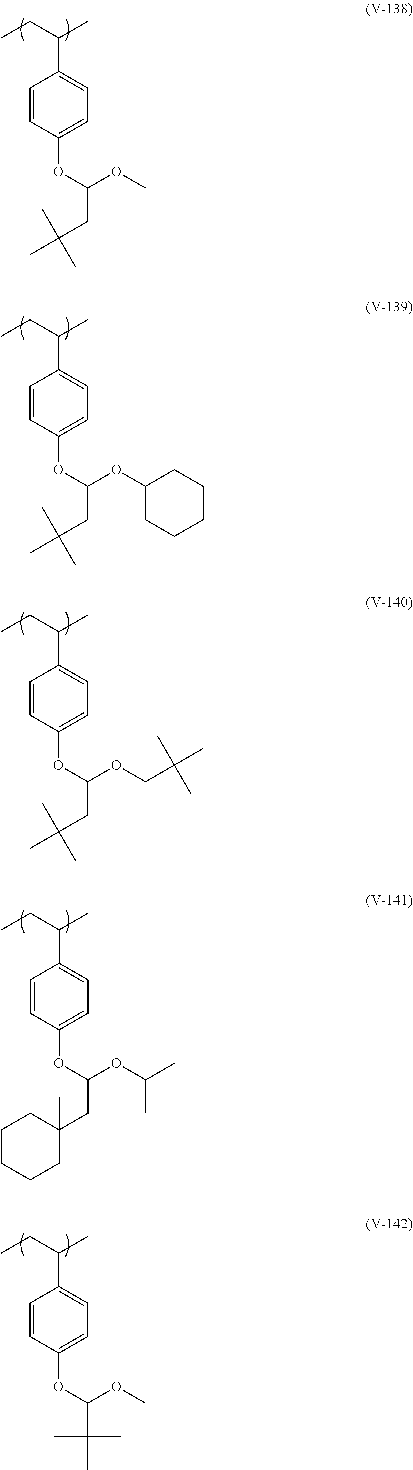

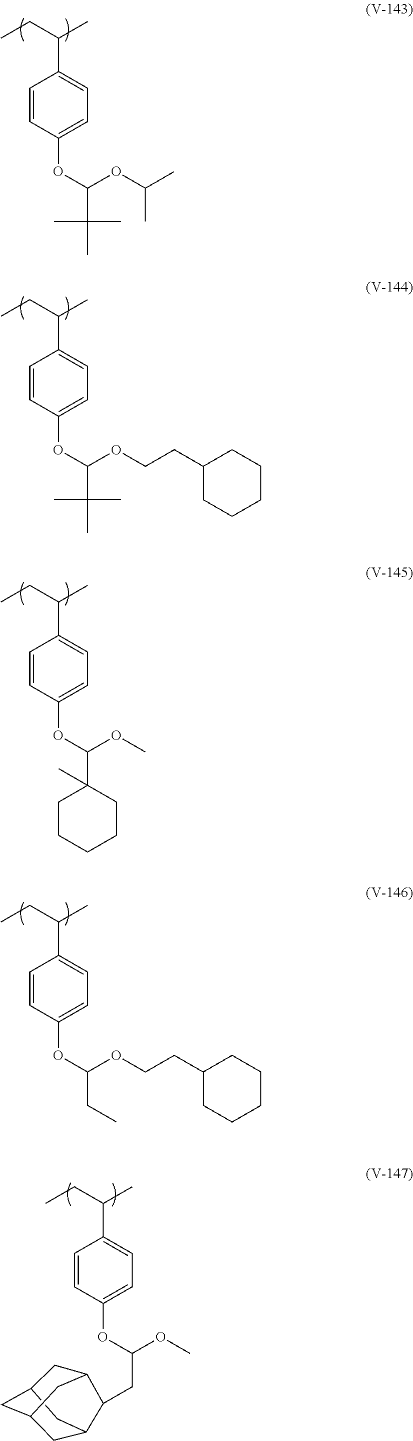

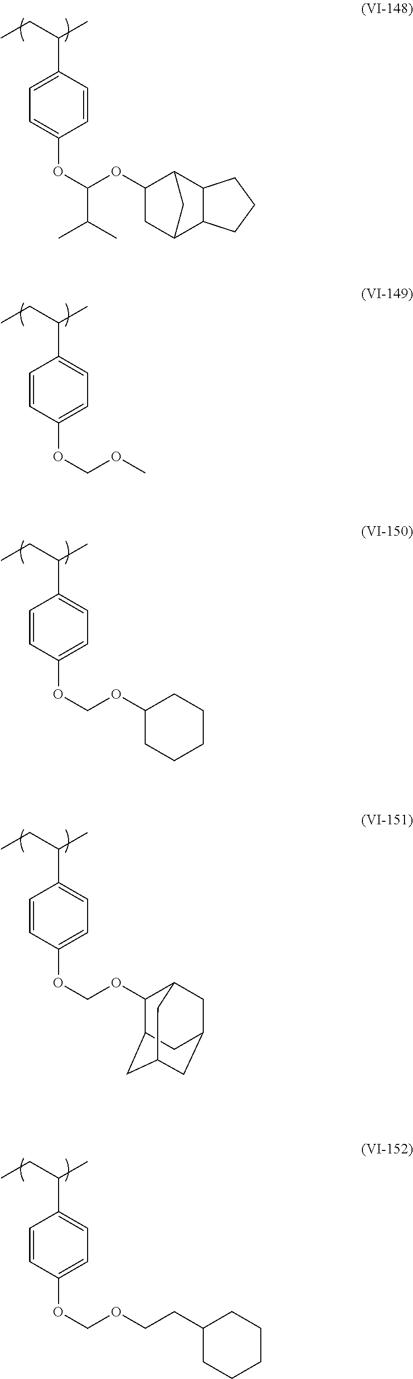

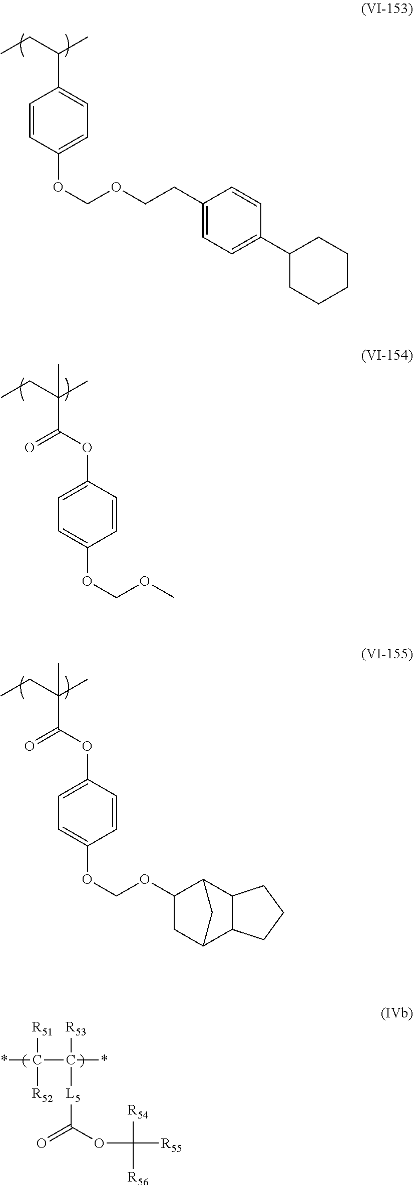

In General Formula (IVb), R₅₁, R₅₂, and R₅₃ each independently represent a hydrogen atom, an alkyl group, a cycloalkyl group, a halogen atom, a cyano group, or an alkoxycarbonyl group. R₅₂ may be bonded to L₅ to form a ring, and R₅₂ in this case represents an alkylene group.

L₅ represents a single bond or a divalent linking group, and in a case of being bonded to R₅₂ to form a ring, L₅ represents a trivalent linking group.

R₅₄ represents an alkyl group, and R₅₅ and R₅₆ each independently represent a hydrogen atom, an alkyl group, a cycloalkyl group, an aryl group, or an aralkyl group. R₅₅ and R₅₆ may be bonded to each other to form a ring. However, R₅₅ and R₅₆ are each not a hydrogen atom at the same time in any case.

General Formula (IVb) will be described in more detail.

Preferred examples of the alkyl group represented by each of R₅₁ to R₅₃ in General Formula (IVb) include an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, which may have a substituent, and an alkyl group having 8 or less carbon atoms is more preferable, and an alkyl group having 3 or less carbon atoms is particularly preferable.

The alkyl group included in the alkoxycarbonyl group is preferably the same one as the alkyl group in each of R₅₁ to R₅₃ as described above.

The cycloalkyl group may be monocyclic or polycyclic. Preferred examples include a monocyclic cycloalkyl group having 3 to 10 carbon atoms, such as a cyclopropyl group, a cyclopentyl group, or a cyclohexyl group, which may have a substituent.

Examples of the halogen atom include a fluorine atom, a chlorine atom, a bromine atom, and an iodine atom, with the fluorine atom being particularly preferable.

Preferred examples of the substituent in each of the groups include an alkyl group, a cycloalkyl group, an aryl group, an amino group, an amide group, a ureido group, a urethane group, a hydroxyl group, a carboxyl group, a halogen atom, an alkoxy group, a thioether group, an acyl group, an acyloxy group, an alkoxycarbonyl group, a cyano group, and nitro group, and the substituent preferably has 8 or less carbon atoms.

Furthermore, in a case where R₅₂ represents an alkylene group and is bonded to L₅ to form a ring, preferred examples of the alkylene group include alkylene groups having 1 to 8 carbon atoms, such as a methylene group, an ethylene group, a propylene group, a butylene group, a hexylene group, and an octylene group. Alkylene groups having 1 to 4 carbon atoms are more preferable, and alkylene groups having 1 or 2 carbon atoms are particularly preferable. A ring formed by the bonding of R₅₂ and L₅ is particularly preferably a 5- or 6-membered ring.

As each of R₅₁ and R₅₃ in Formula (IVb), a hydrogen atom, an alkyl group, or a halogen atom is more preferable, and a hydrogen atom, a methyl group, an ethyl group, a trifluoromethyl group (—CF₃), a hydroxymethyl group (—CH₂—OH), a chloromethyl group (—CH₂—Cl), or a fluorine atom (—F) is particularly preferable. As R₅₂, a hydrogen atom, an alkyl group, a halogen atom, or an alkylene group (which is bonded to L₅ to form a ring) is more preferable, and a hydrogen atom, a methyl group, an ethyl group, a trifluoromethyl group (—CF₃), a hydroxymethyl group (—CH₂—OH), a chloromethyl group (—CH₂—Cl), a fluorine atom (—F), a methylene group (which is bonded to L₅ to form a ring), or an ethylene group (which is bonded to L₅ to form a ring) is particularly preferable.

Examples of the divalent linking group represented by L₅ include an alkylene group, a divalent aromatic ring group, —COO-L₁₁-, —O-L₁₁-, and a group formed by combining two or more of these groups. Here, L₁₁ represents an alkylene group, a cycloalkylene group, a divalent aromatic ring group, or a group formed by combining an alkylene group and a divalent aromatic ring group.

Examples of the alkylene group for each of L₅ and L₁₁ include alkylene groups having 1 to 8 carbon atoms, such as a methylene group, an ethylene group, a propylene group, a butylene group, a hexylene group, and octylene. Alkylene groups having 1 to 5 carbon atoms are preferable, alkylene groups having 1 to 4 carbon atoms are more preferable, and alkylene groups having 1 or 2 carbon atoms are particularly preferable.

The cycloalkylene group for L₁₁ is preferably a cycloalkylene group having 3 to 20 carbon atoms, and examples thereof include a cyclopropylene group, a cyclobutylene group, a cyclopentylene group, a cyclohexylene group, a cycloheptylene group, a cyclooctylene group, a norbornylene group, and an adamantylene group.

In the cycloalkylene group for L₁₁, carbon constituting the ring (carbon which contributes to ring formation) may be carbonyl carbon or a heteroatom such as an oxygen atom, or may form a lactone ring containing an ester bond.

As the divalent aromatic ring group for each of L₅ and L₁₁, a 1,4-phenylene group, a 1,3-phenylene group, a 1,2-phenylene group, or a 1,4-naphthylene group is preferable, and a 1,4-phenylene group is more preferable.

L₁₁ is preferably an alkylene group having 1 to 5 carbon atoms, and more preferably a methylene group or a propylene group.

L₅ is a single bond, a group represented by —COO-L₁₁-, or a divalent aromatic ring group, more preferably a single bond or a group represented by —COO-L₁₁- (here, L₁₁ represents a norbornylene group or an adamantylene group), and particularly preferably a single bond.

Preferred specific examples of the divalent linking group for L₅ are shown below, but the present invention is not limited thereto.

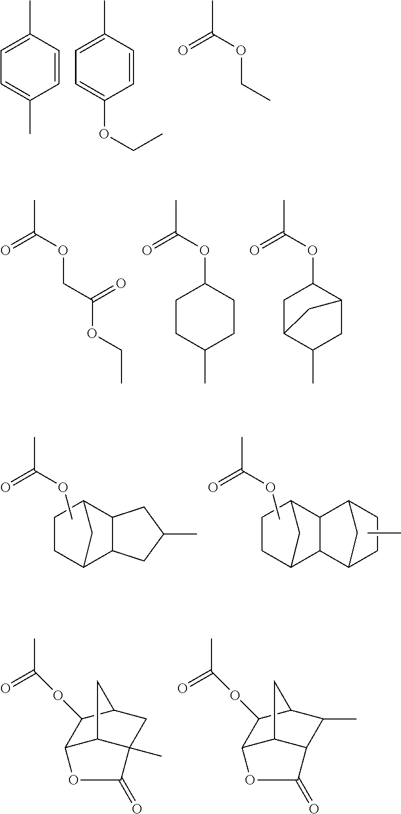

In a case where L₅ is bonded to R₅₂ to form a ring, suitable examples of the trivalent linking group represented by L₅ include a group obtained by removing one arbitrary hydrogen atom from the specific example as described above of the divalent linking group represented by L₅.

The alkyl group of each of R₅₄ to R₅₆ is preferably an alkyl group having 1 to 20 carbon atoms, more preferably an alkyl group having 1 to 10 carbon atoms, and particularly preferably an alkyl group having 1 to 4 carbon atoms, such as a methyl group, an ethyl group, an n-propyl group, an isopropyl group, an n-butyl group, an isobutyl group, or a t-butyl group.

The cycloalkyl group represented by each of R₅₅ and R₅₆ is preferably a cycloalkyl group having 3 to 20 carbon atoms, may be a cycloalkyl group which is monocyclic, such as a cyclopentyl group and a cyclohexyl group, and may be a cycloalkyl group which is polycyclic, such as a norbornyl group, an adamantyl group, a tetratricyclodecanyl group, and a tetracyclodododecanyl group.

Moreover, a ring formed by the mutual bonding of R₅₅ and R₅₆ is preferably a ring having 3 to 20 carbon atoms, may be a monocyclic ring such as a cyclopentyl group and a cyclohexyl group, and may be a polycyclic ring such as a norbornyl group, an adamantyl group, a tetratricyclodecanyl group, and a tetracyclododecanyl group. In a case where R₅₅ and R₅₆ are bonded to each other to form a ring, R₅₄ is preferably an alkyl group having 1 to 3 carbon atoms, and a methyl group or an ethyl group is more preferable.

The aryl group represented by R₅₅ or R₅₆ preferably has 6 to 20 carbon atoms, and may be monocyclic or polycyclic, or may have a substituent. Examples thereof include a phenyl group, a 1-naphthyl group, a 2-naphthyl group, a 4-methylphenyl group, and a 4-methoxyphenyl group. In a case where any one of R₅₅ and R₅₆ is a hydrogen atom, the other is preferably an aryl group.

The aralkyl group represented by R₅₅ or R₅₆ may be monocyclic or polycyclic, or may have a substituent. The aralkyl group preferably has 7 to 21 carbon atoms, and examples thereof include a benzyl group and a 1-naphthylmethyl group.

As a method for synthesizing a monomer corresponding to the repeating unit represented by General Formula (IVb), a general synthetic method of a polymerizable group-containing ester can be applied, but the method is not be particularly limited.

Specific examples of the repeating unit represented by General Formula (IVb) are shown below, but the present invention is not limited thereto.

In the specific examples, Rx and Xa₁ each represent a hydrogen atom, CH₃, CF₃, or CH₂OH. Rxa and Rxb each independently represent an alkyl group having 1 to 4 carbon atoms, an aryl group having 6 to 18 carbon atoms, or an aralkyl group having 7 to 19 carbon atoms. Z represents a substituent. p represents 0 or a positive integer, and is preferably 0 to 2, and more preferably 0 or 1. In a case where a plurality of Z's are present, Z's may be the same as or different from each other. As Z, a group consisting of only hydrogen atoms and carbon atoms is suitably exemplified from the viewpoint of increasing dissolution contrast with respect to a developer including an organic solvent before and after acid decomposition, and for example, a linear or branched alkyl group or a cycloalkyl group is preferable.

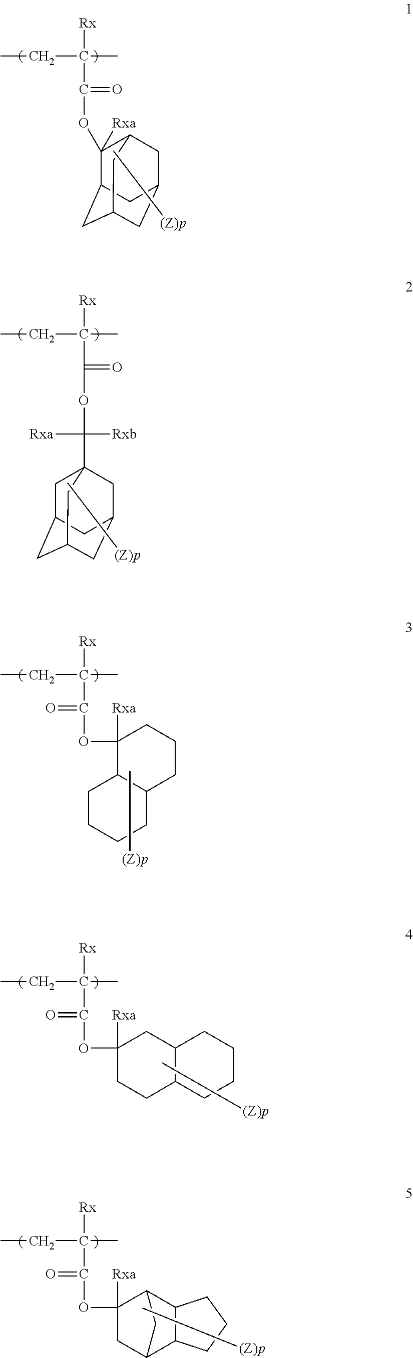

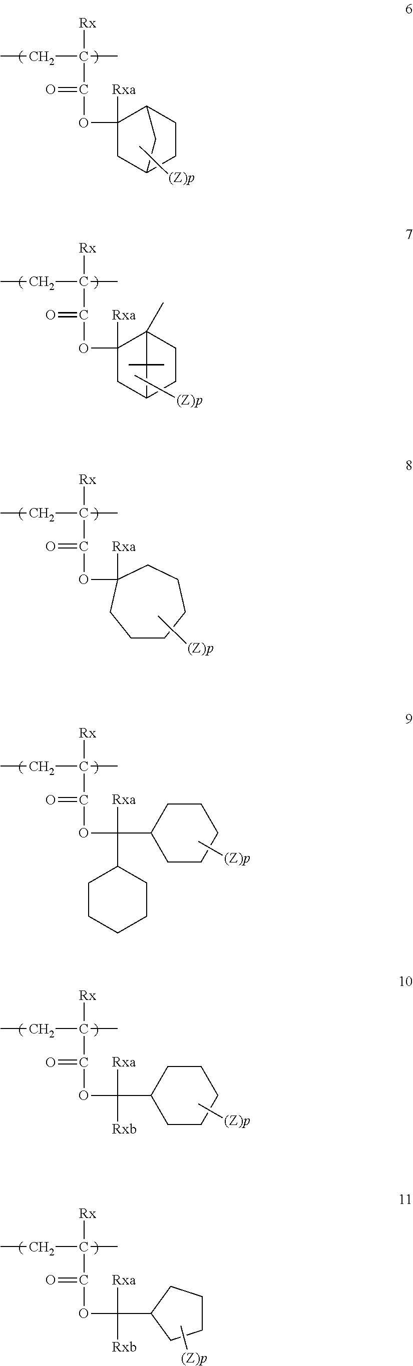

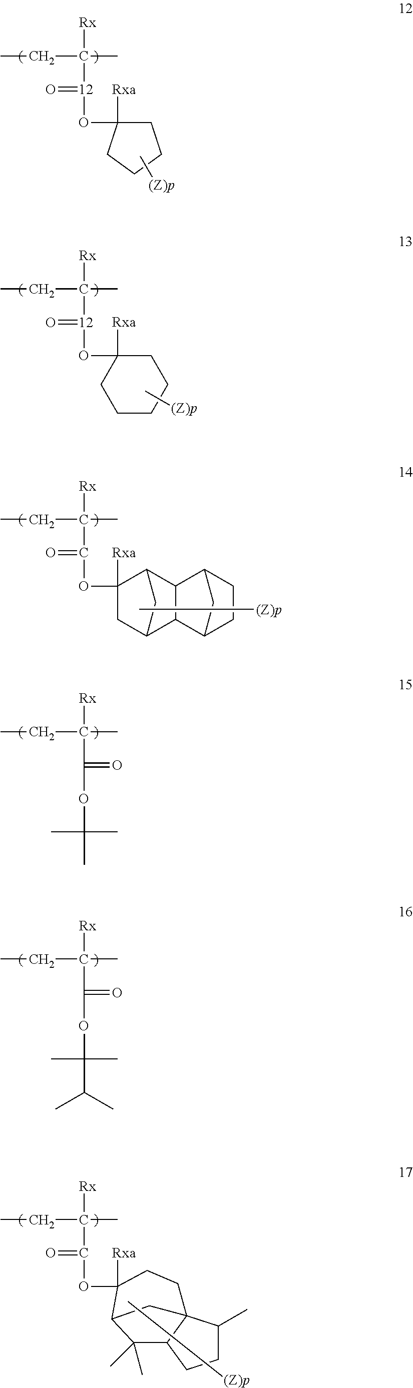

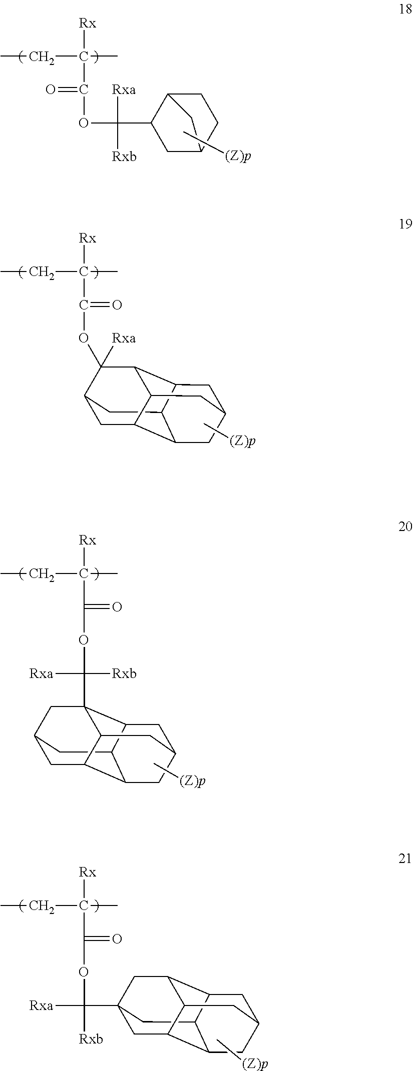

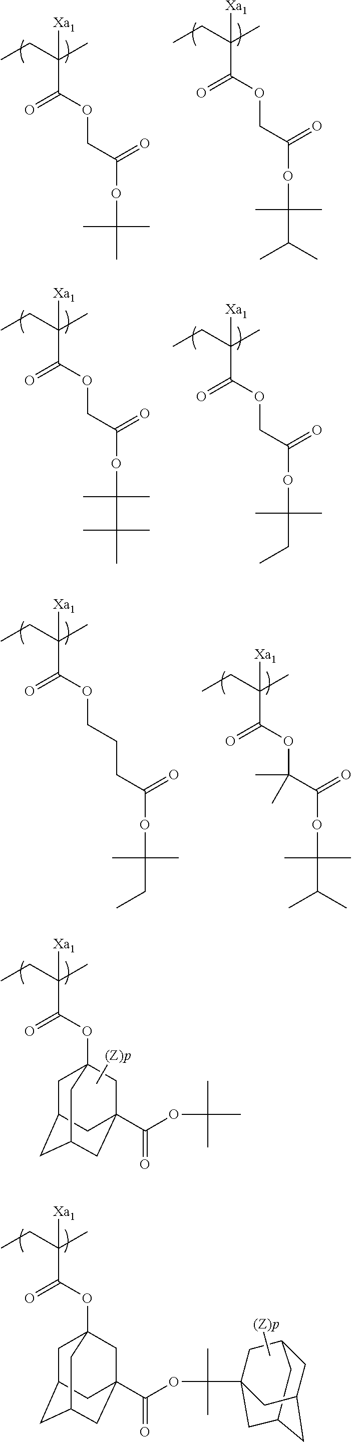

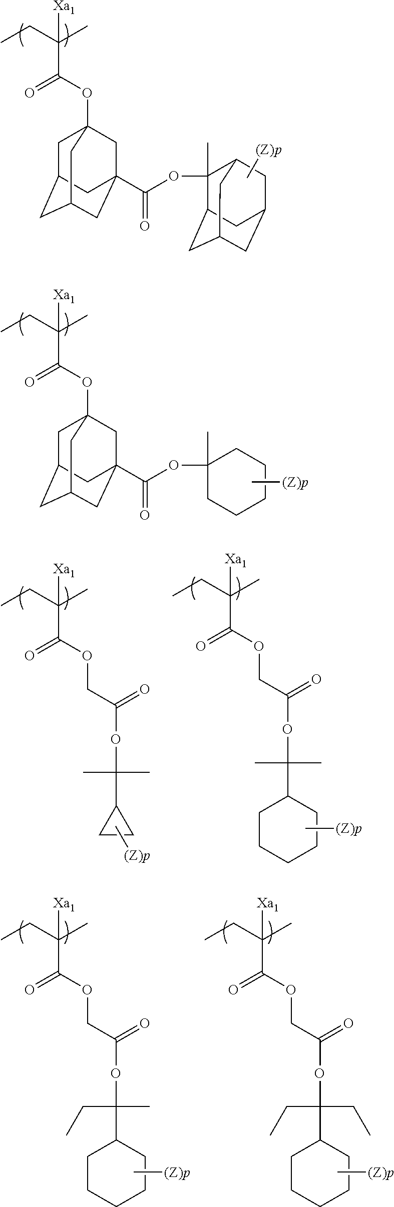

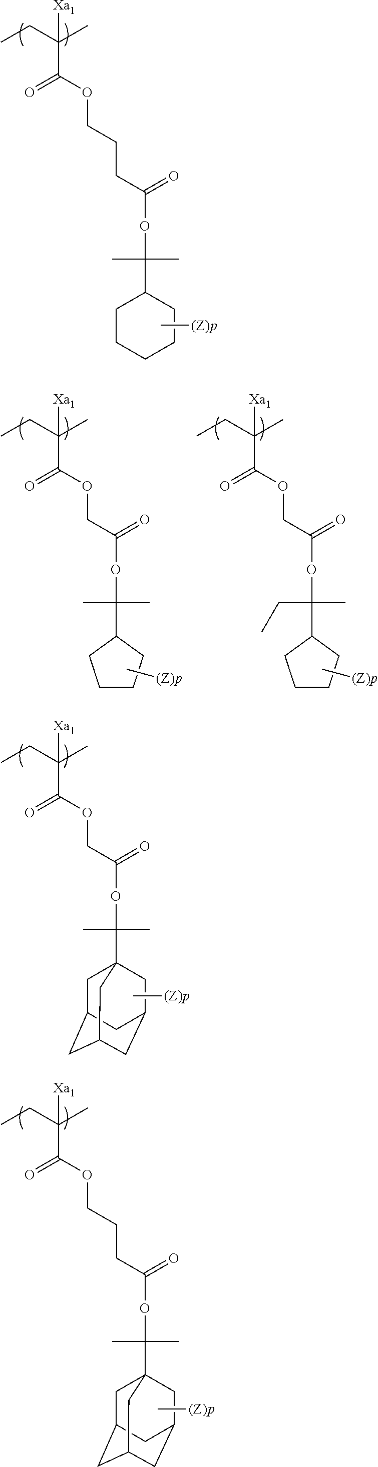

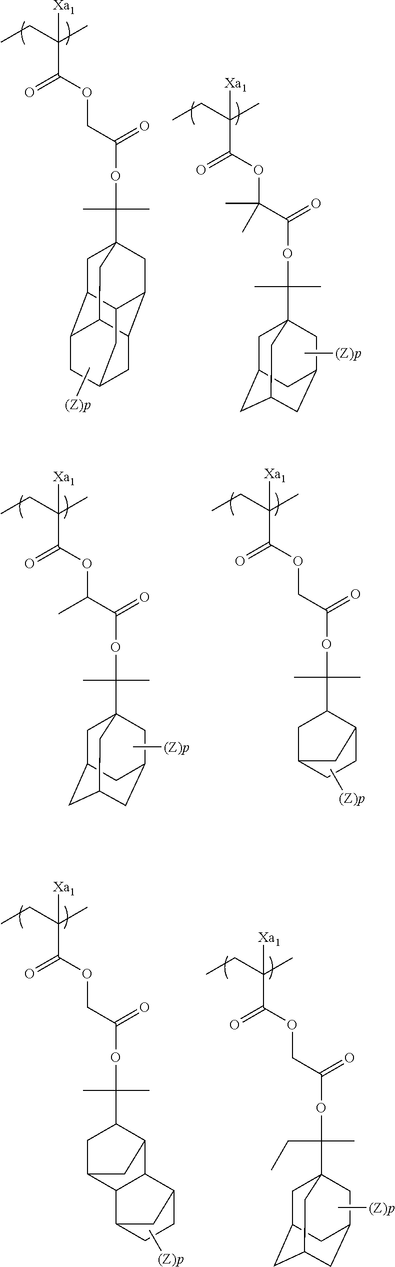

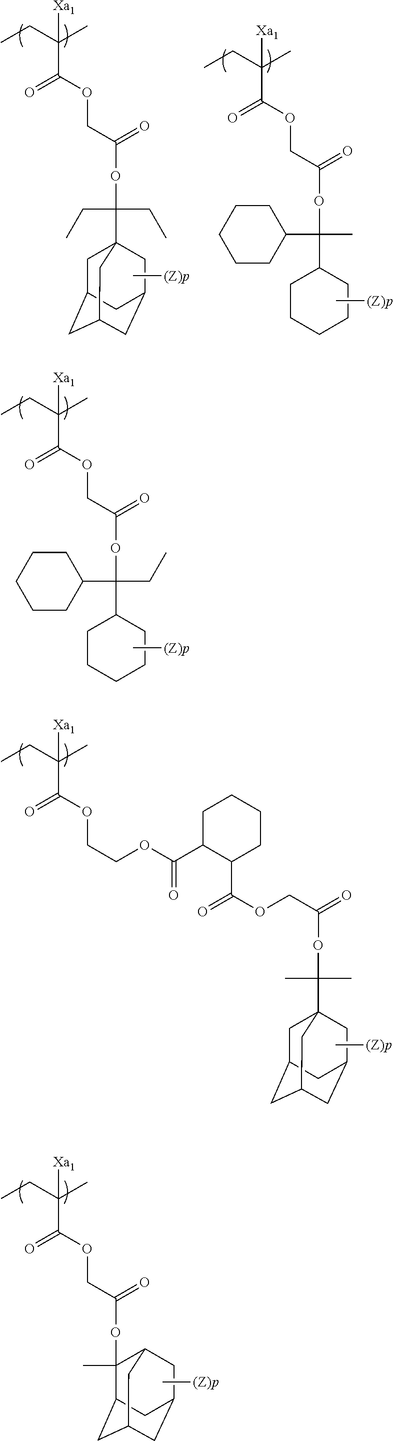

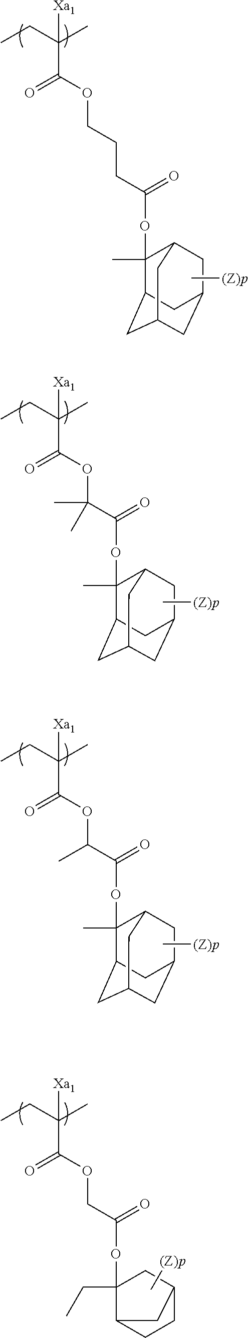

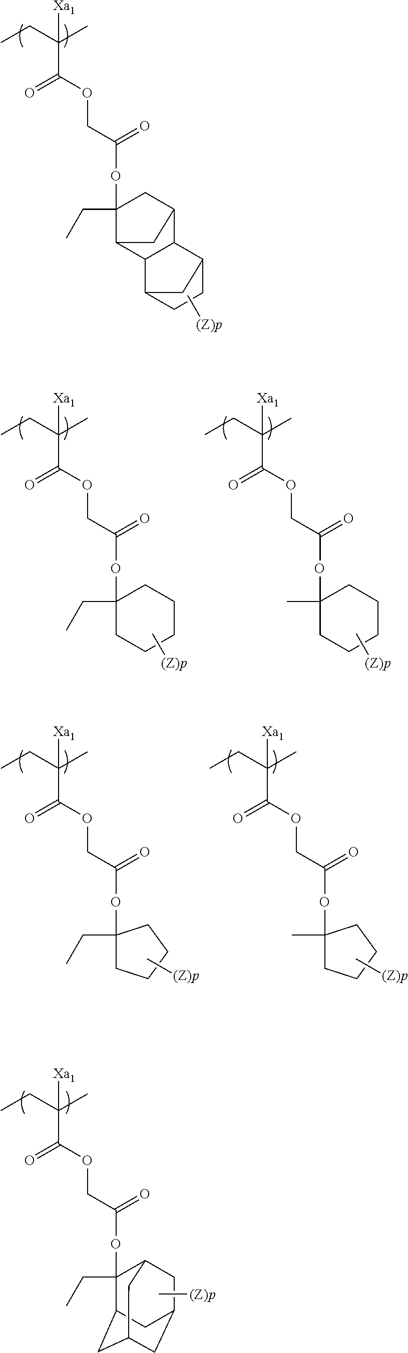

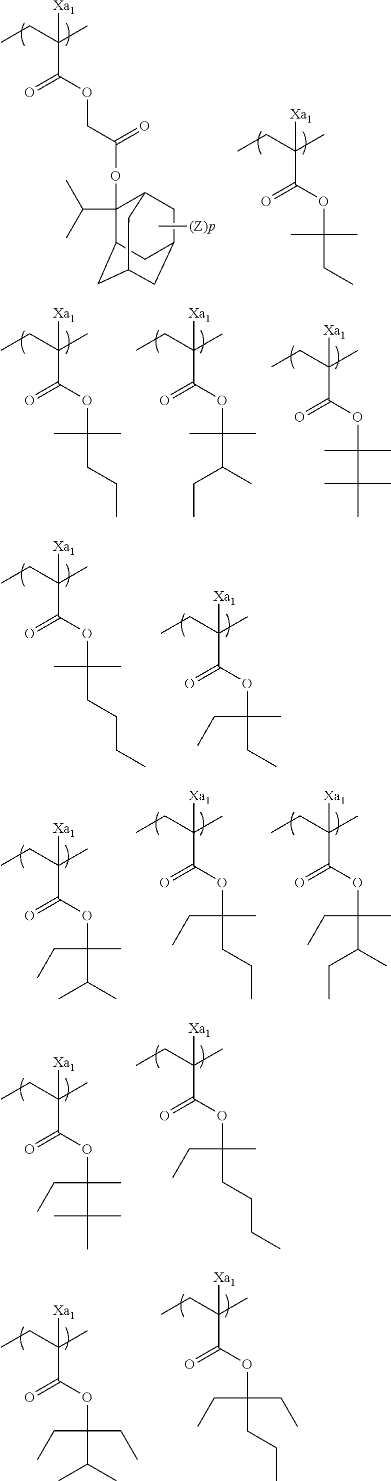

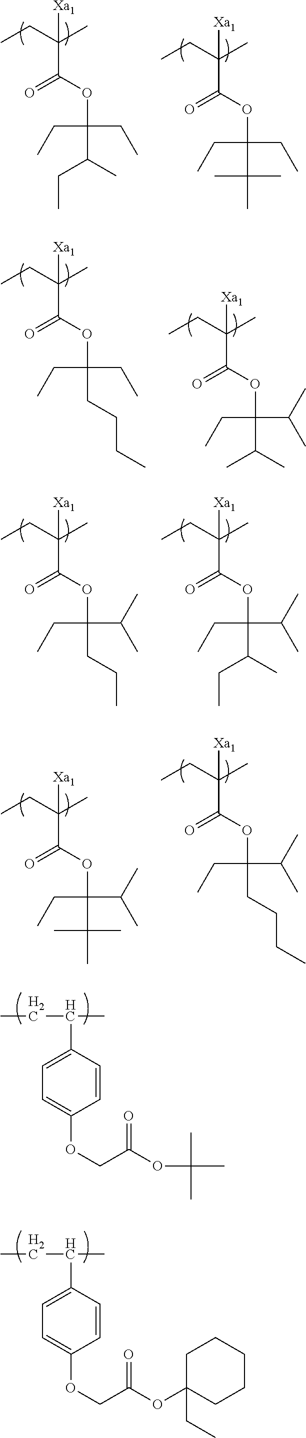

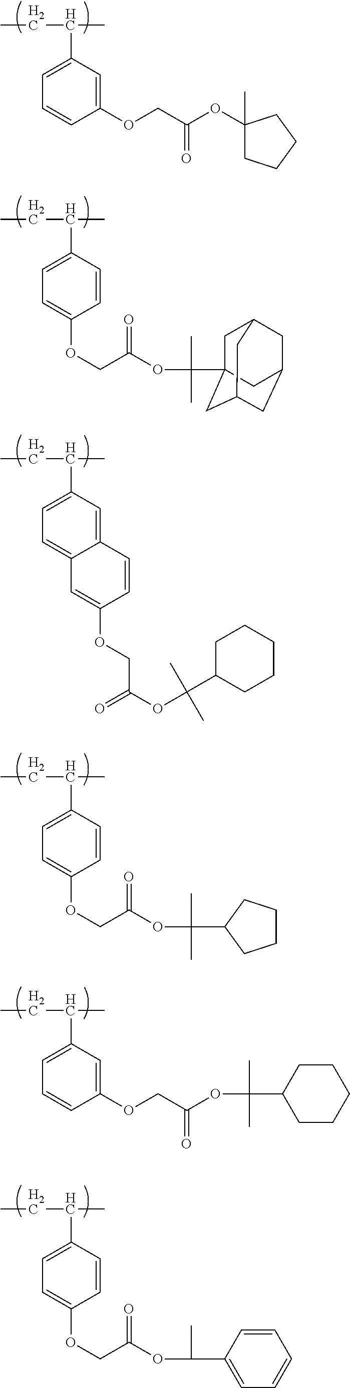

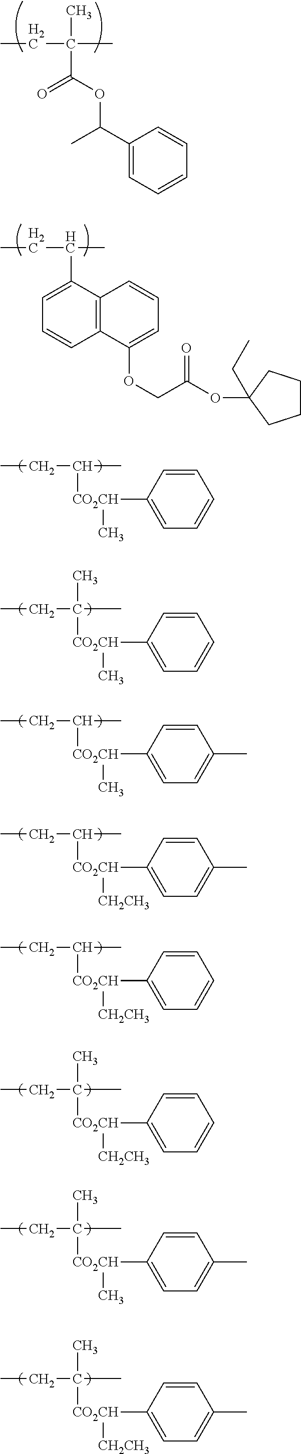

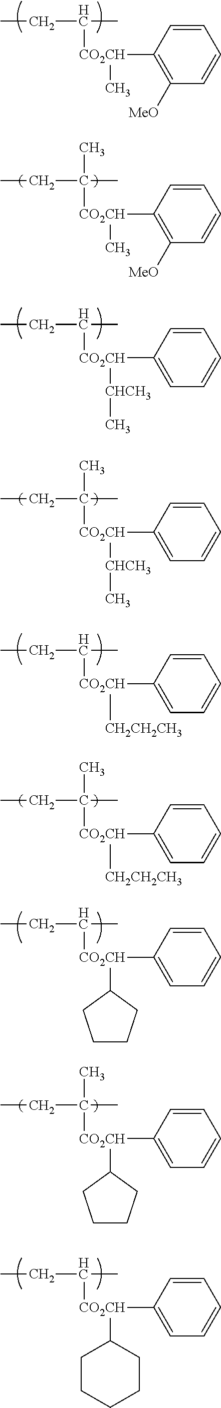

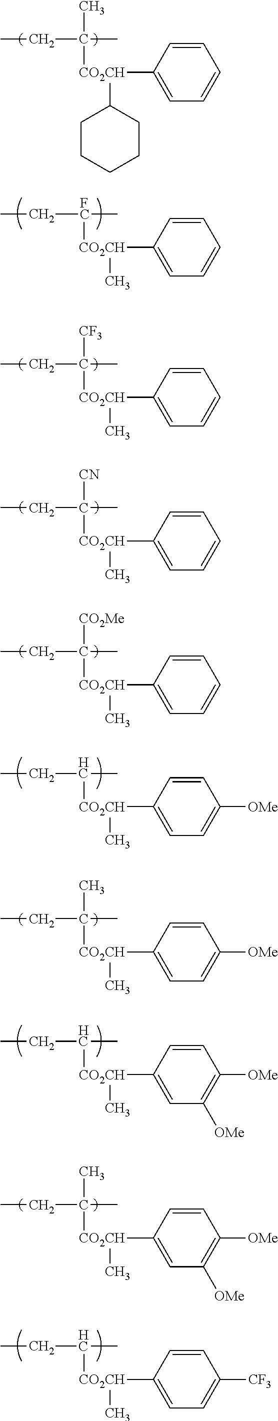

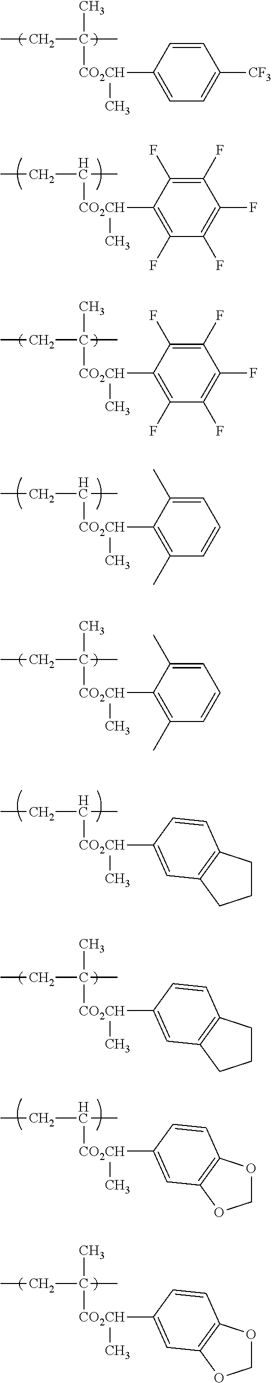

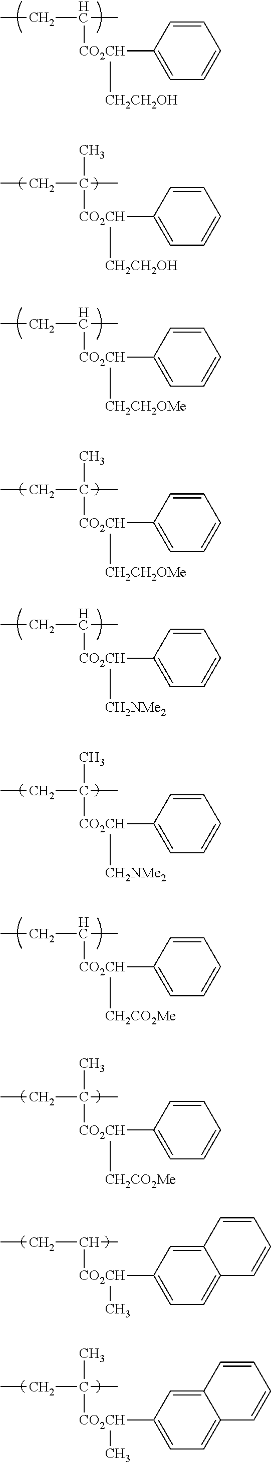

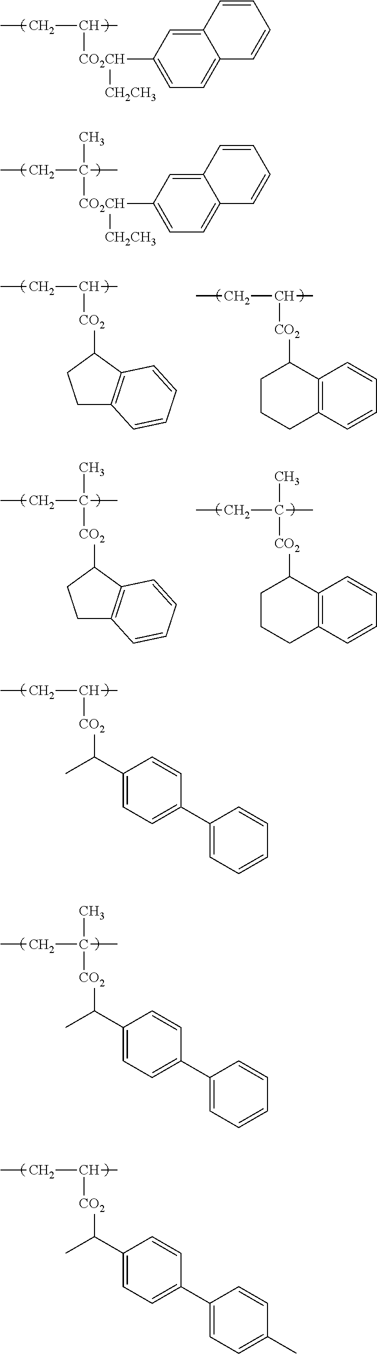

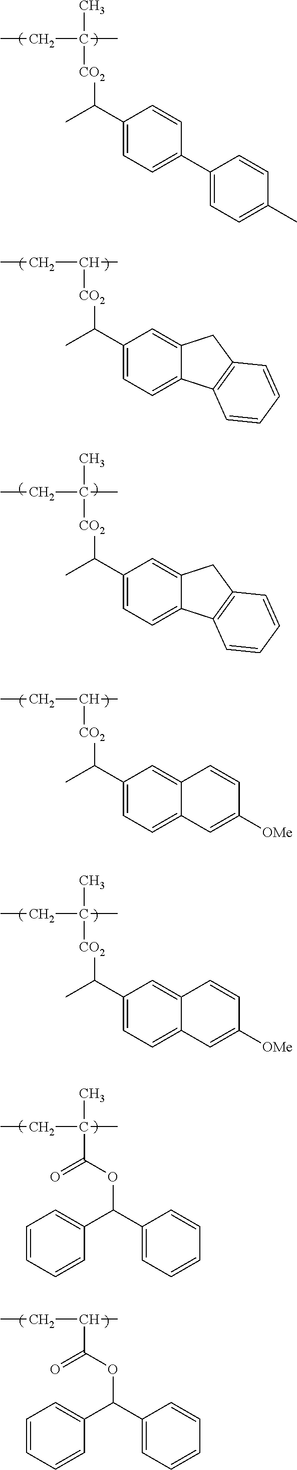

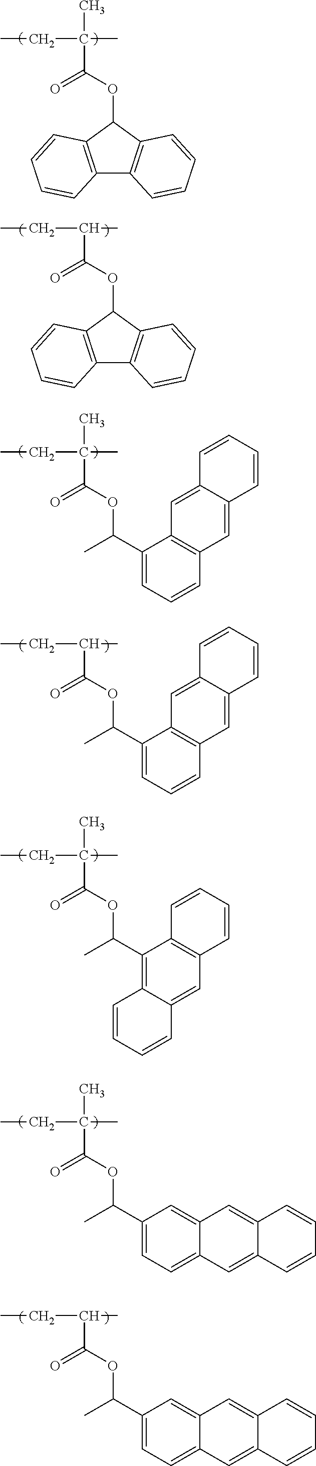

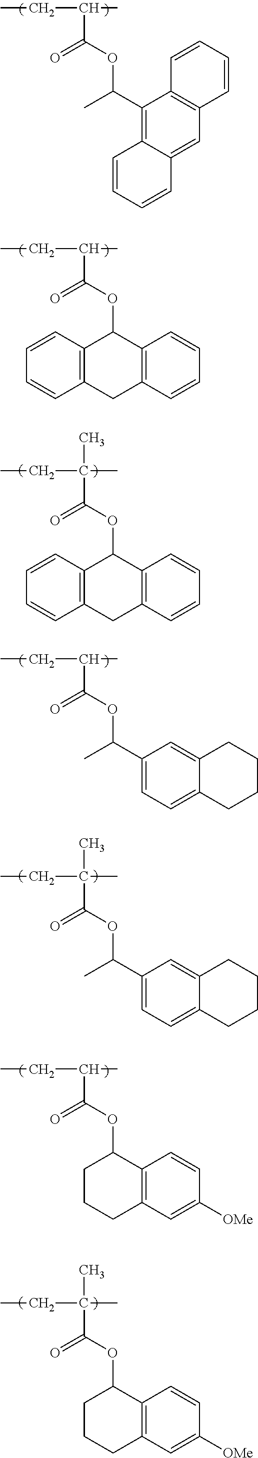

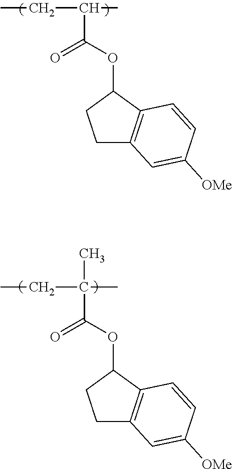 [SMILES: CCC(C)C(=O)OC1CCc2cc(OC)ccc21 ; CCC(C)(C)C(=O)OC1CCc2cc(OC)ccc21]

The repeating unit represented by General Formula (IVb) is preferably a repeating unit represented by the following General Formula (IVb-1) for a reason that the effects of the present invention are more excellent.

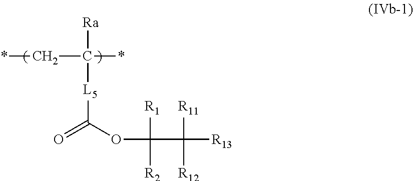

In General Formula (IVb-1),

R₁ and R₂ each independently represent an alkyl group, R₁₁ and R₁₂ each independently represent an alkyl group, and R₁₃ represents a hydrogen atom or an alkyl group. R₁₁ and R₁₂ may be linked to each other to form a ring, and R₁₁ and R₁₃ may be linked to each other to form a ring.

Ra represents a hydrogen atom, an alkyl group, a cyano group, or a halogen atom, and L₅ represents a single bond or a divalent linking group.

In General Formula (IVb-1), the alkyl group as each of R₁, R₂, and R₁₁ to R₁₃ is preferably an alkyl group having 1 to 10 carbon atoms, and examples thereof include a methyl group, an ethyl group, a propyl group, an isopropyl group, an n-butyl group, a sec-butyl group, a t-butyl group, a neopentyl group, a hexyl group, a 2-ethylhexyl group, an octyl group, and a dodecyl group.

The alkyl group for each of R₁ and R₂ is more preferably an alkyl group having 2 to 10 carbon atoms, from the viewpoint of more reliably achieving effects of the present invention.

It is preferable that at least one of R₁ or R₂ is an alkyl group having 2 to 10 carbon atoms, it is more preferable that both of R₁ and R₂ are alkyl groups having 2 to 10 carbon atoms, and it is still more preferable that both of R₁ and R₂ are ethyl groups.

The alkyl group for each of R₁₁ and R₁₂ is more preferably an alkyl group having 1 to 4 carbon atoms, still more preferably a methyl group or an ethyl group, and particularly preferably a methyl group.

R₁₃ is more preferably a hydrogen atom or a methyl group.

R₁₁ and R₁₂ are particularly preferably linked to each other to form a ring, and R₁₁ and R₁₃ may be linked to each other to form a ring.

A ring formed by the linking of R₁₁ and R₁₂ is preferably a 3- to 8-membered ring, and more preferably a 5- or 6-membered ring.

The ring formed by the linking of R₁₁ and R₁₃ to each other is preferably a 3- to 8-membered ring, and more preferably a 5- or 6-membered ring.

The time when R₁₁ and R₁₃ are linked to each other to form a ring is preferably the time when R₁₁ and R₁₂ are linked to each other to form a ring.

A ring formed by the linking of R₁₁ and R₁₂ (or R₁₁ and R₁₃) is more preferably an alicyclic group.

The rings formed by the linking of the alkyl groups as R₁, R₂, and R₁₁ to R₁₃, and R₁₁ and R₁₂ (or R₁₁ and R₁₃) may further have substituents.

Examples of the substituents which the rings formed by the linking of the alkyl groups as R₁, R₂, and R₁₁ to R₁₃, and R₁₁ and R₁₂ (or R₁₁ and R₁₃) can further have include a cycloalkyl group, an aryl group, an amino group, a hydroxy group, a carboxy group, a halogen atom, an alkoxy group, an aralkyloxy group, a thioether group, an acyl group, an acyloxy group, an alkoxycarbonyl group, a cyano group, and a nitro group. The substituents may be bonded to each other to form a ring, and examples of the ring when the substituents are bonded to each other to form a ring include a cycloalkyl group having 3 to 10 carbon atoms and a phenyl group.

The alkyl group for Ra may have a substituent, and is preferably an alkyl group having 1 to 4 carbon atoms.

Examples of the substituent which the alkyl group of Ra may have include a hydroxyl group and a halogen atom.

Examples of the halogen atom of Ra include a fluorine atom, a chlorine atom, a bromine atom, and an iodine atom.

Ra is preferably a hydrogen atom, a methyl group, a hydroxymethyl group, a perfluoroalkyl group having 1 to 4 carbon atoms (for example, a trifluoromethyl group), and a methyl group is particularly preferable from the viewpoint of raising the glass transition point (Tg) of the resin (A) and improving resolving power and a space width roughness.

Here, in a case where L₅ is a phenyl group, Ra is preferably also a hydrogen atom.

Specific examples and preferred examples of L₅ are as described with respect to L₅ of General Formula (IVb).

In view that the resolution of the pattern is more excellent, the repeating unit represented by General Formula (IVb-1) is preferably a repeating unit represented by the following General Formula (IVb-2).

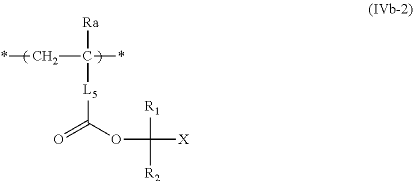

In General Formula (IVb-2), X represents an alicyclic group.

R₁, R₂, Ra, and L₅ have the same definitions as R₁, R₂, Ra, and L₅ in General Formula (IVb-1), respectively, and the specific examples and the preferred examples thereof are also the same as those of R₁, R₂, Ra, and L₅ in General Formula (IVb-1), respectively.

The alicyclic group as X may be monocyclic, polycyclic, or bridged, and preferably represents an alicyclic group having 3 to 25 carbon atoms.

In addition, the alicyclic group may have a substituent, and examples of the substituent include the same substituents as those described above as the substituents which the rings formed by linkage of alkyl groups represented by R₁, R₂, and R₁₁ to R₁₃, or R₁₁ and R₁₂ (or R₁₁ and R₁₃) can further have, and alkyl groups (a methyl group, an ethyl group, a propyl group, a butyl group, and a perfluoroalkyl group (for example, a trifluoromethyl group), and the like).

X preferably represents an alicyclic group having 3 to 25 carbon atoms, more preferably represents an alicyclic group having 5 to 20 carbon atoms, and particularly preferably represents a cycloalkyl group having 5 to 15 carbon atoms.

In addition, X is preferably an alicyclic group having a 3- to 8-membered ring or a fused ring group thereof, and more preferably a 5- or 6-membered ring or a fused ring group thereof.

Examples of the structure of the alicyclic group as X are shown below.

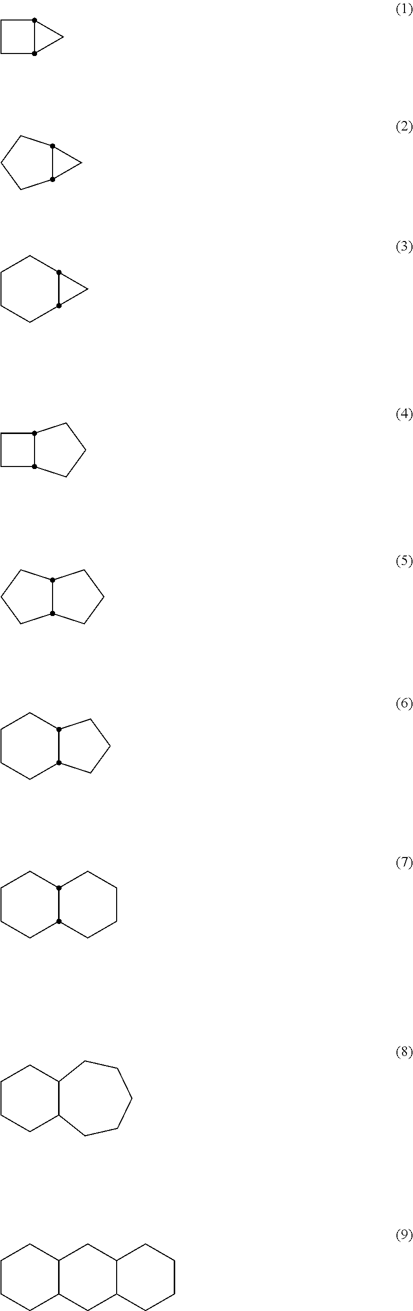

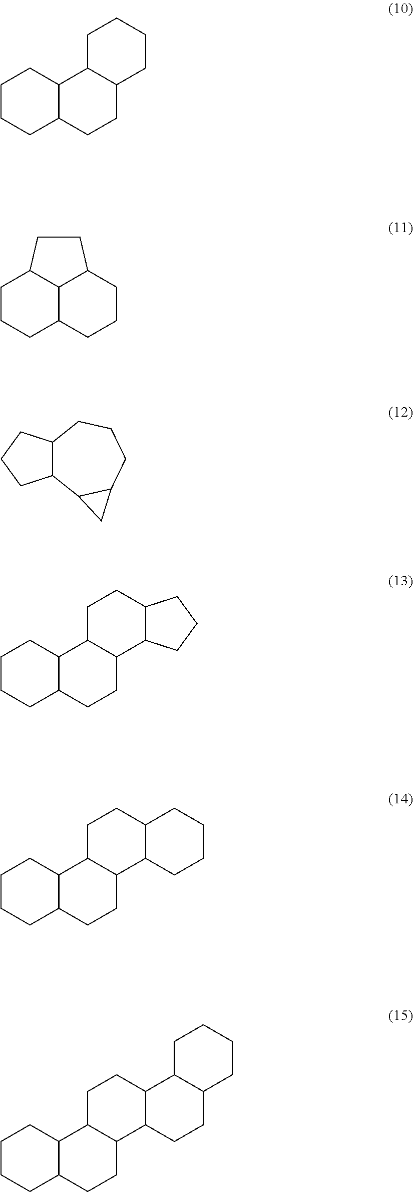

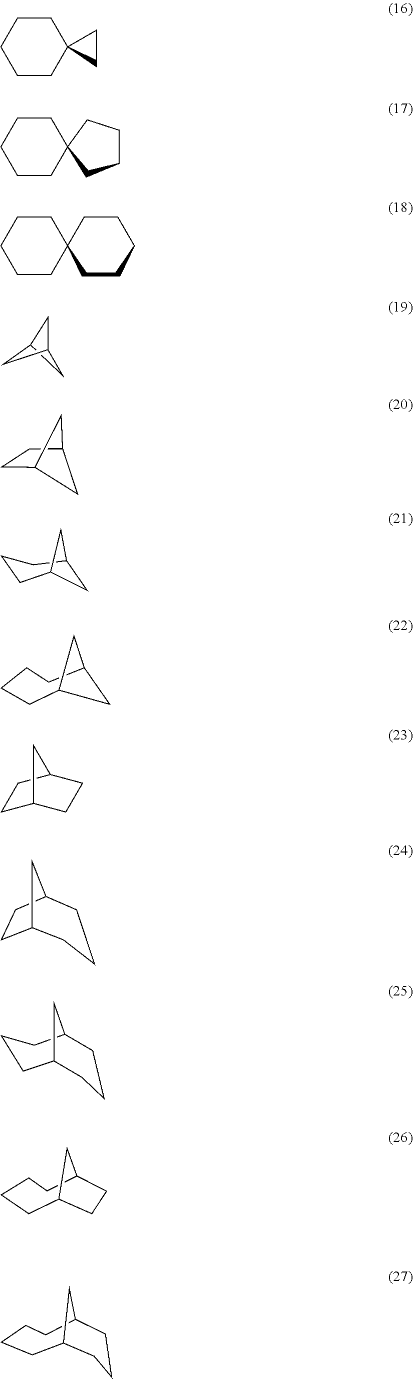

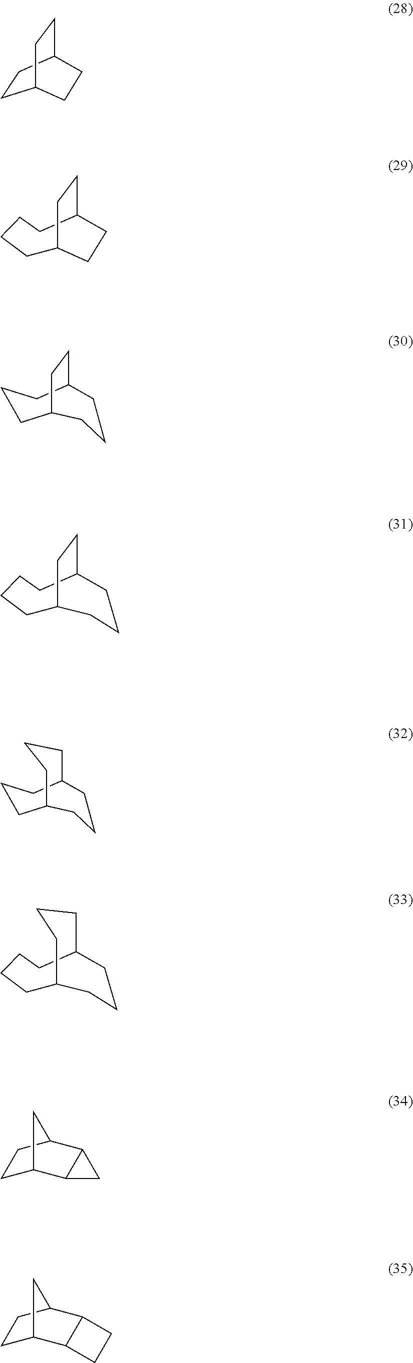

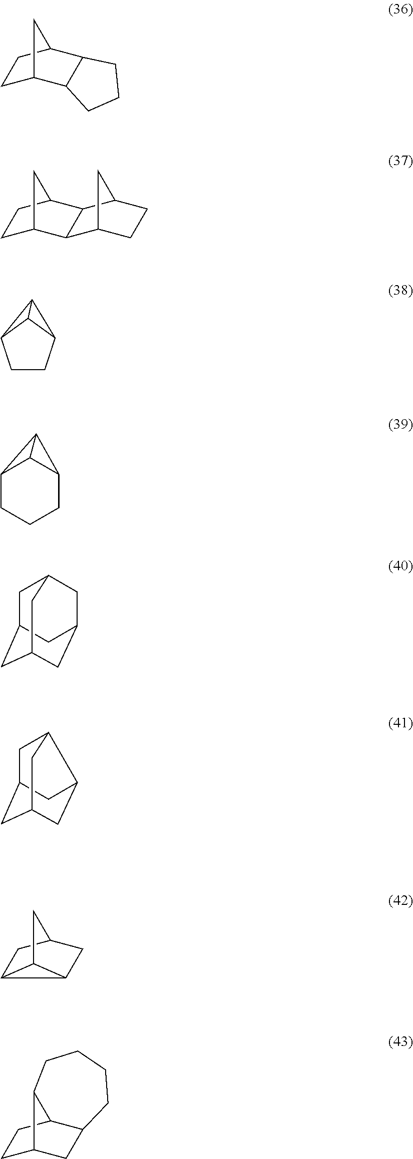

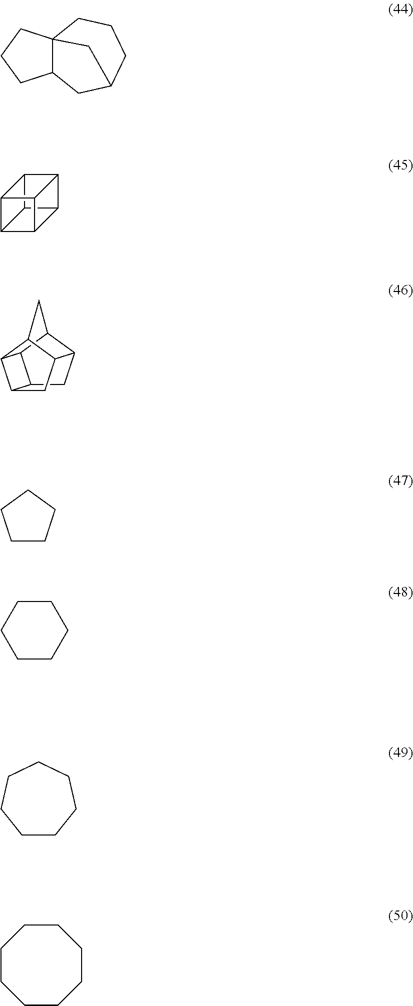

Preferred examples of the alicyclic group include an adamantyl group, a noradamantyl group, a decalin residue, a tricyclodecanyl group, a tetracyclododecanyl group, a norbornyl group, a cedrol group, a cyclopentyl group, a cyclohexyl group, a cycloheptyl group, a cyclooctyl group, a cyclodecanyl group, and a cyclododecanyl group. The alicyclic group is more preferably a cyclohexyl group, a cyclopentyl group, an adamantyl group, or a norbornyl group, still more preferably a cyclohexyl group or a cyclopentyl group, and particularly preferably a cyclohexyl group.

Specific examples of the repeating unit represented by General Formula (IVb-1) or (IVb-2) are shown below, but the present invention is not limited thereto.

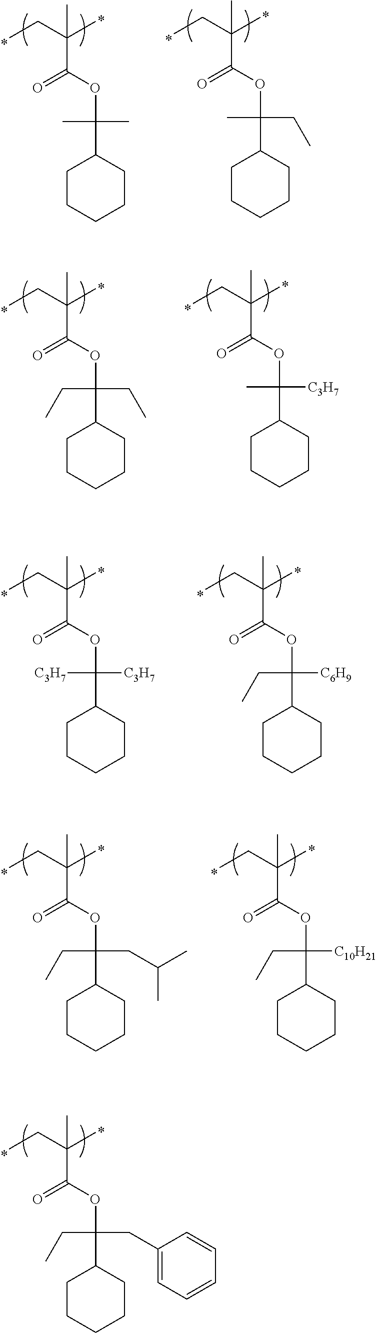

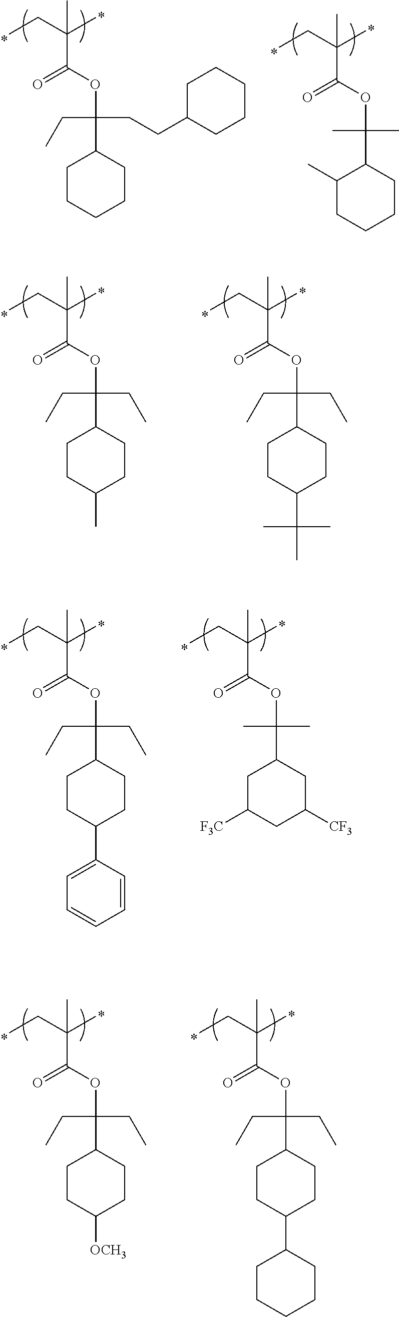

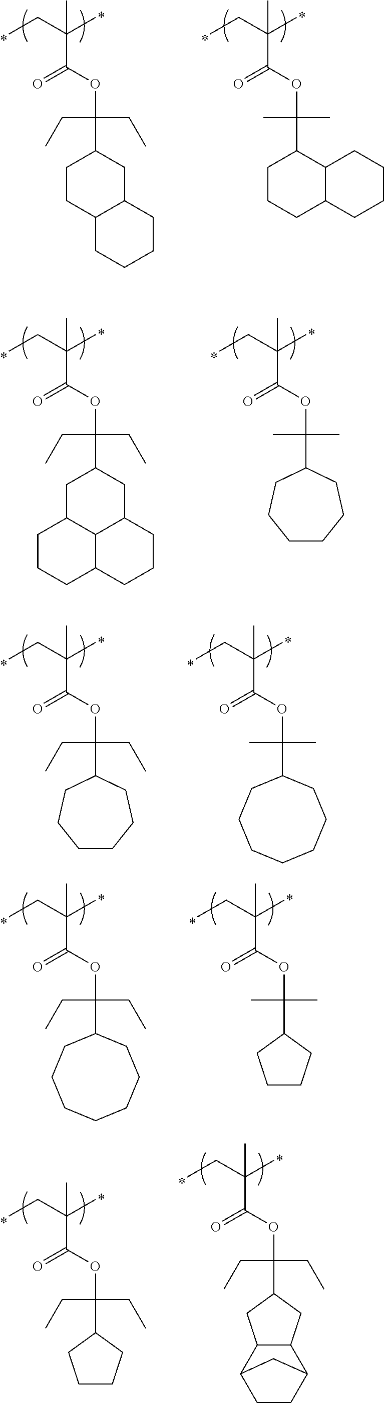

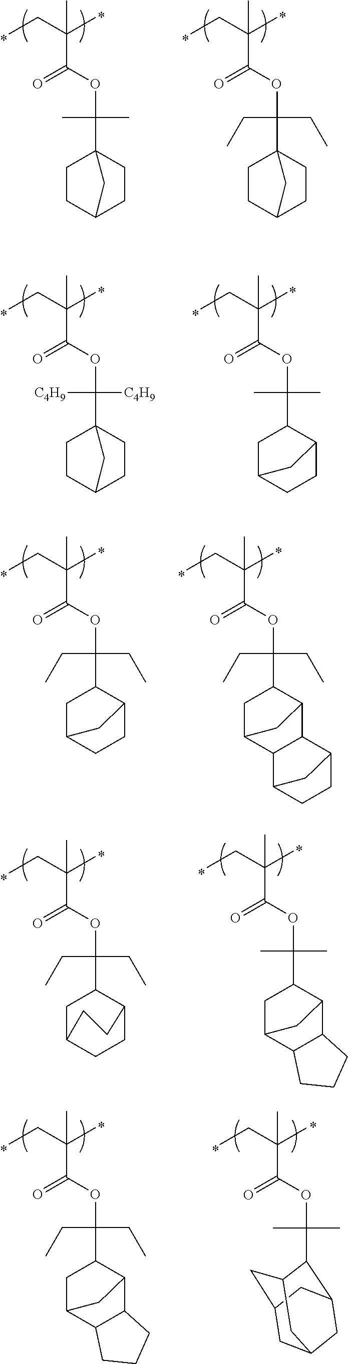

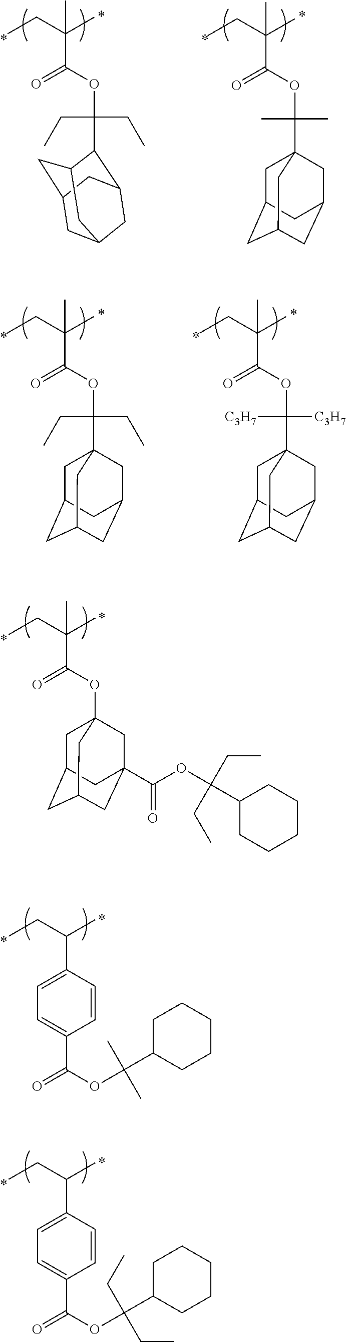

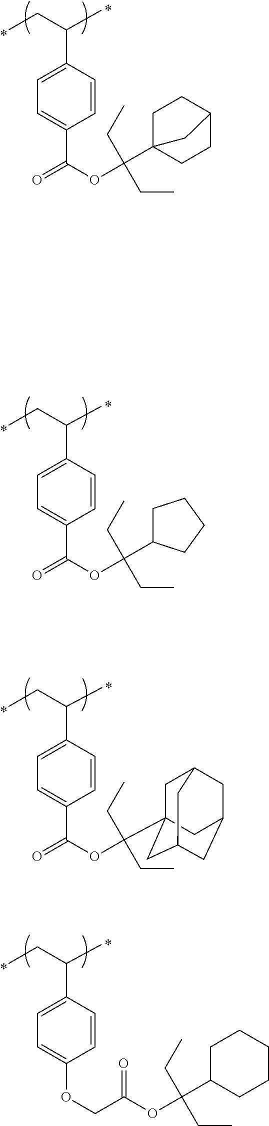

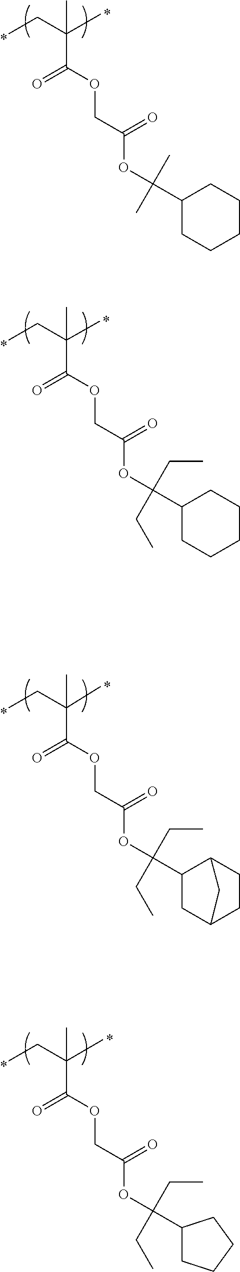

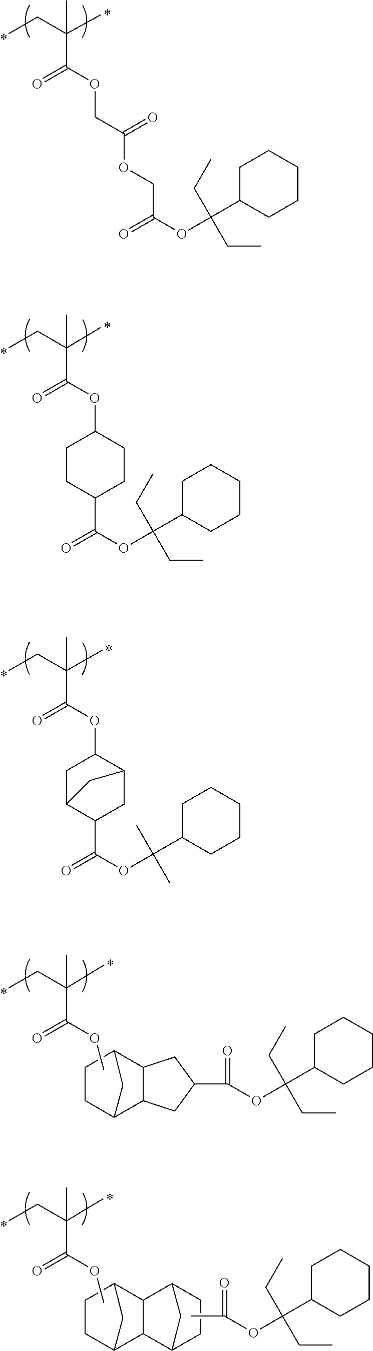

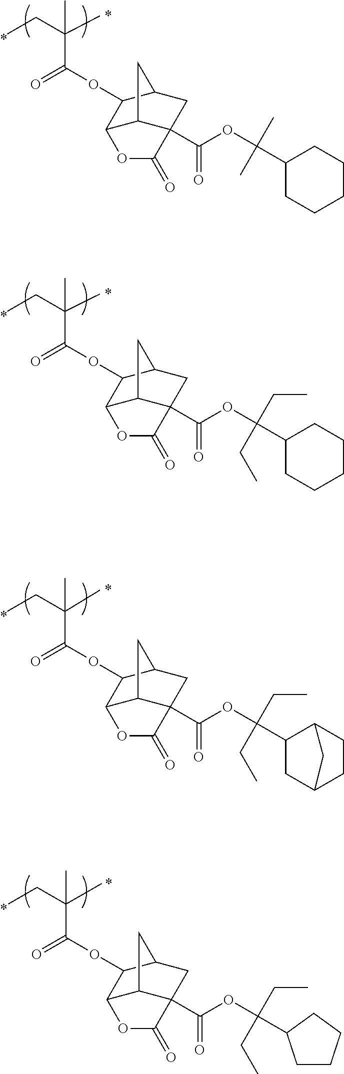

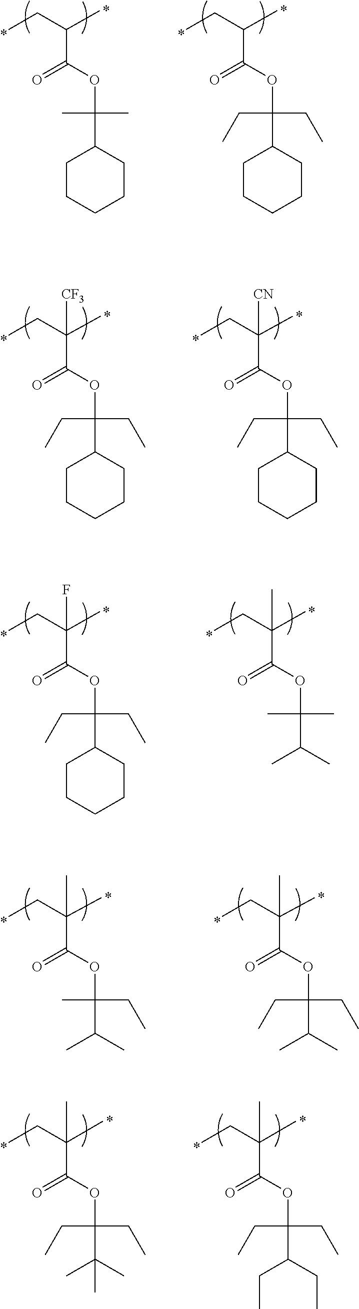

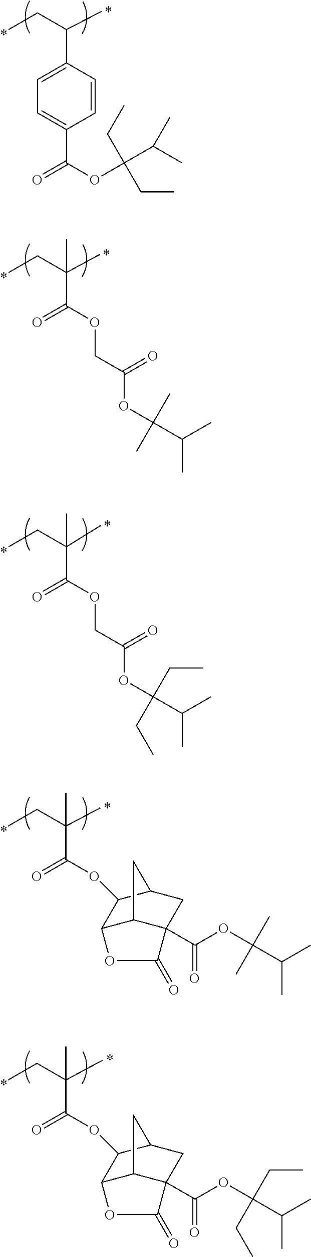

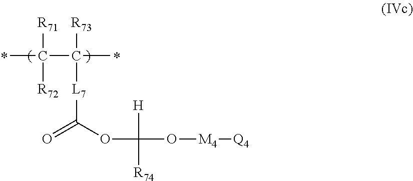

In General Formula (IVc),

R₇₁, R₇₂, and R₇₃ each independently represent a hydrogen atom, an alkyl group, a cycloalkyl group, a halogen atom, a cyano group, or an alkoxycarbonyl group. R₇₂ may be bonded to L₇ to form a ring, and R₇₂ in this case represents an alkylene group.

L₇ represents a single bond or a divalent linking group, and in the case of forming a ring with R₇₂, represents a trivalent linking group.

R₇₄ represents a hydrogen atom, an alkyl group, a cycloalkyl group, an aryl group, an aralkyl group, an alkoxy group, an acyl group, or a heterocyclic group.

M₄ represents a single bond or a divalent linking group.

Q₄ represents an alkyl group, a cycloalkyl group, an aryl group, or a heterocyclic group.

At least two members out of Q₄, M₄, or R₇₄ may be bonded to each other to form a ring.

The specific examples and preferred examples of each of the groups as R₇₁, R₇₂, and R₇₃ are the same as those described as R₅₁, R₅₂, and R₅₃ in General Formula (IVb) as described above, respectively.

The specific examples and preferred examples of the divalent linking group as L₇ are the same as those described as L₅ in General Formula (IVb) as described above.

R₇₄ has the same definition as R₃ in General Formula (IVa′), and the preferable range thereof is also the same.

The specific examples and preferred examples of M₄ are the same as those described as M₃ in General Formula (IVa′) as described above.

The specific examples and preferred examples of Q₄ are the same as those described for Q₃ in General Formula (IVa′) as described above. The specific examples and preferred examples of a ring formed by the bonding of at least two members out of Q₄, M₄, or R₇₄ are the same as those described for a ring formed by the bonding of at least two members out of Q₃, M₃, or R₃, respectively.

Specific examples of the repeating unit represented by General Formula (IVc) are shown below, but the present invention is not limited thereto.

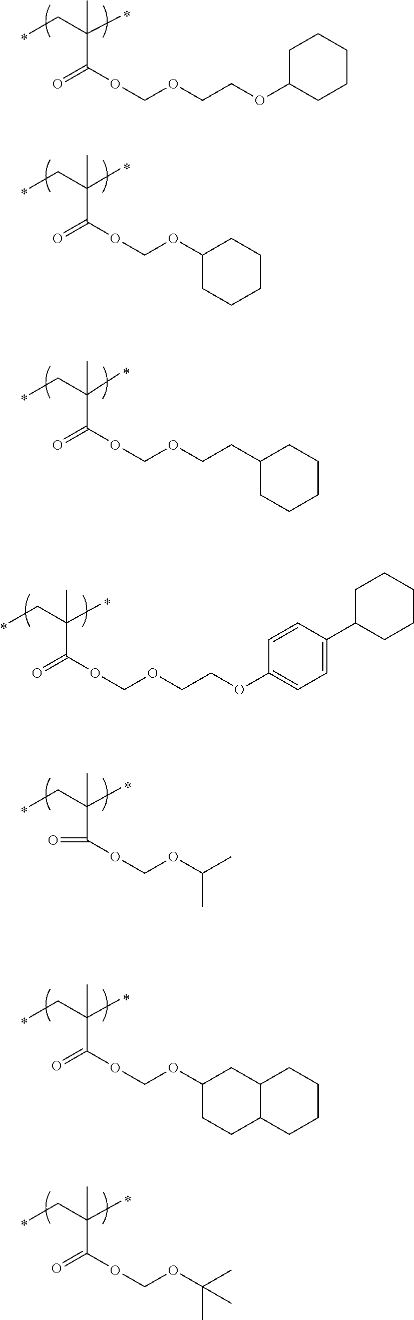

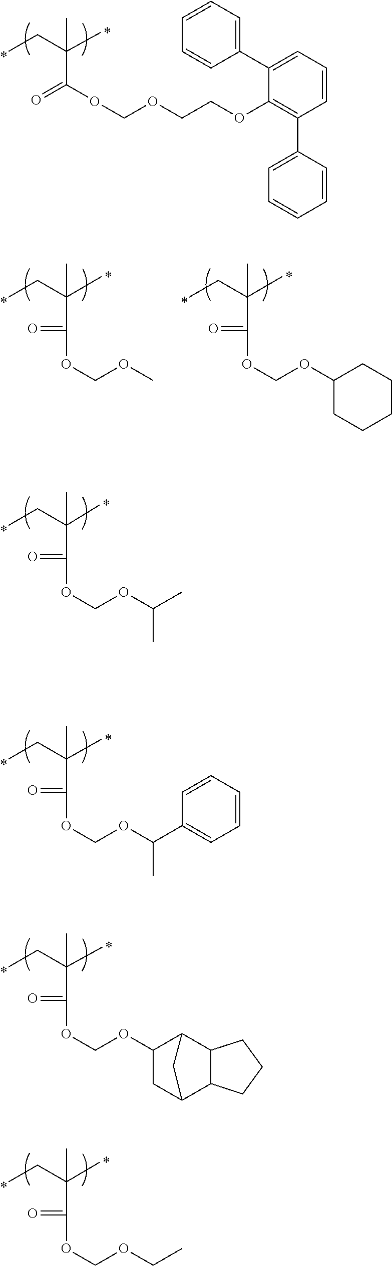

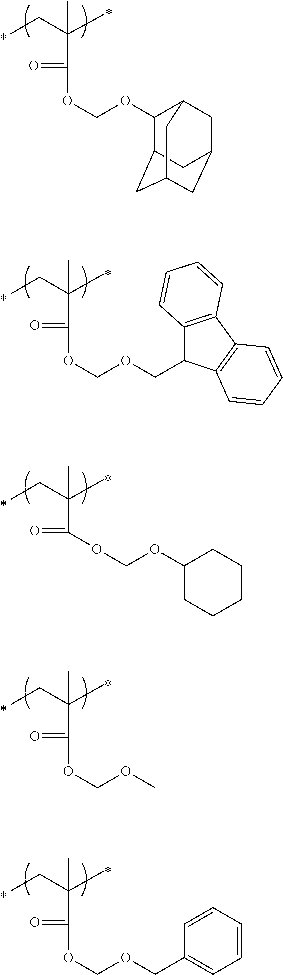

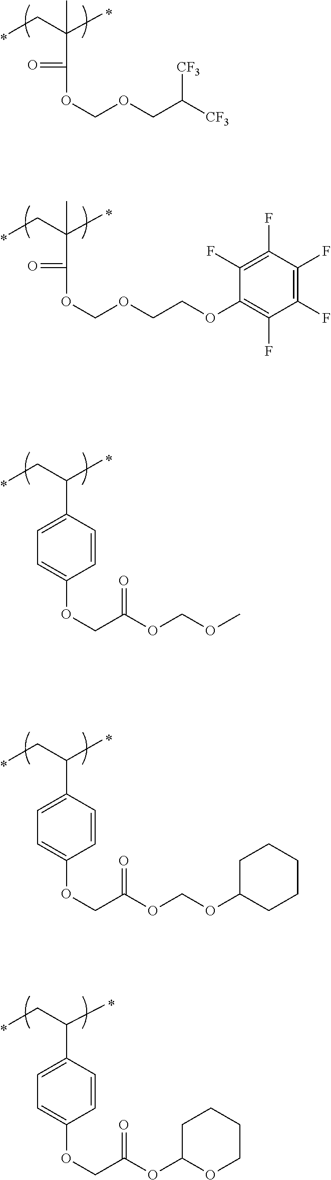

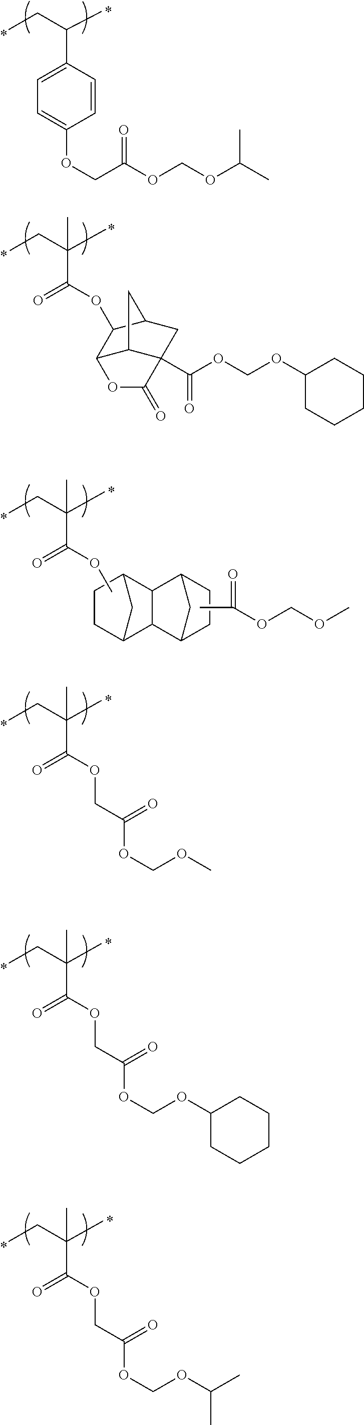

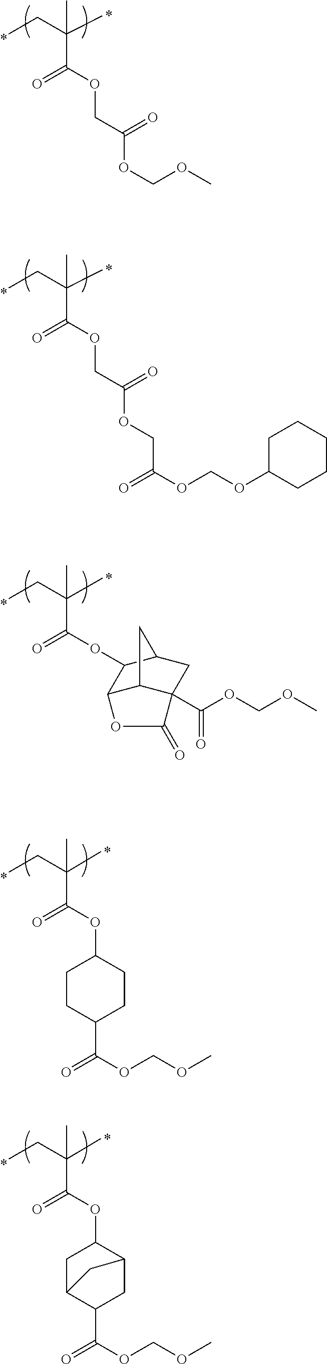

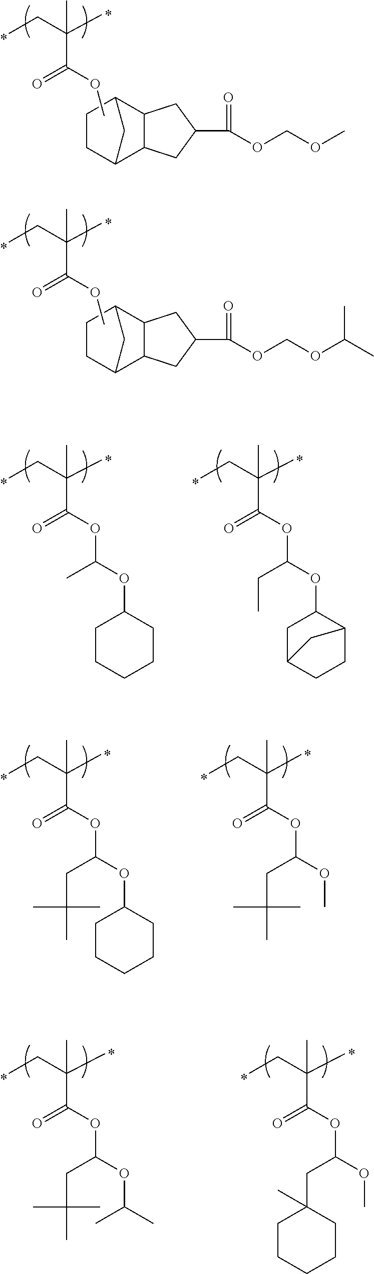

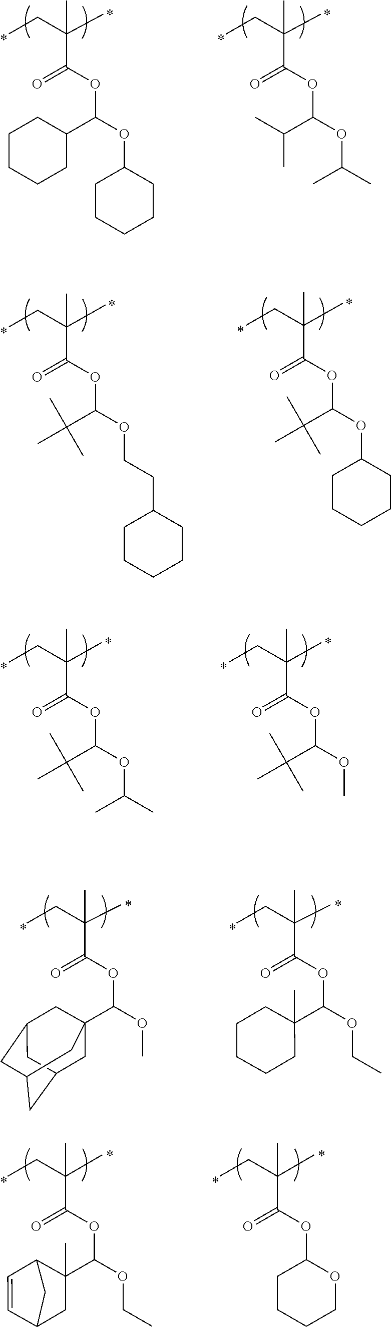

The repeating unit represented by any one of General Formulae (IVa) to (IVc) may be used singly or in combination of two or more kinds thereof.

The content (in the case of containing plural kinds, the total content) of the repeating unit represented by any one of General Formulae (IVa) to (IVc) in the resin is preferably from 5% by mole to 80% by mole, more preferably from 5% by mole to 75% by mole, and still more preferably from 10% by mole to 70% by mole, with respect to all the repeating units in the resin.

(Other Repeating Units)

The resin (A) may include repeating units other than the repeating units as described above.

The resin (A) may include, for example, a repeating unit (c) having a polar group other than the repeating units as described above (for example, the repeating unit represented by General Formula (II)).

By including the repeating unit (c), for example, the sensitivity of a composition including the resin can be improved. The repeating unit (c) is preferably a non-acid-decomposable repeating unit (that is, a repeating unit which does not include an acid-decomposable group).

Regarding the “polar group” which can be included in the repeating unit (c) and the repeating unit having a polar group, reference can be made to the description in paragraphs 0149 to 0157 of JP2013-76991A, the contents of which are incorporated in the present specification.

In a case where the repeating unit (c) has an alcoholic hydroxy group or a cyano group as a polar group, an embodiment of a preferred repeating unit, a repeating unit having an alicyclic hydrocarbon structure substituted with a hydroxyl group or a cyano group is exemplified. Here, it is preferable that an acid-decomposable group is not included. As the alicyclic hydrocarbon structure in the alicyclic hydrocarbon structure substituted with a hydroxyl group or a cyano group, an adamantyl group, a diamantyl group, or a norbornane group is preferable. As a preferred alicyclic hydrocarbon structure substituted with a hydroxyl group or a cyano group, the partial structures represented by the following General Formulae (VIIa) to (VIIc) are preferable. Thus, the adhesiveness to a substrate and the developer affinity are improved.

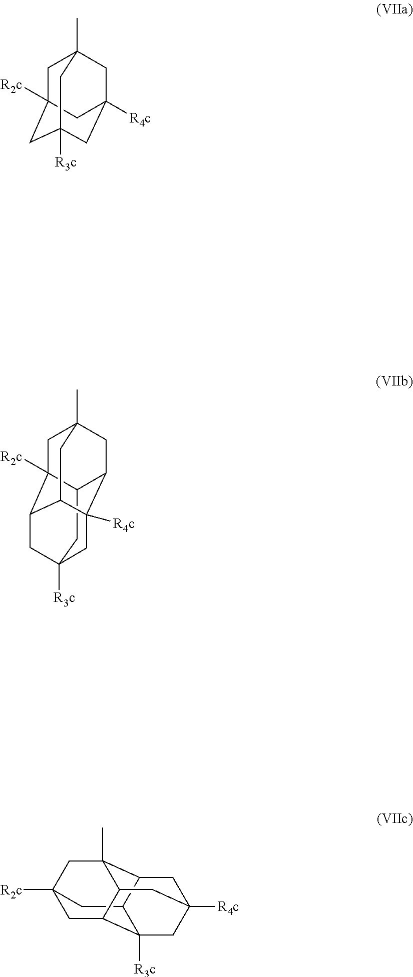

In General Formulae (VIIa) to (VIII),

R₂c to R₄c each independently represent a hydrogen atom, a hydroxyl group, or a cyano group. Here, at least one of R₂c, . . . , or R₄c is a hydroxyl group. It is preferable that one or two members out of R₂c to R₄c are hydroxyl groups, and the other is a hydrogen atom. In General Formula (VIIa), it is more preferable that two members out of R₂c to R₄c are hydroxyl groups, and the others are hydrogen atoms.

Examples of the repeating unit having a partial structure represented by each of General Formulae (VIIa) to (VIII) include repeating units represented by the following General Formulae (AIIa) to (AIIc).

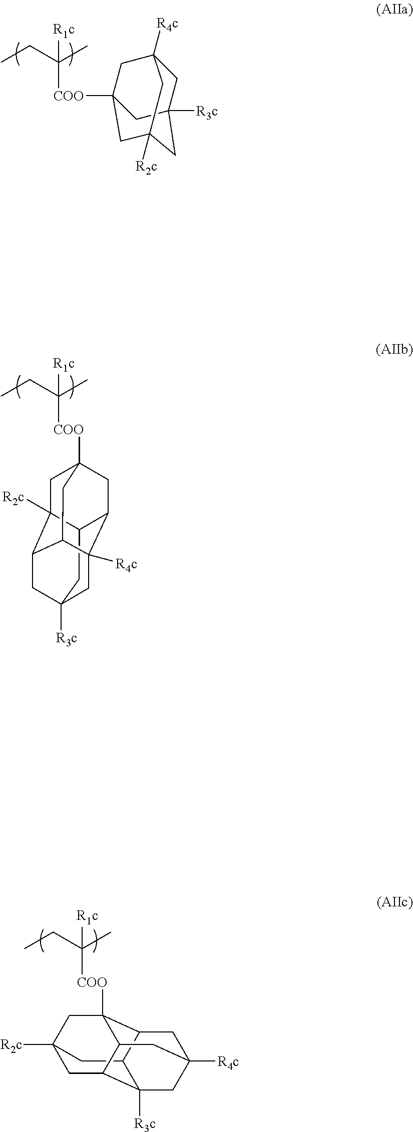

In General Formulae (AIIa) to (AIIc) R₁c represents a hydrogen atom, a methyl group, a trifluoromethyl group, or a hydroxymethyl group.

R₂c to R₄c have the same definitions as R₂c to R₄c in General Formulae (VIIa) to (VIII), respectively.

The resin (A) may or may not contain a repeating unit having a hydroxyl group or a cyano group, but in a case where the resin (A) contains the repeating unit, the content of the repeating unit having a hydroxyl group or a cyano group is preferably 1% to 60% by mole, more preferably 3% to 50% by mole, and still more preferably 5% to 40% by mole, with respect to all the repeating units in the resin (A).

Specific examples of the repeating unit having a hydroxyl group or a cyano group are shown below, but the present invention is not limited thereto.

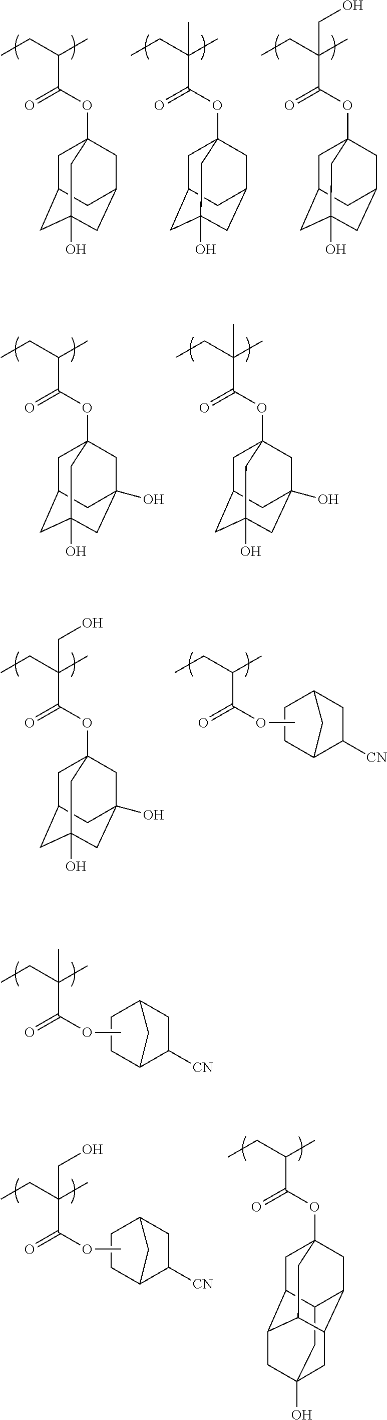

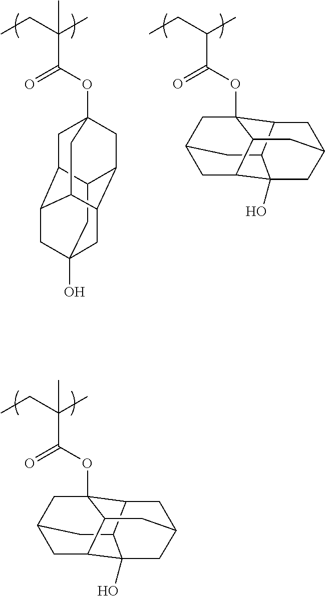

The repeating unit (c) may be a repeating unit having a lactone structure as a polar group.

As the repeating unit having a lactone structure, the repeating unit represented by the following General Formula (AII) is more preferable.

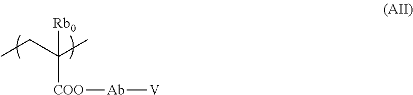

In General Formula (AII), Rb₀ represents a hydrogen atom, a halogen atom, or an alkyl group (preferably having 1 to 4 carbon atoms) which may have a substituent.

Preferred examples of the substituent which the alkyl group of Rb₀ may have include a hydroxyl group and a halogen atom. Examples of the halogen atom of Rb₀ include a fluorine atom, a chlorine atom, a bromine atom, and an iodine atom. Rb₀ is preferably a hydrogen atom, a methyl group, a hydroxymethyl group, or a trifluoromethyl group, and particularly preferably a hydrogen atom or a methyl group.

Ab represents a single bond, an alkylene group, a divalent linking group having a monocyclic or polycyclic cycloalkyl structure, an ether bond, an ester bond, a carbonyl group, or a divalent linking group obtained by combining these. Ab is preferably a single bond or a divalent linking group represented by -Ab₁-CO₂—.

Ab₁ is a linear or branched alkylene group or a monocyclic or polycyclic cycloalkylene group, and preferably a methylene group, an ethylene group, a cyclohexylene group, an adamantylene group, or a norbornylene group.

V represents a group having a lactone structure.

As the group having a lactone structure, any group can be used as long as the group has a lactone structure, but the group preferably has a 5- to 7-membered ring lactone structure. It is preferable that another ring structure is condensed with the 5- to 7-membered lactone structure while forming a bicyclo structure or a spiro structure. The group more preferably has a repeating unit having a lactone structure represented by any one of the following General Formulae (LC1-1) to (LC1-17). In addition, the lactone structure may be directly bonded to the main structure. A preferred structure is (LC1-1), (LC1-4), (LC1-5), (LC1-6), (LC1-8), (LC1-13), or (LC1-14).

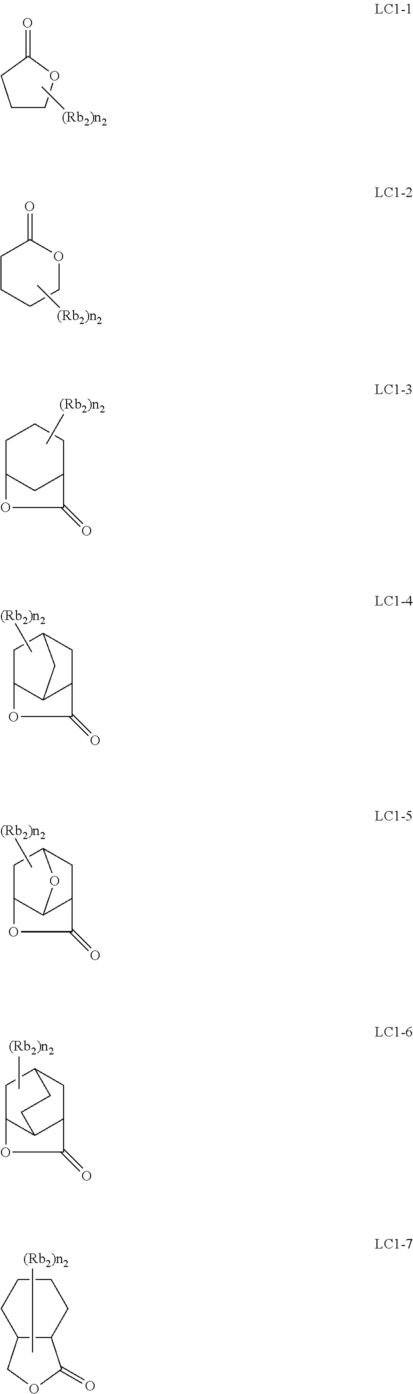

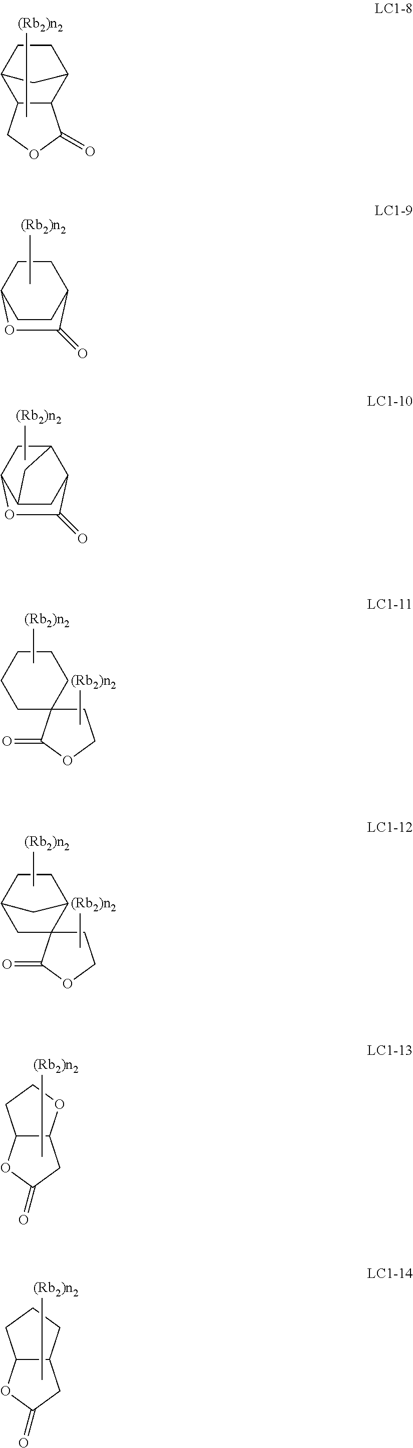

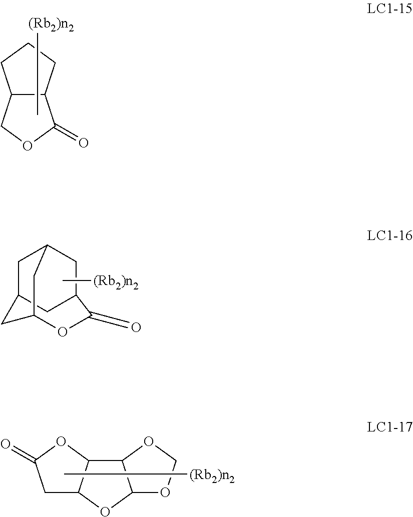

The lactone structure moiety may or may not have a substituent (Rb₂). Preferred examples of the substituent (Rb₂) include an alkyl group having 1 to 8 carbon atoms, a monovalent cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, and an acid-decomposable group. The substituent (Rb₂) is more preferably an alkyl group having 1 to 4 carbon atoms, a cyano group, or an acid-decomposable group. n₂ represents an integer of 0 to 4. When n₂ is 2 or more, the substituents (Rb₂) which are present in plural numbers be the same as or different from each other, and the substituents (Rb₂) which are present in plural numbers be bonded to each other to form a ring.

The repeating unit having a lactone group typically has optical isomers, and any optical isomer may be used. In addition, one kind of optical isomer may be used singly, or plural kinds of optical isomers may be used in combination. In a case where one kind of optical isomer is mainly used, the optical purity (ee) is preferably 90% or more, and more preferably 95% or more.

The resin (A) may contain or may not contain a repeating unit having a lactone structure, and in a case where the resin (A) contains the repeating unit having a lactone structure, the content of the repeating unit in the resin (A) is preferably in a range of 1% to 70% by mole, more preferably in a range of 3% to 65% by mole, and still more preferably in a range of 5% to 60% by mole, with respect to all the repeating units.

Specific examples of the repeating unit having a lactone structure in the resin (A) are shown below, but the present invention is not limited thereto. In the formulae, Rx represents H, CH₃, CH₂OH, or CF₃.

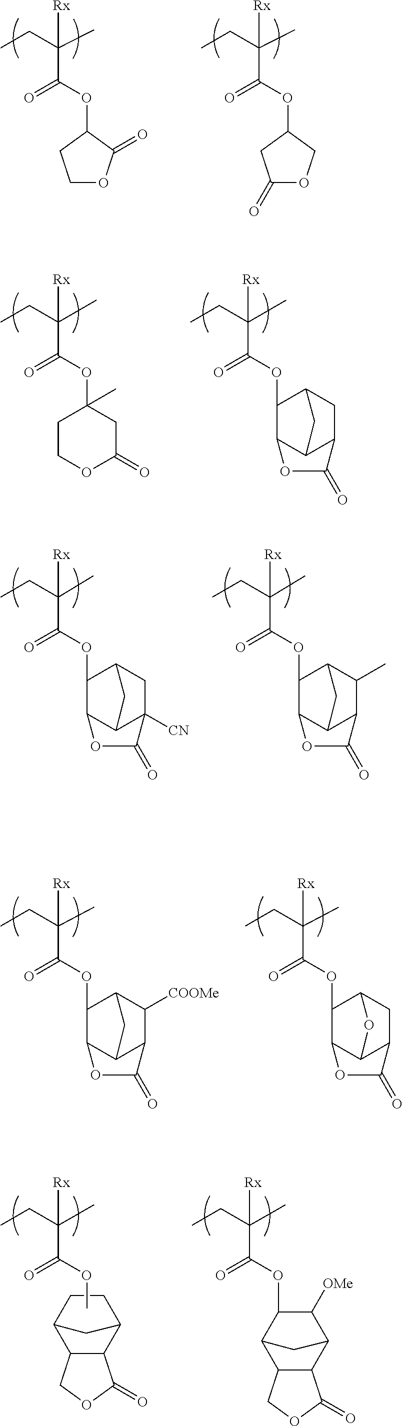

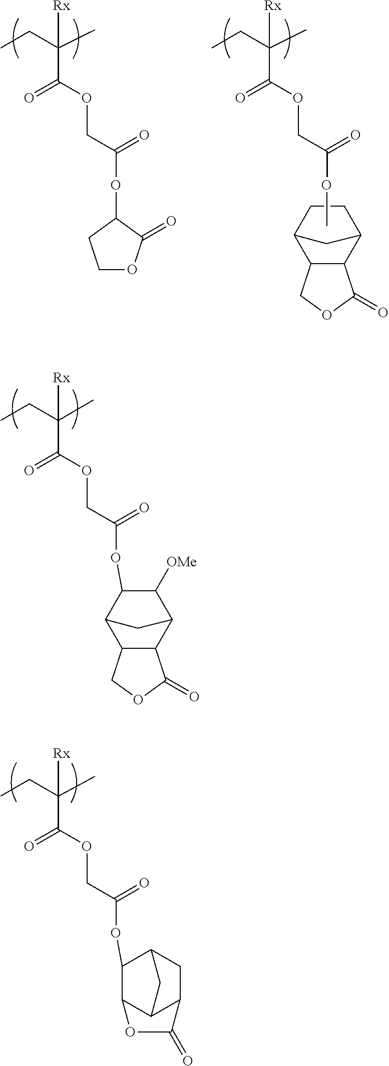

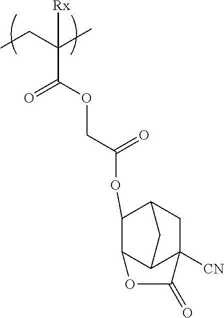

Furthermore, as a sultone group which the resin (A) has, the following General Formula (SL-1) or (SL-2) is preferable. Rb₂ and n₂ in the formulae have the same definitions as those in General Formulae (LC1-1) to (LC1-17), respectively.

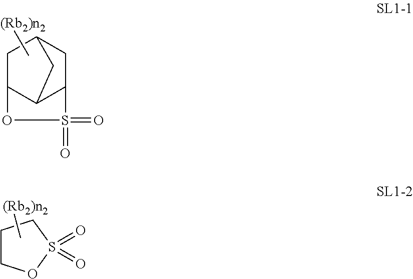

As the repeating unit including a sultone group which the resin (A) has, a repeating unit formed by substituting the lactone group in the repeating unit having an lactone group as described above with a sultone group is preferable.

The repeating unit (c) may be a repeating unit having a cyclic carbonic acid ester structure as a polar group.

The repeating unit having a cyclic carbonic acid ester structure is preferably a repeating unit represented by the following General Formula (A-1).

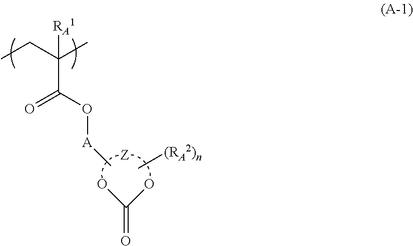

In General Formula (A-1), R_{A}¹ represents a hydrogen atom or an alkyl group.

In a case where n is 2 or more, R_{A2}'s each independently represent a substituent.

A represents a single bond or a divalent linking group.

Z represents an atomic group which forms a monocyclic or polycyclic structure together with a group represented by —O—C(═O)—O— in the formula.

n represents an integer of 0 or more.

General Formula (A-1) will be described in detail.

The alkyl group represented by R_{A}¹ may have a substituent such as a fluorine atom. R_{A}¹ is preferably a hydrogen atom, a methyl group, or a trifluoromethyl group, and more preferably a methyl group.

The substituent represented by R_{A}² is, for example, an alkyl group, a cycloalkyl group, a hydroxyl group, an alkoxy group, an amino group, or an alkoxycarbonylamino group. As the substituent, an alkyl group having 1 to 5 carbon atoms is preferable, and examples thereof include a linear alkyl group having 1 to 5 carbon atoms; and a branched alkyl group having 3 to 5 carbon atoms. The alkyl group may have a substituent such as a hydroxyl group.

n is an integer of 0 or more, which represents the number of substituents. For example, n is preferably 0 to 4, and more preferably 0.

Examples of the divalent linking group represented by A include an alkylene group, a cycloalkylene group, an ester bond, an amide bond, an ether bond, a urethane bond, a urea bond, and combinations thereof. As the alkylene group, an alkylene group having 1 to 10 carbon atoms is preferable, and an alkylene group having 1 to 5 carbon atoms is more preferable.

In one aspect of the present invention, A is preferably a single bond or an alkylene group.

Examples of a monocycle including —O—C(═O)—O—, represented by Z, include a 5- to 7-membered ring having n_{A} of 2 to 4, in the cyclic carbonic acid ester represented by the following General Formula (a), and the monocycle is preferably a 5-membered ring or a 6-membered ring (n_{A}=2 or 3), and more preferably a 5-membered ring (n_{A}=2).

Examples of a polycycle including —O—C(═O)—O—, represented by Z, include a structure in which a fused ring is formed by cyclic carbonic acid ester represented by the following General Formula (a) together with one or two more other ring structures or a structure in which a spiro ring is formed. “Other ring structures” capable of forming a fused ring or a spiro ring may be an alicyclic hydrocarbon group, may be an aromatic hydrocarbon group, or may be a heterocycle.

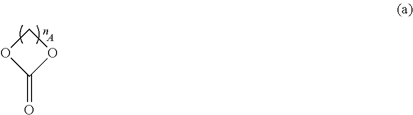

The resin (A) may include one kind of repeating units having a cyclic carbonic acid ester structure, or may include two or more kinds thereof.

In the resin (A), the content of the repeating unit having a cyclic carbonic acid ester structure (preferably the repeating unit represented by General Formula (A-1)) is preferably 3% to 80% by mole, more preferably 3% to 60% by mole, particularly preferably 3% to 30% by mole, and most preferably 10% to 15% by mole, with respect to all the repeating units constituting the resin (A). By setting the content to fall within the above range, developability, low defects, low LWR, low PEB temperature dependence, profiles, and the like as a resist can be improved.

Specific examples of the repeating unit represented by General Formula (A-1) will be described below, but the present invention is not limited thereto.

Moreover, R_{A}¹ in the following specific examples has the same definition as R_{A}¹ in General Formula (A-1).

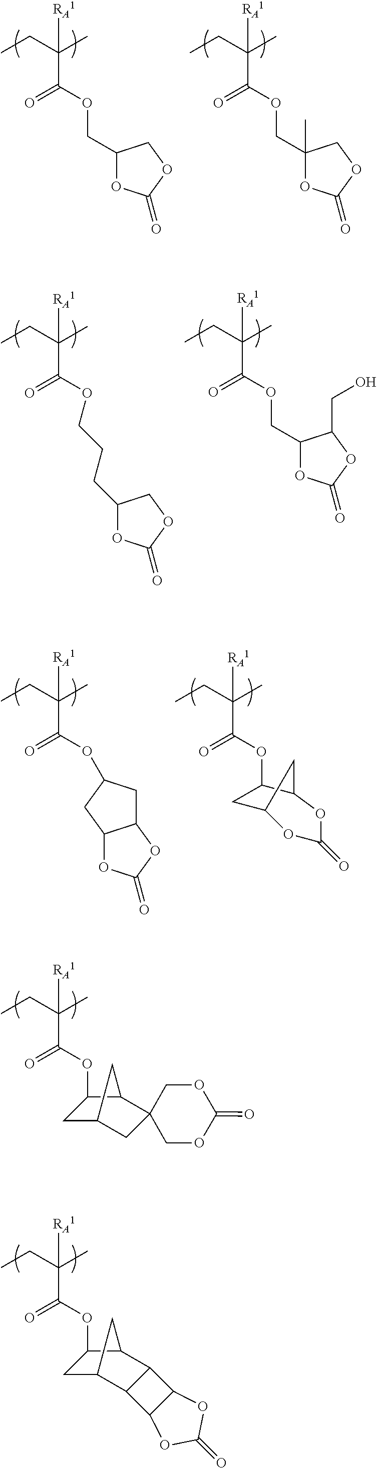

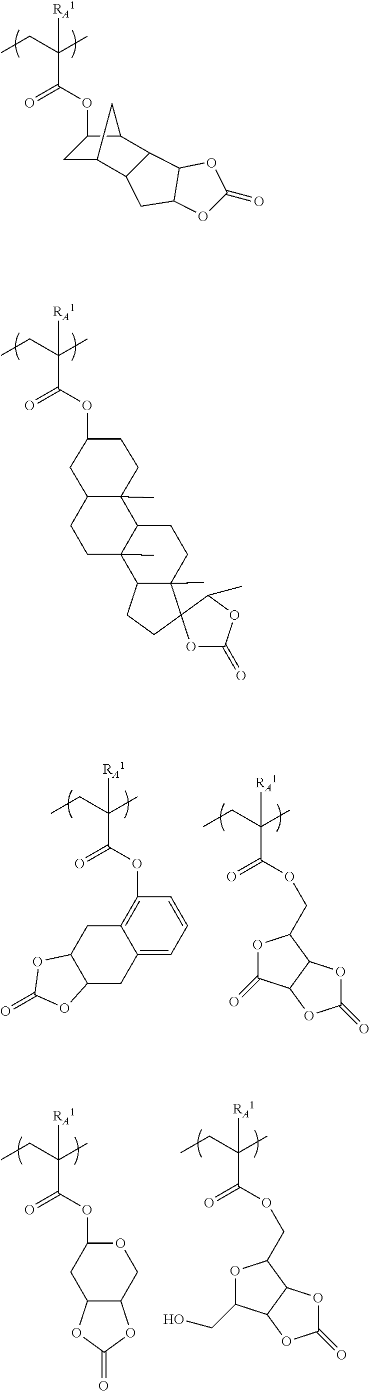

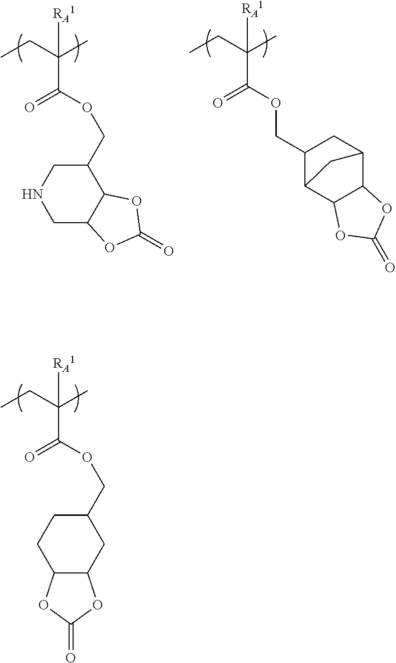

Moreover, it is also one of particularly preferable aspects that a polar group which the repeating unit (c) can have is an acidic group. Preferred examples of the acidic group include a phenolic hydroxyl group, a carboxylic acid group, a sulfonic acid group, a fluorinated alcohol group (for example, a hexafluoroisopropanol group), a sulfonamide group, a sulfonyl imide group, a (alkylsulfonyl)(alkylcarbonyl)methylene group, a (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group. Among these, the repeating unit (c) is more preferably a repeating unit having a carboxyl group. Examples of the repeating unit having an acidic group include a repeating unit of which an acidic group is directly bonded to the main chain of a resin as a repeating unit by acrylic acid or methacrylic acid and a repeating unit of which an acidic group is bonded to the main chain of a resin through a linking group, and any repeating unit introduced to a terminal of a polymer chain using a polymerization initiator or a chain transfer agent having an acidic group at the time of polymerization is preferable. A repeating unit by acrylic acid or methacrylic acid is particularly preferable.

The acidic group which the repeating unit (c) can have may not include an aromatic ring, but in a case where the acidic group has an aromatic ring, the acidic group is preferably selected from acidic groups other than a phenolic hydroxyl group. In a case where the resin (A) contains a repeating unit having an acidic group, the content of the repeating unit having an acidic group in the resin (A) is usually 1% by mole or more.

Specific examples of the repeating unit having an acidic group are shown below, but the present invention is not limited thereto.

In the specific examples, Rx represents H, CH₃, CH₂OH, or CF₃.

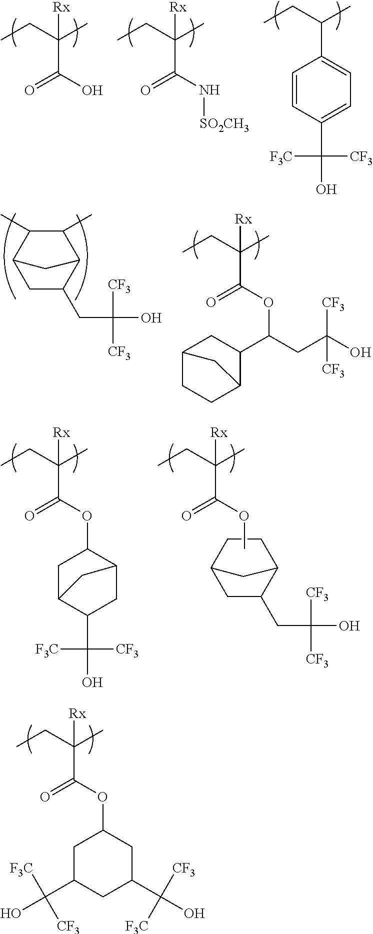

The resin (A) may have the repeating unit (d) having a plurality of aromatic rings. Regarding the repeating unit (d) having a plurality of aromatic rings, reference can be made to the description in paragraphs [0194] to [0207] of JP2013-76991A, the contents of which are incorporated in the present specification.

The resin (A) may contain or may not contain the repeating unit (d), and in a case where the resin (A) contains the repeating unit (d), the content of the repeating unit (d) is preferably in a range of 1% to 30% by mole, more preferably in a range of 1% to 20% by mole, and still more preferably in a range of 1% to 15% by mole, with respect to all the repeating units in the resin (A). The repeating unit (d) included in the resin (A) may be included in combination of two or more kinds thereof.

The resin (A) may appropriately have a repeating unit other than the above-described repeating units. One example of such a repeating unit is a repeating unit which has an alicyclic hydrocarbon structure without a polar group (for example, an acid group, a hydroxyl group, and a cyano group) and does not exhibit acid decomposability. Thus, the solubility of a resin can be appropriately adjusted in development using a developer including an organic solvent. Examples of such a repeating unit include the repeating unit represented by General Formula (IV).

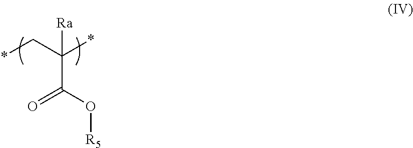

In General Formula (IV), R₅ has at least one cyclic structure and represents a hydrocarbon group not having a polar group.

Ra represents a hydrogen atom, an alkyl group, or a —CH₂—O—Ra₂ group. In the formula, Raₑ represents a hydrogen atom, an alkyl group, or an acyl group. Ra is preferably a hydrogen atom, a methyl group, a hydroxymethyl group, or a trifluoromethyl group, and particularly preferably a hydrogen atom or a methyl group.

Regarding the respective groups in General Formula (IV), reference can be made to the description in paragraphs [0212] to [0216] of JP2013-76991A, the contents of which are incorporated in the present specification.

The resin (A) may or may not contain a repeating unit which has an alicyclic hydrocarbon structure without a polar group and does not exhibit acid decomposability, but in a case where the resin (A) contains the repeating unit, the content of the repeating unit is preferably 1% to 20% by mole, and more preferably 5% to 15% by mole, with respect to all the repeating units in the resin (A).

Specific examples of the repeating unit which has an alicyclic hydrocarbon structure without a polar group and does not exhibit acid decomposability are shown below, but the present invention is not limited thereto. In the formulae, Ra represents H, CH₃, CH₂OH, or CF₃.

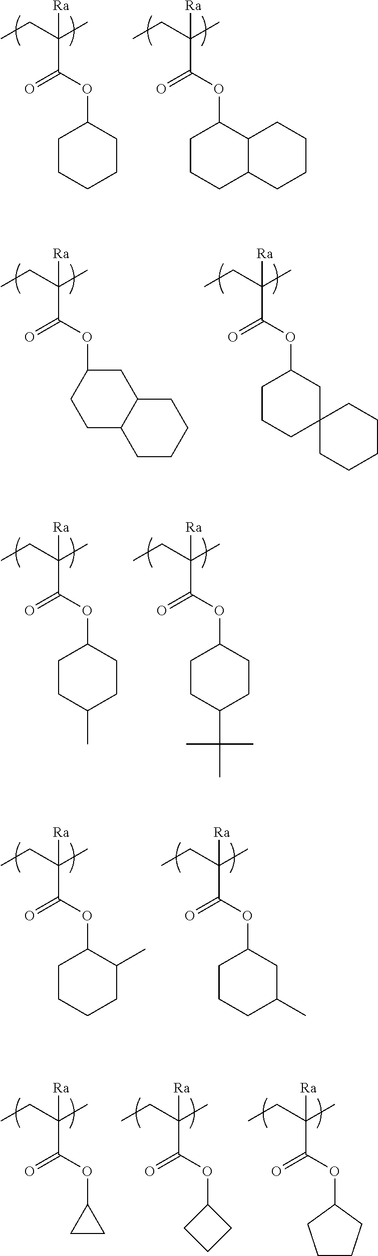

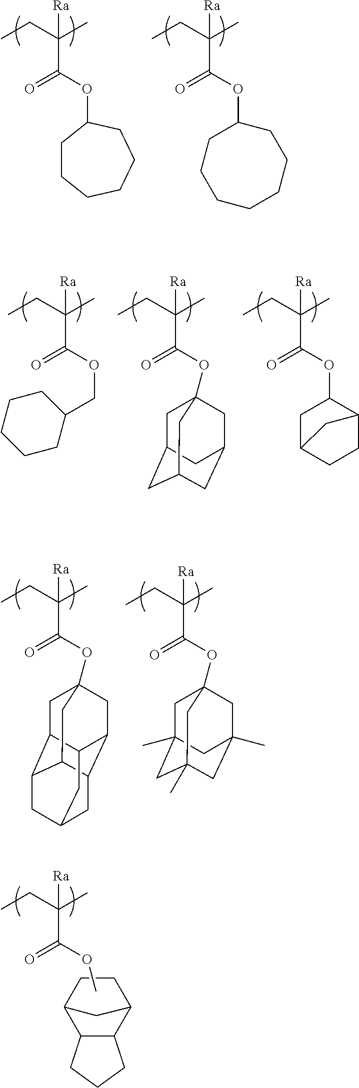

In addition, the resin (A) may include the following repeating units in consideration of effects such as increase in Tg, improvement of dry etching resistance, and an internal filter with respect to the out of band light.

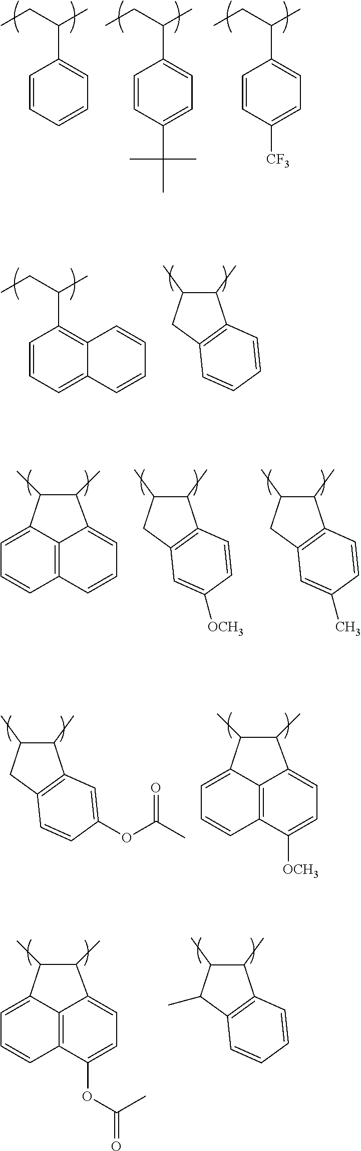

In addition, the resin (A) may further include a repeating unit represented by the following General Formula (P).

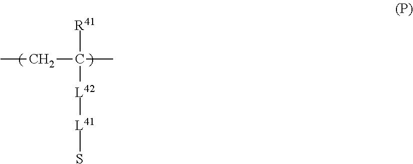

R⁴¹ represents a hydrogen atom or a methyl group. L⁴¹ represents a single bond or a divalent linking group. L⁴² represents a divalent linking group. S represents a structural site that is degraded upon irradiation with electron beams or extreme ultraviolet rays to generate an acid on a side chain.

Specific examples of the repeating unit represented by General Formula (P) are shown below, but the present invention is not limited thereto. Regarding specific examples of the repeating unit represented by General Formula (P), reference can be made to the description in paragraphs [0168] to [0210] of JP2013-80002A and [0191] to [0203] of JP2013-137537A, the contents of which are incorporated in the present specification.

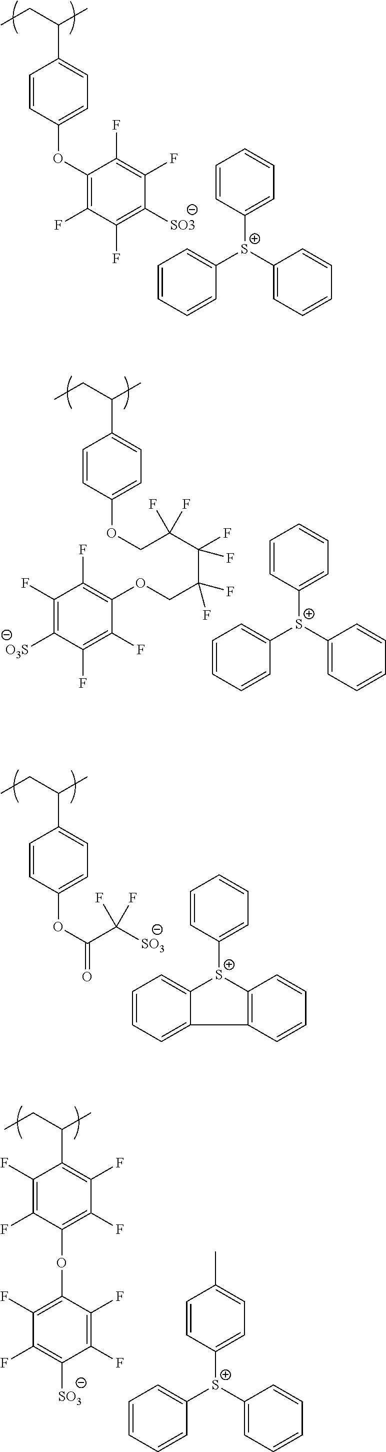

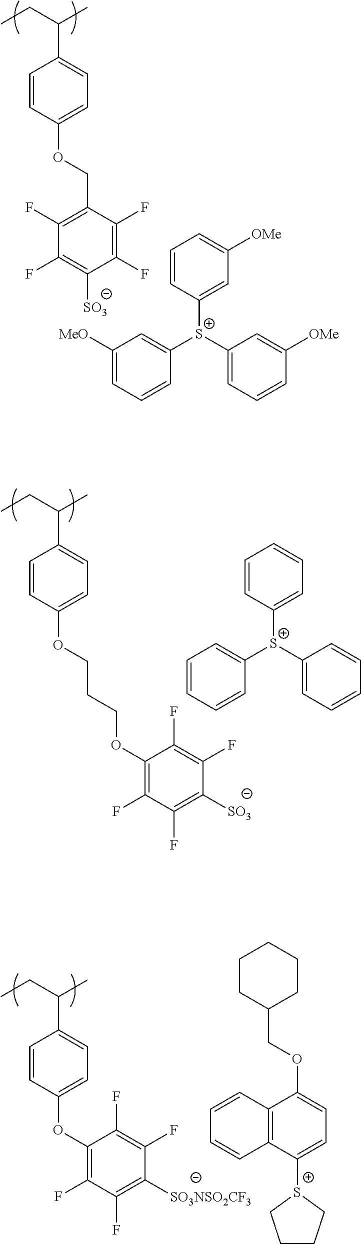

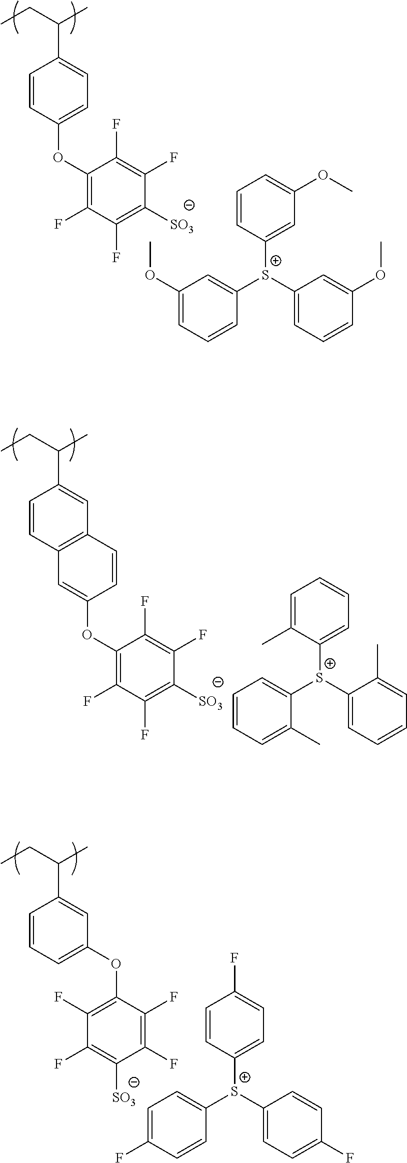

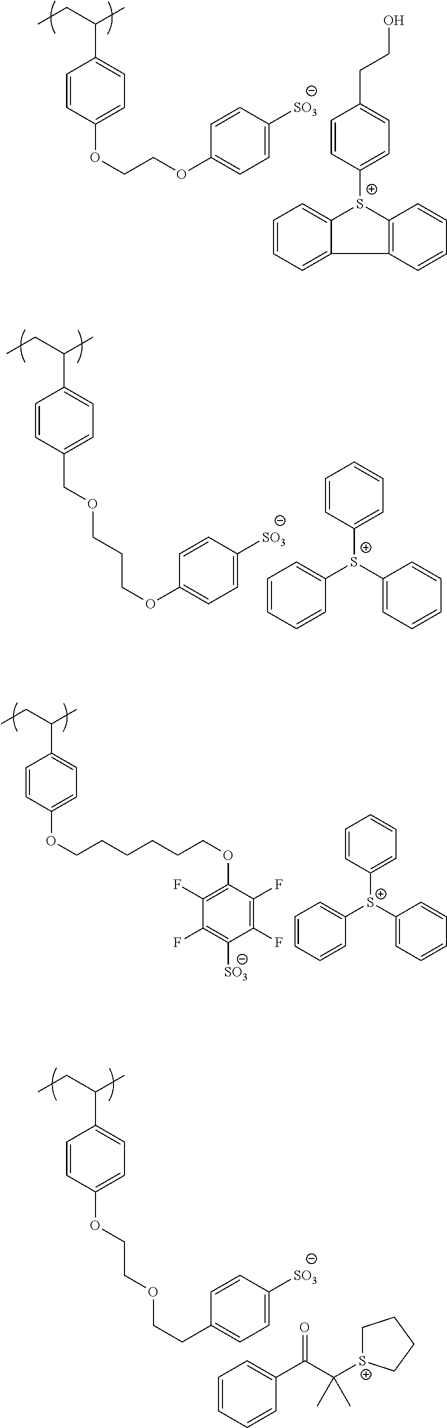

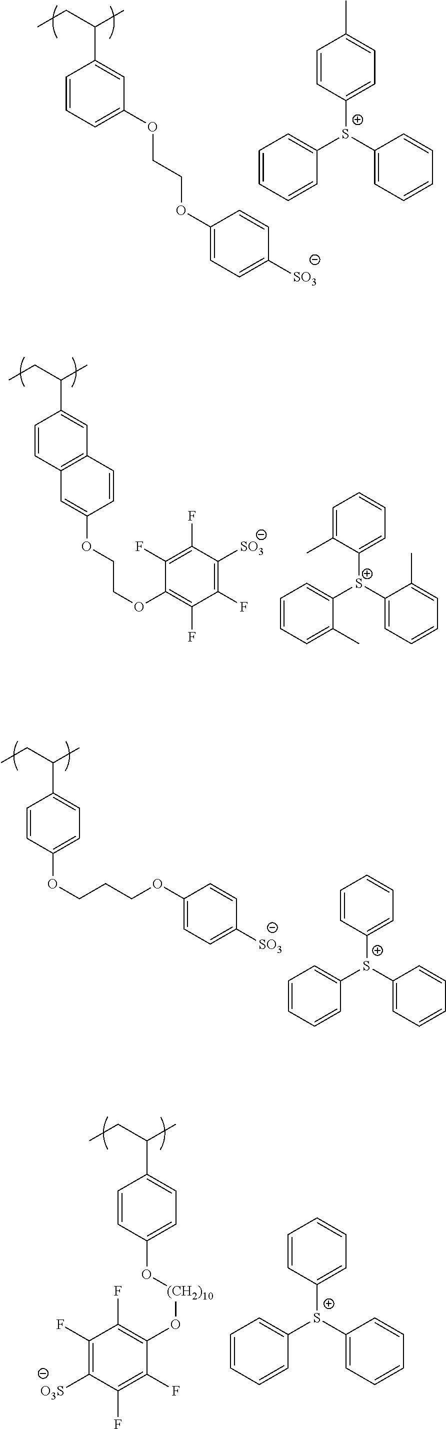

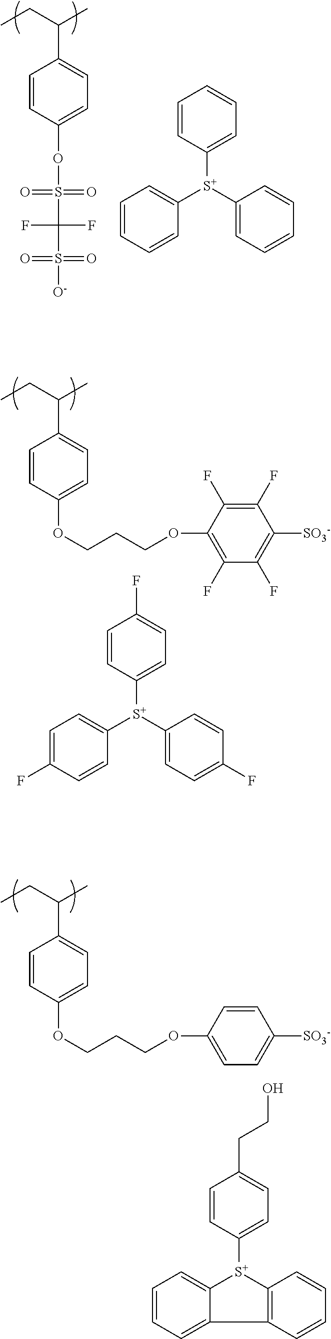

The content of the repeating unit represented by General Formula (P) in the resin (A) is preferably in a range of 1% to 40% by mole, more preferably in a range of 2% to 30% by mole, and particularly preferably in a range of 5% to 25% by mole, with respect to all the repeating units in the resin (A).

Specific examples of the resin are shown below, but the present invention is not limited thereto.

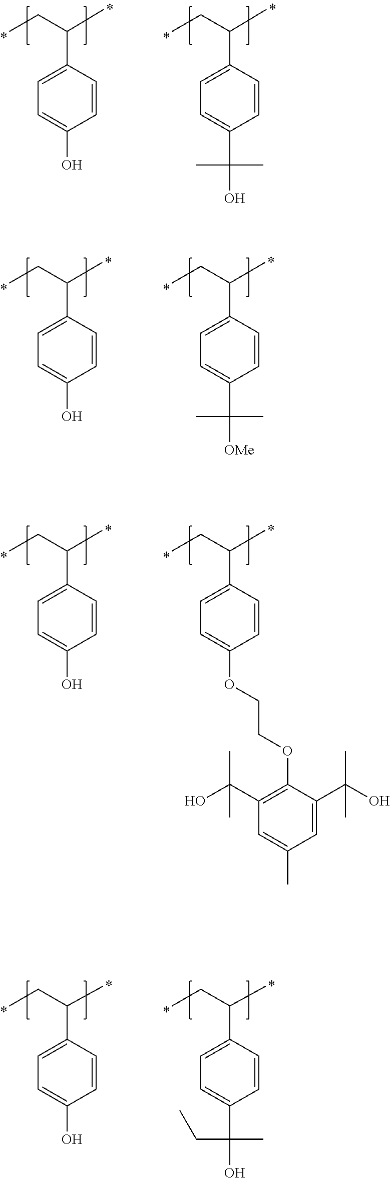

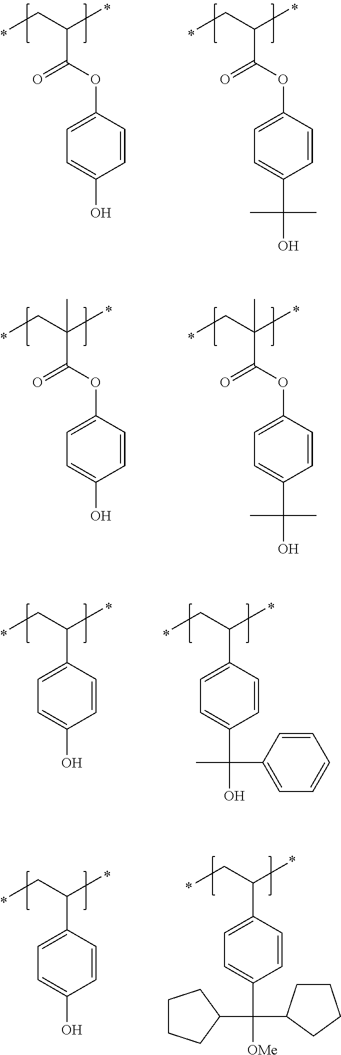

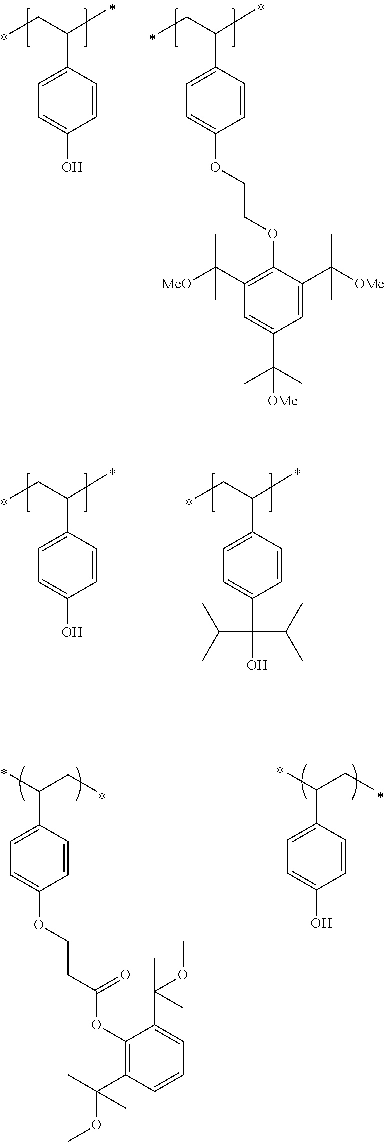

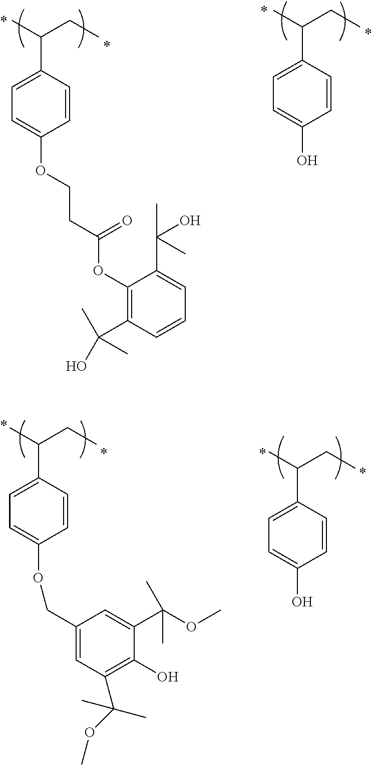

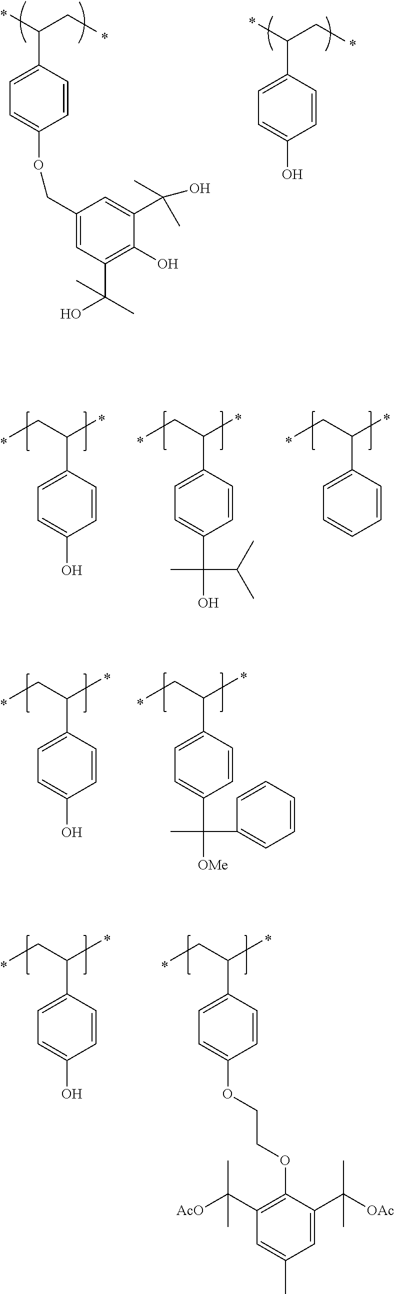

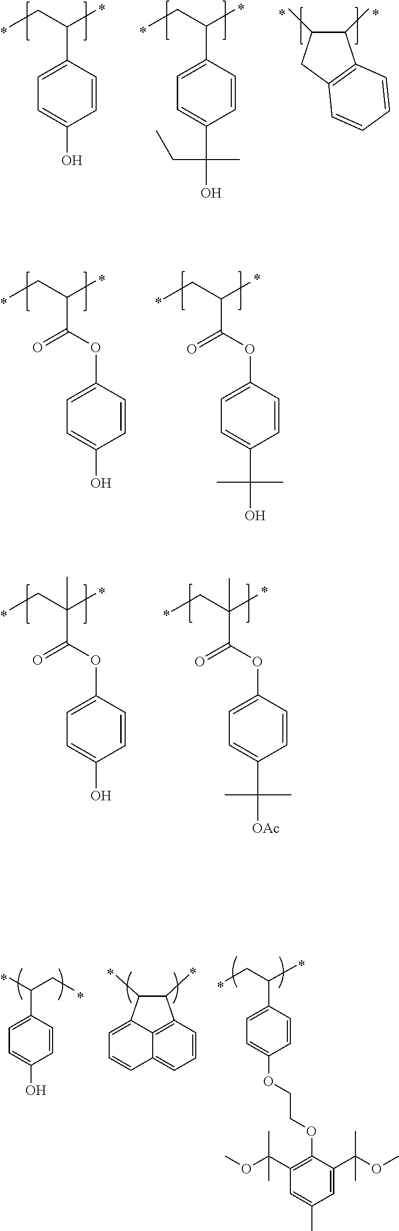

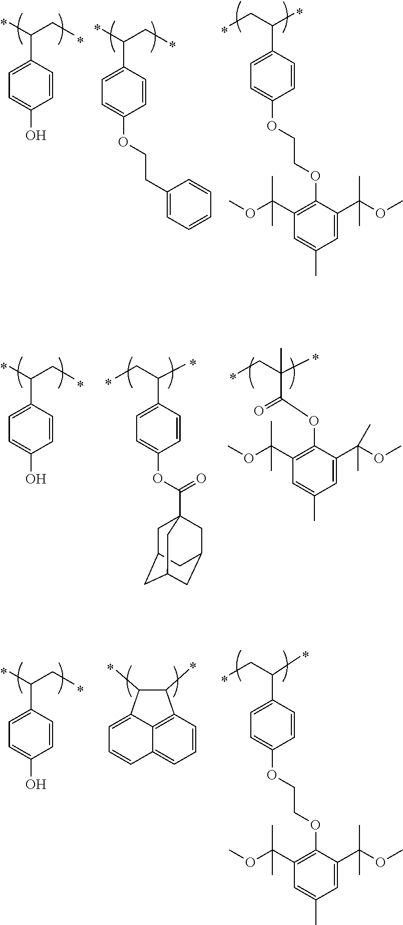

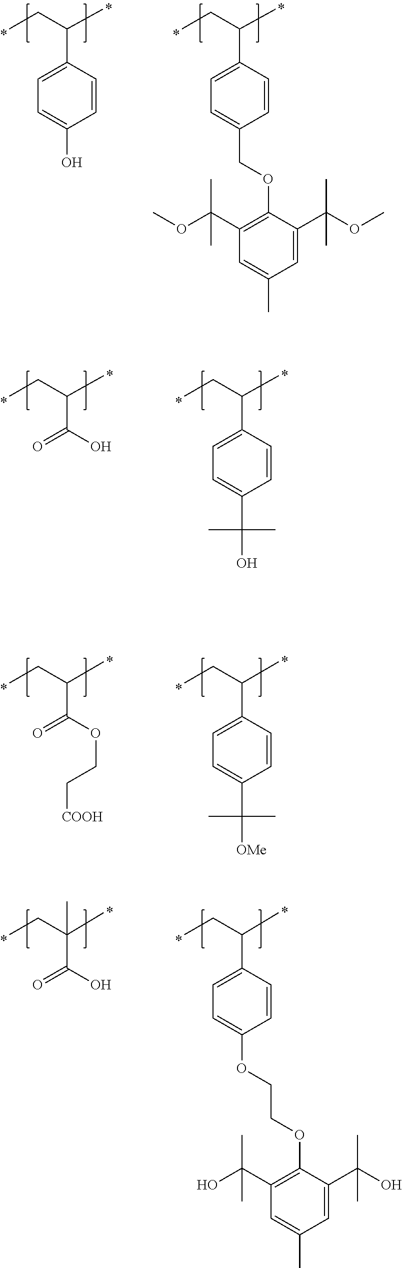

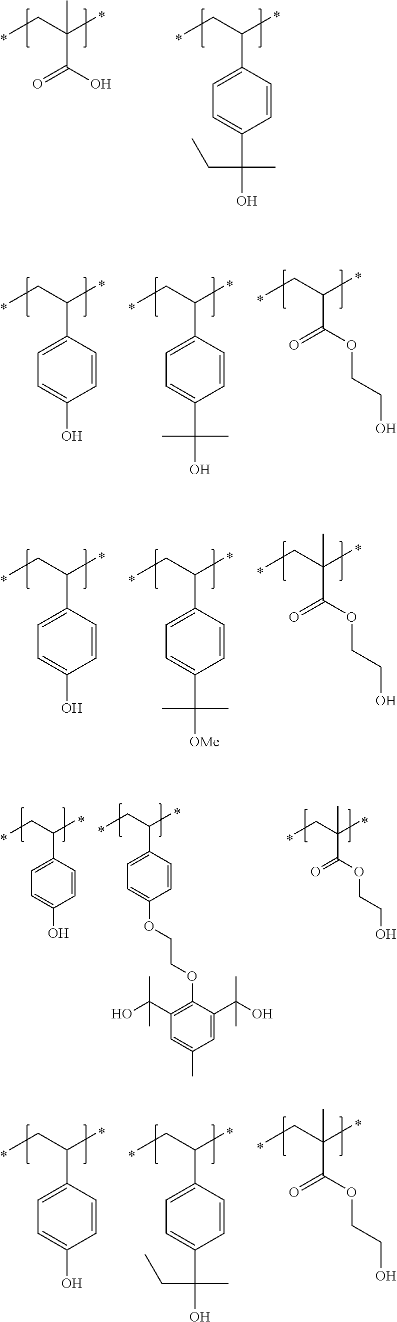

In a case where the compound X used in the composition is the resin (A), the content molar ratio of respective repeating structural units is suitably set to adjust the dry etching resistance or the standard developer suitability of a resist, adhesiveness to a substrate, a resist profile, and resolving power, heat resistance, and sensitivity which are properties generally required for a resist.

The form of the resin (A) may be any form of a random form, a block form, a comb form, and a star form.

The resin (A) can be synthesized by, for example, polymerizing an unsaturated monomer corresponding to each structure through radical polymerization, cationic polymerization, or anionic polymerization. In addition, by carrying out a polymer reaction after polymerization is carried out using an unsaturated monomer corresponding to a precursor of each structure, a target resin can also be obtained.

Examples of a general synthetic method include a collective polymerization method of carrying out polymerization by dissolving an unsaturated monomer and a polymerization initiator in a solvent and heating the resultant product and a dropwise addition polymerization method of adding a solution containing an unsaturated monomer and an polymerization initiator dropwise to a heated solvent over a period of 1 to 10 hours, and the dropwise addition polymerization method is preferable.

Examples of the solvent used in the polymerization include solvents which can be used in preparing an actinic ray-sensitive or radiation-sensitive resin composition which will be described later, and it is more preferable that the polymerization is carried out using the same solvent as the solvent used in the composition. Thus, generation of particles during storage can be suppressed.

The polymerization reaction is preferably performed in an inert gas atmosphere such as nitrogen and argon. The polymerization is initiated using a commercially available radical initiator as a polymerization initiator (an azo-based initiator, a peroxide, or the like). As the radical initiator, an azo-based initiator is preferable, and an azo-based initiator having an ester group, a cyano group, or a carboxyl group is preferable. Preferred examples of the initiator include azobisisobutyronitrile, azobisdimethylvaleronitrile, and dimethyl 2,2′-azobis(2-methylpropionate). If necessary, polymerization may be carried out in the presence of a chain transfer agent (for example, alkyl mercaptan).

The concentration of the reaction is 5% to 70% by mass, and preferably 10% to 50% by mass. The reaction temperature is typically 10° C. to 150° C., preferably 30° C. to 120° C., and more preferably 40° C. to 100° C.

The reaction time is usually 1 to 48 hours, preferably 1 to 24 hours, and more preferably 1 to 12 hours.

After completion of the reaction, cooling to room temperature and purification are carried out. A usual method such as a liquid-liquid extraction method in which a residual monomer or an oligomer component is removed by washing with water or combining suitable solvents, a purification method in a solution state such as ultrafiltration which extracts and removes only substances having a specific molecular weight or less, a reprecipitation method in which a residual monomer or the like is removed by adding a resin solution dropwise to a poor solvent to coagulate the resin in the poor solvent, or a purification method in a solid state in which filtered resin slurry is washed with a poor solvent can be applied to the purification. For example, by bringing into contact with a solvent (a poor solvent), which does poorly dissolve or does not dissolve the resin, corresponding to 10 times or less the volume amount of the reaction solution, or preferably 5 to 10 times the volume amount of the reaction solution, the resin is solidified and precipitated.

The solvent (a precipitation or reprecipitation solvent) used in a precipitation or reprecipitation operation from the polymer solution may be a poor solvent for the polymer, and depending on the type of polymer, the solvent can be appropriately selected from a hydrocarbon, a halogenated hydrocarbon, a nitro compound, ether, ketone, ester, carbonate, alcohol, carboxylic acid, water, and a mixed solvent including these solvents and used. Among these, as a precipitation or reprecipitation solvent, a solvent including at least alcohol (in particular, methanol) or water is preferable.

The amount of the precipitation or reprecipitation solvent to be used can be appropriately selected in consideration of efficiency, a yield, or the like, but is generally 100 to 10,000 parts by mass, preferably 200 to 2,000 parts by mass, and more preferably 300 to 1,000 parts by mass, with respect to 100 parts by mass of the polymer solution.

The temperature at a time of precipitation or reprecipitation can be appropriately selected in consideration of efficiency or operability, but is usually approximately 0° C. to 50° C., and preferably around room temperature (for example, approximately 20° C. to 35° C.). Precipitation or reprecipitation operation can be carried out by a known method such as a batch type method and a continuous type method, using a generally used mixing vessel such as a stirring vessel.

The precipitated or reprecipitated polymer is usually subjected to solid-liquid separation generally used, such as filtration and centrifugation, dried, and then provided for use. The filtration is preferably carried out under pressure using a solvent-resistant filter medium. The drying is carried out at a temperature of approximately 30° C. to 100° C. at normal pressure or under reduced pressure (preferably, under reduced pressure), and preferably at a temperature of approximately 30° C. to 50° C.

Moreover, once the resin is precipitated, and after being separated, the resin is again dissolved in a solvent, and may be brought into contact with a solvent which does poorly dissolve or does not dissolve the resin. That is, a method which includes a step of precipitating a resin by bringing into contact with a poorly soluble or insoluble solvent which does not dissolve the polymer after the radical polymerization reaction ends (step a), a step of separating the resin from the solution (step b), a step of preparing a resin solution A by dissolving the resin in a solvent (step c), thereafter, by bringing the resin solution A into contact with a solvent in which the resin is poorly soluble or insoluble, corresponding to 10 times or less the volume amount (preferably 5 times or less the volume amount) of the resin solution A, the resin solid is precipitated (step d), and a step of separating the precipitated resin (step e) may be carried out.

It is preferable that the polymerization reaction is carried out in an inert gas atmosphere such as nitrogen and argon. As the polymerization initiator, commercially available radical initiators (an azo-based initiator, a peroxide, or the like) are used to initiate the polymerization. As the radical initiator, an azo-based initiator is preferable, and the azo-based initiator having an ester group, a cyano group, or a carboxyl group is preferable. Preferable initiators include azobisisobutyronitrile, azobisdimethylvaleronitrile, dimethyl 2,2′-azobis(2-methyl propionate), or the like. The initiator is added or added in portionwise, depending on the purposes, and after completion of the reaction, the reaction mixture is poured into a solvent, and then a desired polymer is recovered by a method such as powder or solid recovery. The concentration of the reactant is 5% to 50% by mass, and preferably 10% to 30% by mass. The reaction temperature is normally 10° C. to 150° C., preferably 30° C. to 120° C., and more preferably 60° C. to 100° C.

The molecular weight of the resin (A) is not particularly limited, but the weight-average molecular weight is preferably in a range of 1,000 to 100,000, more preferably in a range of 1,500 to 60,000, and particularly preferably in a range of 2,000 to 30,000, in terms of polystyrene by means of a GPC method. When the weight-average molecular weight is in a range of 1,000 to 100,000, degradation of heat resistance or dry etching resistance can be prevented, and degradation of developability or degradation of film formability due to increase in viscosity can be prevented.

Moreover, the dispersity (Mw/Mn) is preferably 1.00 to 5.00, more preferably 1.00 to 3.50, and still more preferably 1.00 to 2.50. As the molecular weight distribution is lower, the resolution and the resist shape become better, and the side wall of the resist pattern becomes smoother, and thus, the roughness becomes excellent.

In the present specification, the weight-average molecular weight (Mw) and the dispersity of the resin (A) can be determined by using, for example, HPL-8120 (manufactured by TOSOH CORPORATION), TSK gel Multipore HXL-M (manufactured by TOSOH CORPORATION, 7.8 mmHD×30.0 cm) as a column, and THF (tetrahydrofuran) or NMP (N-methyl-2-pyrrolidone) as an eluent.

The compound X can be used singly or in combination of two or more kinds thereof. The content of the compound X is preferably 20% to 99% by mass, more preferably 30% to 99% by mass, and still more preferably 40% to 99% by mass, with respect to the total solid content in the actinic ray-sensitive or radiation-sensitive resin composition.

<Compound that Generates Acid by Active Light or Radiation>

The composition preferably contains a compound (B) that generates an acid by active light or radiation (hereinafter referred to as an “acid generator (B)”).

The compound (B) that generates an acid upon irradiation with active rays or radiation may have a form of a low molecular weight compound, or may have a form in which the compound (B) is incorporated into a part of a polymer. In addition, a form of a low molecular weight compound and a form in which the compound (B) is incorporated into a part of a polymer may be used in combination.

In a case where the compound (B) that generates an acid upon irradiation with active rays or radiation has a form of a low molecular weight compound, the molecular weight of the compound (B) is preferably 3,000 or less, more preferably 2,000 or less, and still more preferably 1,000 or less.

In a case where the compound (B) that generates an acid upon irradiation with active rays or radiation has a form in which the compound (B) is incorporated into a part of a polymer, the compound (B) may be incorporated into a part of the resin (A), or may be incorporated into a resin different from the resin (A).

The acid generator (B) is not particularly limited as long as it is a known acid generator, but the acid generator is preferably a compound which generates an organic acid, for example, at least any one of sulfonic acid, bis(alkylsulfonyl)imide, or tris(alkylsulfonyl)methide upon irradiation with active light or radiation, and preferably an electron beam or extreme ultraviolet rays.

More preferably, compounds represented by the following General Formula (ZI), (ZII), and (ZIII) can be exemplified.

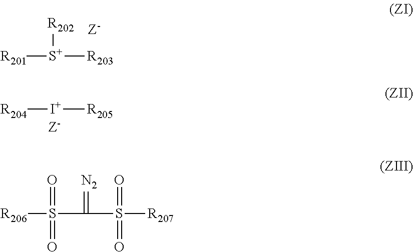

In General Formula (ZI),

R₂₀₁, R₂₀₂, and R₂₀₃ each independently represent an organic group.

The number of carbon atoms of the organic group as R₂₀₁, R₂₀₂, and R₂₀₃ is generally 1 to 30, and preferably 1 to 20.

Furthermore, two members out of R₂₀₁ to R₂₀₃ may be bonded to each other to form a ring structure, and the ring may contain an oxygen atom, a sulfur atom, an ester bond, an amide bond, or a carbonyl group. Examples of the group formed by the mutual bonding of two members out of R₂₀₁ to R₂₀₃ include an alkylene group (for example, a butylene group and a pentylene group).

Z⁻ refers to a non-nucleophilic anion (an anion having an extremely low ability of causing a nucleophilic reaction).

Examples of the non-nucleophilic anion include a sulfonate anion (an aliphatic sulfonate anion, an aromatic sulfonate anion, and a camphorsulfonate anion), a carboxylate anion (an aliphatic carboxylic anion, an aromatic carboxylate anion, and an aralkylcarboxylate anion), a sulfonylimido anion, a bis(alkylsulfonyl)imido anion, and a tris(alkylsulfonyl)methide anion.

Regarding the aliphatic site in the aliphatic sulfonate anion and the aliphatic carboxylate anion, and the aromatic group in the aromatic sulfonate anion and the aromatic carboxylate anion, reference can be made to paragraphs [0234] and [0235] of JP2013-76991A, the contents of which are incorporated in the present specification.

The alkyl group, the cycloalkyl group, and the aryl group as mentioned above may have a substituent. Regarding the specific examples thereof, reference can be made to paragraph [0236] of JP2013-76991A, the contents of which are incorporated in the present specification.

Regarding the aralkylcarboxylate anion, the sulfonylimide anion, the bis(alkylsulfonyl)imide anion, and the tris(alkylsulfonyl)methide anion, reference can be made to paragraphs [0237] to [0239] of JP2013-76991A, the contents of which are incorporated in the present specification.

Regarding the other non-nucleophilic anions, reference can be made to paragraph [0240] of JP2013-76991A, the contents of which are incorporated in the present specification.

The non-nucleophilic anion is preferably an aliphatic sulfonate anion substituted with a fluorine atom at least at the α-position of sulfonic acid, an aromatic sulfonate anion substituted with a fluorine atom or a group having a fluorine atom, a bis(alkylsulfonyl)imide anion in which the alkyl group is substituted with a fluorine atom, or a tris(alkylsulfonyl)methide anion in which the alkyl group is substituted with a fluorine atom. The non-nucleophilic anion is more preferably a perfluoroaliphatic sulfonate anion having 4 to 8 carbon atoms or a benzenesulfonate anion having a fluorine atom, still more preferably a nonafluorobutanesulfonate anion, a perfluorooctanesulfonate anion, a pentafluorobenzenesulfonate anion, or a 3,5-bis(trifluoromethyl)benzenesulfonate anion.

From the viewpoint of the acid strength, the pKa of the generated acid is preferably −1 or less in order to improve the sensitivity.

Moreover, preferred embodiments of the non-nucleophilic anion also include an anion represented by the following General Formula (AN1).

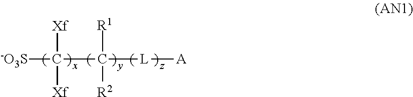

In the formula, Xf's each independently represent a fluorine atom or an alkyl group substituted with at least one fluorine atom.

R¹ and R² each independently represent a hydrogen atom, a fluorine atom, or an alkyl group, and in a case where a plurality of R¹'s or R²'s are present, they may be the same as or different from each other.

L represents a divalent linking group, and in a case where a plurality of L's are present, they may be the same as or different from each other.

A represents a cyclic organic group.

x represents an integer of 1 to 20, y represents an integer of 0 to 10, and z represents an integer of 0 to 10.

General Formula (AN1) will be described in more detail.

The alkyl group in the alkyl group substituted with a fluorine atom of Xf preferably has 1 to 10 carbon atoms, and more preferably 1 to 4 carbon atoms. In addition, the alkyl group substituted with a fluorine atom of Xf is preferably a perfluoroalkyl group.

Xf is preferably a fluorine atom or a perfluoroalkyl group having 1 to 4 carbon atoms. Specific examples of Xf include a fluorine atom, CF₃, C₂F₅, C₃F₇, C₄F₉, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, and among these, a fluorine atom or CF₃ is preferable. In particular, both of Xf s are preferably fluorine atoms.

The alkyl group of R¹ or R² may have a substituent (preferably a fluorine atom), and the alkyl group is preferably an alkyl group having 1 to 4 carbon atoms, and more preferably a perfluoroalkyl group having 1 to 4 carbon atoms. Specific examples of the alkyl group having a substituent of R¹ or R² include CF₃, C₂F₅, C₃F₇, C₄F₉, C₅Fᵢᵢ, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, and among these, CF₃ is preferable.

Each of R¹ and R² is preferably a fluorine atom or CF₃.

x is preferably 1 to 10, and more preferably 1 to 5.

y is preferably 0 to 4, and more preferably 0.

z is preferably 0 to 5, and more preferably 0 to 3.

The divalent linking group of L is not particularly limited, and examples thereof include —COO—, —OCO—, —CO—, —O—, —S—, —SO—, —SO₂—, an alkylene group, a cycloalkylene group, an alkenylene group, and a linking group obtained by connecting a plurality of these, and a linking group having 12 or less total carbon atoms is preferable. Among these, —COO—, —OCO—, —CO—, or —O— is preferable, and —COO— or —OCO— is more preferable.

The cyclic organic group of A is not particularly limited as long as it has a ring structure, and examples thereof include an alicyclic group, an aryl group, and a heterocyclic group (including not only a heterocyclic group having aromaticity but also a heterocyclic group without a aromaticity).

The alicyclic group may be monocyclic or polycyclic, and as the alicyclic group, a monocyclic cycloalkyl group such as a cyclopentyl group, a cyclohexyl group, or a cyclooctyl group, or polycyclic cycloalkyl groups such as a norbornyl group, a tricyclodecanyl group, a tetracyclodecanyl group, a tetracyclododecanyl group, or an adamantyl group is preferable. Among these, an alicyclic group with a bulky structure having 7 or more carbon atoms such as a norbornyl group, a tricyclodecanyl group, a tetracyclodecanyl group, a tetracyclododecanyl group, or an adamantyl group is preferable from the viewpoint of being capable of suppressing in-film diffusibility in a heating step after exposure and MEEF improvement.

Examples of the aryl group include a benzene ring, a naphthalene ring, a phenanthrene ring, and an anthracene ring.

Examples of the heterocyclic group include groups derived from a furan ring, a thiophene ring, a benzofuran ring, a benzothiophene ring, a dibenzofuran ring, a dibenzothiophene ring, and a pyridine ring. Among these, a group derived from a furan ring, a thiophene ring, or a pyridine ring is preferable.

In addition, examples of the cyclic organic group also include a lactone structure, and specific examples thereof include the lactone structures represented by General Formulae (LC1-1) to (LC1-17), which the resin (A) as described above may have.

The above-described cyclic organic group may has a substituent, and regarding the substituent, reference can be made to the description in paragraph [0251] of JP2013-76991A, the contents of which are incorporated in the present specification.

Examples of the organic group of each of R₂₀₁, R₂₀₂, and R₂₀₃ include an aryl group, an alkyl group, and a cycloalkyl group.

It is preferable that at least one of R₂₀₁, R₂₀₂, or R₂₀₃ is an aryl group, and it is more preferable that all of three are aryl groups. Regarding the aryl group, the alkyl group, and the cycloalkyl group, reference can be made to the description in paragraph [0252] of JP2013-76991A, the contents of which are incorporated in the present specification.

Moreover, regarding the structure represented by General Formula (A1) in a case where two members out of R₂₀₁ to R₂₀₃ are bonded to each other to form a ring structure, reference can be made to the description in paragraphs [0253] to [0257] of JP2013-76991A, the contents of which are incorporated in the present specification.

Moreover, examples of a preferable structure in a case where at least one of R₂₀₁, R₂₀₂, or R₂₀₃ is not an aryl group include cationic structures of compounds exemplified in paragraphs 0046 to 0048 of JP2004-233661A, paragraphs 0040 to 0046 of JP2003-35948A, and exemplified as Formulae (I-1) to (I-70) in the specification of US2003/0224288A1, and compounds exemplified as Formulae (IA-1) to (IA-54), and Formulae (IB-1) to (IB-24) in the specification of US2003/0077540A1.

In General Formulae (ZII) and (ZIII),

R₂₀₄ to R₂₀₇ each independently represent an aryl group, an alkyl group, or a cycloalkyl group.

The aryl group, the alkyl group, and the cycloalkyl group of each of R₂₀₄ to R₂₀₇ are the same as the aryl group, the alkyl group, and the cycloalkyl group described as the aryl group, the alkyl group, and the cycloalkyl group of each of R₂₀₁ to R₂₀₃ in the compound (ZI) as described above, respectively.

The aryl group, the alkyl group, and the cycloalkyl group of each of R₂₀₄ to R₂₀₇ may have a substituent. Examples of the substituent include the substituents that the aryl group, the alkyl group, and the cycloalkyl group of each of R₂₀₁ to R₂₀₃ in the compound (ZI) as described above may have.

Z⁻ represent a non-nucleophilic anion, and examples thereof include the same ones as the non-nucleophilic anion of Z in General Formula (ZI).

Examples of the acid generator (B) include the compounds represented by General Formulae (ZIV), (ZV), and (ZVI) described in paragraphs [0262] to [0264] of JP2013-76991A.

Particularly preferred examples of the acid generator (B) are shown below.

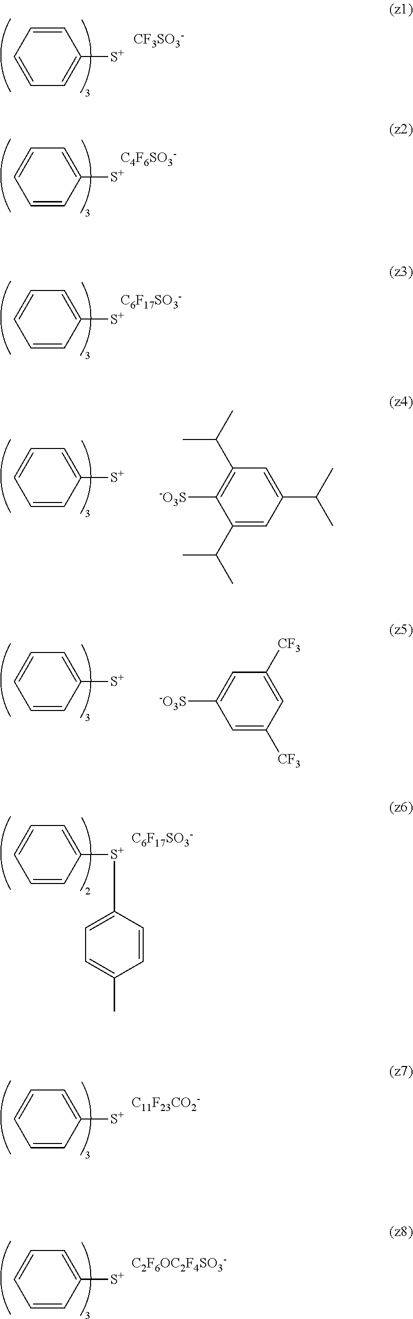

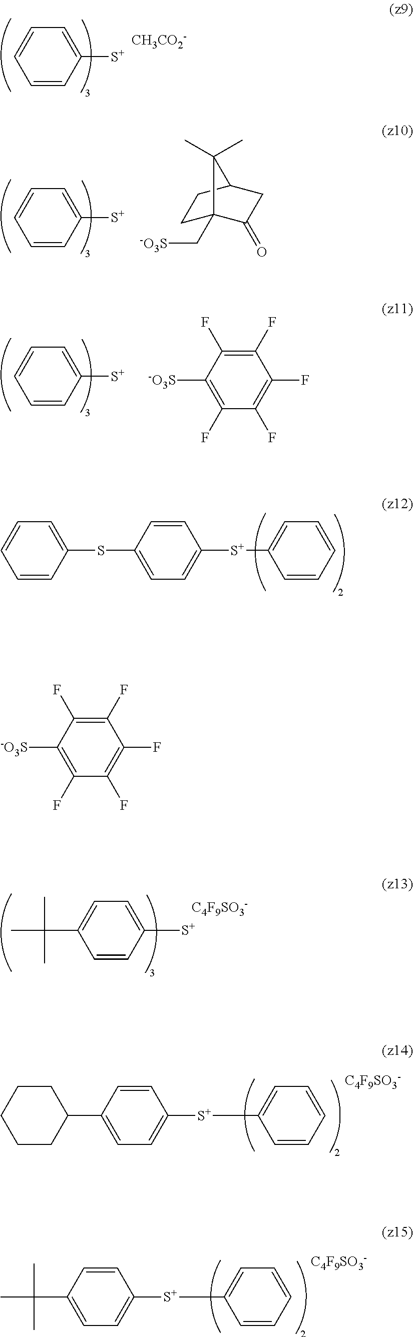

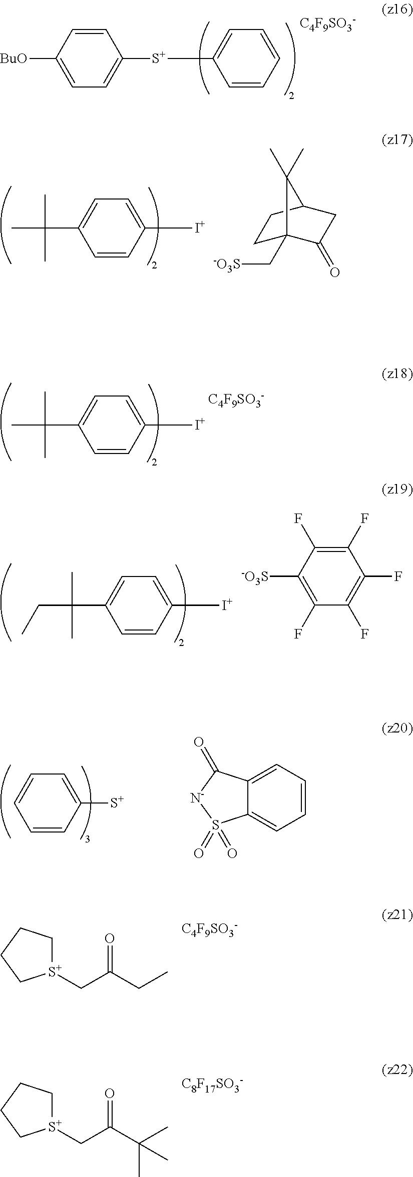

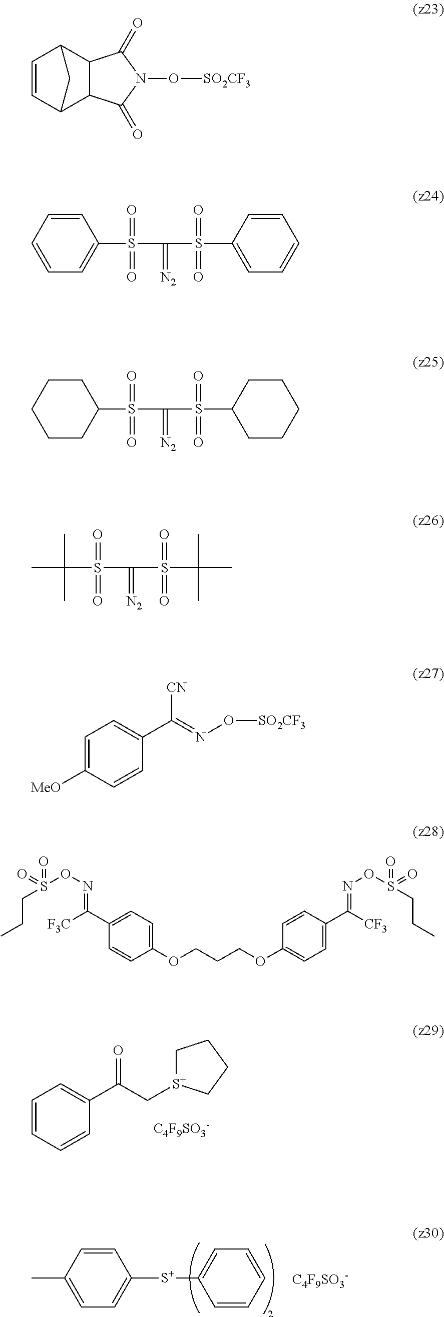

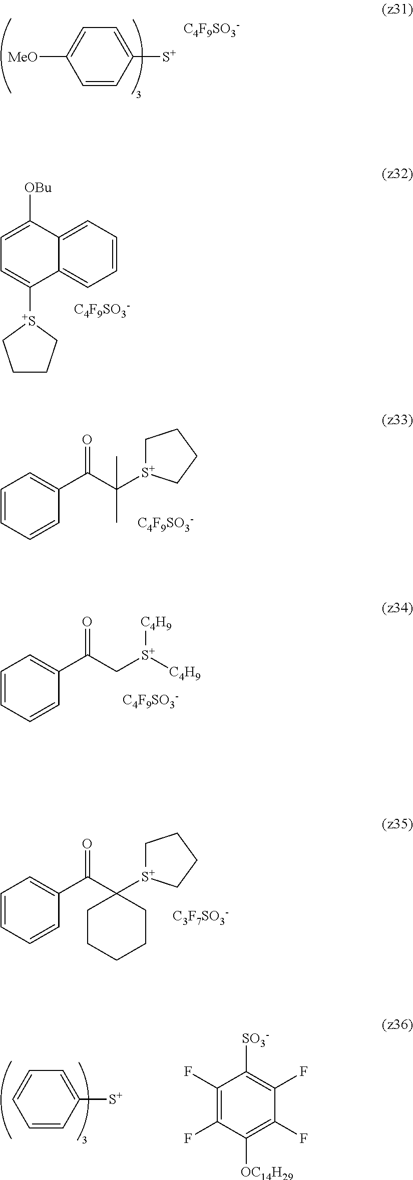

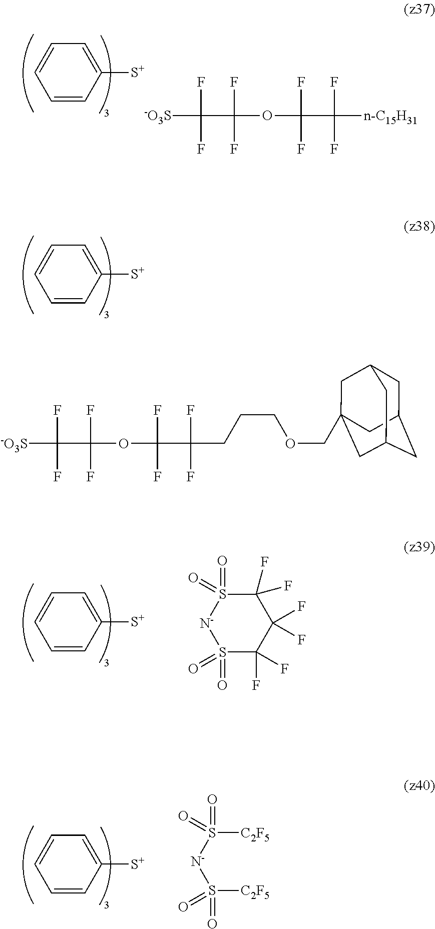

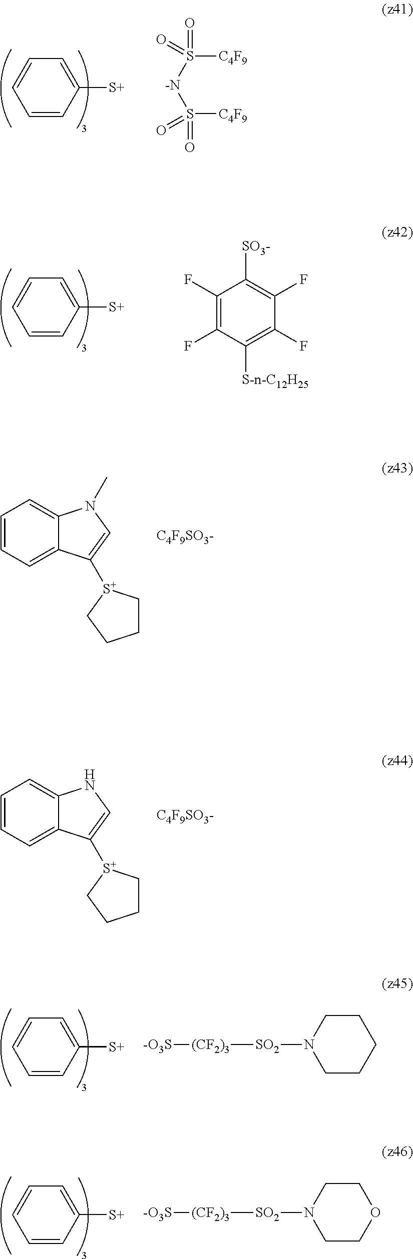

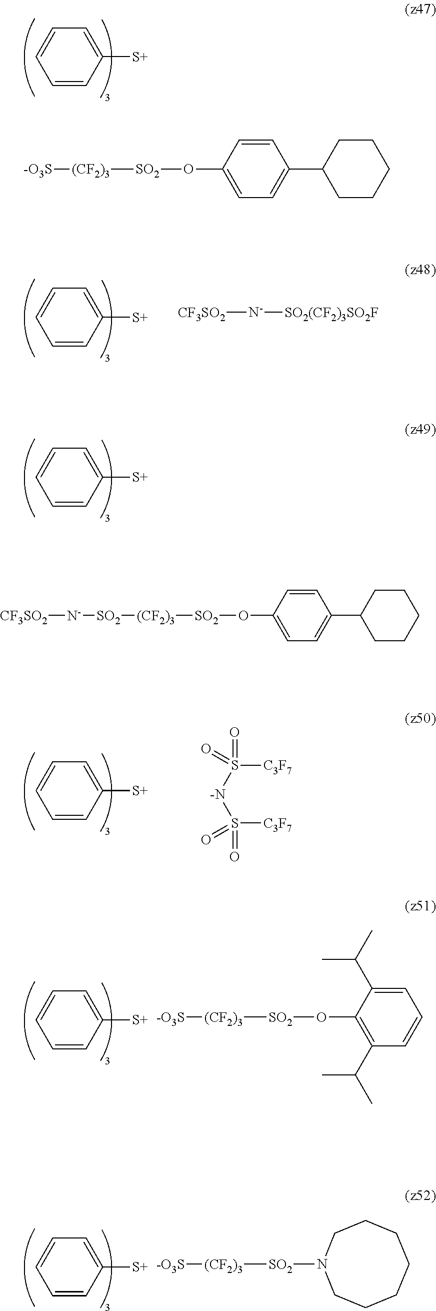

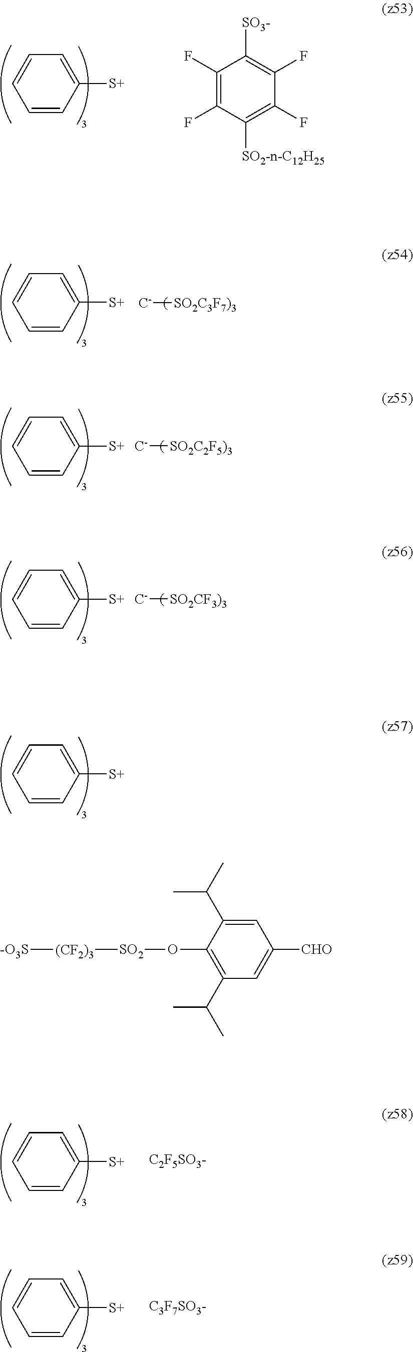

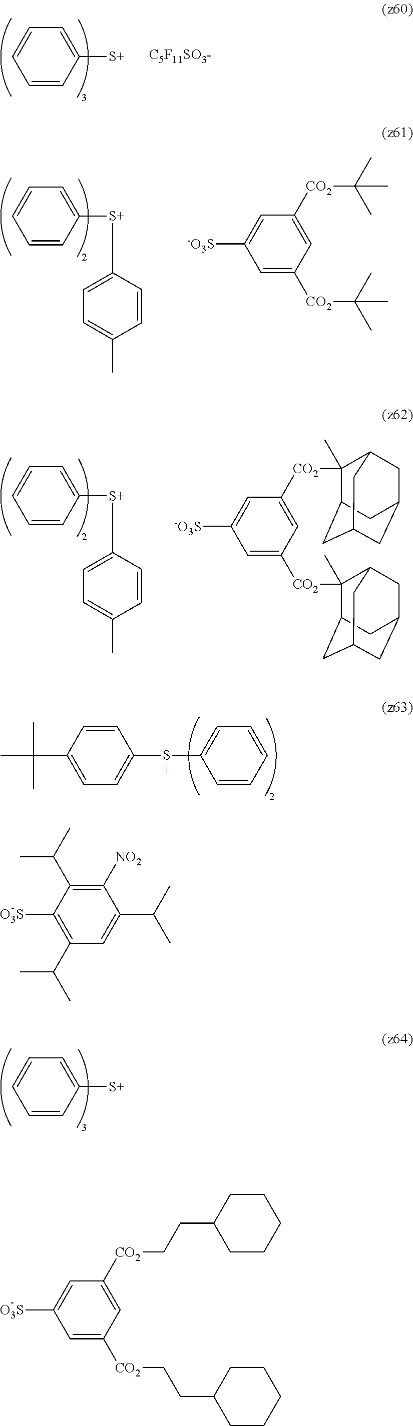

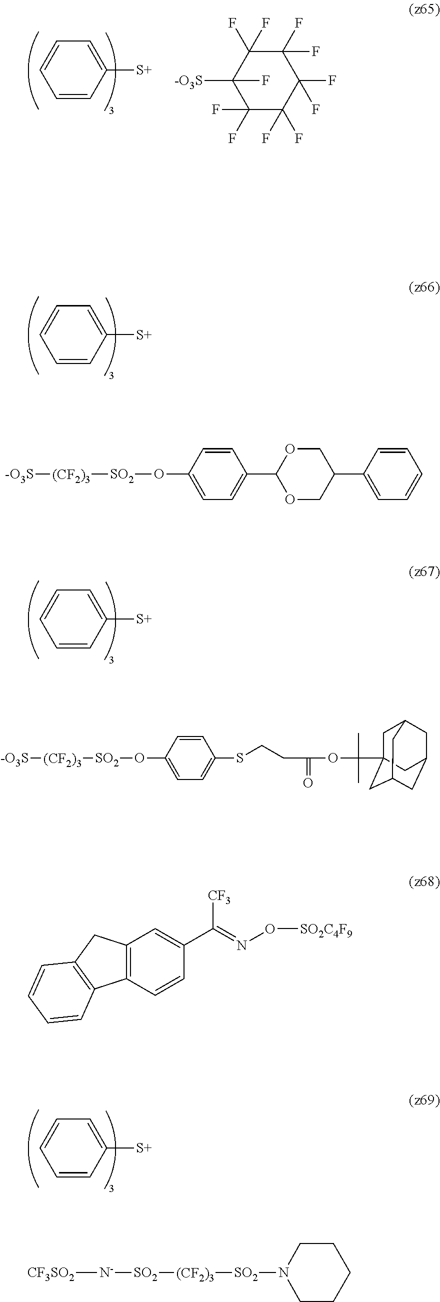

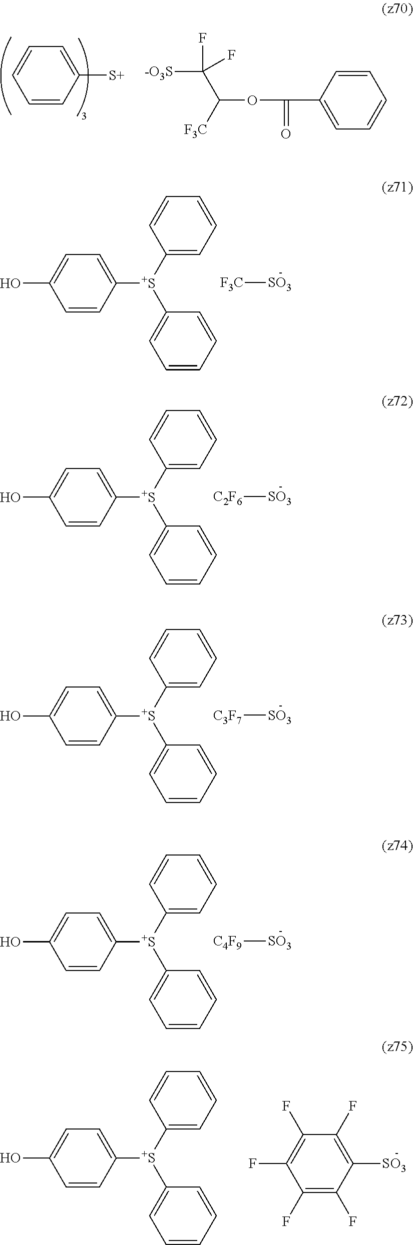

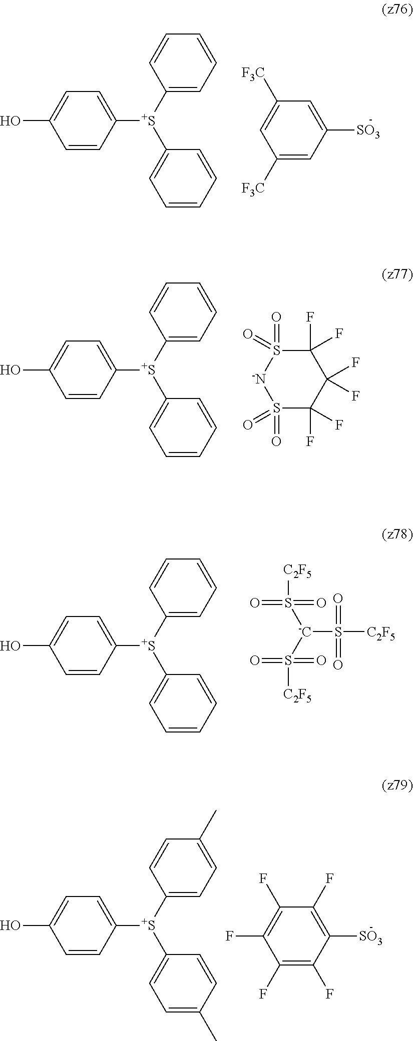

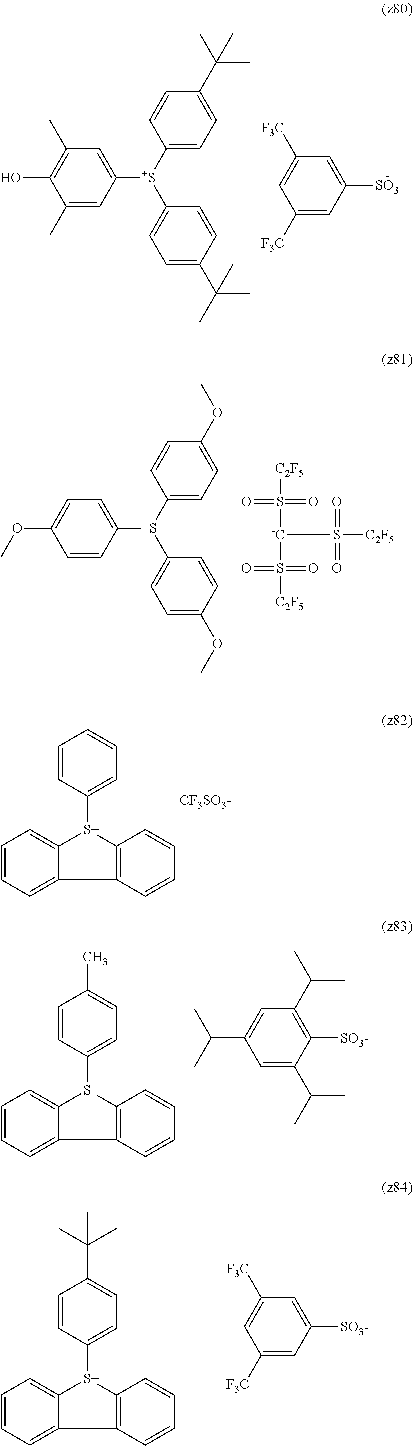

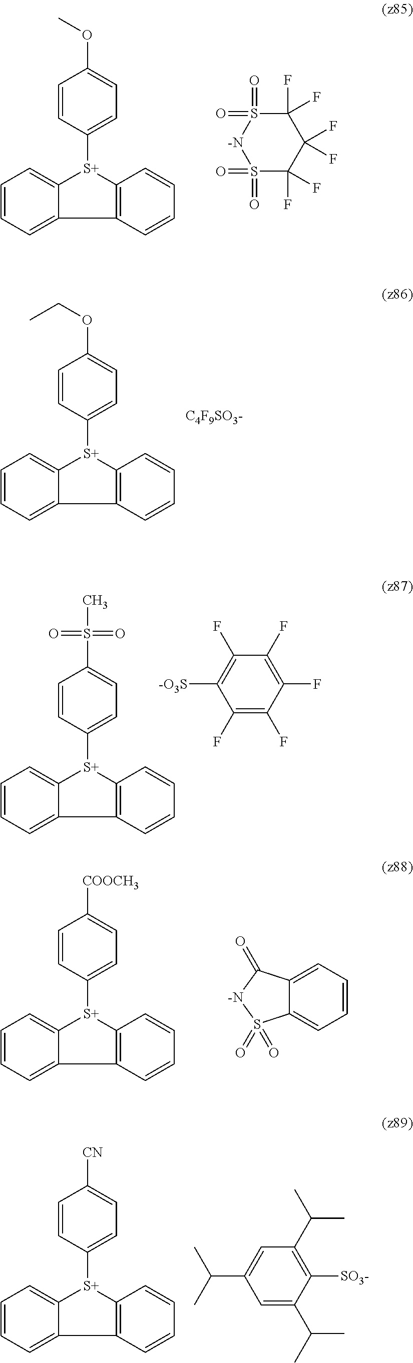

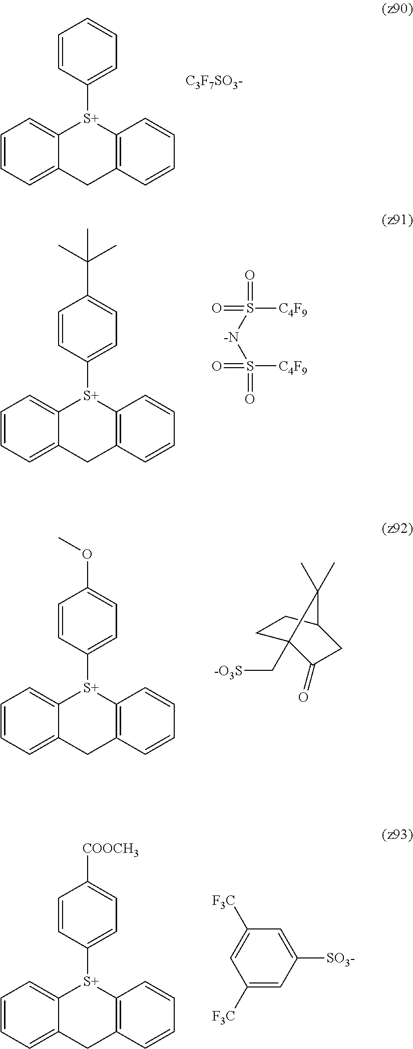

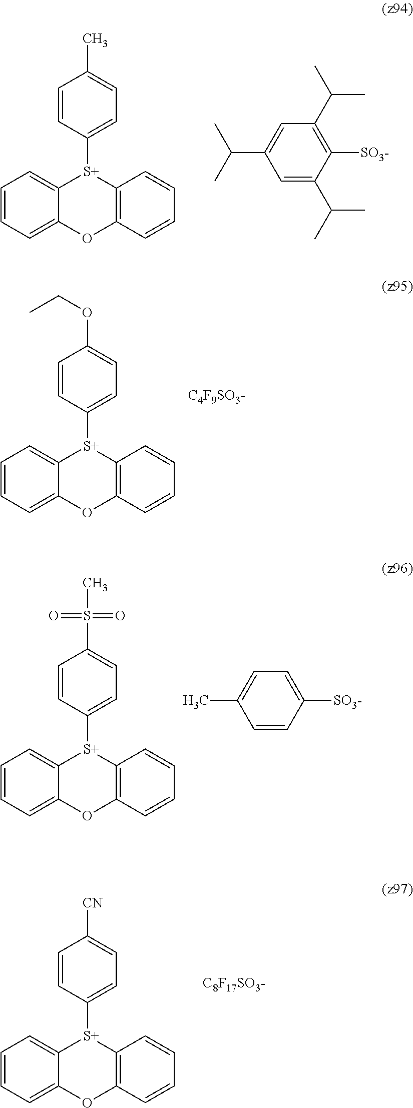

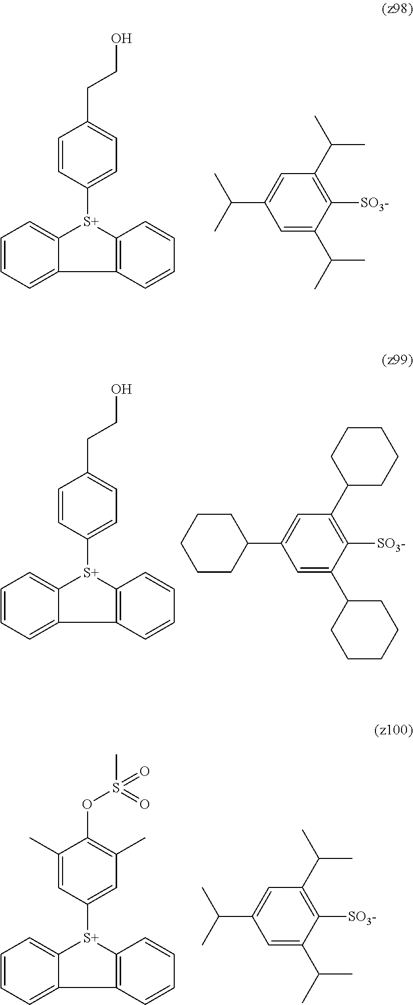

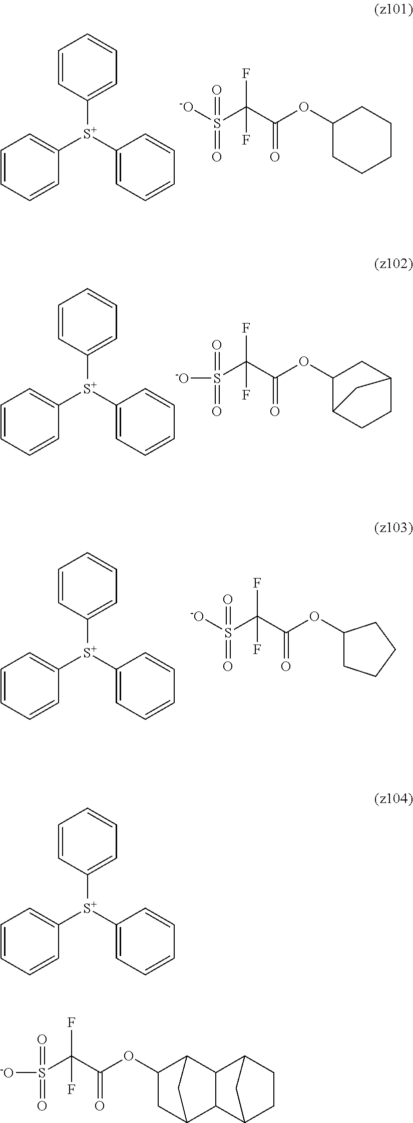

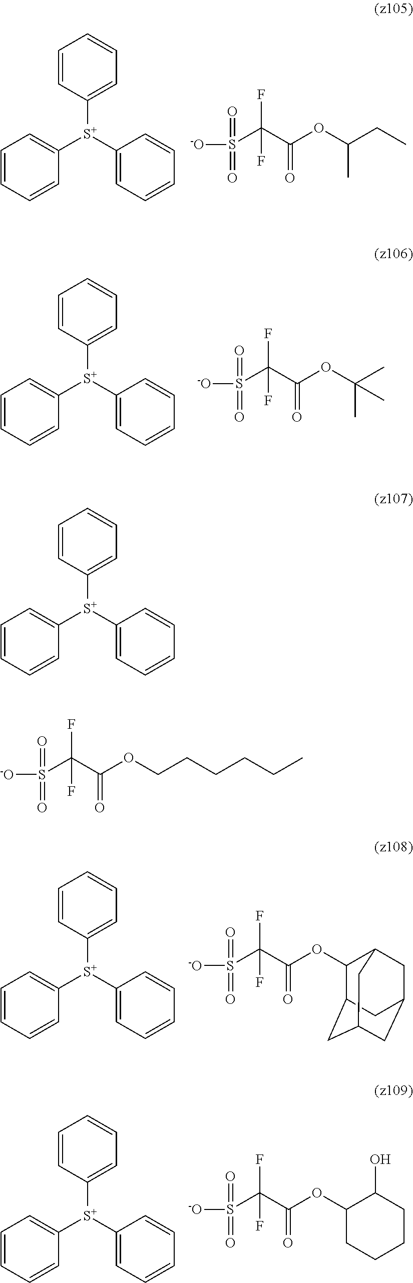

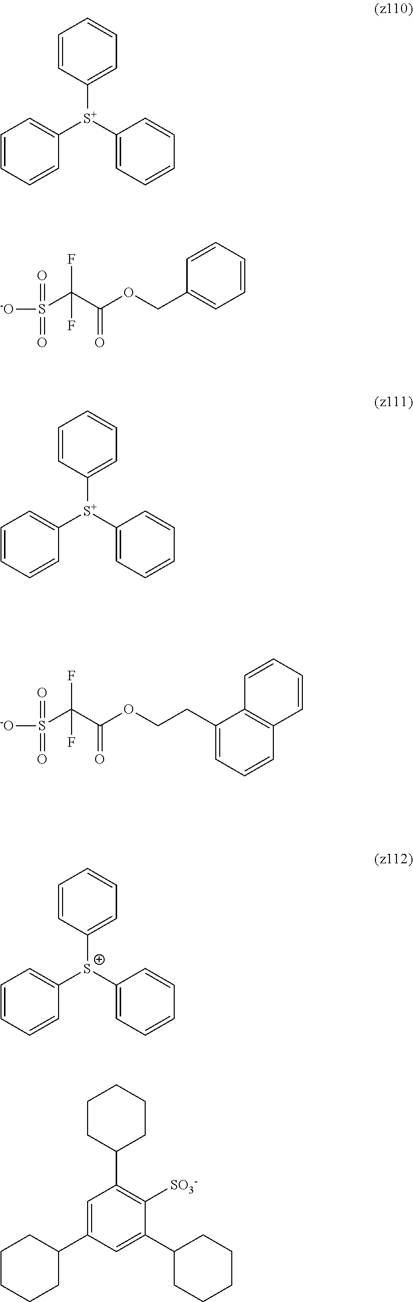

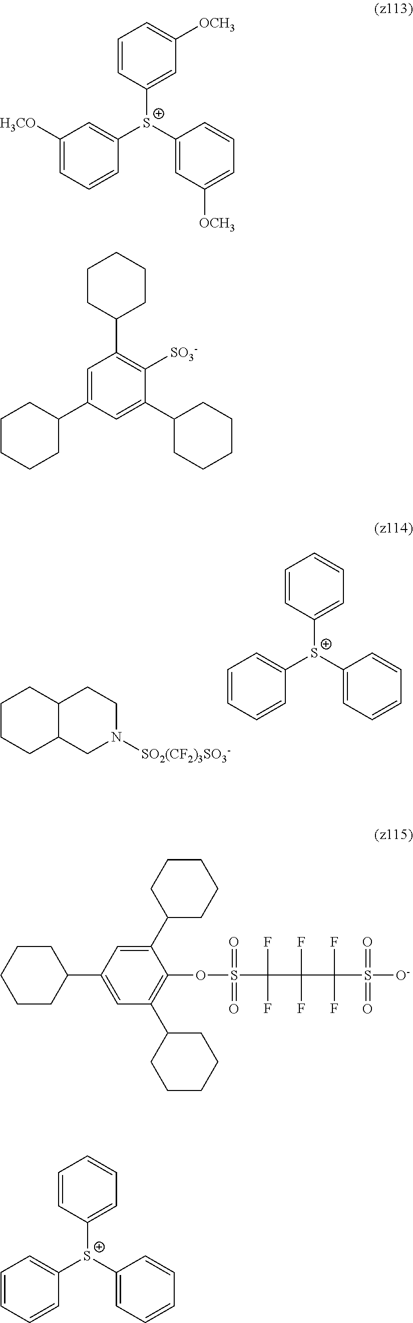

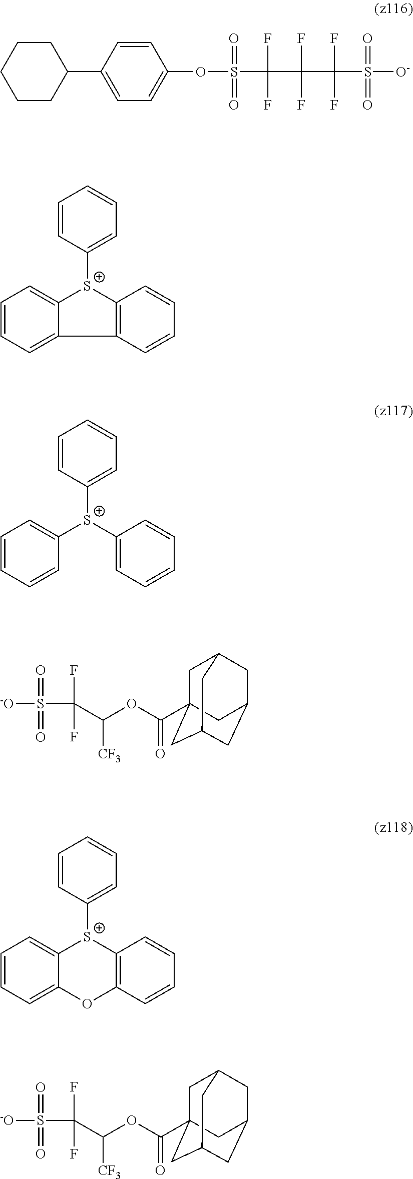

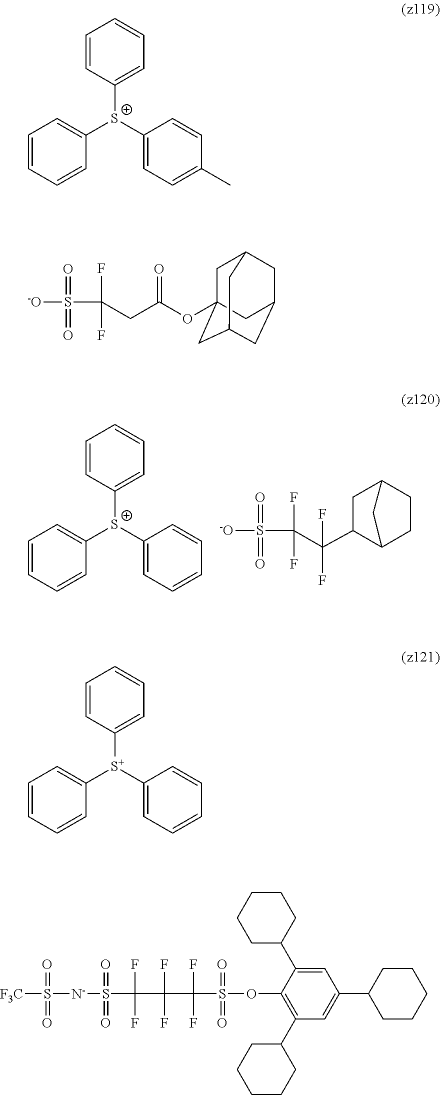

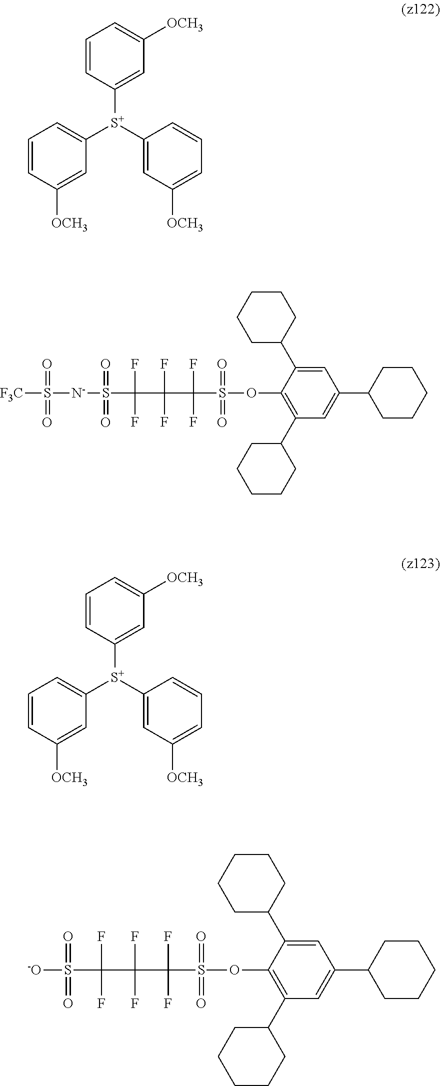

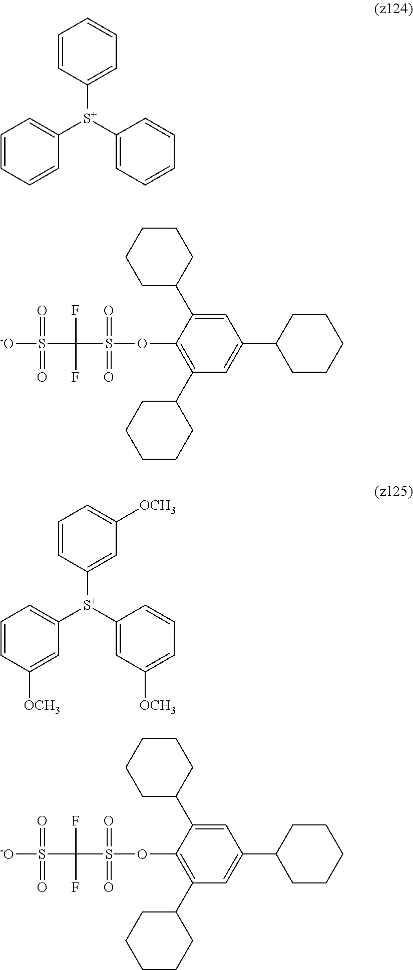

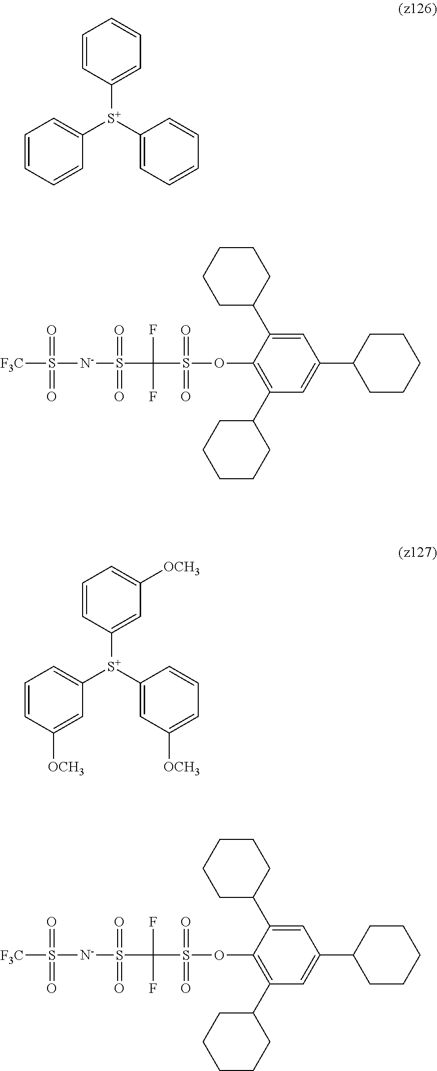 [SMILES: c1ccc([S+](c2ccccc2)c2ccccc2)cc1 ; O=S(=O)([N-]S(=O)(=O)C(F)(F)S(=O)(=O)Oc1c(C2CCCCC2)cc(C2CCCCC2)cc1C1CCCCC1)C(F)(F)F ; COc1cccc([S+](c2cccc(OC)c2)c2cccc(OC)c2)c1 ; O=S(=O)([N-]S(=O)(=O)C(F)(F)S(=O)(=O)Oc1c(C2CCCCC2)cc(C2CCCCC2)cc1C1CCCCC1)C(F)(F)F]

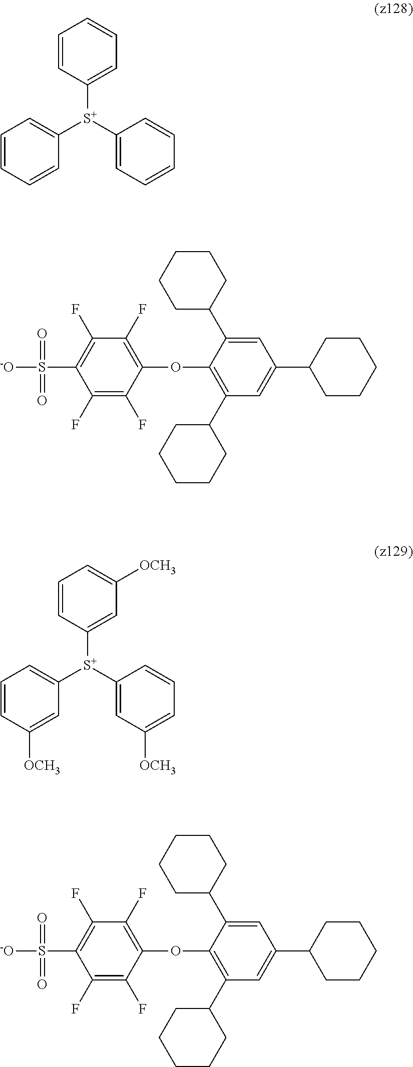

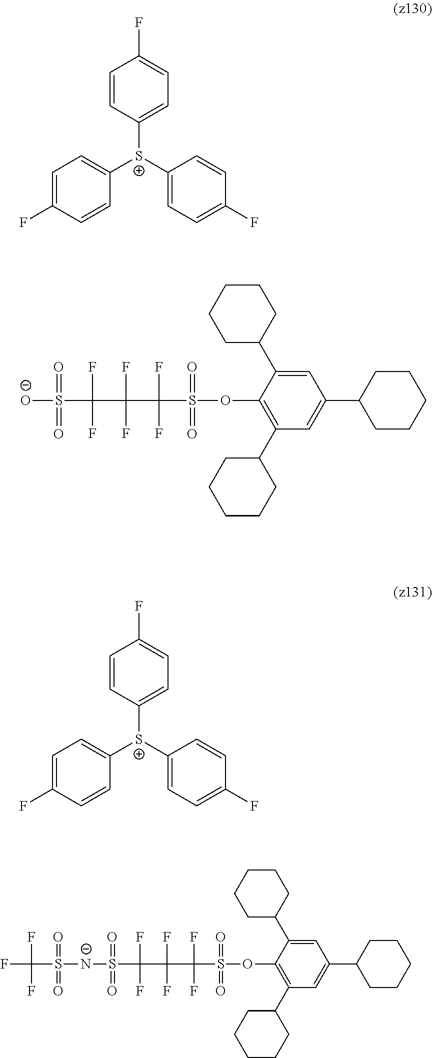 [SMILES: Fc1ccc([S+](c2ccc(F)cc2)c2ccc(F)cc2)cc1 ; O=S(=O)([O-])C(F)(F)C(F)(F)C(F)(F)S(=O)(=O)Oc1c(C2CCCCC2)cc(C2CCCCC2)cc1C1CCCCC1 ; Fc1ccc([S+](c2ccc(F)cc2)c2ccc(F)cc2)cc1 ; O=S(=O)([N-]S(=O)(=O)C(F)(F)C(F)(F)C(F)(F)S(=O)(=O)Oc1c(C2CCCCC2)cc(C2CCCCC2)cc1C1CCCCC1)C(F)(F)F]

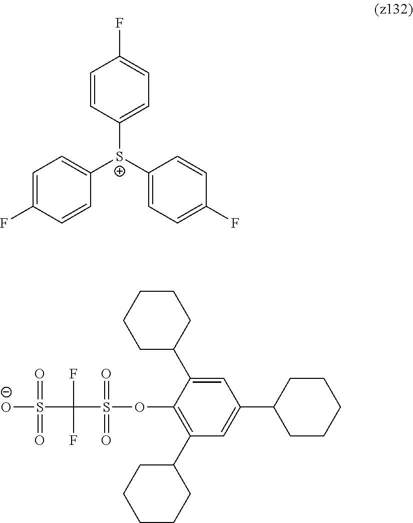 [SMILES: Fc1ccc([S+](c2ccc(F)cc2)c2ccc(F)cc2)cc1 ; O=S(=O)([O-])C(F)(F)S(=O)(=O)Oc1c(C2CCCCC2)cc(C2CCCCC2)cc1C1CCCCC1]

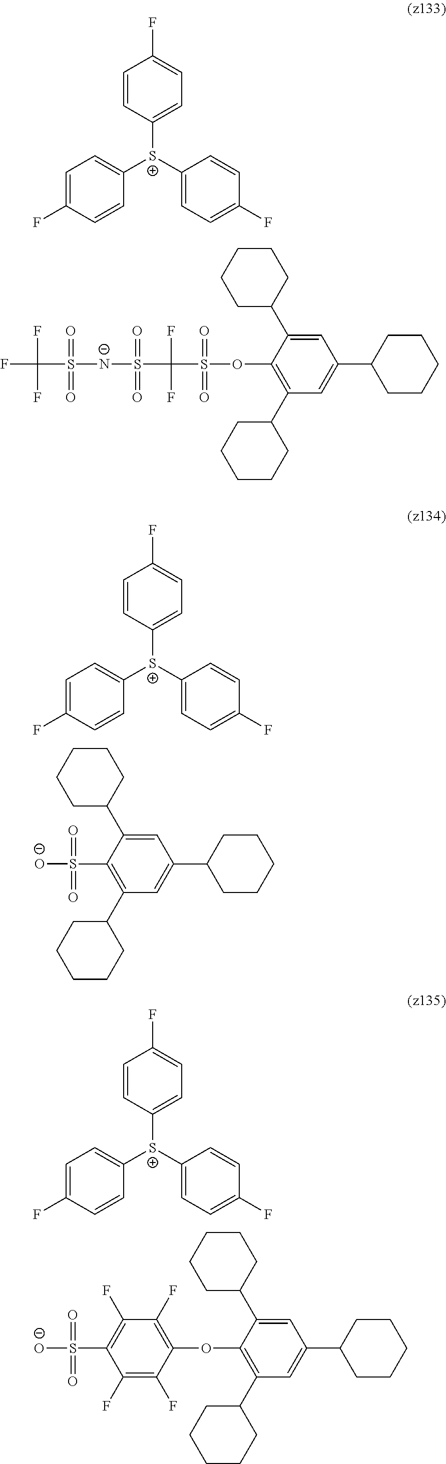 [SMILES: Fc1ccc([S+](c2ccc(F)cc2)c2ccc(F)cc2)cc1 ; O=S(=O)([N-]S(=O)(=O)C(F)(F)S(=O)(=O)Oc1c(C2CCCCC2)cc(C2CCCCC2)cc1C1CCCCC1)C(F)(F)F ; Fc1ccc([S+](c2ccc(F)cc2)c2ccc(F)cc2)cc1 ; O=S(=O)([O-])c1c(C2CCCCC2)cc(C2CCCCC2)cc1C1CCCCC1 ; Fc1ccc([S+](c2ccc(F)cc2)c2ccc(F)cc2)cc1 ; O=S(=O)([O-])c1c(F)c(F)c(Oc2c(C3CCCCC3)cc(C3CCCCC3)cc2C2CCCCC2)c(F)c1F]

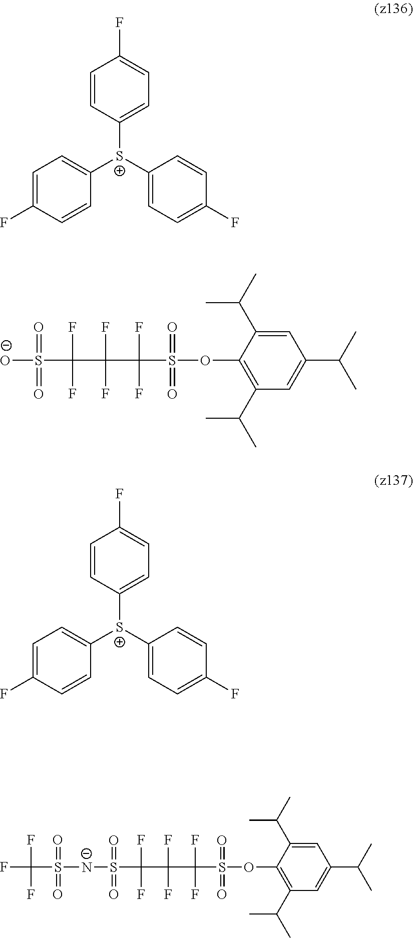 [SMILES: Fc1ccc([S+](c2ccc(F)cc2)c2ccc(F)cc2)cc1 ; CC(C)c1cc(C(C)C)c(OS(=O)(=O)C(F)(F)C(F)(F)C(F)(F)S(=O)(=O)[O-])c(C(C)C)c1 ; Fc1ccc([S+](c2ccc(F)cc2)c2ccc(F)cc2)cc1 ; CC(C)c1cc(C(C)C)c(OS(=O)(=O)C(F)(F)C(F)(F)C(F)(F)S(=O)(=O)[N-]S(=O)(=O)C(F)(F)F)c(C(C)C)c1]

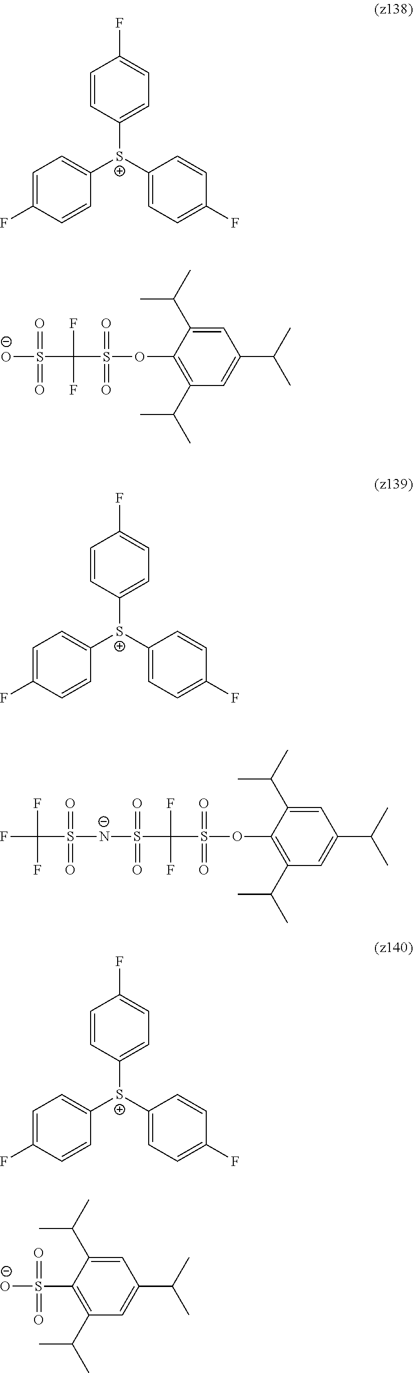 [SMILES: Fc1ccc([S+](c2ccc(F)cc2)c2ccc(F)cc2)cc1 ; CC(C)c1cc(C(C)C)c(OS(=O)(=O)C(F)(F)S(=O)(=O)[O-])c(C(C)C)c1 ; Fc1ccc([S+](c2ccc(F)cc2)c2ccc(F)cc2)cc1 ; CC(C)c1cc(C(C)C)c(OS(=O)(=O)C(F)(F)S(=O)(=O)[N-]S(=O)(=O)C(F)(F)F)c(C(C)C)c1 ; Fc1ccc([S+](c2ccc(F)cc2)c2ccc(F)cc2)cc1 ; CC(C)c1cc(C(C)C)c(S(=O)(=O)[O-])c(C(C)C)c1]

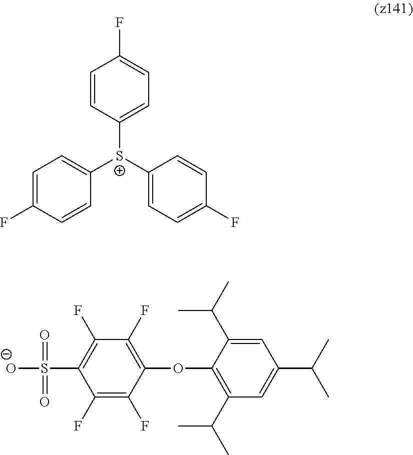 [SMILES: Fc1ccc([S+](c2ccc(F)cc2)c2ccc(F)cc2)cc1 ; CC(C)c1cc(C(C)C)c(Oc2c(F)c(F)c(S(=O)(=O)[O-])c(F)c2F)c(C(C)C)c1]

The compound (B) that generates an acid is preferably a compound that generates an acid having a volume of 240 Angstroms³ (0.24 nm³) or more, more preferably a compound that generates an acid having a volume of 300 Angstroms³ or more, still more preferably a compound that generates an acid having a volume of 350 Angstroms³ or more, and particularly preferably a compound that generates an acid having a volume of 400 Angstroms³ or more, upon irradiation with active light or radiation (for example, an electron beam or extreme ultraviolet rays), from the viewpoint of suppressing diffusion of the acid generated by exposure to the unexposed area and improving resolution. Here, from the viewpoint of sensitivity and solubility in a coating solvent, the volume is preferably 2,000 Angstroms³ or less, and more preferably 1,500 Angstroms³ or less. The volume value is determined by using “WinMOPAC” manufactured by FUJITSU. That is, first, the chemical structure of the acid according to each example is input, then, using this structure as an initial structure, the most stable conformation of each acid is determined by molecular force field calculation using an MM3 method, and then, by carrying out molecular orbital calculation using a PM3 method on these most stable conformations, the “accessible volume” of each acid can be calculated.

The acid generator (B) can be used singly, or two or more kinds thereof can be used in combination.

The content of the acid generator (B) in the composition is preferably 0.1% to 50% by mass, more preferably 5% to 50% by mass, and still more preferably 10% to 40% by mass, with respect to the total solid content of the composition. In particular, to achieve both high sensitivity and high resolution when exposure is carried out by electron beams or extreme ultraviolet rays, the content of an acid generator (B) is preferably higher, more preferably 15% to 40% by mass, and most preferably 20% to 40% by mass.

<Basic Compound (D)>

The actinic ray-sensitive or radiation-sensitive resin composition preferably further includes a basic compound (D). The basic compound (D) is preferably a compound having stronger basicity, as compared to phenol. In addition, the basic compound is preferably an organic basic compound, and more preferably a nitrogen-containing basic compound.

The nitrogen-containing basic compound which can be used is not particularly limited, but the compounds which are classified into (1) to (7) below, for example, can be used.

(1) Compound Represented by General Formula (BS-1)

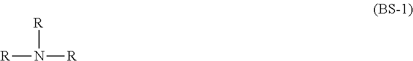

In General Formula (BS-1),

R's each independently represent a hydrogen atom or an organic group. Here, at least one of three Rs is an organic group. This organic group is a linear or branched alkyl group, a monocyclic or polycyclic cycloalkyl group, an aryl group, or an aralkyl group.

The number of carbon atoms in the alkyl group as R is not particularly limited, but is normally 1 to 20, and preferably 1 to 12.

The number of carbon atoms in the cycloalkyl group as R is not particularly limited, but is normally 3 to 20, and preferably 5 to 15.

The number of carbon atoms in the aryl group as R is not particularly limited, but is normally 6 to 20, and preferably 6 to 10. Specific examples thereof include a phenyl group and a naphthyl group.

The number of carbon atoms in the aralkyl group as R is not particularly limited, but is normally 7 to 20, and preferably 7 to 11. Specifically, examples thereof include a benzyl group.

A hydrogen atom in the alkyl group, the cycloalkyl group, the aryl group, or the aralkyl group as R may be substituted with a substituent. Examples of the substituent include an alkyl group, a cycloalkyl group, an aryl group, an aralkyl group, a hydroxy group, a carboxy group, an alkoxy group, an aryloxy group, an alkylcarbonyloxy group, and an alkyloxycarbonyl group.

At least two members out of R's in the compound represented by General Formula (BS-1) are preferably organic groups.

Specific examples of the compound represented by General Formula (BS-1) include tri-n-butyl amine, tri-n-pentyl amine, tri-n-octyl amine, tri-n-decyl amine, triisodecyl amine, dicyclohexyl methyl amine, tetradecyl amine, pentadecyl amine, hexadecyl amine, octadecyl amine, didecyl amine, methyl octadecyl amine, dimethyl undecyl amine, N,N-dimethyl dodecyl amine, methyl dioctadecyl amine, N,N-dibutyl aniline, N,N-dihexyl aniline, 2,6-diisopropyl aniline, and 2,4,6-tri(t-butyl)aniline.

In addition, as the preferable basic compound represented by General Formula (BS-1), an alkyl group in which at least one R is substituted with a hydroxy group is exemplified. Specific examples thereof include triethanol amine and N,N-dihydroxyethyl aniline.

The alkyl group as R may have an oxygen atom in the alkyl chain. That is, an oxyalkylene chain may be formed. As the oxyalkylene chain, —CH₂CH₂O— is preferable. Specific examples thereof include tris(methoxyethoxyethyl)amine and a compound disclosed after line 60 of column 3 in the specification of U.S. Pat. No. 6,040,112A.

Among basic compounds represented by General Formula (BS-1), examples of a compound having such a hydroxyl group or an oxygen atom include the followings.

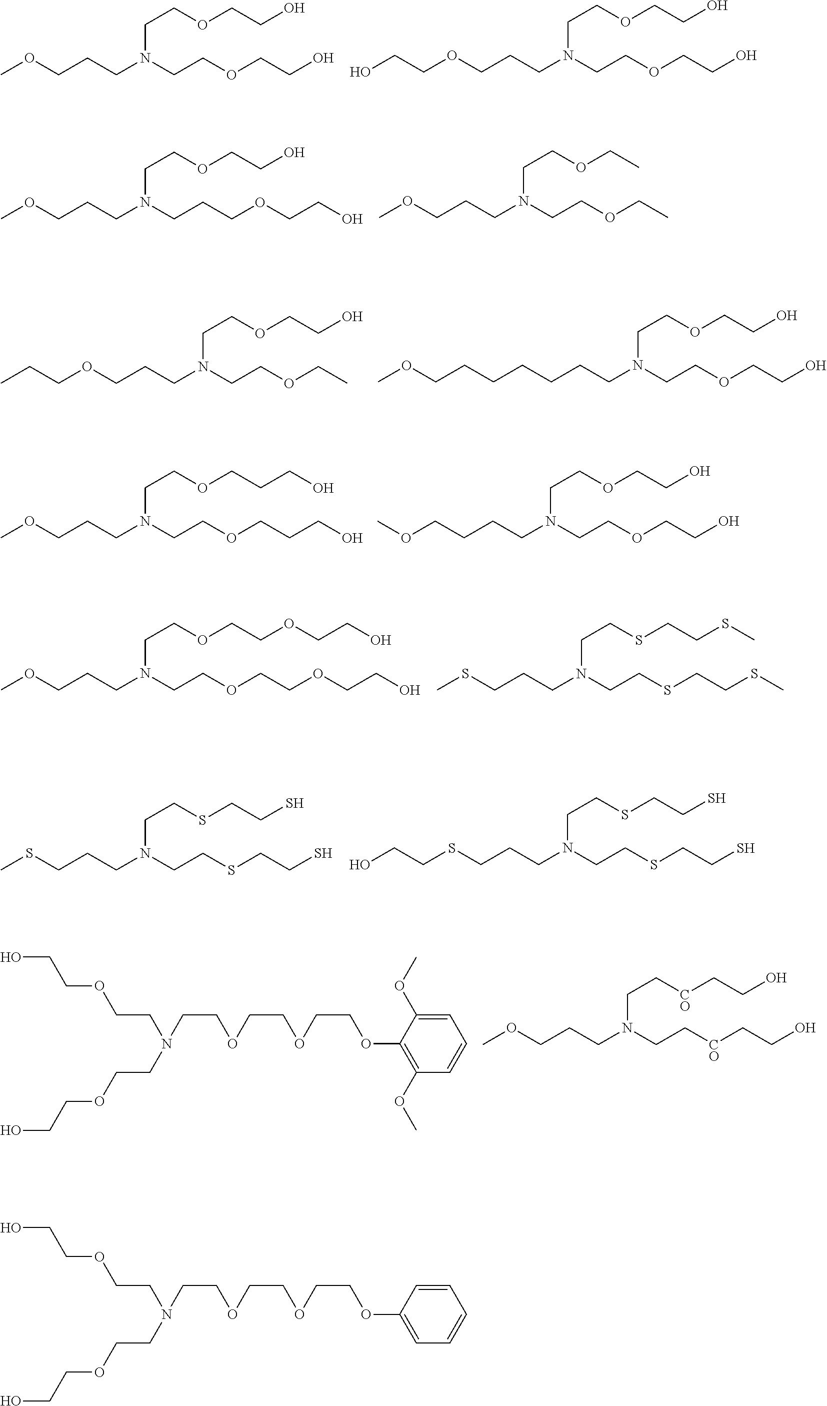

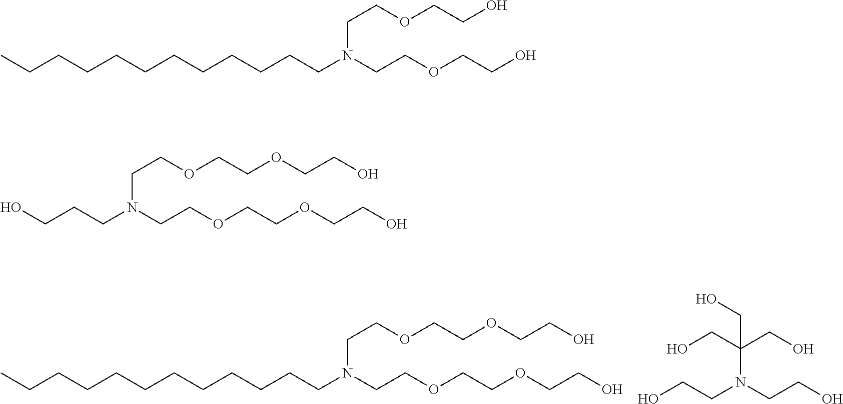

(2) Compound Having Nitrogen-Containing Heterocyclic Structure

The nitrogen-containing heterocycle may have aromatic properties, or may not have aromatic properties. The nitrogen-containing heterocycle may have a plurality of nitrogen atoms. Furthermore, the nitrogen-containing heterocycle may contain heteroatoms other than the nitrogen atom. Specific examples thereof include a compound having an imidazole structure (2-phenylbenzimidazole, 2,4,5-triphenyl imidazole and the like), a compound having a piperidine structure [N-hydroxyethylpiperidine, bis(1,2,2,6,6-pentamethyl-4-piperidyl)sebacate, and the like), a compound having a pyridine structure (4-dimethylaminopyridine and the like], and a compound having an antipyrine structure (antipyrine, hydroxyantipyrine, and the like).

Preferred examples of the compound having a nitrogen-containing heterocyclic structure include guanidine, aminopyridine, aminoalkyl pyridine, aminopyrrolidine, indazole, imidazole, pyrazole, pyrazine, pyrimidine, purine, imidazoline, pyrazoline, piperazine, aminomorpholine, and aminoalkyl morpholine. These may further have a substituent.

Preferred examples of the substituent include an amino group, an aminoalkyl group, an alkylamino group, an aminoaryl group, an arylamino group, an alkyl group, an alkoxy group, an acyl group, an acyloxy group, an aryl group, an aryloxy group, a nitro group, a hydroxyl group, and a cyano group.

Particularly preferred examples of the basic compound include imidazole, 2-methyl imidazole, 4-methyl imidazole, N-methyl imidazole, 2-phenyl imidazole, 4,5-diphenyl imidazole, 2,4,5-triphenyl imidazole, 2-amino pyridine, 3-amino pyridine, 4-amino pyridine, 2-dimethyl amino pyridine, 4-dimethyl amino pyridine, 2-diethyl amino pyridine, 2-(aminomethyl)pyridine, 2-amino-3-methyl pyridine, 2-amino-4-methyl pyridine, 2-amino-5-methyl pyridine, 2-amino-6-methyl pyridine, 3-amino ethyl pyridine, 4-amino ethyl pyridine, 3-amino pyrrolidine, piperazine, N-(2-aminoethyl)piperazine, N-(2-aminoethyl)piperidine, 4-amino-2,2,6,6-tetramethyl piperidine, 4-piperidinopiperidine, 2-iminopiperidine, 1-(2-aminoethyl)pyrrolidine, pyrazole, 3-amino-5-methyl pyrazole, 5-amino-3-methyl-1-p-tolyl pyrazole, pyrazine, 2-(aminomethyl) 5-methyl pyrazine, pyrimidine, 2,4-diaminopyrimidine, 4,6-dihydroxypyrimidine, 2-pyrazoline, 3-pyrazoline, N-aminomorpholine, and N-(2-aminoethyl)morpholine.

Furthermore, a compound having two or more ring structures can also be suitably used. Specific examples thereof include 1,5-diazabicyclo[4.3.0]non-5-ene and 1, 8-diazabicyclo[5.4.0]undeca-7-ene.

(3) Amine Compound Having Phenoxy Group

An amine compound having a phenoxy group is a compound having a phenoxy group at the terminal on the opposite side to the N atom of the alkyl group which is contained in an amine compound. The phenoxy group may have a substituent such as an alkyl group, an alkoxy group, a halogen atom, a cyano group, a nitro group, a carboxy group, a carboxylic acid ester group, a sulfonic acid ester group, an aryl group, an aralkyl group, an acyloxy group, or an aryloxy group.

This compound more preferably has at least one oxyalkylene chain between the phenoxy group and the nitrogen atom. The number of oxyalkylene chains in one molecule is preferably 3 to 9, and more preferably 4 to 6. Among oxyalkylene chains, —CH₂CH₂O— is particularly preferable.

Specific examples thereof include 2-[2-{2-(2,2-dimethoxyphenoxyethoxy)ethyl}-bis-(2-methoxy-ethyl)-amine and the compounds (C1-1) to (C3-3) exemplified in paragraph <0066> in the specification of US2007/0224539A1.

An amine compound having a phenoxy group is obtained by, for example, heating a mixture of a primary or secondary amine having a phenoxy group and an haloalkyl ether to be reacted, by adding an aqueous solution of a strong base such as sodium hydroxide, potassium hydroxide, or tetraalkylammonium thereto, and by extracting the resultant product with an organic solvent such as ethyl acetate or chloroform. In addition, an amine compound having a phenoxy group can also be obtained by heating a mixture of a primary or secondary amine and an haloalkyl ether having a phenoxy group at the terminal to be reacted, by adding an aqueous solution of a strong base such as sodium hydroxide, potassium hydroxide, or tetraalkylammonium thereto, and by extracting the resultant product with an organic solvent such as ethyl acetate or chloroform.

(4) Ammonium Salt

An ammonium salt can be appropriately used as a basic compound.

As the cation of the ammonium salt, a tetraalkylammonium cation in which an alkyl group having 1 to 18 carbon atoms is substituted is preferable, a tetramethylammonium cation, a tetraethylammonium cation, a tetra(n-butyl)ammonium cation, a tetra(n-heptyl)ammonium cation, a tetra(n-octyl)ammonium cation, a dimethylhexadecylammonium cation, or a benzyltrimethyl cation is more preferable, and tetra(n-butyl)ammonium cation is most preferable.

Examples of the anion of the ammonium salt include hydroxide, carboxylate, halide, sulfonate, borate, and phosphate. Among these, hydroxide or carboxylate is particularly preferable.

As the halide, chloride, bromide, or iodide is particularly preferable.

As the sulfonate, an organic sulfonate having 1 to 20 carbon atoms is particularly preferable. Examples of the organic sulfonate include alkyl sulfonate and aryl sulfonate having 1 to 20 carbon atoms.

The alkyl group included in the alkyl sulfonate may have a substituent. Examples of the substituent include a fluorine atom, a chlorine atom, a bromine atom, an alkoxy group, an acyl group, and an aryl group. Specific examples of the alkyl sulfonate include methanesulfonate, ethanesulfonate, butanesulfonate, hexanesulfonate, octanesulfonate, benzylsulfonate, trifluoromethanesulfonate, pentafluoroethanesulfonate, and nonafluorobutanesulfonate.

Examples of the aryl group included in the aryl sulfonate include a phenyl group, a naphthyl group, and an anthryl group. These aryl groups may have a substituent. As the substituent, for example, a linear or branched alkyl group having 1 to 6 carbon atoms or a cycloalkyl group having 3 to 6 carbon atoms is preferable. Specifically, for example, a methyl group, an ethyl group, an n-propyl group, an isopropyl group, an n-butyl group, an i-butyl group, a t-butyl group, an n-hexyl group, or a cyclohexyl group is preferable. Examples of other substituents include an alkoxy group having 1 to 6 carbon atoms, a halogen atom, a cyano group, a nitro group, an acyl group, and an acyloxy group.

The carboxylate may be aliphatic carboxylate or aromatic carboxylate, and examples thereof include acetate, lactate, pyruvate, trifluoroacetate, adamantane carboxylate, hydroxyadamantane carboxylate, benzoate, naphthoate, salicylate, phthalate, and phenolate, and, in particular, benzoate, naphthoate, or phenolate is preferable, and benzoate is most preferable.

In this case, as the ammonium salt, tetra(n-butyl)ammonium benzoate or tetra(n-butyl)ammonium phenolate is preferable.

In the case of hydroxide, the ammonium salt is particularly preferably tetraalkylammonium hydroxide (tetraalkyl ammonium hydroxide such as tetramethyl ammonium hydroxide, tetraethyl ammonium hydroxide, or tetra-(n-butyl)ammonium hydroxide) having 1 to 8 carbon atoms.

(5) Compound (PA) that has Proton-Accepting Functional Group and Generates Compound in which Proton-Acceptability is Reduced or Lost, or which is Changed from being Proton-Accepting to be Acidic, by being Decomposed Upon Irradiation with Active Light or Radiation

The composition may further include a compound [hereinafter also referred to as a “compound (PA)”] which has a proton-accepting functional group and generates a compound in which the proton-acceptability is reduced or lost, or which is changed from being proton-accepting to be acidic, by being decomposed upon irradiation with active light or radiation, as a basic compound.

Regarding the compound (PA) which has a proton-accepting functional group and generates a compound in which the proton-acceptability is reduced or lost, or which is changed from being proton-accepting to be acidic, by being decomposed upon irradiation with active light or radiation, reference can be made to the description in paragraphs <0379> to <0425> of JP2012-32762A (paragraphs <0386> to <0435> of the corresponding US2012/0003590A), the contents of which are incorporated in the present specification.

(6) Guanidine Compound

The composition may further contain a guanidine compound having a structure represented by the following formula.

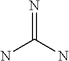

The guanidine compound exhibits strong basicity since the positive charge of the conjugate acid is dispersed and stabilized by the three nitrogen atoms.

For the basicity of the guanidine compound (A) of the present invention, the pKa of a conjugate acid is preferably 6.0 or more, preferably 7.0 to 20.0 since neutralization reactivity with an acid is high and the roughness properties are excellent, and more preferably 8.0 to 16.0.

Due to such strong basicity, the diffusibility of an acid is suppressed, and the strong basicity can contribute to formation of an excellent pattern shape.

Moreover, the “pKa” here represents pKa in an aqueous solution, and for example, it is described in Chemical Handbook (II) (revised 4th edition, 1993, edited by The Chemical Society of Japan, published by Maruzen Co., Ltd.), and a smaller value means higher acidity. Specifically, the pKa in aqueous solution can be obtained by measuring the acid dissociation constant at 25° C. using an infinite dilution aqueous solution, and a value based on the database of Hammett substituent constants and known literature values can also be determined by calculation using the following software package 1. All of pKa values described in the present specification are values determined by calculation using this software package.

Software package 1: Advanced Chemistry Development (ACD/Labs) Software V 8.14 for Solaris (1994-2007 ACD/Labs).

The log P is a logarithmic value of an n-octanol/water distribution coefficient (P), and with respect to a wide range of compounds, it is an effective parameter that can characterize the hydrophilicity/hydrophobicity. In general, the distribution coefficient is determined not by experiment but by calculation, and in the present invention, the distribution coefficient is a value calculated by a CS Chem Draw Ultra Ver. 8.0 software package (Crippen's fragmentation method).

In addition, the log P of the guanidine compound is preferably 10 or less. When the log P is the above value or less, the guanidine compound can be uniformly contained in a resist film.

The log P of the guanidine compound is preferably in a range of 2 to 10, more preferably in a range of 3 to 8, and particularly preferably in a range of 4 to 8.

In addition, the guanidine compound preferably does not have a nitrogen atom other than a guanidine structure.

Specific examples of the guanidine compound are shown below, but the present invention is not limited thereto.

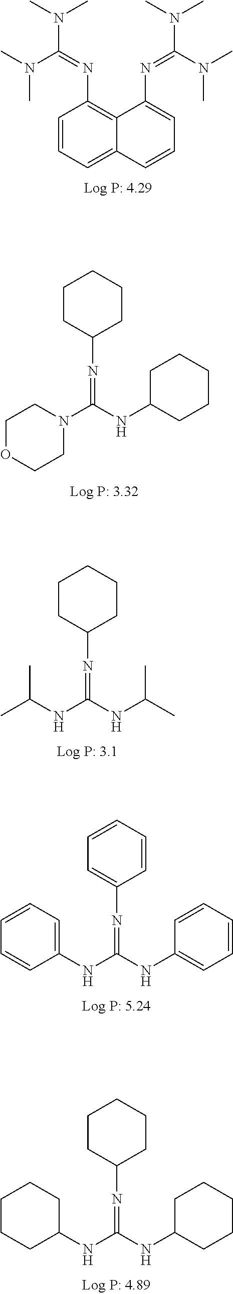

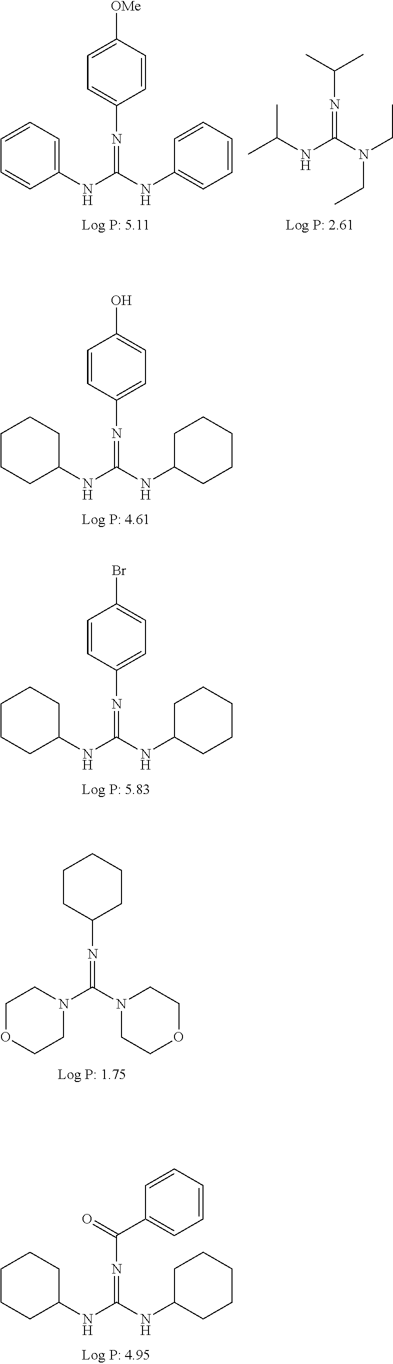

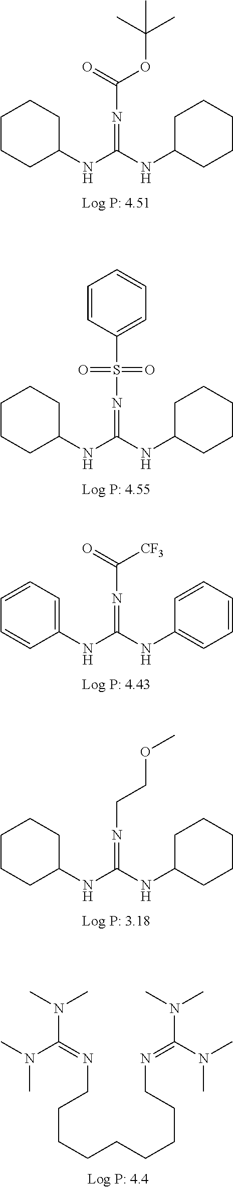

(7) Low Molecular Weight Compound Having Nitrogen Atom and Group Leaving Due to Action of Acid

The composition of the present invention can contain a low molecular weight compound (hereinafter, also referred to as a “low molecular weight compound (D)”) having a nitrogen atom and a group that leaves by the action of an acid. The low molecular weight compound (D) preferably has basicity, after a group that leaves by the action of an acid leaves.

Regarding the low molecular compound (D), reference can be made to the description in paragraphs <0324> to <0337> of JP2012-133331A, the contents of which are incorporated in the present specification.

The low molecular weight compound (D) may be used singly or in mixture of two or more kinds thereof.

In addition to these, examples of the compound which can be used in the composition include the compounds synthesized in Examples of JP2002-363146A and the compounds described in paragraph 0108 of JP2007-298569A.

As the basic compound (D), a photosensitive basic compound may be used. As the photosensitive basic compound, for example, the compounds described in JP2003-524799A, J. Photopolym. Sci. & Tech. Vol. 8, P. 543-553 (1995), and the like as can be used.

The molecular weight of the basic compound is usually 100 to 1,500, preferably 150 to 1,300, and more preferably 200 to 1,000.

These basic compounds (D) may be used singly or in combination of two or more kinds thereof.

The content of the basic compound (D) included in the composition of the present invention is preferably 0.01% to 8.0% by mass, more preferably 0.1% to 5.0% by mass, and particularly preferably 0.2% to 4.0% by mass, with respect to the total solid content of the composition.

The molar ratio of the basic compound (D) to the acid generator is preferably set to 0.01 to 10, more preferably set to 0.05 to 5, and still more preferably set to 0.1 to 3. When the molar ratio is excessively large, the sensitivity and/or the resolution may be reduced in some cases. When the molar ratio is excessively small, there is a possibility that thinning of a pattern occurs, during exposure and heating (post baking). The molar ratio is more preferably 0.05 to 5, and still more preferably 0.1 to 3. Moreover, the acid generator in the above molar ratio is based on the total amount of the repeating unit represented by General Formula (P), of the resin (A) and the acid generator (B) which the resin (A) can further include.

<Solvent>

The composition preferably includes a solvent. The solvent preferably includes propylene glycol monoalkyl ether carboxylate (S1) and (S2) at least one selected from the group consisting of propylene glycol monoalkyl ether, lactic acid ester, methyl 2-hydroxyisobutyrate, acetic acid ester, alkoxypropionic acid ester, chain ketone, cyclic ketone, lactone, and alkylene carbonate. The solvent may further include a component other than the component (S1) and the component (S2).

The present inventors find that when such a solvent and the resin as described above are used in combination, coatability of a composition is improved, and a pattern having a small number of development defects can be formed. The reason is not clear, but the present inventors consider that the reason is due to the fact that, since these solvents have excellent balance among solubility with respect to the resin as described above, a boiling point, and viscosity, unevenness in the film thickness of the composition layer or the generation of precipitates during the spin coating can be suppressed.

As the component (S1), at least one selected from the group of consisting of propylene glycol monomethyl ether acetate, propylene glycol monomethyl ether propionate, and propylene glycol monoethyl ether acetate is preferable, and propylene glycol monomethyl ether acetate is particularly preferable.

As the component (S2), the followings are preferable.

As propylene glycol monoalkyl ether, propylene glycol monomethyl ether or propylene glycol monoethyl ether is preferable.

As lactic acid ester, ethyl lactate, butyl lactate, or propyl lactate is preferable.

As acetic acid ester, methyl acetate, ethyl acetate, butyl acetate, isobutyl acetate, propyl acetate, isoamyl acetate, methyl formate, ethyl formate, butyl formate, propyl formate, or 3-methoxybutyl acetate is preferable.

As alkoxypropionic acid ester, methyl 3-methoxypropionate (MMP) or ethyl 3-ethoxypropionate (EEP) is preferable.

As chain ketone, 1-octanone, 2-octanone, 1-nonanone, 2-nonanone, acetone, 4-heptanone, 1-hexanone, 2-hexanone, diisobutyl ketone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, or methyl amyl ketone is preferable.

As cyclic ketone, methyl cyclohexanone, isophorone, or cyclohexanone is preferable.

As lactone, γ-butyrolactone is preferable.

As alkylene carbonate, propylene carbonate is preferable.

As the component (S2), propylene glycol monomethyl ether, ethyl lactate, ethyl 3-ethoxypropionate, methyl amyl ketone, cyclohexanone, butyl acetate, pentyl acetate, γ-butyrolactone, or propylene carbonate is more preferable.

As the component (S2), a component having a flash point (hereinafter, also referred to as fp) of 37° C. or higher is preferably used. As the component (S2) as described above, propylene glycol monomethyl ether (fp: 47° C.), ethyl lactate (fp: 53° C.), ethyl 3-ethoxypropionate (fp: 49° C.), methyl amyl ketone (fp: 42° C.), cyclohexanone (fp: 44° C.), pentyl acetate (fp: 45° C.), γ-butyrolactone (fp: 101° C.), or propylene carbonate (fp: 132° C.) is preferable. Among these, propylene glycol monoethyl ether, ethyl lactate, pentyl acetate, or cyclohexanone is more preferable, and propylene glycol monoethyl ether or ethyl lactate is particularly preferable. In addition, the “flash point” herein means a value described in the reagent catalog of Tokyo Chemical Industry Co., Ltd. or Sigma-Aldrich Co. LLC.

The solvent preferably includes the component (S1). It is more preferable that the solvent consists of substantially only the component (S1) or is a mixed solvent of the component (S1) and other components. In the latter case, the solvent still more preferably includes both the component (S1) and the component (S2).

The mass ratio between the component (S1) and the component (S2) is preferably in a range of 100:0 to 15:85, more preferably in a range of 100:0 to 40:60, and still more preferably in a range of 100:0 to 60:40. That is, it is preferable that the solvent consists of only the component (S1), or includes both the component (S1) and the component (S2) and the mass ratio thereof is as follows. That is, in the latter case, the mass ratio of the component (S1) to the component (S2) is preferably 15/85 or more, more preferably 40/60 or more, and still more preferably 60/40 or more. When such a configuration is adopted, the number of development defects can further be reduced.

Moreover, in a case where the solvent includes both the component (S1) and the component (S2), the mass ratio of the component (S1) with respect to the component (S2) is, for example, set to 99/1 or less.

As described above, the solvent may further include a component other than the component (S1) and the component (S2). In this case, the content of the component other than the component (S1) and the component (S2) is preferably in a range of 5% by mass to 30% by mass with respect to the total amount of the solvent.

The content of the solvent in the composition is preferably set such that the solid content concentration of all components becomes 2% to 30% by mass, and more preferably set such that the solid content concentration of all components becomes 3% to 20% by mass. Within this range, the coatability of the composition can further be improved.

<Hydrophobic Resin>

The composition may contain a hydrophobic resin (hereinafter also referred to as a “hydrophobic resin (E)”), in addition to the resin (A).

Although the hydrophobic resin (E) is preferably designed to be unevenly localized on an interface, it does not necessarily have to have a hydrophilic group in its molecule as different from the surfactant, and does not need to contribute to uniform mixing of polar/nonpolar materials.

Examples of the effect of addition of the hydrophobic resin (E) include control of the static/dynamic contact angle of the resist film surface with respect to water, improvement of the immersion liquid tracking properties, and inhibition of out gas.

The hydrophobic resin (E) preferably has at least one of a “fluorine atom,” a “silicon atom,” or a “CH₃ partial structure which is contained in a side chain moiety of a resin” from the viewpoint of uneven distribution on the film surface layer, and more preferably has two or more kinds.

In a case where hydrophobic resin (E) contains a fluorine atom and/or a silicon atom, the fluorine atom and/or the silicon atom in the hydrophobic resin (E) may be contained in the main chain or the side chain of the resin.

In a case where the hydrophobic resin (E) contains a fluorine atom, the resin is preferably a resin which contains an alkyl group having a fluorine atom, a cycloalkyl group having a fluorine atom, or an aryl group having a fluorine atom, as a partial structure having a fluorine atom.

The alkyl group having a fluorine atom (preferably having 1 to 10 carbon atoms, and more preferably having 1 to 4 carbon atoms) is a linear or branched alkyl group in which at least one hydrogen atom is substituted with a fluorine atom, and may further have a substituent other than a fluorine atom.

The cycloalkyl group having a fluorine atom and the aryl group having a fluorine atom are each a cycloalkyl group in which one hydrogen atom is substituted with a fluorine atom, and an aryl group in which one hydrogen atom is substituted with a fluorine atom, and they may further have a substituent other than a fluorine atom.

Preferred examples of the alkyl group having a fluorine atom, the cycloalkyl group having a fluorine atom, and the aryl group having a fluorine atom include groups represented by the following General Formulae (F2) to (F4), but the present invention is not limited

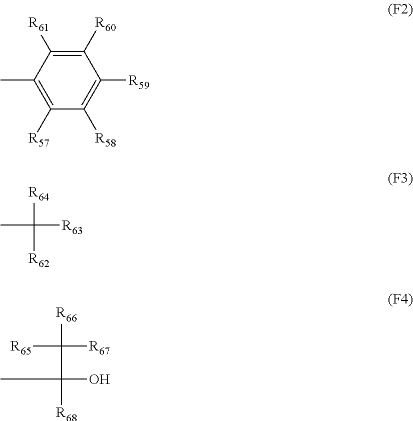

In General Formulae (F2) to (F4),

R₅₇ to R₆₈ each independently represent a hydrogen atom, a fluorine atom, or an (linear or branched) alkyl group. Here, at least one of R₅₇, . . . , or R₆₁, at least one of R₆₂, . . . , or R₆₄, and at least one of R₆₅, . . . , or R₆₈ each independently represent a fluorine atom or an alkyl group (preferably having 1 to 4 carbon atoms) in which at least one hydrogen atom is substituted with a fluorine atom.

It is preferable that all of R₅₇ to R₆₁, and R₆₅ to R₆₇ are fluorine atoms. R₆₂, R₆₃, and R₆₈ are each preferably an alkyl group (preferably having 1 to 4 carbon atoms) in which at least one hydrogen atom is substituted with a fluorine atom, and more preferably a perfluoroalkyl group having 1 to 4 carbon atoms. R₆₂ and R₆₃ may be linked to each other to form a ring.

The hydrophobic resin (E) may contain a silicon atom. The resin preferably has, as the partial structure having a silicon atom, an alkylsilyl structure (preferably a trialkylsilyl group) or a cyclic siloxane structure.

Examples of the repeating unit having a fluorine atom or a silicon atom include those exemplified in [0519] of US2012/0251948A1.

Furthermore, it is also preferable that the hydrophobic resin (E) contains a CH₃ partial structure in the side chain moiety as described above.

Here, the CH₃ partial structure (hereinafter also simply referred to as a “side chain CH₃ partial structure”) contained in the side chain moiety in the hydrophobic resin (E) includes a CH₃ partial structure contained in an ethyl group, a propyl group, and the like.

On the other hand, a methyl group bonded directly to the main chain of the hydrophobic resin (E) (for example, an α-methyl group in the repeating unit having a methacrylic acid structure) makes only a small contribution of uneven distribution to the surface of the hydrophobic resin (E) due to the effect of the main chain, and it is therefore not included in the “side chain CH₃ partial structure”.

More specifically, in a case where the hydrophobic resin (E) contains a repeating unit derived from a monomer having a polymerizable moiety with a carbon-carbon double bond, such as repeating units represented by the following General Formula (M), and in addition, R₁₁ to R₁₄ are CH₃ “themselves,” such CH₃ is not included in the “CH₃ partial structure contained in the side chain moiety” in the present invention.

On the other hand, a CH₃ partial structure which is present via a certain atom from a C—C main chain corresponds to the “side chain CH₃ partial structure” in the present invention. For example, in a case where R₁₁ is an ethyl group (CH₂CH₃), the hydrophobic resin has “one” CH₃ partial structure in the present invention.

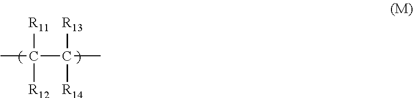

In General Formula (M),

R₁₁ to R₁₄ each independently represent a side chain moiety.

Examples of R₁₁ to R₁₄ at the side chain moiety include a hydrogen atom and a monovalent organic group.

Examples of the monovalent organic group for each of R₁₁ to R₁₄ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, and an arylaminocarbonyl group, each of which may further have a substituent.

The hydrophobic resin (E) is preferably a resin including a repeating unit having the CH₃ partial structure in the side chain moiety thereof. Further, the hydrophobic resin preferably has, as such a repeating unit, at least one repeating unit (x) selected from repeating units represented by the following General Formula (II) and repeating units represented by the following General Formula (III).

Hereinafter, the repeating unit represented by General Formula (II) will be described in detail.

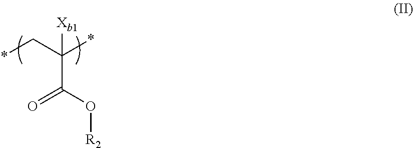

In General Formula (II), X_{b1} represents a hydrogen atom, an alkyl group, a cyano group, or a halogen atom, and R₂ represents an organic group which has one or more CH₃ partial structures and is stable against an acid. Here, more specifically, the organic group which is stable against an acid is preferably an organic group which does not have an “acid-decomposable group” described with respect to the resin (A).

The alkyl group of X_{b1} is preferably an alkyl group having 1 to 4 carbon atoms, and examples thereof include a methyl group, an ethyl group, a propyl group, a hydroxymethyl group, and a trifluoromethyl group, with the methyl group being preferable.

X_{b1} is preferably a hydrogen atom or a methyl group.

Examples of R₂ include an alkyl group, a cycloalkyl group, an alkenyl group, a cycloalkenyl group, an aryl group, and an aralkyl group, each of which has one or more CH₃ partial structures. Each of the cycloalkyl group, the alkenyl group, the cycloalkenyl group, the aryl group and the aralkyl group may further have an alkyl group as a substituent.

R₂ is preferably an alkyl group or an alkyl-substituted cycloalkyl group, each of which has one or more CH₃ partial structures.

The number of the CH₃ partial structures contained in the organic group which has one or more CH₃ partial structures and is stable against an acid as R₂ is preferably 2 to 10, and more preferably 2 to 8.

Specific preferred examples of the repeating unit represented by General Formula (II) are shown below, but the present invention is not limited thereto.

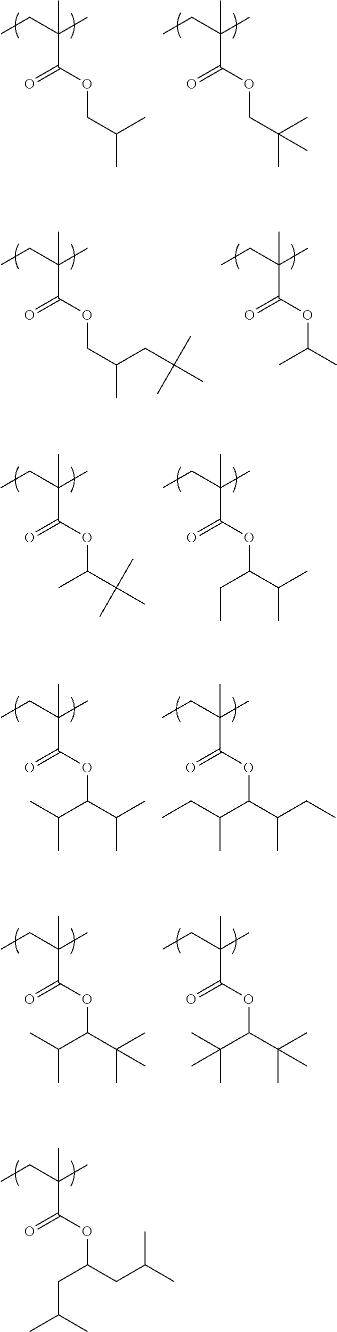

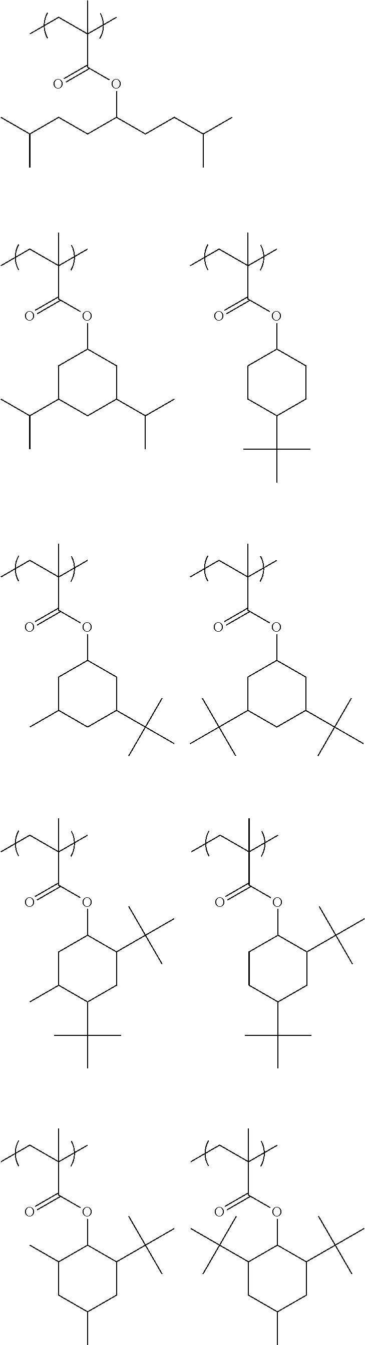

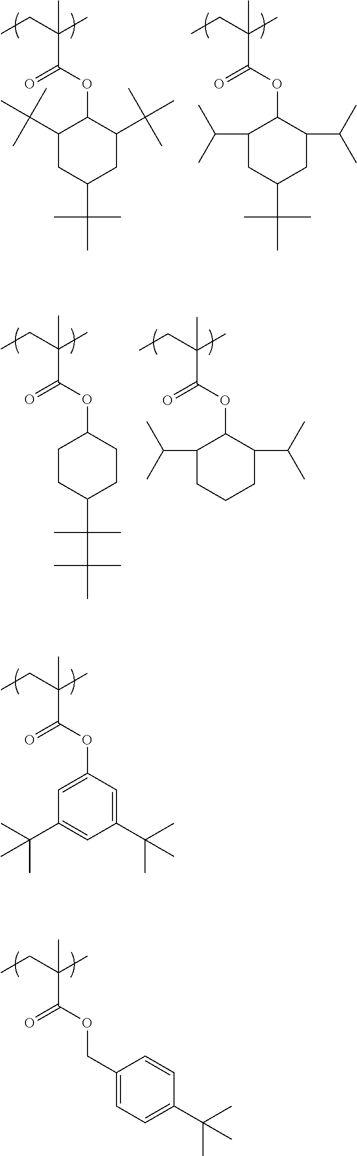

The repeating unit represented by General Formula (II) is preferably a repeating unit which is stable against an acid (acid-indecomposable), and specifically, it is preferably a repeating unit not having a group that decomposes by the action of an acid to generate a polar group.

Hereinafter, the repeating unit represented by General Formula (III) will be described in detail.

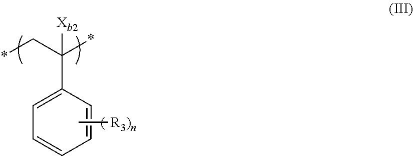

In General Formula (III), X_{b2} represents a hydrogen atom, an alkyl group, a cyano group, or a halogen atom, R₃ represents an organic group which has one or more CH₃ partial structures and is stable against an acid, and n represents an integer of 1 to 5.

The alkyl group of X_{b2} is preferably an alkyl group having 1 to 4 carbon atoms, and examples thereof include a methyl group, an ethyl group, a propyl group, a hydroxymethyl group, and a trifluoromethyl group, but a hydrogen atom is preferable.

X_{b2} is preferably a hydrogen atom.

Since R₃ is an organic group stable against an acid, and more specifically, R₃ is preferably an organic group which does not have the “acid-decomposable group” described with respect to the resin (A).

Examples of R₃ include an alkyl group having one or more CH₃ partial structures.

The number of the CH₃ partial structures contained in the organic group which has one or more CH₃ partial structures and is stable against an acid as R₃ is preferably 1 to 10, more preferably 1 to 8, and still more preferably 1 to 4.

n represents an integer of 1 to 5, more preferably 1 to 3, and still more preferably 1 or 2.

Specific preferred examples of the repeating unit represented by General Formula (III) are shown below, but the present invention is not limited thereto.

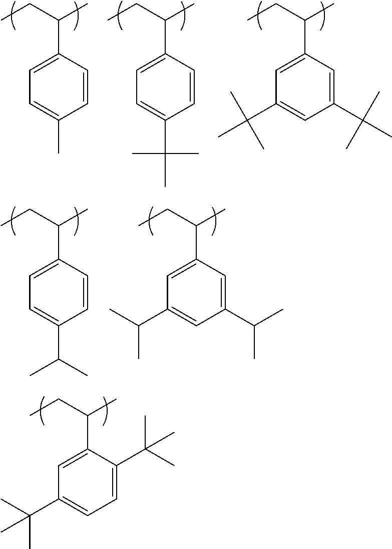

The repeating unit represented by General Formula (III) is preferably a repeating unit which is stable against an acid (acid-indecomposable), and specifically, it is a repeating unit which does not have a group that decomposes by the action of an acid to generate a polar group.

In a case where the hydrophobic resin (E) contains a CH₃ partial structure in the side chain moiety thereof, and in particular, it does not have any one of a fluorine atom and a silicon atom, the content of at least one repeating unit (x) of the repeating unit represented by General Formula (II) and the repeating unit represented by General Formula (III) is preferably 90% by mole or more, and more preferably 95% by mole or more, with respect to all the repeating units of the hydrophobic resin (E). The content is usually 100% by mole or less with respect to all the repeating units of the hydrophobic resin (E).

By incorporating at least one repeating unit (x) of the repeating unit represented by General Formula (II) and the repeating unit represented by General Formula (III) in a proportion of 90% by mole or more with respect to all the repeating units of the hydrophobic resin (E) into the hydrophobic resin (E), the surface free energy of the hydrophobic resin (E) is increased. As a result, it is difficult for the hydrophobic resin (E) to be unevenly distributed on the surface of the resist film and the static/dynamic contact angle of the resist film with respect to water can be securely increased, thereby enhancing the immersion liquid tracking properties.

In addition, in a case where the hydrophobic resin (E) contains (i) a fluorine atom and/or a silicon atom or (ii) contains a CH₃ moiety structure in the side chain moiety, the hydrophobic resin may have at least one group selected from the following groups (x) to (z):

(x) an acid group,

(y) a group having a lactone structure, an acid anhydride group, or an acid imido group, and

(z) a group that decomposes by the action of an acid.

Examples of the acid group (x) include a phenolic hydroxyl group, a carboxylic acid group, a fluorinated alcohol group, a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group.

Preferred examples of the acid group include a fluorinated alcohol group (preferably hexafluoroisopropanol), a sulfonimido group, and a bis(alkylcarbonyl)methylene group.

Examples of the repeating unit containing an acid group (x) include a repeating unit in which the acid group is directly bonded to the main chain of the resin, such as a repeating unit by an acrylic acid or a methacrylic acid, and a repeating unit in which the acid group is bonded to the main chain of the resin through a linking group, and the acid group may also be introduced into the polymer chain terminal by using a polymerization initiator or chain transfer agent containing an acid group during the polymerization. All of these cases are preferable. The repeating unit having an acid group (x) may have at least one of a fluorine atom or a silicon atom.

The content of the repeating units containing an acid group (x) is preferably 1% to 50% by mole, more preferably 3% to 35% by mole, and still more preferably 5% to 20% by mole, with respect to all the repeating units in the hydrophobic resin (E).

Specific preferred examples of the repeating unit containing an acid group (x) are shown below, but the present invention is not limited thereto. In the formulae, Rx represents a hydrogen atom, CH₃, CF₃, or CH₂OH.

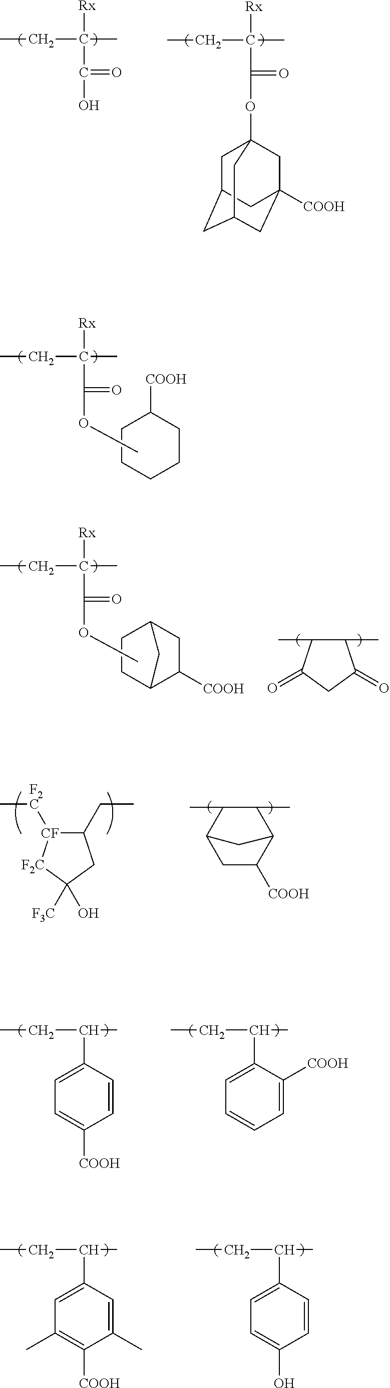

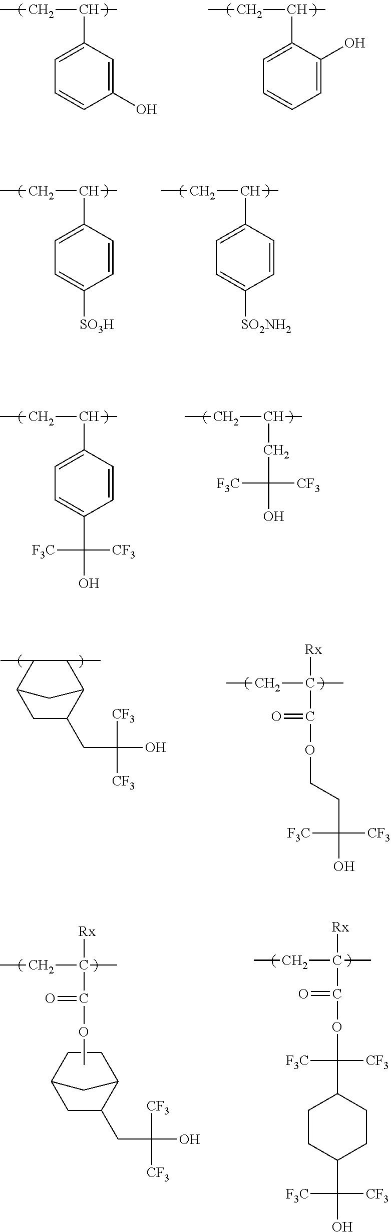

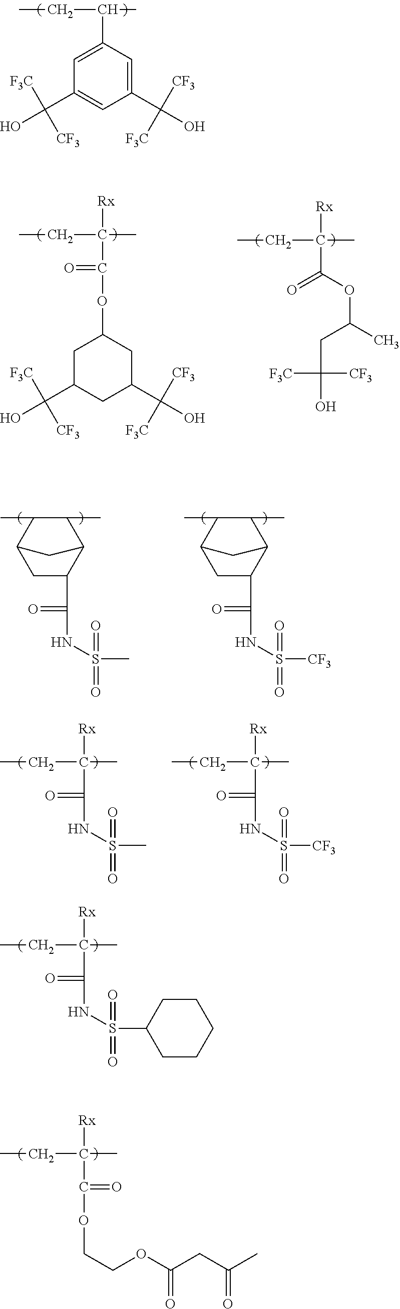

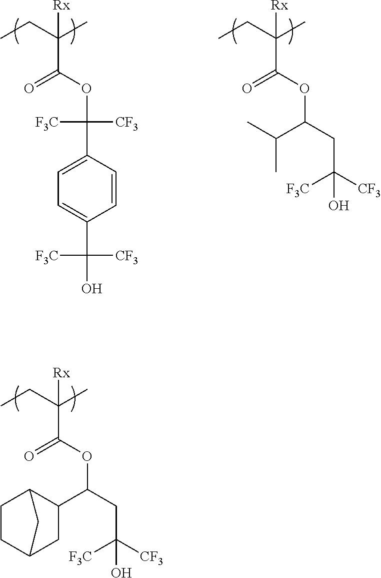

As the group having a lactone structure, the acid anhydride group, or the acid imido group (y), a group having a lactone structure is particularly preferable.

The repeating unit containing such a group is, for example, a repeating unit in which the group is directly bonded to the main chain of the resin, such as a repeating unit by an acrylic ester or a methacrylic ester. This repeating unit may be a repeating unit in which the group is bonded to the main chain of the resin through a linking group. Alternatively, this repeating unit may be introduced into the terminal of the resin by using a polymerization initiator or chain transfer agent containing the group during the polymerization.

Examples of the repeating unit containing a group having a lactone structure include the same ones as the repeating unit having a lactone structure as described earlier in the section of the resin (A).

The content of the repeating units having a group having a lactone structure, an acid anhydride group, or an acid imido group (y) is preferably 1% to 100% by mole, more preferably 3% to 98% by mole, and still more preferably 5% to 95% by mole, with respect to all the repeating units in the hydrophobic resin (E).

With respect to the hydrophobic resin (E), examples of the repeating unit having a group (z) that decomposes by the action of an acid include the same ones as the repeating units having an acid-decomposable group, exemplified as the resin (A). The repeating unit having a group (z) that decomposes by the action of an acid may have at least one of a fluorine atom or a silicon atom. With respect to the hydrophobic resin (E), the content of the repeating units having a group (z) that decomposes by the action of an acid is preferably 1% to 80% by mole, more preferably 10% to 80% by mole, and still more preferably 20% to 60% by mole, with respect to all the repeating units in the hydrophobic resin (E).

The hydrophobic resin (E) may further have repeating units that are different from the repeating units as described above.

The content of the repeating units including a fluorine atom is preferably 10% to 100% by mole, and more preferably 30% to 100% by mole, with respect to all the repeating units included in the hydrophobic resin (E). Further, the content of the repeating units including a silicon atom is preferably 10% to 100% by mole, and more preferably 20% to 100% by mole, with respect to all the repeating units included in the hydrophobic resin (E).

On the other hand, in particular, in a case where the hydrophobic resin (E) includes a CH₃ partial structure in the side chain moiety thereof, it is also preferable that the hydrophobic resin (E) has a form not having substantially any one of a fluorine atom and a silicon atom. Further, it is preferable that the hydrophobic resin (E) is substantially composed of only repeating units, which are composed of only atoms selected from a carbon atom, an oxygen atom, a hydrogen atom, a nitrogen atom, and a sulfur atom.

The weight-average molecular weight of the hydrophobic resin (E) in terms of standard polystyrene is preferably 1,000 to 100,000, and more preferably 1,000 to 50,000.

Furthermore, the hydrophobic resin (E) may be used singly or in combination of plural kinds thereof.

The content of the hydrophobic resin (E) in the composition is preferably 0.01% to 10% by mass, and more preferably 0.05% to 8% by mass, with respect to the total solid content of the composition.

In the hydrophobic resin (E), the content of residual monomers or oligomer components is preferably 0.01% to 5% by mass, and more preferably 0.01% to 3% by mass. Further, the molecular weight distribution (Mw/Mn, also referred to as a dispersity) is preferably in the range of 1 to 5, and more preferably in the range of 1 to 3.

As the hydrophobic resin (E), various commercial products may be used, or the resin can be synthesized by an ordinary method (for example, radical polymerization).

<Surfactant>

The composition may further include a surfactant (F). By incorporating the surfactant into the composition, it becomes possible to form a pattern which is improved in adhesiveness and decreased in development defects with good sensitivity and resolution in a case of using an exposure light source of 250 nm or less, and particularly 220 nm or less.

As the surfactant, a fluorine-based and/or silicone-based surfactant is/are particularly preferably used.

Examples of the fluorine- and/or silicon-based surfactants include the surfactants described in <0276> of US2008/0248425A. Further, examples thereof include EFTOP EF301 and EF303 (manufactured by Shin-Akita Kasei K. K.); FLORAD FC430, 431, and 4430 (manufactured by Sumitomo 3M Inc.); MEGAFACE F171, F173, F176, F189, F113, F110, F177, F120, and R₀₈ (manufactured by DIC Corp.); Surflon S-382, SC101, 102, 103, 104, 105, and 106 (manufactured by Asahi Glass Co., Ltd.); TROYSOL S-366 (manufactured by Troy Chemical Corp.); GF-300 and GF-150 (manufactured by Toagosei Chemical Industry Co., Ltd.); SURFLON S-393 (manufactured by Seimi Chemical Co., Ltd.); EFTOP EF121, EF122A, EF122B, RF122C, EF125M, EF135M, EF351, EF352, EF801, EF802, and EF601 (manufactured by JEMCO Inc.); PF636, PF656, PF6320, and PF6520 (manufactured by OMNOVA); and FTX-204G, 208G, 218G, 230G, 204D, 208D, 212D, 218D, and 222D (manufactured by NEOS Co., Ltd.). In addition, Polysiloxane Polymer KP-341 (manufactured by Shin-Etsu Chemical Co., Ltd.) can also be used as the silicon-based surfactant.

Furthermore, in addition to those known surfactants as described above, surfactants may also be synthesized using a fluoro-aliphatic compound which is produced by a telomerization method (also referred to as a telomer method) or an oligomerization method (also referred to as an oligomer method). Specifically, a polymer including a fluoro-aliphatic group derived from the fluoro-aliphatic compound may also be used as the surfactant. The fluoro-aliphatic compound can be synthesized in accordance with the method described in JP2002-90991A.

The polymer having a fluoro-aliphatic group is preferably a copolymer of a fluoro-aliphatic group-containing monomer with a (poly(oxyalkylene))acrylate and/or a (poly(oxyalkylene))methacrylate, and the polymer may have an irregular distribution or may be a block copolymer.

Examples of the poly(oxyalkylene) group include a poly(oxyethylene) group, a poly(oxypropylene) group, and a poly(oxybutylene) group. This group may also be a unit having alkylenes differing in the chain length within the same chain, such as block-linked poly(oxyethylene, oxypropylene, and oxyethylene) and block-linked poly(oxyethylene and oxypropylene).

Furthermore, the copolymer of a fluoro-aliphatic group-containing monomer and a (poly(oxyalkylene))acrylate (or methacrylate) is not limited only to a binary copolymer but may also be a ternary or more copolymer obtained by simultaneously copolymerizing two or more different fluoro-aliphatic group-containing monomers or two or more different (poly(oxyalkylene))acrylates (or methacrylates).

Examples of the commercially available surfactant corresponding to the above include MEGAFACE F178, F-470, F-473, F-475, F-476, and F-472 (manufactured by DIC Corp.). Other examples include a copolymer of an acrylate or methacrylate having a C₆F₁₃ group and a (poly(oxyalkylene)) acrylate or methacrylate, a copolymer of an acrylate or methacrylate having a C₆F₁₃ group, a (poly(oxyethylene)) acrylate or methacrylate, and a (poly(oxypropylene)) acrylate or methacrylate, a copolymer of an acrylate or methacrylate having a C₈F₁₇ group and a (poly(oxyalkylene)) acrylate or methacrylate, and a copolymer of an acrylate or methacrylate having a C₈F₁₇ group, a (poly(oxyethylene)) acrylate or methacrylate, and a (poly(oxypropylene)) acrylate or methacrylate.

In addition, in the present invention, a surfactant other than the fluorine- and/or silicon-based surfactants described in <0280> of US2008/0248425A can also be used.

These surfactants may be used singly or in combination of a few surfactants.

In a case where the composition includes the surfactant, the content thereof is preferably 0% to 2% by mass, more preferably 0.0001% to 2% by mass, and still more preferably 0.0005% to 1% by mass, with respect to the total solid content amount of the composition.

<Other Additives>

The composition may further include a dissolution inhibiting compound, a dye, a plasticizer, a light sensitizer, a light absorbent, and/or a compound promoting solubility in a developer (for example, a phenol compound having a molecular weight of 1,000 or less, and an alicyclic or aliphatic compound having a carboxyl group).

The composition may further include a dissolution inhibiting compound. Here, the “dissolution inhibiting compound” is a compound having a molecular weight of 3,000 or less, that decomposes by the action of an acid, and thus, has a reduced solubility in an organic developer.

As the dissolution inhibiting compound, an alicyclic or aliphatic compound which contains an acid-decomposable group such as a cholic acid derivative which including an acid-decomposable group described in the Proceeding of SPIE, 2724, 355 (1996) is preferable since the transparency with respect to light having a wavelength of 220 nm or less is not reduced. Examples of the acid-decomposable group and the alicyclic structure include the same as those described above, respectively.

Furthermore, in a case where the composition is exposed to a KrF excimer laser or irradiated with electron beams, the dissolution inhibiting compound is preferably a compound including a structure in which the phenolic hydroxyl group of a phenol compound is substituted with an acid-decomposable group. As the phenol compound, a phenol compound containing 1 to 9 phenol skeletons is preferable, and a phenol compound having 2 to 6 phenol skeletons is more preferable.

The amount of the dissolution inhibiting compound to be added is preferably 3% to 50% by mass, and more preferably 5% to 40% by mass, with respect to the solid content of the composition.

Specific examples of the dissolution inhibiting compound are shown below.

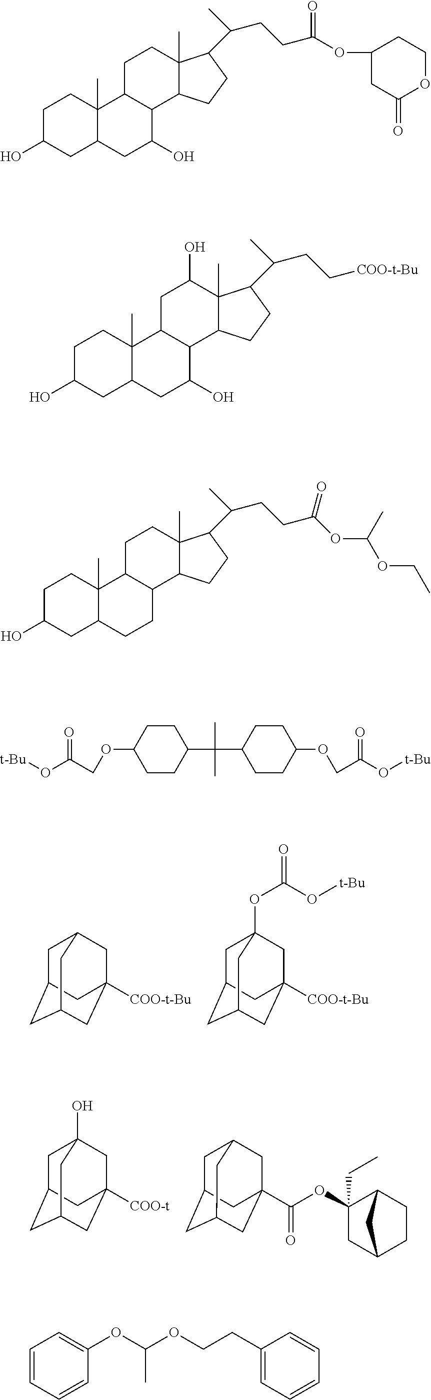

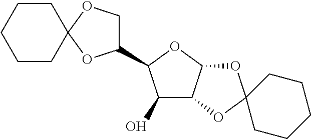 [SMILES: O[C@@H]1[C@H]2OC3(CCCCC3)O[C@H]2O[C@@H]1C1COC2(CCCCC2)O1]

The phenol compound having a molecular weight of 1,000 or less may be easily synthesized by those skilled in the art with reference to the method described in, for example, JP1992-122938A (JP-H04-122938A), JP1990-28531A (JP-H02-28531A), U.S. Pat. No. 4,916,210A, EP219294B, and the like.

Specific examples of the alicyclic compound or aliphatic compound including a carboxyl group include, but not limited to, a carboxylic acid derivative having a steroid structure such as a cholic acid, deoxycholic acid or lithocholic acid, an adamantane carboxylic acid derivative, adamantane dicarboxylic acid, cyclohexane carboxylic acid, and cyclohexane dicarboxylic acid.

In addition, as other additives, a resin having the repeating unit represented by General Formula (II) which is different from the compound X may also be included.

<Suitable Aspects of Composition>

Suitable aspects of the composition include, an actinic ray-sensitive or radiation-sensitive resin composition (hereinafter also simply referred to as a “composition X”) including a resin that contains the repeating unit represented by General Formula (II), the repeating unit represented by General Formula (III), and the repeating unit having a group that decomposes by the action of an acid to generate a polar group, in view that the resolution of the pattern is more excellent.

In addition, examples of the repeating unit having a group that decomposes by the action of an acid to generate a polar group include the repeating unit represented by any one of General Formulae (IVa) to (IVc) as described above.

The present invention further relates to a resist film formed by the composition X, and such a film is formed by, for example, coating the composition X on a support as described above.

Furthermore, the present invention also relates to a mask blank having the resist film obtained as described above coated thereon. In a case of forming a pattern on a photo mask blank for manufacturing a photo mask in order to obtain such a mask blank including the resist film, examples of the transparent substrate to be used include transparent substrates such as quartz and calcium fluoride. In general, those requiring functional films, such as a shielding film, an antireflection film, and a phase shift film, and additionally, an etching stopper film, and an etching mask film are laminated on the substrate.

The present invention also relates to a pattern forming method including exposing a mask blank having the resist film formed therein, and developing the mask blank including the exposed film.

### EXAMPLES

Hereinafter, the present invention will be described in more detail with reference to Examples, but the present invention is not limited thereto.

Hereinbelow, the respective components used in Examples will be firstly shown.

<Compounds X and Comparative Compounds>

By using the same method as the synthesis for 2,2′-(5-hydroxy-1,3-phenylene)dipropan-2-ol in Journal of Photopolymer Science and Technology Volume 26, Number 5 (2013) 665-671, or the same method as the method described in JP2013-164588A, various compounds X (and comparative compounds) were synthesized. Hereinbelow, the structures, the weight-average molecular weights (Mw), and the dispersities (Mw/Mn) of the compounds X are shown. Further, the compositional ratios of the respective units with the following structures are shown in molar ratios.

In addition, in Table 1, “Me” represents a methyl group and “Ac” represents an acetyl group.

TABLE 1

| | | Compo- | Weight | |
|---|---|---|---|---|
| | | sitional | average | |
| Compound | | ratio (molar | molecular | Dis- |
| X | Chemical formula | ratio) | weight | persity |
| Compound (A1) | 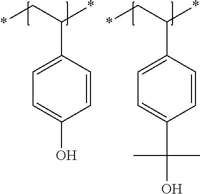 | 70/30 | 6,500 | 1.45 |
| Compound (A2) | 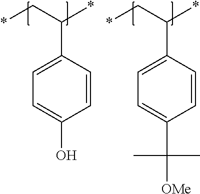 | 60/40 | 4,800 | 1.52 |
| Compound (A3) | 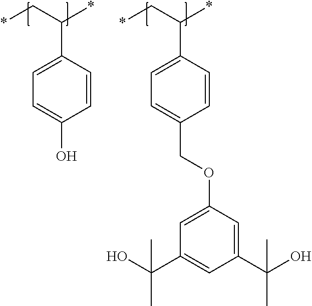 | 75/25 | 3,900 | 1.67 |
| Compound (A4) | 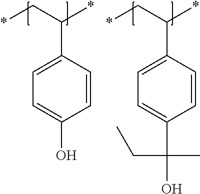 | 75/25 | 5,400 | 1.53 |
| Compound (A5) | 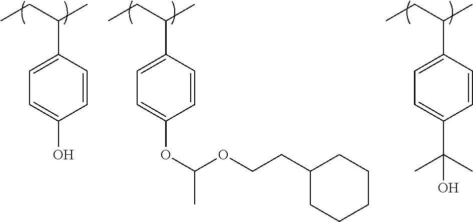 | 60/30/10 | 9,500 | 1.62 |
| Compound (A6) | 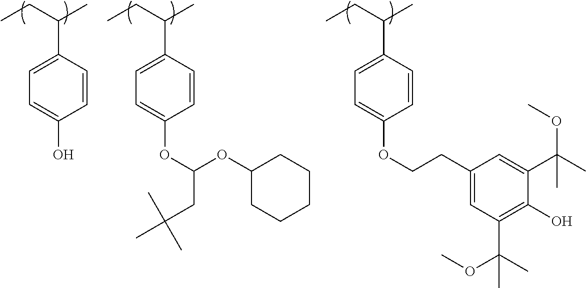 | 55/30/15 | 8,800 | 1.45 |
| Compound (A7) | 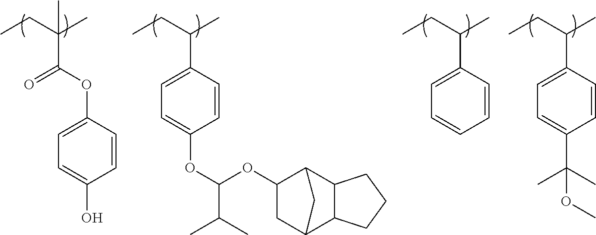 | 40/40/10/10 | 12,000 | 1.13 |
| Compound (A8) | 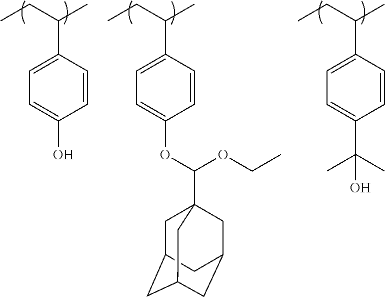 | 60/20/20 | 5,600 | 1.32 |
| Compound (A9) | 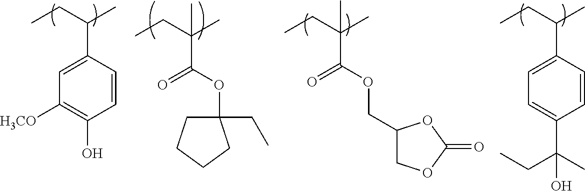 | 20/60/10/10 | 6,600 | 1.83 |
| Compound (A10) | 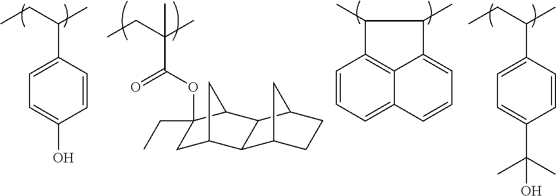 | 40/30/10/20 | 7,700 | 1.53 |
| Compound (A11) | 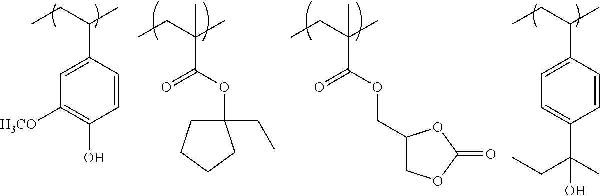 | 20/60/10/10 | 12,000 | 1.43 |
| Compound (A12) | 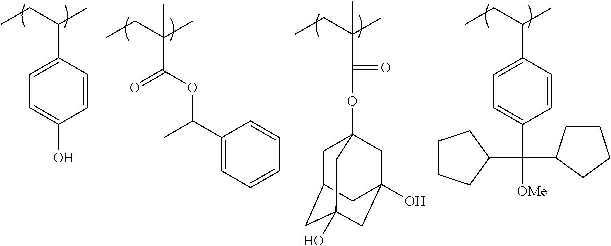 | 35/40/10/15 | 9,800 | 1.35 |
| Compound (A13) | 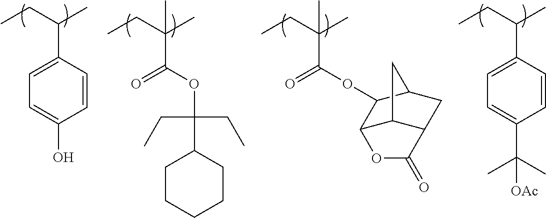 | 30/50/10/10 | 8,800 | 1.38 |
| Compound (A14) | 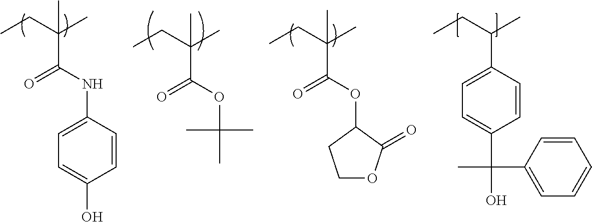 | 35/50/5/10 | 7,700 | 1.34 |
| Compound (A15) | 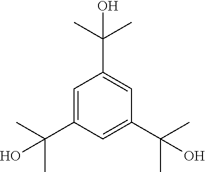 [SMILES: CC(C)(O)c1cc(C(C)(C)O)cc(C(C)(C)O)c1] | — | — | — |
| Compound (A16) | 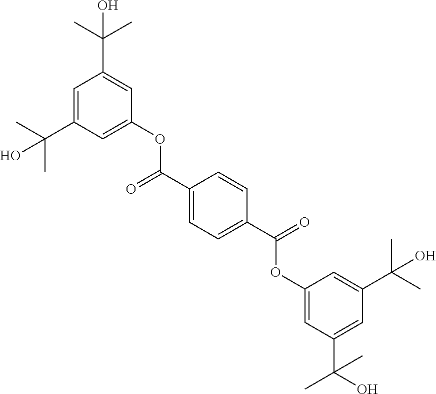 [SMILES: CC(C)(O)c1cc(OC(=O)c2ccc(C(=O)Oc3cc(C(C)(C)O)cc(C(C)(C)O)c3)cc2)cc(C(C)(C)O)c1] | | | |
| Compound (A17) | 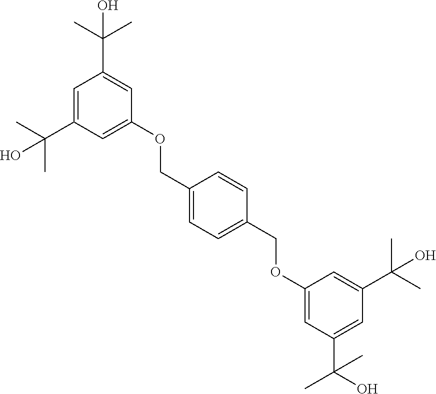 [SMILES: CC(C)(O)c1cc(OCc2ccc(COc3cc(C(C)(C)O)cc(C(C)(C)O)c3)cc2)cc(C(C)(C)O)c1] | — | — | — |
| | | Compo- | Weight | |
| | | sitional | average | |
| | | ratio (molar | molecular | Dis- |
| Compound | Chemical formula | ratio) | weight | persity |
| Comparative compound (R1) | 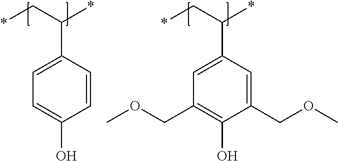 | 70/30 | 4,500 | 1.52 |
| Comparative compound (R2) | 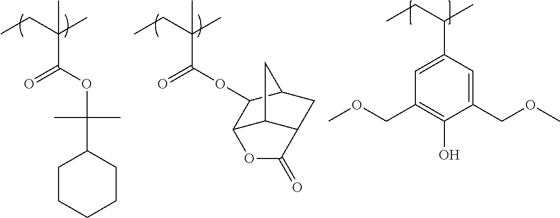 | 40/50/10 | 14,000 | 1.45 |
| Comparative compound (R3) | 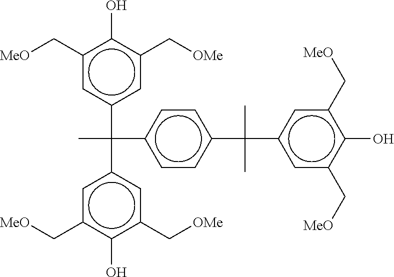 | — | — | — |
| Comparative compound (R4) | 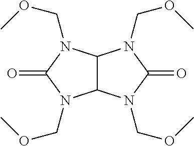 | — | — | — |

<Comparative Compounds>

As the comparative compounds, the following resins were used. The weight-average molecular weights (Mw) and the dispersities (Mw/Mn) of the resins are listed below. Further, the compositional ratios of the respective repeating units of the resins are shown in molar ratios.

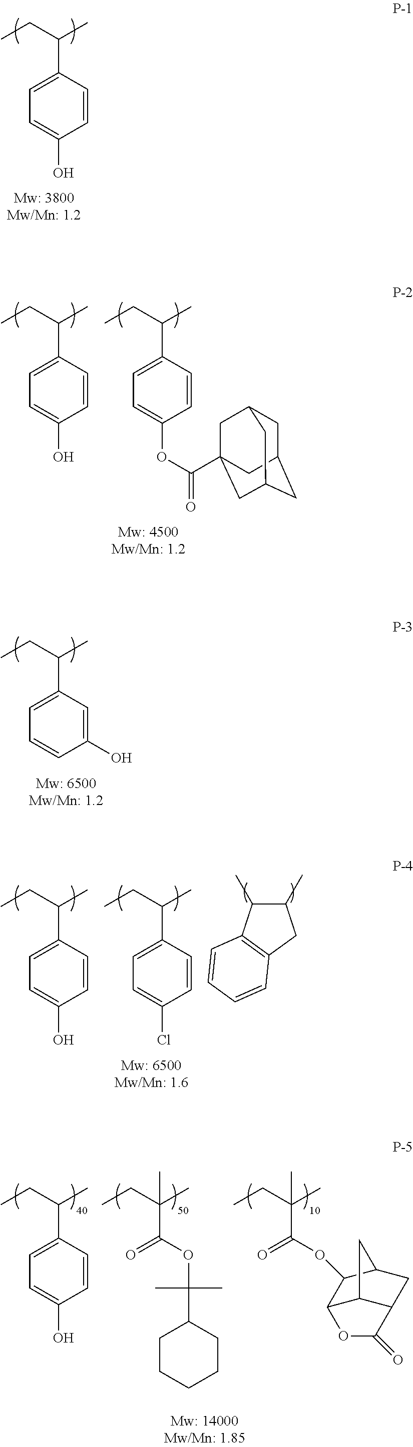

<Photoacid Generator>

As the photoacid generator, a photoacid generator appropriately selected from the aforementioned acid generators z1 to z141 was used.

<Basic Compounds>

As the basic compound, any one of the following compounds (N-1) to (N-12) was used.

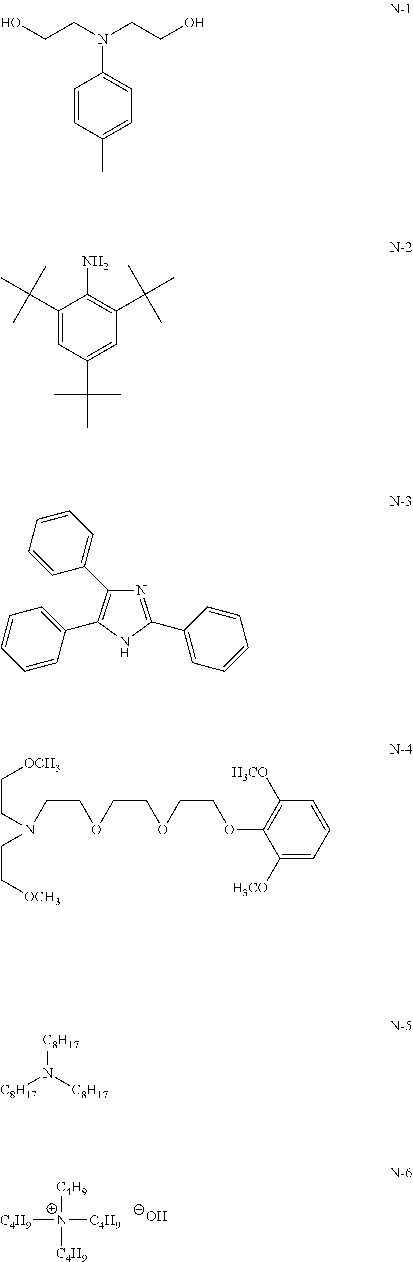

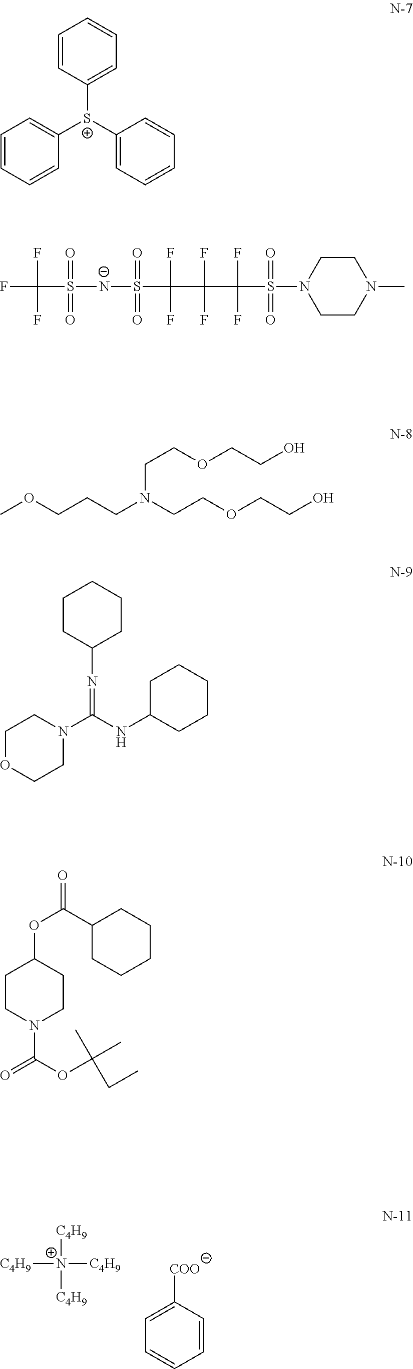

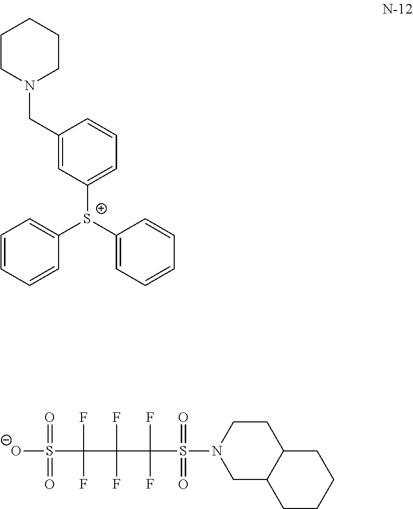 [SMILES: c1ccc([S+](c2ccccc2)c2cccc(CN3CCCCC3)c2)cc1 ; O=S(=O)([O-])C(F)(F)C(F)(F)C(F)(F)S(=O)(=O)N1CCC2CCCCC2C1]

<Surfactant>

As the surfactant, the following W-1 to W-4 were used.

W-1: MEGAFACE R₀₈ (manufactured by DIC, Inc.; fluorine- and silicon-based) W-2: Polysiloxane Polymer KP-341 (manufactured by Shin-Etsu Chemical Co., Ltd.; silicone-based)

W-3: TROYSOL S-366 (manufactured by Troy Chemical Co., Ltd.; fluorine-based) W-4: PF6320 (manufactured by OMNOVA Solutions Inc.; fluorine-based)

<Organic Solvent>

As the organic solvent, the following ones were used.

S1: Propylene glycol monomethyl ether acetate (PGMEA)

S2: Propylene glycol monomethyl ether (PGME)

S3: Lactic acid ethyl

S4: Cyclohexanone

<Developer>

As the organic solvent used in the developer, the following ones were used.

SG-1: Anisole

SG-2: Methyl amyl ketone (2-heptanone)

SG-3: Butyl acetate

SG-4: 3-Methylbutyl acetate

TM-1: 2.38%-by-mass Aqueous tetramethylammonium hydroxide solution (an alkaline developer for Comparative Examples)

<Rinsing Liquid>

In a case of using a rinsing liquid, the following ones were used.

SR-1: 4-Methyl-2-pentanol

SR-2: 1-Hexanol

SR-3: 2-Pentanol

### Examples 1-1 to 1-21, and Comparative Examples 1-1 to 1-5 (Electron Beams (EB) Exposure)

(1) Preparation and Application of Actinic Ray-Sensitive or Radiation-Sensitive Resin Composition

A composition having the compositional ratio shown in the following table was microfiltered using a membrane filter having a pore diameter of 0.1 μm, thereby obtaining an actinic ray-sensitive or radiation-sensitive resin composition (resist composition) having a solid content concentration of 3.5% by mass.

This actinic ray-sensitive or radiation-sensitive resin composition was coated on a 6-inch Si wafer that had been subjected to a hexamethyldisilazane (HMDS) treatment in advance, using a spin coater Mark 8 manufactured by Tokyo Electron Limited, and dried on a hot plate at 100° C. for 60 seconds, thereby obtaining a resist film having a film thickness of 50 nm.

(2) EB Exposure and Development

The wafer having the resist film obtained above in (1) coated thereon was subjected to pattern irradiation, using an electron beam irradiating device (HL750, manufactured by Hitachi, Ltd., an acceleration voltage of 50 keV). At this time, lithography was carried out such that a 1:1 line-and-space was formed. After the lithography with electron beams, the wafer was heated on a hot plate at 110° C. for 60 seconds and then developed by paddling the organic developer described in the following table for 30 seconds, and if necessary, rinsed by paddling using a rinsing liquid described in the following table (Examples in which a rinsing liquid is not described mean that rinsing was not carried out in the Examples) for 30 seconds. The wafer was rotated for 30 seconds at a rotation speed of 4,000 rpm, and then heated at 90° C. for 60 seconds, thereby obtaining a resist pattern with a 1:1 line-and-space pattern having a line width of 50 nm.

(3) Evaluation of Resist Pattern

The sensitivity and the resolving power of the obtained resist pattern were evaluated by the following method, using a scanning electron microscope (S-9220 manufactured by Hitachi, Ltd.). In addition, the amount of the film was also evaluated. The results are shown in the following table.

(3-1) Sensitivity

The irradiation energy at a time when the 1:1 line-and-space pattern having a line width of 50 nm was resolved was taken as sensitivity (Eop). A smaller value thereof indicates better performance.

(3-2) Resolving Power

In the Eop, the line-and-space width was minimized, and the minimum line width (the minimum line width of the line portion) of the separated 1:1 line-and-space pattern was taken as resolving power. A smaller value thereof indicates better performance.

(3-3) Line Width Roughness (LWR) Regarding the line width roughness, in the Eop, the line widths at arbitrary 50 points having a size of 0.5 μm in the longitudinal direction of a 1:1 line-and-space pattern having a line width of 50 nm were measured, the standard deviation thereof was determined, and 3σ was calculated. A smaller value thereof indicates better performance.

(3-4) Amount of Film Loss

After a series of processes were completed, the film thickness of the remaining resist film was measured, and the value obtained by subtracting the residual film thickness from the initial film thickness was taken as the amount (nm) of film loss. In addition, an optical interference film thickness measuring device (Lambda Ace, manufactured by SCREEN Holdings Co., Ltd.) was used for measurement of the film thickness.

(3-5) Exposure Latitude (EL (%))

The exposure dose at which a mask pattern of a line-and-space (line:space=1:1) having a line width of 50 nm was reproduced was determined and this was taken as the optimal exposure dose Eopt. Next, the exposure dose when the line width became ±10% of 50 nm (that is, 45 nm and 55 nm) which were desired values was determined. Then, the exposure latitude (EL) defined by the following equation was calculated. As the value of EL was increased, the change in performance due to a change in the exposure dose was decreased.

[EL (%)]=[(exposure dose when line width becomes 55 nm)−(exposure dose when line width becomes 45 nm)]/Eopt×100

(3-6) Dry Etching Resistance

The wafer having the resist film obtained in the above (1) coated thereon was subjected to overall irradiation, using an electron beam irradiating device (HL750, manufactured by Hitachi, Ltd., acceleration voltage of 50 KeV). After the irradiation with electron beams, the wafer was heated on a hot plate at 110° C. for 60 seconds, and developed by paddling the organic developer described in the following Table for 30 seconds, and if necessary, rinsed by paddling using the rinsing liquid described in the following Table for 30 seconds. The wafer was rotated for 30 seconds at a rotation speed of 4,000 rpm, and then heated at 90° C. for 60 seconds, thereby obtaining a resist film for dry etching evaluation.

The initial film thickness (FT1, Angstroms) of the resist film obtained above was measured. Subsequently, etching was carried out for 30 seconds while supplying C₄F₆ gas, using a dry etcher (U-621, manufactured by Hitachi High-Technologies Corporation). Thereafter, the film thickness (FT2, Angstroms) of the resist film obtained after the etching was measured. Then, the dry etching rate (DE) defined by the following equation was calculated.

[Dry etching rate(DE,Angstroms/sec)]=(FT1−FT2)/30

Superiority or inferiority of DE was evaluated according to the following criteria. A smaller value of DE indicates a smaller change in the film thickness due to etching, with good performance.

A . . . Dry etching rate being less than 10 Angstroms/sec

B . . . Dry etching rate being 10 Angstroms/sec or more and less than 12 Angstroms/sec

C . . . Dry etching rate being 12 Angstroms/sec or more

TABLE 2

| | | | | | | | Organic | Surfactant | |
|---|---|---|---|---|---|---|---|---|---|
| | | | | | | | solvent | Type | |
| | Compound | | Acid generator | | Basic compound | | (mass | (mass | |
| | Type | Concentration | Type | Concentration | Type | Concentration | ratio) | ratio) | Concentration |
| Example 1-1 | A1 | 67.95 | Z-113 | 30 | N-7 | 2 | S1/S2 | W-1 | 0.05 |
| | | | | | | | (40/60) | | |
| Example 1-2 | A2 | 72.95 | Z-112 | 25 | N-12 | 2 | S1/S2 | W-1 | 0.05 |
| | | | | | | | (40/60) | | |
| Example 1-3 | A3 | 62.95 | Z-134 | 35 | N-12 | 2 | S1/S2 | W-1 | 0.05 |
| | | | | | | | (40/60) | | |
| Example 1-4 | A4 | 67.95 | Z-134 | 30 | N-7 | 2 | S1/S2 | W-1 | 0.05 |
| | | | | | | | (40/60) | | |
| Example 1-5 | A5 | 67.95 | Z-128 | 30 | N-12 | 2 | S1/S2 | W-2 | 0.05 |
| | | | | | | | (40/60) | | |
| Example 1-6 | A6 | 83.95 | Z-114 | 15 | N-12 | 1 | S1/S2 | W-4 | 0.05 |
| | | | | | | | (40/60) | | |
| Example 1-7 | A7 | 82.95 | Z-29 | 15 | N-1 | 2 | S1/S3 | W-4 | 0.05 |
| | | | | | | | (40/60) | | |
| Example 1-8 | A8 | 82.95 | Z-2 | 15 | N-2 | 2 | S1/S2 | W-1/W-2 | 0.05 |
| | | | | | | | (40/60) | (1/1) | |
| Example 1-9 | A9 | 78 | Z-108 | 20 | N-7 | 2 | S1/S2/S3 | None | |
| | | | | | | | (30/60/10) | | |
| Example 1-10 | A10 | 82.95 | Z-117 | 15 | N-12 | 2 | S1/S2 | W-3 | 0.05 |
| | | | | | | | (20/80) | | |
| Example 1-11 | A11 | 67.95 | Z-124 | 30 | N-12 | 2 | S1/S2 | W-1 | 0.05 |
| | | | | | | | (40/60) | | |
| Example 1-12 | A12 | 67.95 | Z-124 | 30 | N-7 | 2 | S1/S2 | W-1 | 0.05 |
| | | | | | | | (40/60) | | |
| Example 1-13 | A13 | 62.95 | Z-135 | 35 | N-7 | 2 | S1/S2 | W-3 | 0.05 |
| | | | | | | | (40/60) | | |
| Example 1-14 | A14 | 67.95 | Z-132 | 30 | N-12 | 2 | S1/S2 | W-1 | 0.05 |
| | | | | | | | (40/60) | | |
| Example 1-15 | A15 | 40.00 | Z-4/ | 25 | N-4 | 3 | S1/S2/S3 | None | |
| | P-1 | 32.00 | Z-112 = | | | | (30/60/10) | | |
| | | | 1:1 | | | | | | |
| Example 1-16 | A16 | 37.95 | Z-115 | 30 | N-11 | 2 | S1/S4 | W-1 | 0.05 |
| | P-2 | 30 | | | | | (40/60) | | |
| Example 1-17 | A17 | 37.95 | Z-99 | 30 | N-10 | 2 | S1/S4 | W-1 | 0.05 |
| | P-3 | 30.00 | | | | | (40/60) | | |
| Example 1-18 | A1 | 37.95 | Z-130 | 30 | N-9 | 2 | S1/S4 | W-1 | 0.05 |
| | P-4 | 30.00 | | | | | (40/60) | | |
| Example 1-19 | A16 | 36.95 | Z-124 | 30 | N-3 | 3 | S1/S4 | W-2 | 0.05 |
| | A13 | 30.00 | | | | | (40/60) | | |
| Example 1-20 | A1 | 36.95 | Z-113 | 30 | N-6 | 3 | S1/S2 | W-2 | 0.05 |
| | P-5 | 30.00 | | | | | (40/60) | | |
| Example 1-21 | A17 | 37.95 | Z-118 | 30 | N-8 | 2 | S1/S3 | W-3 | 0.05 |
| | P-5 | 30.00 | | | | | (40/60) | | |
| Comparative | R-1 | 67.95 | Z-2 | 30 | N-5 | 2 | S1/S2 | W-1 | 0.05 |
| Example 1-1 | | | | | | | (40/60) | | |
| Comparative | R-2 | 67.95 | Z-2 | 30 | N-5 | 2 | S1/S2 | W-1 | 0.05 |
| Example 1-2 | | | | | | | (40/60) | | |
| Comparative | R-3 | 37.95 | Z-2 | 30 | N-5 | 2 | S1/S2 | W-1 | 0.05 |
| Example 1-3 | P-1 | 30.00 | | | | | (40/60) | | |
| Comparative | R-4 | 47.95 | Z-2 | 10 | N-5 | 2 | S1/S2 | W-1 | 0.05 |
| Example 1-4 | P-1 | 40.00 | | | | | (40/60) | | |
| Comparative | A1 | 67.95 | Z-113 | 30 | N-7 | 2 | S1/S2 | W-1 | 0.05 |
| Example 1-5 | | | | | | | (40/60) | | |

| | | | Evaluation | | | | | |
|---|---|---|---|---|---|---|---|---|
| | | | | | | Amount | | Dry |
| | | Rinsing | Sensitivity | Resolving | LWR | of film | EL | etching |
| | Developer | liquid | (μC/cm²) | power (nm) | (nm) | loss(nm) | (%) | resistance |
| Example 1-1 | SG-3 | | 29.5 | 35 | 4.5 | 8.7 | 17.5 | A |
| Example 1-2 | SG-3 | | 29.0 | 34 | 4.5 | 8.5 | 18.2 | A |
| Example 1-3 | SG-3 | | 26.1 | 35 | 4.3 | 8.8 | 18.6 | A |
| Example 1-4 | SG-3 | | 29.5 | 35 | 4.5 | 8.6 | 17.5 | A |
| Example 1-5 | SG-3 | | 29.0 | 30 | 4.3 | 8.9 | 17.6 | A |
| Example 1-6 | SG-3 | SR-3 | 26.0 | 30 | 4.2 | 5.7 | 17.2 | A |
| Example 1-7 | SG-4 | SR-2 | 28.6 | 32 | 4.8 | 8.5 | 15.9 | A |
| Example 1-8 | SG-2 | | 27.9 | 32 | 4.8 | 7.8 | 15.7 | A |
| Example 1-9 | SG-1 | SR-3 | 28.2 | 28 | 4.2 | 7.9 | 16.4 | A |
| Example 1-10 | SG-3 | SR-1 | 28.1 | 29 | 4.3 | 7.8 | 17.0 | A |
| Example 1-11 | SG-3 | | 27.0 | 28 | 4.2 | 7.5 | 20.3 | A |
| Example 1-12 | SG-3 | | 28.0 | 28 | 4.5 | 8.5 | 19.4 | A |
| Example 1-13 | SG-3 | | 27.0 | 29 | 4.2 | 7.7 | 20.0 | A |
| Example 1-14 | SG-4 | | 29.0 | 28 | 4.3 | 7.7 | 18.0 | A |
| Example 1-15 | SG-3 | | 29.0 | 35 | 4.8 | 10.5 | 17.8 | B |
| Example 1-16 | SG-3 | | 28.0 | 35 | 4.9 | 10.3 | 19.2 | B |
| Example 1-17 | SG-3 | | 29.0 | 33 | 4.8 | 10.1 | 18.0 | B |
| Example 1-18 | SG-3 | | 28.0 | 33 | 4.7 | 10.2 | 18.7 | A |
| Example 1-19 | SG-4 | | 28.0 | 29 | 4.8 | 9.8 | 18.8 | A |
| Example 1-20 | SG-3 | | 28.5 | 35 | 4.8 | 8.1 | 19.5 | A |
| Example 1-21 | SG-3 | | 29.2 | 34 | 4.7 | 10.1 | 17.0 | B |
| Comparative | SG-3 | | 33.0 | 42 | 5.4 | 12.2 | 15.1 | B |
| Example 1-1 | | | | | | | | |
| Comparative | TM-1 | | 34.0 | 40 | 5.2 | 12.3 | 13.0 | B |
| Example 1-2 | | | | | | | | |
| Comparative | SG-3 | | 33.0 | 43 | 5.5 | 15.1 | 14.0 | C |
| Example 1-3 | | | | | | | | |
| Comparative | SG-3 | | 32.0 | 43 | 5.7 | 16.0 | 13.0 | C |
| Example 1-4 | | | | | | | | |
| Comparative | TM-1 | | 32.0 | 45 | 5.2 | 12.2 | 15.0 | B |
| Example 1-5 | | | | | | | | |

The concentrations of the respective components represent the concentrations (% by mass) in the total concentration of the solid contents.

As shown in Table 2, in the pattern forming methods of Examples 1-1 to 1-21, it was confirmed that the “resolving power” was excellent.

Above all, as seen from comparison between Example 1-1 to Example 1-4 and Example 1-5 to Example 1-14, in a case of Example 1-5 to Example 1-14 in which the compound had a repeating unit having a group that decomposes by the action of an acid to generate a polar group, it was confirmed that the “resolving power” was excellent. In addition, from comparison between Example 1-5 to Example 1-8 and Example 1-9 to Example 1-14, in a case of the repeating unit represented by General Formula (IVb) as the repeating unit having an acid-decomposable group, it was confirmed that the “resolving power” was excellent.

Furthermore, in a case of using N-7 and N-12 which are each “a compound having a functional group with proton acceptor properties and generating a compound in which the proton-acceptability is reduced or lost, or which is changed from being proton-accepting to be acidic, by being decomposed upon irradiation with active light or radiation,” as a basic compound, it was confirmed that LWR was more excellent.

In addition, the acid generators used in Example 1-7 and Example 1-8 were compounds that generate an acid having a size with a volume of less than 240 Angstrom³, whereas the acid generators used in the other Examples were compounds that generate an acid having a size with a volume of 240 Angstrom³ or more. In comparison of these Examples, it was confirmed that EL was more excellent at a time of using the acid generators generating an acid having a size with a volume of 240 Angstrom³ or more.

On the other hand, in Comparative Examples 1-1 to 1-5 which did not satisfy the requirements of the present invention, it was confirmed that the “resolving power” was deteriorated. In particular, in Comparative Example 1-5 that corresponded to the aspect of JP2013-164588A, it was confirmed that desired effects were not obtained.

### Examples 2-1 to 2-21, and Comparative Examples 2-1 to 2-5 (Extreme Ultraviolet Rays (EUV) Exposure)

(4) Preparation and Application of Actinic Ray-Sensitive or Radiation-Sensitive Resin Composition

A composition having the compositional ratio shown in the following table was microfiltered using a membrane filter having a pore diameter of 0.05 μm, thereby obtaining an actinic ray-sensitive or radiation-sensitive resin composition (resist composition) having a solid content concentration of 2.0% by mass.

This actinic ray-sensitive or radiation-sensitive resin composition was coated on a 6-inch Si wafer that had been subjected to a hexamethyldisilazane (HMDS) treatment in advance, using a spin coater Mark 8 manufactured by Tokyo Electron Limited, and dried on a hot plate at 100° C. for 60 seconds, thereby obtaining a resist film having a film thickness of 50 nm.

(5) EUV Exposure and Development

The wafer having the resist film obtained above in (4) coated thereon was subjected to pattern exposure, using an a EUV exposure device (Micro Exposure Tool, manufactured by Exitech Corporation, NA0.3, Quadrupole, outer sigma of 0.68, inner sigma of 0.36), and employing an exposure mask (line/space=1/1). After the irradiation, the wafer was heated on a hot plate at 110° C. for 60 seconds and then developed by paddling the organic developer described in the following table for 30 seconds, and if necessary, rinsed by paddling using a rinsing liquid described in the following table (Examples in which a rinsing liquid is not described mean that rinsing was not carried out in the Examples) for 30 seconds. The wafer was rotated for 30 seconds at a rotation speed of 4,000 rpm, and then heated at 90° C. for 60 seconds, thereby obtaining a resist pattern with a 1:1 line-and-space pattern having a line width of 50 nm.

(6) Evaluation of Resist Pattern

The sensitivity and the resolving power of the obtained resist pattern were evaluated by the following method, using a scanning electron microscope (S-9380 II, manufactured by Hitachi, Ltd.). In addition, the amount of the film was also evaluated. The results are shown in the following table.

(6-1) Sensitivity

The exposure dose at a time when the 1:1 line-and-space pattern having a line width of 50 nm was resolved was taken as sensitivity (Eop). A smaller value thereof indicates better performance.

(6-2) Resolving Power

In the Eop, the line-and-space width was minimized, and the minimum line width (the minimum line width of the line portion) of the separated 1:1 line-and-space pattern was taken as resolving power. A smaller value thereof indicates better performance.

(6-3) Line Width Roughness (LWR)

Regarding the line width roughness, in the Eop, the line widths at arbitrary 50 points having a size of 0.5 μm in the longitudinal direction of a 1:1 line-and-space pattern having a line width of 50 nm were measured, the standard deviation thereof was determined, and 3σ was calculated. A smaller value thereof indicates better performance.

(6-4) Amount of Film Loss

After a series of processes were completed, the film thickness of the remaining resist film was measured, and the value obtained by subtracting the residual film thickness from the initial film thickness was taken as the amount (nm) of film loss. In addition, an optical interference film thickness measuring device (Lambda Ace, manufactured by SCREEN Holdings Co., Ltd.) was used for measurement of the film thickness.

(6-5) Exposure Latitude (EL)

The exposure dose at which a mask pattern of a line-and-space (line:space=1:1) having a line width of 50 nm was reproduced was determined and this was taken as the optimal exposure dose Eopt. Next, the exposure dose when the line width became ±10% of 50 nm (that is, 45 nm and 55 nm) which were desired values was determined. Then, the exposure latitude (EL) defined by the following equation was calculated. As the value of EL was increased, the change in performance due to a change in the exposure dose was decreased.

[EL (%)]=[(exposure dose when line width becomes 55 nm)−(exposure dose when line width becomes 45 nm)]/Eopt×100

(6-6) Dry Etching Resistance

The wafer having the resist film obtained in the above (4) coated thereon was subjected to overall irradiation, using an a EUV exposure device (Micro Exposure Tool manufactured by Exitech Corporation, NA0.3, Quadrupole, outer sigma of 0.68, inner sigma of 0.36). After the irradiation, the wafer was heated on a hot plate at 110° C. for 60 seconds, and developed by paddling the organic developer described in the following Table for 30 seconds, and if necessary, rinsed by paddling using the rinsing liquid described in the following Table for 30 seconds. The wafer was rotated for 30 seconds at a rotation speed of 4,000 rpm, and then heated at 90° C. for 60 seconds, thereby obtaining a resist film for dry etching evaluation.

The initial film thickness (FT1, Angstroms) of the resist film obtained above was measured. Subsequently, etching was carried out for 30 seconds while supplying C₄F₆ gas, using a dry etcher (U-621, manufactured by Hitachi High-Technologies Corporation). Thereafter, the film thickness (FT2, Angstroms) of the resist film obtained after the etching was measured. Then, the dry etching rate (DE) defined by the following equation was calculated.

[Dry etching rate(DE,Angstroms/sec)]=(FT1−FT2)/30

Superiority or inferiority of DE was evaluated according to the following criteria. A smaller value of DE indicates a smaller change in the film thickness due to etching.

A . . . Dry etching rate being less than 10 Angstroms/sec

B . . . Dry etching rate being 10 Angstroms/sec or more and less than 12 Angstroms/sec

C . . . Dry etching rate being 12 Angstroms/sec or more

TABLE 3

| | | | | | | | Organic | Surfactant | |
|---|---|---|---|---|---|---|---|---|---|
| | | | | | | | solvent | Type | |
| | Compound | | Acid generator | | Basic compound | | (mass | (mass | |
| | Type | Concentration | Type | Concentration | Type | Concentration | ratio) | ratio) | Concentration |
| Example 2-1 | A1 | 67.95 | Z-113 | 30 | N-7 | 2 | S1/S2 | W-1 | 0.05 |
| | | | | | | | (40/60) | | |
| Example 2-2 | A2 | 72.95 | Z-112 | 25 | N-12 | 2 | S1/S2 | W-1 | 0.05 |
| | | | | | | | (40/60) | | |
| Example 2-3 | A3 | 62.95 | Z-134 | 35 | N-12 | 2 | S1/S2 | W-1 | 0.05 |
| | | | | | | | (40/60) | | |
| Example 2-4 | A4 | 67.95 | Z-134 | 30 | N-7 | 2 | S1/S2 | W-1 | 0.05 |
| | | | | | | | (40/60) | | |
| Example 2-5 | A5 | 67.95 | Z-128 | 30 | N-12 | 2 | S1/S2 | W-2 | 0.05 |
| | | | | | | | (40/60) | | |
| Example 2-6 | A6 | 83.95 | Z-114 | 15 | N-12 | 1 | S1/S2 | W-4 | 0.05 |
| | | | | | | | (40/60) | | |
| Example 2-7 | A7 | 82.95 | Z-29 | 15 | N-1 | 2 | S1/S3 | W-4 | 0.05 |
| | | | | | | | (40/60) | | |
| Example 2-8 | A8 | 82.95 | Z-2 | 15 | N-2 | 2 | S1/S2 | W-1/W-2 | 0.05 |
| | | | | | | | (40/60) | (1/1) | |
| Example 2-9 | A9 | 78 | Z-108 | 20 | N-7 | 2 | S1/S2/S3 | None | |
| | | | | | | | (30/60/10) | | |
| Example 2-10 | A10 | 82.95 | Z-117 | 15 | N-12 | 2 | S1/S2 | W-3 | 0.05 |
| | | | | | | | (20/80) | | |
| Example 2-11 | A11 | 67.95 | Z-124 | 30 | N-12 | 2 | S1/S2 | W-1 | 0.05 |
| | | | | | | | (40/60) | | |
| Example 2-12 | A12 | 67.95 | Z-124 | 30 | N-7 | 2 | S1/S2 | W-1 | 0.05 |
| | | | | | | | (40/60) | | |
| Example 2-13 | A13 | 62.95 | Z-135 | 35 | N-7 | 2 | S1/S2 | W-3 | 0.05 |
| | | | | | | | (40/60) | | |
| Example 2-14 | A14 | 67.95 | Z-132 | 30 | N-12 | 2 | S1/S2 | W-1 | 0.05 |
| | | | | | | | (40/60) | | |
| Example 2-15 | A15 | 40.00 | Z-4/ | 25 | N-4 | 3 | S1/S2/S3 | None | |
| | P-1 | 32.00 | Z-112 = | | | | (30/60/10) | | |
| | | | 1:1 | | | | | | |
| Example 2-16 | A16 | 37.95 | Z-115 | 30 | N-11 | 2 | S1/S4 | W-1 | 0.05 |
| | P-2 | 30 | | | | | (40/60) | | |
| Example 2-17 | A17 | 37.95 | Z-99 | 30 | N-10 | 2 | S1/S4 | W-1 | 0.05 |
| | P-3 | 30.00 | | | | | (40/60) | | |
| Example 2-18 | A1 | 37.95 | Z-130 | 30 | N-9 | 2 | S1/S4 | W-1 | 0.05 |
| | P-4 | 30.00 | | | | | (40/60) | | |
| Example 2-19 | A16 | 36.95 | Z-124 | 30 | N-3 | 3 | S1/S4 | W-2 | 0.05 |
| | A13 | 30.00 | | | | | (40/60) | | |
| Example 2-20 | A1 | 36.95 | Z-113 | 30 | N-6 | 3 | S1/S2 | W-2 | 0.05 |
| | P-5 | 30.00 | | | | | (40/60) | | |
| Example 2-21 | A17 | 37.95 | Z-118 | 25 | N-8 | 2 | S1/S3 | W-3 | 0.05 |
| | P-5 | 30.00 | | | | | (40/60) | | |
| Comparative | R-1 | 67.95 | Z-2 | 30 | N-5 | 2 | S1/S2 | W-1 | 0.05 |
| Example 2-1 | | | | | | | (40/60) | | |
| Comparative | R-2 | 67.95 | Z-2 | 30 | N-5 | 2 | S1/S2 | W-1 | 0.05 |
| Example 2-2 | | | | | | | (40/60) | | |
| Comparative | R-3 | 37.95 | Z-2 | 30 | N-5 | 2 | S1/S2 | W-1 | 0.05 |
| Example 2-3 | P-1 | 30.00 | | | | | (40/60) | | |
| Comparative | R-4 | 47.95 | Z-2 | 10 | N-5 | 2 | S1/S2 | W-1 | 0.05 |
| Example 2-4 | P-1 | 40.00 | | | | | (40/60) | | |
| Comparative | A1 | 67.95 | Z-113 | 30 | N-7 | 2 | S1/S2 | W-1 | 0.05 |
| Example 2-5 | | | | | | | (40/60) | | |

| | | | Evaluation | | | | | |
|---|---|---|---|---|---|---|---|---|
| | | | | | | Amount | | Dry |
| | | Rinsing | Sensitivity | Resolving | LWR | of film | EL | etching |
| | Developer | liquid | (μC/cm²) | power (nm) | (nm) | loss(nm) | (%) | resistance |
| Example 2-1 | SG-3 | | 17.5 | 28 | 4.3 | 9.1 | 17.3 | A |
| Example 2-2 | SG-3 | | 17.0 | 28 | 4.4 | 9.2 | 18.1 | A |
| Example 2-3 | SG-4 | | 15.1 | 28 | 4.3 | 9.3 | 18.4 | A |
| Example 2-4 | SG-3 | | 17.0 | 28 | 4.4 | 9.9 | 17.6 | A |
| Example 2-5 | SG-3 | | 17.0 | 24 | 4.3 | 9.8 | 17.5 | A |
| Example 2-6 | SG-3 | SR-3 | 15.0 | 24 | 4.2 | 9.7 | 16.8 | A |
| Example 2-7 | SG-3 | SR-2 | 18.0 | 25 | 4.7 | 9.7 | 15.8 | A |
| Example 2-8 | SG-2 | | 18.0 | 25 | 4.7 | 9.6 | 15.7 | A |
| Example 2-9 | SG-1 | SR-3 | 17.5 | 23 | 4.2 | 7.7 | 16.4 | A |
| Example 2-10 | SG-3 | SR-1 | 17.0 | 22 | 4.3 | 7.6 | 17.2 | A |
| Example 2-11 | SG-3 | | 18.0 | 22 | 4.2 | 7.7 | 20.1 | A |
| Example 2-12 | SG-3 | | 17.0 | 22 | 4.2 | 7.5 | 19.4 | A |
| Example 2-13 | SG-4 | | 17.5 | 22 | 4.2 | 7.8 | 20.0 | A |
| Example 2-14 | SG-3 | | 17.0 | 22 | 4.3 | 7.6 | 18.2 | A |
| Example 2-15 | SG-3 | | 18.0 | 28 | 4.8 | 10.3 | 17.8 | B |
| Example 2-16 | SG-3 | | 18.0 | 28 | 4.9 | 10.5 | 19.2 | B |
| Example 2-17 | SG-3 | | 18.0 | 27 | 4.8 | 10.3 | 18.2 | B |
| Example 2-18 | SG-4 | | 17.0 | 27 | 4.7 | 9.1 | 18.7 | A |
| Example 2-19 | SG-3 | | 17.0 | 24 | 4.8 | 8.9 | 18.7 | A |
| Example 2-20 | SG-3 | | 18.0 | 27 | 4.8 | 8.4 | 19.2 | A |
| Example 2-21 | SG-3 | | 17.0 | 28 | 4.7 | 10.1 | 17.0 | B |
| Comparative | SG-3 | | 20.0 | 36 | 5.4 | 12.6 | 15.3 | B |
| Example 2-1 | | | | | | | | |
| Comparative | TM-1 | | 22.0 | 34 | 5.2 | 17.2 | 13.5 | B |
| Example 2-2 | | | | | | | | |
| Comparative | SG-3 | | 21.0 | 38 | 5.5 | 15.4 | 14.2 | C |
| Example 2-3 | | | | | | | | |
| Comparative | SG-3 | | 23.0 | 38 | 5.7 | 16.4 | 13.2 | C |
| Example 2-4 | | | | | | | | |
| Comparative | TM-3 | | 17.5 | 40 | 5.2 | 12.6 | 15.3 | A |
| Example 2-5 | | | | | | | | |

The concentrations of the respective components represent the concentrations (% by mass) in the total concentration of the solid contents.

As shown in Table 3, in the pattern forming methods of Examples 2-1 to 2-21, it was confirmed that the “resolving power” was excellent.

Above all, as seen from comparison between Example 2-1 to Example 2-4 and Example 2-5 to Example 2-14, in a case of Example 2-5 to Example 2-14 in which the compound had a repeating unit having a group that decomposes by the action of an acid to generate a polar group, it was confirmed that the “resolving power” was excellent.

Furthermore, in a case of using N-7 and N-12 which are each “a compound having a functional group with proton acceptor properties and generating a compound in which the proton-acceptability is reduced or lost, or which is changed from being proton-accepting to be acidic, by being decomposed upon irradiation with active light or radiation,” as a basic compound, it was confirmed that LWR was more excellent.

On the other hand, in Comparative Examples 2-1 to 2-5 which did not satisfy the requirements of the present invention, it was confirmed that the “resolving power” was deteriorated. In particular, in Comparative Example 2-5 that corresponded to the aspect of JP2013-164588A, it was confirmed that desired effects were not obtained.

What is claimed is:

1. A pattern forming method comprising:
forming a film using an actinic ray-sensitive or radiation-sensitive resin composition;
exposing the film with active light or radiation; and
developing the exposed film using a developer including an organic solvent,
wherein the actinic ray-sensitive or radiation-sensitive resin composition contains a compound having a partial structure represented by the following General Formula (I), 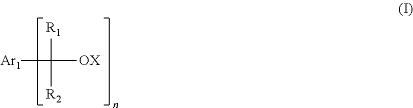
in General Formula (I),
Ar₁ represents an aromatic ring group or an alicyclic group,
R₁ and R₂ each independently represent an alkyl group, a cycloalkyl group, or an aryl group,
X represents a hydrogen atom, an alkyl group, a cycloalkyl group, an aryl group, or an acyl group, and
n represents an integer of 1 or more.

2. The pattern forming method according to claim 1, wherein the compound is a resin having a partial structure represented by General Formula (I) and a repeating unit represented by General Formula (II), 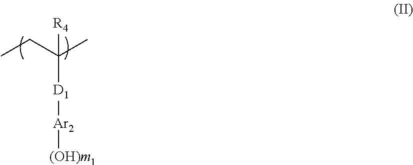
in General Formula (II),
R₄ represents a hydrogen atom, an organic group, or a halogen atom,
Ar₂ represents an aromatic ring group,
D₁ represents a single bond or a divalent linking group, and
m₁ represents an integer of 1 or more.

3. The pattern forming method according to claim 2, wherein the compound is a resin having a repeating unit represented by General Formula (II) and a repeating unit represented by General Formula (III), 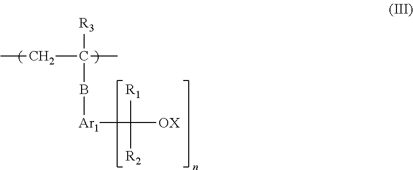
in General Formula (III),
R₃ represents a hydrogen atom, an organic group, or a halogen atom,
Ar₁ represents an aromatic ring group or an alicyclic group,
R₁ and R₂ each independently represent an alkyl group, a cycloalkyl group, or an aryl group,
B represents a single bond or a divalent linking group,
X represents a hydrogen atom, an alkyl group, a cycloalkyl group, an aryl group, or an acyl group, and
n represents an integer of 1 or more.

4. The pattern forming method according to claim 3, wherein the compound is a resin containing a repeating unit represented by any one of General Formulae (IVa) to (IVc), a repeating unit represented by General Formula (II), and a repeating unit represented by General Formula (III), 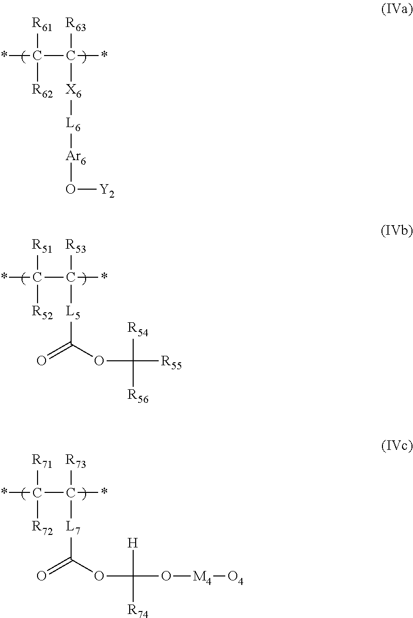
in General Formula (IVa),
R₆₁, R₆₂, and R₆₃ each independently represent a hydrogen atom, an alkyl group, a cycloalkyl group, a halogen atom, a cyano group, or an alkoxycarbonyl group, R₆₂ may be bonded to Ar₆ to form a ring, and R₆₂ in this case represents a single bond or an alkylene group,
X₆ represents a single bond, —COO—, or —CONR₆₄—, and R₆₄ represents a hydrogen atom or an alkyl group,
L₆ represents a single bond or an alkylene group,
Ar₆ represents a divalent aromatic ring group, and in the case of being bonded to R₆₂ to form a ring, Ar₆ represents a trivalent aromatic ring group, and
Y₂ represents a group that leaves by the action of an acid;
in General Formula (IVb),
R₅₁, R₅₂, and R₅₃ each independently represent a hydrogen atom, an alkyl group, a cycloalkyl group, a halogen atom, a cyano group, or an alkoxycarbonyl group, R₅₂ may be bonded to L₅ to form a ring, and R₅₂ in this case represents an alkylene group,
L₅ represents a single bond or a divalent linking group, and in a case of being bonded to R₅₂ to form a ring, L₅ represents a trivalent linking group, and
R₅₄ represents an alkyl group, and R₅₅ and R₅₆ each independently represent a hydrogen atom, an alkyl group, a cycloalkyl group, an aryl group, or an aralkyl group, R₅₅ and R₅₆ may be bonded to each other to form a ring, but R₅₅ and R₅₆ are each not a hydrogen atom at the same time in any case; and
in General Formula (IVc),
R₇₁, R₇₂, and R₇₃ each independently represent a hydrogen atom, an alkyl group, a cycloalkyl group, a halogen atom, a cyano group, or an alkoxycarbonyl group, R₇₂ may be bonded to L₇ to form a ring, and R₇₂ in this case represents an alkylene group,
L₇ represents a single bond or a divalent linking group, and in the case of forming a ring with R₇₂, L₇ represents a trivalent linking group,
R₇₄ represents a hydrogen atom, an alkyl group, a cycloalkyl group, an aryl group, an aralkyl group, an alkoxy group, an acyl group, or a heterocyclic group,
M₄ represents a single bond or a divalent linking group,
Q₄ represents an alkyl group, a cycloalkyl group, an aryl group, or a heterocyclic group, and
at least two members out of Q₄, M₄, or R₇₄ may be bonded to each other to form a ring.

5. The pattern forming method according to claim 1, wherein the actinic ray-sensitive or radiation-sensitive resin composition further comprises a compound that generates an acid by active light or radiation.

6. The pattern forming method according to claim 5, wherein the compound that generates an acid by active light or radiation is a compound that generates an acid in a size for a volume of 240 Angstrom³ or more.

7. The pattern forming method according to claim 1, which uses electron beams or extreme ultraviolet rays as the active light or radiation.

8. A method for manufacturing an electronic device, comprising the pattern forming method according to claim 1.

9. An actinic ray-sensitive or radiation-sensitive resin composition comprising a resin that contains a repeating unit represented by General Formula (II), a repeating unit represented by General Formula (III), and a repeating unit having a group that decomposes by the action of an acid to generate a polar group, 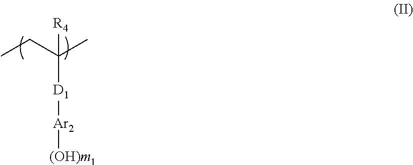
in General Formula (II),
R₄ represents a hydrogen atom, an organic group, or a halogen atom,
Ar₂ represents an aromatic ring group,
D₁ represents a single bond or a divalent linking group, and
m₁ represents an integer of 1 or more; and 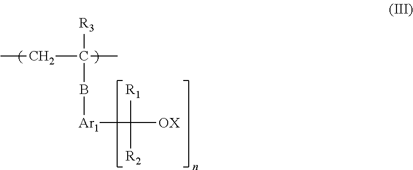
in General Formula (III),
R₃ represents a hydrogen atom, an organic group, or a halogen atom,
Ar₁ represents an aromatic ring group or an alicyclic group,
R₁ and R₂ each independently represent an alkyl group, a cycloalkyl group, or an aryl group,
B represents a single bond or a divalent linking group,
X represents a hydrogen atom, an alkyl group, a cycloalkyl group, an aryl group, or an acyl group, and
n represents an integer of 1 or more.

10. The actinic ray-sensitive or radiation-sensitive resin composition according to claim 9, wherein the repeating unit having a group that decomposes by the action of an acid to generate a polar group includes a repeating unit represented by any one of General Formulae (IVa) to (IVc), 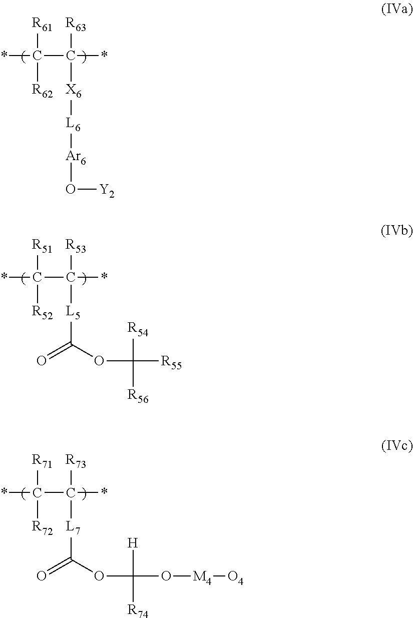
in General Formula (IVa),
R₆₁, R₆₂, and R₆₃ each independently represent a hydrogen atom, an alkyl group, a cycloalkyl group, a halogen atom, a cyano group, or an alkoxycarbonyl group, R₆₂ may be bonded to Ar₆ to form a ring, and R₆₂ in this case represents a single bond or an alkylene group,
X₆ represents a single bond, —COO—, or —CONR₆₄—, and R₆₄ represents a hydrogen atom or an alkyl group,
L₆ represents a single bond or an alkylene group,
Ar₆ represents a divalent aromatic ring group, and in the case of being bonded to R₆₂ to form a ring, Ar₆ represents a trivalent aromatic ring group, and
Y₂ represents a group that leaves by the action of an acid;
in General Formula (IVb),
R₅₁, R₅₂, and R₅₃ each independently represent a hydrogen atom, an alkyl group, a cycloalkyl group, a halogen atom, a cyano group, or an alkoxycarbonyl group, R₅₂ may be bonded to L₅ to form a ring, and R₅₂ in this case represents an alkylene group,
L₅ represents a single bond or a divalent linking group, and in a case of being bonded to R₅₂ to form a ring, L₅ represents a trivalent linking group, and
R₅₄ represents an alkyl group, and R₅₅ and R₅₆ each independently represent a hydrogen atom, an alkyl group, a cycloalkyl group, an aryl group, or an aralkyl group, R₅₅ and R₅₆ may be bonded to each other to form a ring, but R₅₅ and R₅₆ are each not a hydrogen atom at the same time in any case; and
in General Formula (IVc),
R₇₁, R₇₂, and R₇₃ each independently represent a hydrogen atom, an alkyl group, a cycloalkyl group, a halogen atom, a cyano group, or an alkoxycarbonyl group, R₇₂ may be bonded to L₇ to form a ring, and R₇₂ in this case represents an alkylene group,
L₇ represents a single bond or a divalent linking group, and in the case of forming a ring with R₇₂, L₇ represents a trivalent linking group,
R₇₄ represents a hydrogen atom, an alkyl group, a cycloalkyl group, an aryl group, an aralkyl group, an alkoxy group, an acyl group, or a heterocyclic group,
M₄ represents a single bond or a divalent linking group,
Q₄ represents an alkyl group, a cycloalkyl group, an aryl group, or a heterocyclic group, and
at least two members out of Q₄, M₄, or R₇₄ may be bonded to each other to form a ring.

11. A resist film formed by using the actinic ray-sensitive or radiation-sensitive resin composition according to claim 9.

12. A mask blank comprising the resist film according to claim 11.
